(19) United States
(12) Patent Application Publication
(10) Pub. No.: US 2025/0098518 A1
(43) Pub. Date: Mar. 20, 2025

(54) COMPOSITION, LIGHT-EMITTING DEVICE, ELECTRONIC APPARATUS INCLUDING THE LIGHT-EMITTING DEVICE, AND ORGANOMETALLIC COMPOUND

(71) Applicant: Samsung Display Co., Ltd., Yongin-si (KR)

(72) Inventors: Chanseok Oh, Yongin-si (KR); Iljoon Kang, Yongin-si (KR); Soobyung Ko, Yongin-si (KR); Haejin Kim, Yongin-si (KR); Sujin Shin, Yongin-si (KR); Sooinn Lee, Yongin-si (KR); Eunyoung Lee, Yongin-si (KR); Mina Jeon, Yongin-si (KR)

(21) Appl. No.: 18/830,437

(22) Filed: Sep. 10, 2024

(30) Foreign Application Priority Data
Sep. 12, 2023 (KR) 10-2023-0121344

(51) Int. Cl. H10K 85/30; C07F 15/00; C09K 11/02; C09K 11/06; H10K 50/12; H10K 85/40; H10K 101/00

(52) U.S. Cl. CPC H10K 85/346; C07F 15/0086; C09K 11/02; C09K 11/06; H10K 85/40; C09K 2211/1007; C09K 2211/1022; C09K 2211/1029; C09K 2211/1044; C09K 2211/185; H10K 50/12; H10K 2101/90

(57) ABSTRACT

An organometallic compound, and a composition and a light-emitting device each including the organometallic compound are provided. An electronic apparatus including the light-emitting device is also provided.

### CROSS-REFERENCE TO RELATED APPLICATION

This application claims priority to and the benefit of Korean Patent Application No. 10-2023-0121344, filed on Sep. 12, 2023, in the Korean Intellectual Property Office, the entire content of which is incorporated by reference herein.

### BACKGROUND

### 1. Field

One or more aspects of embodiments of the present disclosure relate to a composition, a light-emitting device, an electronic apparatus including the light-emitting device, and an organometallic compound.

### 2. Description of the Related Art

So-called “self-emissive” devices (for example, organic light-emitting devices) in light-emitting devices have relatively wide viewing angles, relatively high contrast ratios, relatively short response times, and have excellent or suitable characteristics in terms of luminance, driving voltage, and/or response speed.

In a light-emitting device, a first electrode is arranged on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. These excitons may then transition (i.e., relax) from an excited state to a ground state to thereby generate light.

### SUMMARY

One or more aspects of embodiments of the present disclosure are directed toward a composition and an organometallic compound, which are capable of providing improved color purity, improved luminescence efficiency, and/or improved lifespan, a light-emitting device having improved color purity, improved luminescence efficiency, and/or improved lifespan, and an electronic apparatus including the light-emitting device.

Additional aspects will be set forth in part in the description which follows and, in part, will be apparent from the description, or may be learned by practice of the presented embodiments of the disclosure.

According to one or more embodiments,
a composition includes:
an organometallic compound represented by Formula 1; and
a second compound including at least one π electron-deficient nitrogen-containing C₁-C₆₀ heterocyclic group, a third compound including a group represented by Formula 3, a fourth compound capable of emitting delayed fluorescence, or a (e.g., any) combination thereof,
wherein the organometallic compound, the second compound, the third compound, and the fourth compound may be different from each other.

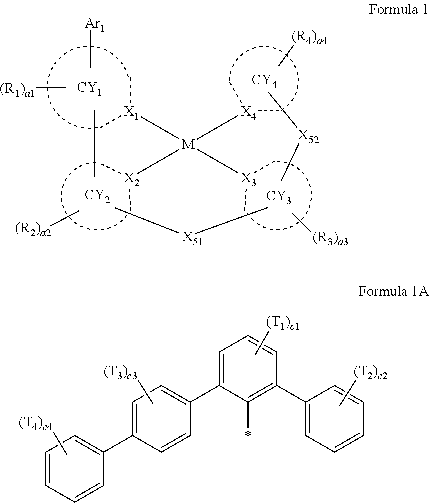

Ar₁ in Formula 1 may be a group represented by Formula 1A,
* in Formula 1A indicates a binding site to ring CY₁ in Formula 1,
in Formulae 1 and 1A,
M may be platinum (Pt), palladium (Pd), gold (Au), nickel (Ni), silver (Ag), or copper (Cu),
X₁ to X₄ may each independently be C or N,
i) a bond between X₁ and M may be a coordinate bond, ii) one selected from among a bond between X₂ and M, a bond between X₃ and M, and a bond between X₄ and M may be a coordinate bond, and two selected from among the bond between X₂ and M, the bond between X₃ and M, and the bond between X₄ and M is each a covalent bond, (e.g., the other two bonds may each be a covalent bond), for example, each of a bond between X₂ and M, a bond between X₃ and M, and a bond between X₄ and M may be a coordinate bond or a covalent bond, wherein one of the bonds is a coordinate bond,
ring CY₁ to ring CY₄ may each independently be a C₃-C₆₀ carbocyclic group or a C₁-C₆₀ heterocyclic group,
X₅₁ may be a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, *—O—*′, *—C(═O)—*′, *—S(=O)—*′, *—S(═O)₂—*′, *—C(Z₅₁ₐ)═*′, *=C(Z₅₁ₐ)—*′, *—C(Z₅₁ₐ)═C(Z_{51b})—*′, *—C(═S)—*′, or *—C≡C—*′,
X₅₂ may be a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′, *—O—*′, *—C(═O)—*′, *—S(=O)—*′, *—S(═O)₂—*′, *—C(Z₅₂ₐ)=*′, *=C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, Z_{52b}, and T₁ to T₄ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a1 to a4 may each independently be an integer from 0 to 10,
c1 may be an integer from 1 to 3,
c2 and c4 may each independently be an integer from 1 to 5,
c3 may be an integer from 1 to 4,
in Formula 1A, a group represented by

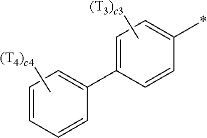

and a group represented by

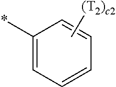

may be different from each other,
two or more selected from among R₁, R₂, R₃, R₄, Z₅₁ₐ, Z_{51b}, Z₅₂ₐ, Z_{52b}, T₁, T₂, T₃, and T₄ may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
* and *′ each indicate a binding site to a neighboring atom,
R₁₀ₐ may be:
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a (e.g., any) combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any) combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a (e.g., any) combination thereof.

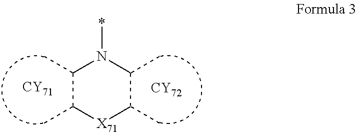

In Formula 3,
ring CY₇₁ and ring CY₇₂ may each independently be a π electron-rich C₃-C₆₀ cyclic group or a pyridine group,
X₇₁ may be a single bond, or a linking group including O, S, N, B, C, Si, or a (e.g., any) combination thereof, and
* in Formula 3 indicates a binding site to an atom in the third compound that is not included in Formula 3 (e.g., a (e.g., any) atom included in remaining moieties other than Formula 3 in the third compound).

According to one or more embodiments,
a light-emitting device includes a first electrode,
a second electrode facing the first electrode,
an interlayer arranged between the first electrode and the second electrode and including an emission layer, and
the organometallic compound represented by Formula 1.

According to one or more embodiments, an electronic apparatus includes the light-emitting device.

According to one or more embodiments, electronic equipment includes the light-emitting device.

According to one or more embodiments, provided is the organometallic compound represented by Formula 1.

### BRIEF DESCRIPTION OF THE DRAWINGS

The accompanying drawings are included to provide a further understanding of the preceding and other aspects, features, and advantages of certain embodiments of the disclosure are incorporated in and constitute a part of this specification. The drawings illustrate example embodiments and, together with the following description taken in conjunction with the accompanying drawings, serve to make the principles of the present disclosure more apparent. In the drawings:

FIG. 1 is a schematic view of a structure of a light-emitting device according to one or more embodiments of the present disclosure;

FIGS. 2 and 3 are each a schematic view of a structure of a light-emitting apparatus which is one of electronic apparatuses, according to one or more embodiments of the present disclosure; and

FIG. 4 is a schematic perspective view of electronic equipment including a light-emitting device according to one or more embodiments of the present disclosure;

FIG. 5 is a schematic perspective view of the exterior of a vehicle as electronic equipment including a light-emitting device according to one or more embodiments of the present disclosure; and

FIGS. 6A-6C are each a schematic view of the interior of a vehicle that includes electronic equipment including a light-emitting device according to one or more embodiments of the present disclosure.

### DETAILED DESCRIPTION

Reference will now be made in more detail to embodiments, examples of which are illustrated in the accompanying drawings, wherein like reference numerals refer to like elements throughout, and duplicative descriptions thereof may not be provided the specification. In this regard, the present embodiments may have different forms and should not be construed as being limited to the descriptions set forth herein. Accordingly, the embodiments are merely described, by referring to the drawings, to explain aspects of the present description. As utilized herein, the term “and/or” includes any and all combinations of one or more of the associated listed items. Expressions such as “at least one of,” “one of,” and “selected from,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, etc. may be used herein to describe various elements, these elements should not be limited by these terms. These terms are only used to distinguish one element from another element. Thus, a first element could be termed a second element without departing from the teachings of the present disclosure. Similarly, a second element could be termed a first element.

As used herein, singular forms such as “a,” “an,” and “the” are intended to include the plural forms as well, unless the context clearly indicates otherwise.

It will be further understood that the terms “comprise,” “comprises,” “comprising,” “has,” “have,” “having,” “include,” “includes,” and/or “including,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, the term “and/or” includes any, and all, combination(s) of one or more of the associated listed items.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

It will be understood that when an element is referred to as being “on,” “connected to,” or “on” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

In this context, “consisting essentially of” means that any additional components will not materially affect the chemical, physical, optical or electrical properties of the semiconductor film.

In present disclosure, “not include (or not including) a or any ‘component’”, “exclude (or excluding) a or any ‘component’”, “‘component’-free”, and/or the like refers to that the “component” not being added, selected or utilized as a component in the element/composition, but the “component” of less than a suitable amount may still be included due to other impurities and/or external factors.

Further, in this specification, the phrase “on a plane,” or “plan view,” means viewing a target portion from the top, and the phrase “on a cross-section” means viewing a cross-section formed by vertically cutting a target portion from the side.

### Composition

According to one or more embodiments,
a composition includes: an organometallic compound represented by Formula 1; and
a second compound including at least one π electron-deficient nitrogen-containing C₁-C₆₀ heterocyclic group, a third compound including a group represented by Formula 3, a fourth compound capable of emitting delayed fluorescence, or a (e.g., any) combination thereof,
wherein the organometallic compound, the second compound, the third compound, and the fourth compound may be different from each other:

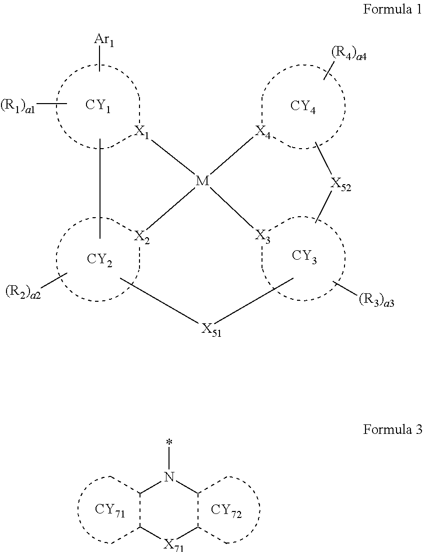

wherein, in Formula 3,
ring CY₇₁ and ring CY₇₂ may each independently be a π electron-rich C₃-C₆₀ cyclic group or a pyridine group,
X₇₁ may be a single bond, or a linking group including O, S, N, B, C, Si, or any combination thereof, and
* in Formula 3 indicates a binding site to an atom in the third compound that is not included in Formula 3 (e.g., a (e.g., any) atom included in remaining moieties other than Formula 3 in the third compound).

The organometallic compound represented by Formula 1 as utilized herein may be referred to as a “first compound.”

Formula 1 and Formula 3 are each as described herein.

In one or more embodiments, the composition may be included in a layer. The “layer including the composition” may include a mixture including 1) the organometallic compound and 2) the second compound, the third compound, the fourth compound, or any combination thereof. Therefore, the “layer including the composition” is clearly distinguished from, for example, a double layer including 1) a first layer including the organometallic compound and 2) a second layer including the second compound, the third compound, the fourth compound, or any combination thereof.

In one or more embodiments, the composition may be a composition prepared to form a layer including 1) the organometallic compound and 2) the second compound, the third compound, the fourth compound, or any combination thereof by utilizing one or more suitable methods such as a deposition method, a wet process, and/or the like. In one or more embodiments, the composition may be a pre-mixed mixture prepared for utilizing in a deposition method (for example, a vacuum deposition method). The pre-mixed mixture may be charged, for example, into a deposition source within a vacuum chamber, and two or more compounds included in the pre-mixed mixture may be co-deposited.

In one or more embodiments, a weight ratio of the organometallic compound and the second compound in the composition may be 10:90 to 90:10 or 20:80 to 80:20.

According to one or more embodiments, a light-emitting device includes: a first electrode;
a second electrode facing the first electrode;
an interlayer arranged between the first electrode and the second electrode and including an emission layer; and
the organometallic compound represented by Formula 1.

Formula 1 is as described herein.

The light-emitting device includes the organometallic compound represented by Formula 1, and thus, may have improved color purity, improved luminescence efficiency, and improved lifespan characteristics.

In one or more embodiments, the interlayer in the light-emitting device may include the organometallic compound.

In one or more embodiments, the emission layer in the light-emitting device may include the organometallic compound.

In one or more embodiments, the light-emitting device may further include a second compound including at least one π electron-deficient nitrogen-containing C₁-C₆₀ heterocyclic group, a third compound including a group represented by Formula 3, a fourth compound capable of emitting delayed fluorescence, or a (e.g., any) combination thereof, and
the organometallic compound, the second compound, the third compound, and the fourth compound in the light-emitting device may be different from each other.

The second compound to the fourth compound in the composition and the light-emitting device are each as described herein.

In one or more embodiments, the organometallic compound may include at least one deuterium.

In one or more embodiments, the second compound to the fourth compound may each include at least one deuterium.

In one or more embodiments, the second compound may include at least one silicon.

In one or more embodiments, the third compound may include at least one silicon.

In one or more embodiments, the composition and the light-emitting device (for example, the emission layer in the light-emitting device) may each further include a second compound and a third compound, in addition to the organometallic compound represented by Formula 1, and at least one of the second compound and the third compound may include at least one deuterium, at least one silicon, or a combination thereof.

In one or more embodiments, the composition and the light-emitting device (for example, the emission layer in the light-emitting device) may each further include a second compound, in addition to the organometallic compound. At least one of the organometallic compound and the second compound may include at least one deuterium. In one or more embodiments, each of the composition and the light-emitting device (for example, the emission layer in the light-emitting device) may further include a third compound, a fourth compound, or any combination thereof, in addition to the organometallic compound and the second compound.

In one or more embodiments, the composition and the light-emitting device (for example, the emission layer in the light-emitting device) may each further include a third compound, in addition to the organometallic compound. At least one of the organometallic compound and the third compound may include at least one deuterium. In one or more embodiments, each of the composition and the light-emitting device (for example, the emission layer in the light-emitting device) may further include a second compound, a fourth compound, or any combination thereof, in addition to the organometallic compound and the third compound.

In one or more embodiments, the composition and the light-emitting device (for example, the emission layer in the light-emitting device) may each further include a fourth compound, in addition to the organometallic compound. At least one of the organometallic compound and the fourth compound may include at least one deuterium. The fourth compound may serve to improve color purity, luminescence efficiency, and lifespan characteristics of the light-emitting device. In one or more embodiments, each of the composition and the light-emitting device (for example, the emission layer in the light-emitting device) may further include a second compound, a third compound, or any combination thereof, in addition to the organometallic compound and the fourth compound.

In one or more embodiments, the composition and the light-emitting device (for example, the emission layer in the light-emitting device) may each further include a second compound and a third compound, in addition to the organometallic compound. The second compound and the third compound may form an exciplex. At least one of the organometallic compound, the second compound, and the third compound may include at least one deuterium.

In one or more embodiments, a highest occupied molecular orbital (HOMO) energy level of the organometallic compound may be about −5.35 electron volt (eV) to about −5.15 eV or about −5.30 eV to about −5.20 eV.

In one or more embodiments, a lowest unoccupied molecular orbital (LUMO) energy level of the organometallic compound may be about −2.20 eV to about −1.80 eV or about −2.15 eV to about −1.90 eV.

The HOMO and LUMO energy levels may be evaluated via cyclic voltammetry analysis (for example, Evaluation Example 1 as described herein) for the organometallic compound.

In one or more embodiments, the maximum emission wavelength (or emission peak wavelength) of the photoluminescence (PL) spectrum in a film of the organometallic compound may be about 430 nanometer (nm) to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, about 450 nm to about 465 nm, about 430 nm to about 460 nm, about 440 nm to about 460 nm, or about 450 nm to about 460 nm.

In one or more embodiments, the emission full width at half maximum (FWHM) of the PL spectrum in a film of the organometallic compound may be 40 nm or less, about 5 nm to about 40 nm, about 10 nm to about 40 nm, about 15 nm to about 40 nm, about 20 nm to about 40 nm, about 5 nm to about 38 nm, about 10 nm to about 38 nm, about 15 nm to about 38 nm, or about 20 nm to about 38 nm.

In one or more embodiments, the photoluminescence quantum yield (PLQY) in a film of the organometallic compound may be about 50% to about 99% or about 55% to about 90%.

In one or more embodiments, the decay time of the organometallic compound may be about 1.80 microsecond (μs) to about 3.00 μs, about 1.90 μs to about 2.70 μs, or about 1.90 μs to about 2.50 μs.

The maximum emission wavelength, emission FWHM, PLQY, and decay time of the organometallic compound were evaluated for a film including the organometallic compound, and an evaluation method thereof is as described in connection with, for example, Evaluation Examples 2 and 3 as described herein.

In one or more embodiments, the emission layer of the light-emitting device may include: i) the organometallic compound; and ii) the second compound, the third compound, the fourth compound, or any combination thereof, and the emission layer may be to emit blue light.

In one or more embodiments, the maximum emission wavelength of the blue light may be about 430 nm to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, or about 450 nm to about 465 nm.

In one or more embodiments, the emission FWHM of the blue light may be 40 nm or less, about 5 nm to about 40 nm, about 10 nm to about 40 nm, about 15 nm to about 40 nm, about 20 nm to about 40 nm, about 5 nm to about 38 nm, about 10 nm to about 38 nm, about 15 nm to about 38 nm, or about 20 nm to about 38 nm.

In one or more embodiments, the blue light may be deep blue light.

In one or more embodiments, the CIEx coordinate (for example, the bottom emission CIEx coordinate) of the blue light may be about 0.125 to about 0.140 or about 0.130 to about 0.140.

In one or more embodiments, the CIEy coordinate (for example, the bottom emission CIEy coordinate) of the blue light may be about 0.100 to about 0.130.

Examples of the maximum emission wavelength and CIEy coordinate of the blue light are as described herein in Tables 7 and 9.

In one or more embodiments, the second compound may include a pyridine group, a pyrimidine group, a pyrazine group, a pyridazine group, a triazine group, or any combination thereof.

In one or more embodiments, the following compounds may be excluded from the third compound.

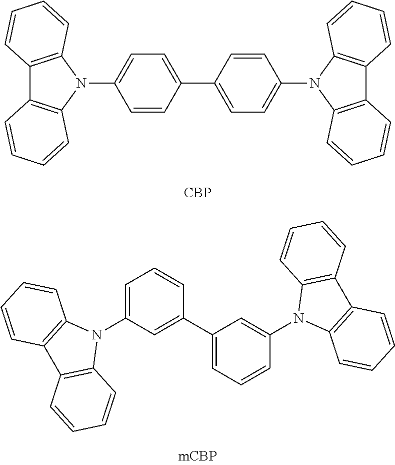 [SMILES: c1ccc2c(c1)c1ccccc1n2-c1ccc(-c2ccc(-n3c4ccccc4c4ccccc43)cc2)cc1 ; "CBP" ; c1cc(-c2cccc(-n3c4ccccc4c4ccccc43)c2)cc(-n2c3ccccc3c3ccccc32)c1]

In one or more embodiments, a difference between the triplet energy level (eV) of the fourth compound and the singlet energy level (eV) of the fourth compound may be about 0 eV or higher and about 0.5 eV or lower (or, about 0 eV or higher and about 0.3 eV or lower).

In one or more embodiments, the fourth compound may include at least one cyclic group including each of boron (B) and nitrogen (N) as a ring-forming atom.

In one or more embodiments, the fourth compound may be a C₈-C₆₀ polycyclic group-containing compound including at least two condensed cyclic groups that share boron (B).

In one or more embodiments, the fourth compound may include a condensed ring in which at least one third ring and at least one fourth ring are condensed together,
the third ring may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and
the fourth ring may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or a 1,4-dihydroborinine group.

In one or more embodiments, the third compound may not include (e.g., may exclude) a compound represented by Formula 3-1 described herein.

In one or more embodiments, the second compound may include a compound represented by Formula 2:

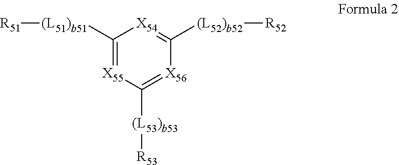

wherein, in Formula 2,

L₅₁ to L₅₃ may each independently be a single bond, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
b51 to b53 may each independently be an integer from 1 to 5,
X₅₄ may be N or C(R₅₄), X₅₅ may be N or C(R₅₅), X₅₆ may be N or C(R₅ₛ), and at least one of X₅₄ to X₅₆ may be N, and
R₅₁ to R₅₆ and R₁₀ₐ are each as described herein.

In one or more embodiments, the third compound may include a compound represented by Formula 3-1, a compound represented by Formula 3-2, a compound represented by Formula 3-3, a compound represented by Formula 3-4, a compound represented by Formula 3-5, or any combination thereof:

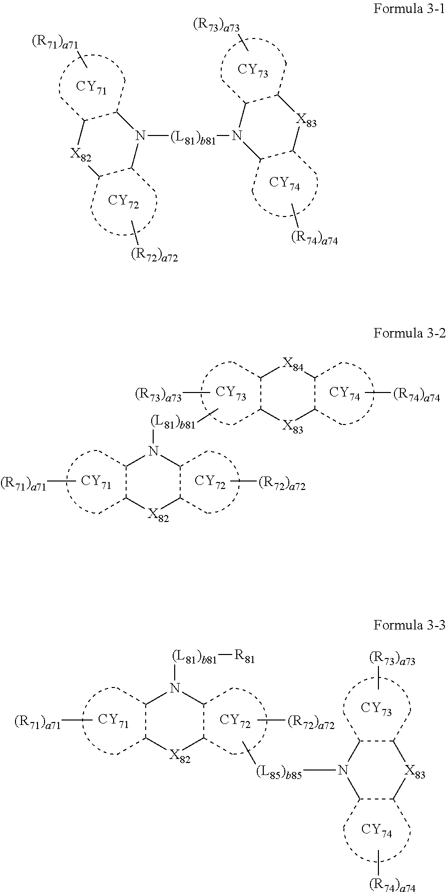

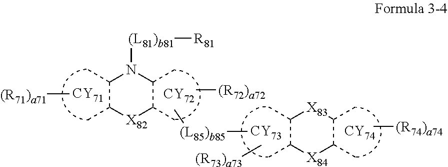

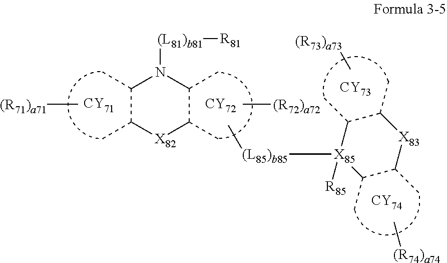

wherein, in Formulae 3-1 to 3-5,
ring CY₇₁ to ring CY₇₄ may each independently be a π electron-rich C₃-C₆₀ cyclic group or a pyridine group,
X₈₂ may be a single bond, O, S, N-[(L₈₂)_{b82}-R₈₂], C(R₈₂ₐ)(R_{82b}), or Si(R₈₂ₐ)(R_{82b}),
X₈₃ may be a single bond, O, S, N-[(L₈₃)_{b83}-R₈₃], C(R₈₃ₐ)(R_{83b}), or Si(R₈₃ₐ)(R_{83b}),
X₈₄ may be O, S, N-[(L₈₄)_{b84}-R₈₄], C(R₈₄ₐ)(R_{84b}), or Si(R₈₄ₐ)(R_{84b}),
X₈₅ may be C or Si,
L₈₁ to L₈₅ may each independently be a single bond, *—C(Q₄)(Q₅)-*′, *—Si(Q₄)(Q₅)-*′, a π electron-rich C₃-C₆₀ cyclic group that is unsubstituted or substituted with at least one R₁₀ₐ or a pyridine group that is unsubstituted or substituted with at least one R₁₀ₐ, wherein Q₄ and Q₅ are each as described in connection with Q₁,
b81 to b85 may each independently be an integer from 1 to 5,
R₇₁ to R₇₄, R₈₁ to R₈₅, R₈₂ₐ, R_{82b}, R₈₃ₐ, R_{83b}, R₈₄ₐ, and R_{84b} are each as described herein,
a71 to a74 may each independently be an integer from 0 to 20, and
R₁₀ₐ is as described herein.

In one or more embodiments, the fourth compound may include a compound represented by Formula 502, a compound represented by Formula 503, or a (e.g., any) combination thereof:

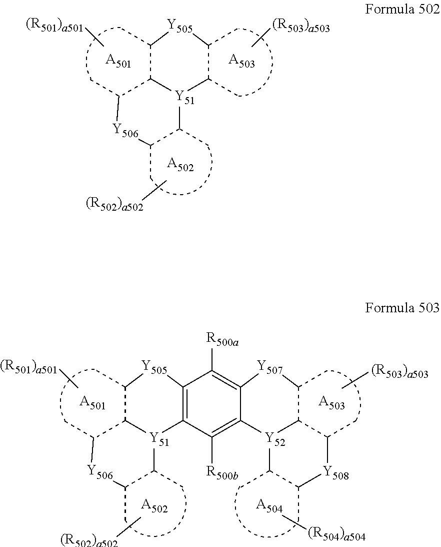

wherein, in Formulae 502 and 503,
ring A₅₀₁ to ring A₅₀₄ may each independently be a C₃-C₆₀ carbocyclic group or a C₁-C₆₀ heterocyclic group,
Y₅₀₅ may be O, S, N(R₅₀₅), B(R₅₀₅), C(R₅₀₅ₐ)(R_{505b}), or Si(R₅₀₅ₐ)(R_{505b}),
Y₅₀₆ may be O, S, N(R₅₀₆), B(R₅₀₆), C(R₅₀₆ₐ)(R_{506b}), or Si(R₅₀₆ₐ)(R_{506b}),
Y₅₀₇ may be O, S, N(R₅₀₇), B(R₅₀₇), C(R₅₀₇ₐ)(R_{507b}), or Si(R₅₀₇ₐ)(R_{507b}),
Y₅₀₈ may be O, S, N(R₅₀₈), B(R₅₀₈), C(R₅₀₈ₐ)(R_{508b}), or Si(R₅₀₈ₐ)(R_{58b}),
Y₅₁ and Y₅₂ may each independently be B, P(═O), or S(═O),
R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} are each as described herein, and
a501 to a504 may each independently be an integer from 0 to 20.

In one or more embodiments, the light-emitting device may satisfy at least one of (e.g., at least one selected from among) Conditions 1 to 4:

### Condition 1

LUMO energy level (eV) of third compound>LUMO energy level (eV) of organometallic compound;

### Condition 2

LUMO energy level (eV) of organometallic compound>LUMO energy level (eV) of second compound;

### Condition 3

HOMO energy level (eV) of organometallic compound>HOMO energy level (eV) of third compound; and

### Condition 4

HOMO energy level (eV) of third compound>HOMO energy level (eV) of second compound.

Each of the HOMO energy level and the LUMO energy level of each of the organometallic compound, the second compound, and the third compound may be a negative value, and may be measured according to a suitable method, for example, a method described in Evaluation Example 1.

In one or more embodiments, an absolute value of a difference between a LUMO energy level of the organometallic compound and a LUMO energy level of the second compound may be about 0.1 eV or higher and about 1.0 eV or lower, an absolute value of a difference between a LUMO energy level of the organometallic compound and a LUMO energy level of the third compound may be about 0.1 eV or higher and about 1.0 eV or lower, an absolute value of a difference between a HOMO energy level of the organometallic compound and a HOMO energy level of the second compound may be about 1.25 eV or lower (for example, about 1.25 eV or lower and about 0.2 eV or higher), and an absolute value of a difference between a HOMO energy level of the organometallic compound and a HOMO energy level of the third compound may be about 1.25 eV or lower (for example, about 1.25 eV or lower and about 0.2 eV or higher).

When the relationships between LUMO energy level and HOMO energy level satisfy the conditions as described herein, the balance between holes and electrons injected into the emission layer may be achieved.

The light-emitting device may have a structure of a first embodiment or a second embodiment.

### First Embodiment

According to the first embodiment, the organometallic compound may be included in the emission layer in the interlayer of the light-emitting device, wherein the emission layer may further include a host, the organometallic compound and the host may be different from each other, and the emission layer may be to emit phosphorescence or fluorescence emitted from the organometallic compound. In other words, according to the first embodiment, the organometallic compound may be a dopant or an emitter. In one or more embodiments, the organometallic compound may be a phosphorescent dopant or a phosphorescent emitter.

Phosphorescence or fluorescence emitted from the organometallic compound may be blue light.

The emission layer may further include an auxiliary dopant. The auxiliary dopant may serve to improve luminescence efficiency from the organometallic compound by effectively transferring a dopant or the organometallic compound as an emitter.

The auxiliary dopant may be different from each of the organometallic compound and the host.

In one or more embodiments, the auxiliary dopant may be a delayed fluorescence-emitting compound.

In one or more embodiments, the auxiliary dopant may be a compound including at least one cyclic group including each of boron (B) and nitrogen (N) as a ring-forming atom.

### Second Embodiment

According to the second embodiment, the organometallic compound may be included in the emission layer in the interlayer of the light-emitting device, wherein the emission layer may further include a host and a dopant, the organometallic compound, the host and the dopant may be different from one another, and the emission layer may be to emit phosphorescence or fluorescence (for example, delayed fluorescence) from the dopant.

In one or more embodiments, the organometallic compound in the second embodiment may serve as an auxiliary dopant that transfers energy to a dopant (or an emitter), not as a dopant.

In one or more embodiments, the organometallic compound in the second embodiment may serve as an emitter and as an auxiliary dopant that transfers energy to a dopant (or an emitter).

For example, phosphorescence or fluorescence emitted from the dopant (or the emitter) in the second embodiment may be blue phosphorescence or blue fluorescence (e.g., blue delayed fluorescence).

The dopant (or the emitter) in the second embodiment may be a phosphorescent dopant material (for example, the organometallic compound represented by Formula 1, the organometallic compound represented by Formula 401, or any combination thereof) or any fluorescent dopant material (for example, the compound represented by Formula 501, the compound represented by Formula 502, the compound represented by Formula 503, or any combination thereof).

In the first embodiment and the second embodiment, the blue light may be blue light having a maximum emission wavelength of about 390 nm to about 500 nm, about 410 nm to about 490 nm, about 430 nm to about 480 nm, about 440 nm to about 475 nm, or about 455 nm to about 470 nm.

The auxiliary dopant in the first embodiment may include, for example, the fourth compound represented by Formula 502 or Formula 503.

The host in the first embodiment and the second embodiment may be any host material (for example, a compound represented by Formula 301, a compound represented by 301-1, a compound represented by Formula 301-2, or any combination thereof).

In one or more embodiments, the host in the first embodiment and the second embodiment may be the second compound, the third compound, or any combination thereof.

In one or more embodiments, the light-emitting device may further include a capping layer located outside the first electrode and/or outside the second electrode.

In one or more embodiments, the light-emitting device may further include at least one of a first capping layer located outside the first electrode and a second capping layer located outside the second electrode, and at least one of the first capping layer and the second capping layer may include the organometallic compound represented by Formula 1. The first capping layer and/or the second capping layer are each as described herein.

In one or more embodiments, the light-emitting device may further include:
a first capping layer located outside the first electrode and including the organometallic compound represented by Formula 1;
a second capping layer located outside the second electrode and including the organometallic compound represented by Formula 1; or
the first capping layer and the second capping layer.

The expression “(interlayer and/or a capping layer) includes an organometallic compound represented by Formula 1” as utilized herein may be to refer to that the (interlayer and/or the capping layer) may include one kind of organometallic compound represented by Formula 1 or two or more different kinds of organometallic compounds, each represented by Formula 1.

In one or more embodiments, the interlayer and/or the capping layer may include Compound 1 only as the organometallic compound. In this regard, Compound 1 may be present in the emission layer of the light-emitting device. In one or more embodiments, the interlayer may include, as the organometallic compound, Compound 1 and Compound 2. In this regard, Compound 1 and Compound 2 may be present in substantially the same layer (for example, all of Compound 1 and Compound 2 may be present in the emission layer), or may be present in different layers (for example, Compound 1 may be present in the emission layer, and Compound 2 may be present in the electron transport region).

The term “interlayer” as utilized herein refers to a single layer and/or all of a plurality of layers arranged between the first electrode and the second electrode of the light-emitting device.

According to one or more embodiments, an electronic apparatus includes the light-emitting device. The electronic apparatus may further include a thin-film transistor. For example, the electronic apparatus may further include a thin-film transistor including a source electrode and a drain electrode, and the first electrode of the light-emitting device may be electrically connected to the source electrode or the drain electrode. In one or more embodiments, the electronic apparatus may further include a color filter, a color conversion layer, a touch screen layer, a polarizing layer, or any combination thereof. More details of the electronic apparatus may be referred to the descriptions provided herein.

According to one or more embodiments, electronic equipment includes the light-emitting device.

For example, the electronic equipment may be at least one selected from among a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, and a signboard, or a combination thereof.

According to one or more embodiments, provided is the organometallic compound represented by Formula 1. Formula 1 is as described herein.

Methods of synthesizing the organometallic compound may be easily understood by those of ordinary skill in the art by referring to Synthesis Examples and/or Examples described herein.

### Description of Formula 1

Ar₁ in Formula 1 may be a group represented by Formula 1A:

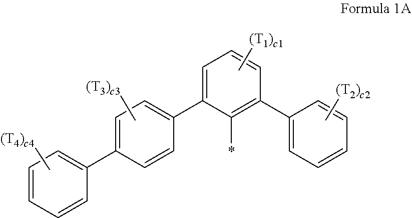

wherein * in Formula 1A indicates a binding site to ring CY₁ in Formula 1.

Description of Formula 1A (or description of Ar₁ in Formula 1) is as provided herein.

In Formula 1, M may be platinum (Pt), palladium (Pd), gold (Au), nickel (Ni), silver (Ag), or copper (Cu).

In one or more embodiments, M may be Pt.

In Formula 1, X₁ to X₄ may each independently be C or N.

In one or more embodiments, X₁ may be C. In one or more embodiments, X₁ in Formula 1 may be C, and C may be carbon of a carbene moiety.

In one or more embodiments, X₁ in Formula 1 may be N.

In one or more embodiments, X₂ and X₃ may each be C, and X₄ may be N.

In Formula 1, i) a bond between X₁ and M may be a coordinate bond, ii) one selected from among a bond between X₂ and M, a bond between X₃ and M, and a bond between X₄ and M may be a coordinate bond, and two selected from among the bond between X₂ and M, the bond between X₃ and M, and the bond between X₄ and M is each a covalent bond, (e.g., the other two may each be a covalent bond. For example, each of a bond between X₂ and M, a bond between X₃ and M, and a bond between X₄ and M may be a coordinate bond or a covalent bond, wherein one of the bonds is a coordinate bond.

In one or more embodiments, a bond between X₂ and M and a bond between X₃ and M may each be a covalent bond, and a bond between X₄ and M may be a coordinate bond.

In one or more embodiments, X₄ may be N, and a bond between X₄ and M may be a coordinate bond.

In Formula 1, ring CY₁ to ring CY₄ may each independently be a C₃-C₆₀ carbocyclic group or a C₁-C₆₀ heterocyclic group.

For example, ring CY₁ may be a nitrogen-containing C₁-C₆₀ heterocyclic group.

Ring CY₁ in Formula 1 may be i) an X₁-containing 5-membered ring, ii) an X₁-containing 5-membered ring in which at least one 6-membered ring is condensed, or iii) an X₁-containing 6-membered ring.

In one or more embodiments, ring CY₁ in Formula 1 may be i) an X₁-containing 5-membered ring or ii) an X₁-containing 5-membered ring in which at least one 6-membered ring is condensed. For example, ring CY₁ may include a 5-membered ring bonded to M in Formula 1 via X₁. Here, the X₁-containing 5-membered ring may be a pyrrole group, a pyrazole group, an imidazole group, a triazole group, an oxazole group, an isoxazole group, a thiazole group, an isothiazole group, an oxadiazole group, or a thiadiazole group, and the X₁-containing 6-membered ring and the 6-membered ring which may be optionally condensed to the X₁-containing 5-membered ring may each independently be a benzene group, a pyridine group, or a pyrimidine group.

In one or more embodiments, ring CY₁ may be an X₁-containing 5-membered ring, and the X₁-containing 5-membered ring may be an imidazole group or a triazole group.

In one or more embodiments, ring CY₁ may be an X₁-containing 5-membered ring in which at least one 6-membered ring is condensed, and the X₁-containing 5-membered ring in which the at least one 6-membered ring is condensed may be a benzimidazole group or an imidazopyridine group.

In one or more embodiments, ring CY₁ may be an imidazole group, a triazole group, a benzimidazole group, a naphthoimidazol group, or an imidazopyridine group.

In one or more embodiments, X₁ may be C, and ring CY₁ may be an imidazole group, a triazole group, a benzimidazole group, a naphthoimidazol group, or an imidazopyridine group.

In one or more embodiments, ring CY₂, ring CY₃, and ring CY₄ may each independently be a benzene group, a pyridine group, a pyrimidine group, a pyrazine group, a pyridazine group, a triazine group, a naphthalene group, a quinoline group, an isoquinoline group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

In one or more embodiments, ring CY₂ may be a benzene group, a pyridine group, a pyrimidine group, a naphthalene group, a dibenzofuran group, a dibenzothiophene group, a carbazole group, a fluorene group, or a dibenzosilole group.

In one or more embodiments, ring CY₃ may be a benzene group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

In one or more embodiments, ring CY₃ may be a carbazole group, a benzocarbazole group, a dibenzocarbazole group, an azacarbazole group, an azabenzocarbazole group, or an azadibenzocarbazole group.

In one or more embodiments, ring CY₄ may be a pyridine group, a pyrimidine group, a pyrazine group, a pyridazine group, a triazine group, a quinoline group, or an isoquinoline group.

X₅₁ in Formula 1 may be a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, *—O—*′, *—C(═O)—*′, *—S(═O)—*′, *—S(═O)₂—*′, *—C(Z₅₁ₐ)=*′, *=C(Z₅₁ₐ)—*′, *—C(Z₅₁ₐ)═C(Z_{51b})—*′, *—C(═S)—*′, or *—C≡C—*′. Z₅₁ₐ and Z_{51b} are each as described herein. Z₅₁ₐ and Z_{51b} may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ.

For example, X₅₁ may be *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′, or *—O—*′.

X₅₂ in Formula 1 may be a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′, *—O—*′, *—C(═O)—*′, *—S(═O)—*′, *—S(═O)₂—*′, *—C(Z₅₂ₐ)=*′, *=C(Z₅₂ₐ)—*′, *—C(Z₅₂ₐ)═C(Z_{52b})—*′, *—C(═S)—*′, or *—C≡C—*′. Z₅₂ₐ and Z_{52b} are each as described herein. Z₅₂ₐ and Z_{52b} may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ.

X₅₂ in Formula 1 may be a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′, or *—O—*′. * and each indicate a binding site to a neighboring atom.

In one or more embodiments, in Formula 1,
i) X₅₂ may be a single bond, and a group represented by

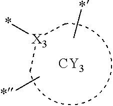

in Formula 1 may be a group represented by Formula CY3A or CY3B,
ii) X₅₂ may not be a single bond, and a group represented by

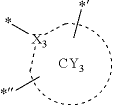

in Formula 1 may be a group represented by Formula CY3C, or
iii) X₅₂ may be *—N(R₅₂ₐ)—*′, and R₅₂ₐ and R₃ may be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ:

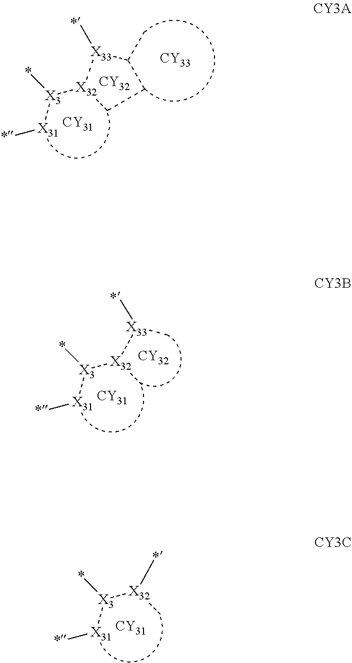

wherein, in Formulae CY3A to CY3C,
X₃ and X₃₁ to X₃₃ may each independently be C or N,
ring CY₃₁, ring CY₃₂, and ring CY₃₃ are each a C₂-C₈ monocyclic group,
a bond between X₃₁ and X₃, a bond between X₃ and X₃₂, and a bond between X₃₂ and X₃₃ may each be a chemical bond,
*″ indicates a binding site to X₅₁,
* indicates a binding site to M in Formula 1, and
*′ indicates a binding site to X₅₂.

In one or more embodiments, in Formulae CY₃A and CY₃B, X₃₁, X₃, and X₃₂ may each be C, and X₃₃ may be N.

In one or more embodiments, X₃₁, X₃, and X₃₂ in Formula CY₃C may each be C.

In Formulae 1 and 1A, R₁ to R₄, Z₅₁ₐ, Z_{51b}, Z₅₂ₐ, Z_{52b}, and T₁ to T₄ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Q₁ to Q₃ are each as described herein.

In one or more embodiments, R₁ to R₄, Z₅₁ₐ, Z_{51b}, Z₅₂ₐ, Z_{52b}, and T₁ to T₄ in Formulae 1 and 1A may each independently be:
hydrogen, deuterium, —F, or a cyano group;
a C₁-C₂₀ alkyl group that is unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any) combination thereof; or
a C₃-C₁₀ cycloalkyl group, a phenyl group, a naphthyl group, a dibenzofuranyl group, or a dibenzothiophenyl group, each unsubstituted or substituted with deuterium, —F, cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any) combination thereof.

In one or more embodiments, R₄ in Formula 1 may be:
hydrogen, deuterium, —F, or a cyano group; or
a C₁-C₂₀ alkyl group that is unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a (e.g., any) combination thereof.

In one or more embodiments, R₄ in Formula 1 may be:
hydrogen, deuterium, —F, or a cyano group; or
a C₁-C₂₀ alkyl group that is unsubstituted or substituted with deuterium, —F, a cyano group, or a (e.g., any) combination thereof.

In one or more embodiments, T₁ to T₄ in Formula 1A may each independently be:
hydrogen, deuterium, —F, or a cyano group; or
a C₁-C₂₀ alkyl group that is unsubstituted or substituted with deuterium, —F, a cyano group, or a (e.g., any) combination thereof.

The “C₁-C₆₀ alkyl group that is unsubstituted or substituted with at least one deuterium” and the “C₁-C₂₀ alkyl group that is unsubstituted or substituted with at least one deuterium” as utilized herein may be, for example, a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, or a tert-decyl group, each unsubstituted or substituted with at least one deuterium.

In one or more embodiments, the “C₁-C₆₀ alkyl group that is unsubstituted or substituted with at least one deuterium” and the “C₁-C₂₀ alkyl group that is unsubstituted or substituted with at least one deuterium” may be —CH₃, —CDH₂, —CD₂H, —CD₃, —CH₂CH₃, —CDHCH₃, —CD₂CH₃, —CH₂CDH₂, —CDHCDH₂, —CD₂CDH₂, —CH₂CD₂H, —CDHCD₂H, —CD₂CD₂H, —CH₂CD₃, —CDHCD₃, —CD₂CD₃, or a group represented by one of Formulae X-1 to X-30:

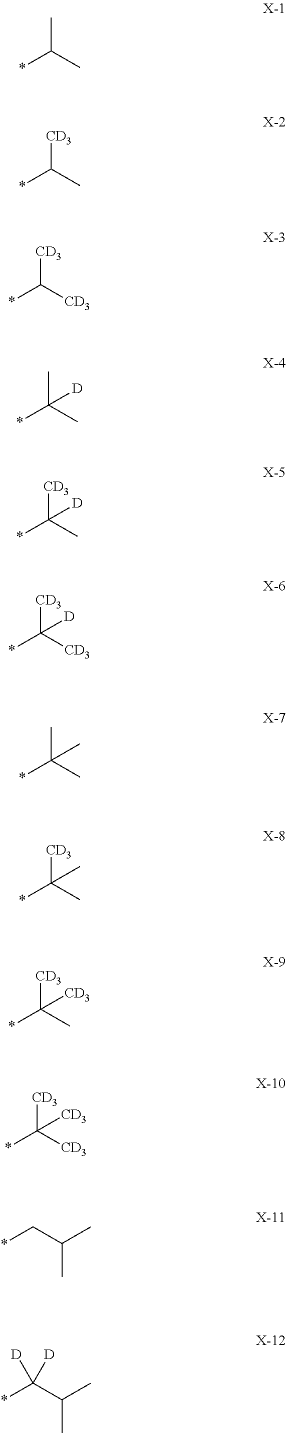

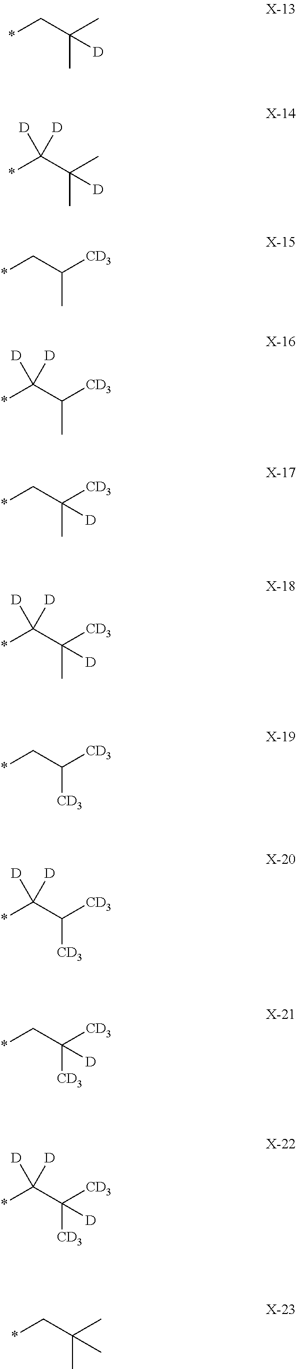

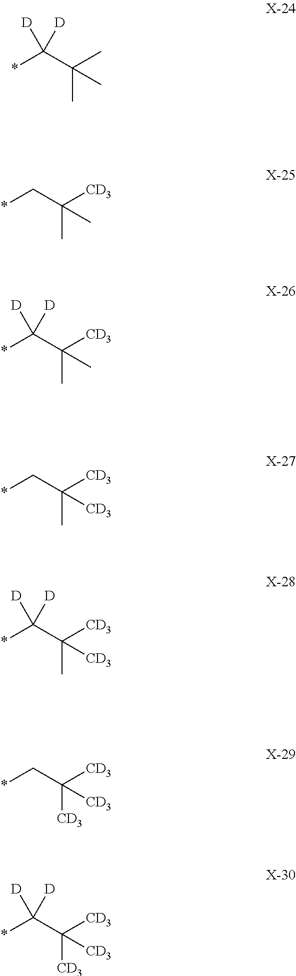

wherein * in Formulae X-1 to X-30 indicates a binding site to a neighboring atom.

A “deuterated C₁-C₆₀ alkyl group,” a “C₁-C₆₀ alkyl group that is substituted with (at least one) deuterium,” a “deuterated C₁-C₂₀ alkyl group,” or a “C₁-C₂₀ alkyl group that is substituted with (at least one) deuterium” as utilized herein may refer to a group represented by a linear or branched C₁-C₆₀ alkyl group (or a linear or branched C₁-C₂₀ alkyl group) in which at least one hydrogen is substituted with deuterium, and may be, for example, a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, or a tert-decyl group, each substituted with at least one deuterium (for example, —CDH₂, —CD₂H, —CD₃, —CDHCH₃, —CD₂CH₃, —CH₂CDH₂, —CDHCDH₂, —CD₂CDH₂, —CH₂CD₂H, —CDHCD₂H, —CD₂CD₂H, —CH₂CD₃, —CDHCD₃, —CD₂CD₃, or a group represented by one of (e.g., one selected from among) Formulae X-2 to X-6, X-8 to X-10, X-12 to X-22, and X-23 to X-30).

a1, a2, a3, a4, c1, c2, c3, and c4 in Formulae 1 and 1A respectively indicate the numbers of R₁, R₂, R₃, R₄, T₁, T₂, T₃, and T₄, wherein a1 to a4 may each independently be an integer from 0 to 10 (for example, an integer from 0 to 6), c1 may be an integer from 1 to 3, c2 and c4 may each independently be an integer from 1 to 5, and c3 may be an integer from 1 to 4. When a1 is 2 or more, two or more of R₁ may be identical to or different from each other, when a2 is 2 or more, two or more of R₂ may be identical to or different from each other, when a3 is 2 or more, two or more of R₃ may be identical to or different from each other, when a4 is 2 or more, two or more of R₄ may be identical to or different from each other, when c1 is 2 or more, two or more of T₁ may be identical to or different from each other, when c2 is 2 or more, two or more of T₂ may be identical to or different from each other, when c3 is 2 or more, two or more of T₃ may be identical to or different from each other, and when c4 is 2 or more, two or more of T₄ may be identical to or different from each other.

In one or more embodiments, the organometallic compound represented by Formula 1 may satisfy at least one of (e.g., at least one selected from among) Condition A1 to Condition A4:

### Condition A1

a1 is not 0, and R₁ is not hydrogen;

### Condition A2

a2 is not 0, and R₂ is not hydrogen;

### Condition A3

a3 is not 0, and R₃ is not hydrogen; and

### Condition A4

a4 is not 0, and R₄ is not hydrogen.

In one or more embodiments, the organometallic compound represented by Formula 1 may include at least one deuterium.

In one or more embodiments, the organometallic compound represented by Formula 1 may satisfy at least one of (e.g., at least one selected from among) Condition B1 to Condition B4:

### Condition B1

a1 is not 0, and at least one R₁ is deuterium or a deuterium-containing group;

### Condition B2

a2 is not 0, and at least one R₂ is deuterium or a deuterium-containing group;

### Condition B3

a3 is not 0, and at least one R₃ is deuterium or a deuterium-containing group; and

### Condition B4

a4 is not 0, and at least one R₄ is deuterium or a deuterium-containing group.

The “deuterium-containing group” as utilized herein refers to a (e.g., any) group including at least one deuterium, and may be further substituted with substituents other than deuterium. For example, the deuterium-containing group may be a C₁-C₂₀ alkyl group, a fluorinated C₁-C₂₀ alkyl group, a phenyl group, a fluorinated a phenyl group, a (C₁-C₂₀ alkyl)phenyl group, a biphenyl group, a fluorinated biphenyl group, a (C₁-C₂₀ alkyl)biphenyl group, a C₃-C₁₀ cycloalkyl group, a naphthyl group, a carbazolyl group, a dibenzofuranyl group, or a dibenzothiophenyl group, each substituted with at least one deuterium (for example, —CH₂D, —CHD₂, —CD₃, —C₆D₅, and/or the like).

In Formula 1A, a group represented by

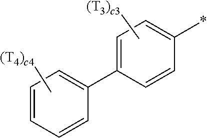

and a group represented by

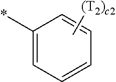

may be different from each other. In other words, a group represented by Formula 1A has an asymmetric structure.

In one or more embodiments, Formula 1A may satisfy one of (e.g., one selected from among) Condition C1 to Condition C3:

### Condition C1

T₁ is hydrogen or deuterium;

### Condition C2

one of T₁ is:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and the (e.g., any) remaining T₁ are hydrogen or deuterium; and

### Condition C3

two of T₁ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₁ is hydrogen or deuterium.

In one or more embodiments, Formula 1A may satisfy one of (e.g., one selected from among) Condition D1 to Condition D4:

### Condition D1

T₂ is hydrogen or deuterium;

### Condition D2

one of T₂ is:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₂ are hydrogen or deuterium;

### Condition D3

two of T₂ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₂ are hydrogen or deuterium; and

### Condition D4

three of T₂ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₂ are hydrogen or deuterium.

In one or more embodiments, Formula 1A may satisfy one of (e.g., one selected from among) Condition E1 to Condition E3:

### Condition E1

T₃ is hydrogen or deuterium;

### Condition E2

one of T₃ is:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₃ are hydrogen or deuterium; and

### Condition E3

two of T₃ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₃ are hydrogen or deuterium.

In one or more embodiments, Formula 1A may satisfy one of (e.g., one selected from among) Condition F1 to Condition F4:

### Condition F1

T₄ is hydrogen or deuterium;

### Condition F2

one of T₄ is:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₄ are hydrogen or deuterium;

### Condition F3

two of T₄ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₄ are hydrogen or deuterium; and

### Condition F4

three of T₄ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
the (e.g., any) remaining T₄ are hydrogen or deuterium.

In one or more embodiments, Formula 1A may satisfy one selected from among Condition C1 to Condition C3, one selected from among Condition D1 to Condition D4, one selected from among Condition E1 to Condition E3, one selected from among Condition F1 to Condition F4, or a (e.g., any) combination thereof.

In one or more embodiments, when, in Formula 1A, T₁, T₃, and T₄ are each hydrogen, c2 is 1, and T₂ is a tert-butyl group, Formula 1 satisfies Condition G1:

### Condition G1

R₄ is:
hydrogen, deuterium, —F, or a cyano group; or
a C₁-C₂₀ alkyl group that is unsubstituted or substituted with deuterium, —F, a cyano group, or a (e.g., any) combination thereof.

In one or more embodiments, a group represented by

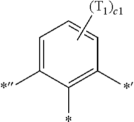

### in Formula 1A may be:

i) one of groups represented by Formulae A1-1 to A1-8; or
ii) one of groups represented by Formulae A1-1 to A1-8 in which at least one hydrogen is substituted with deuterium:

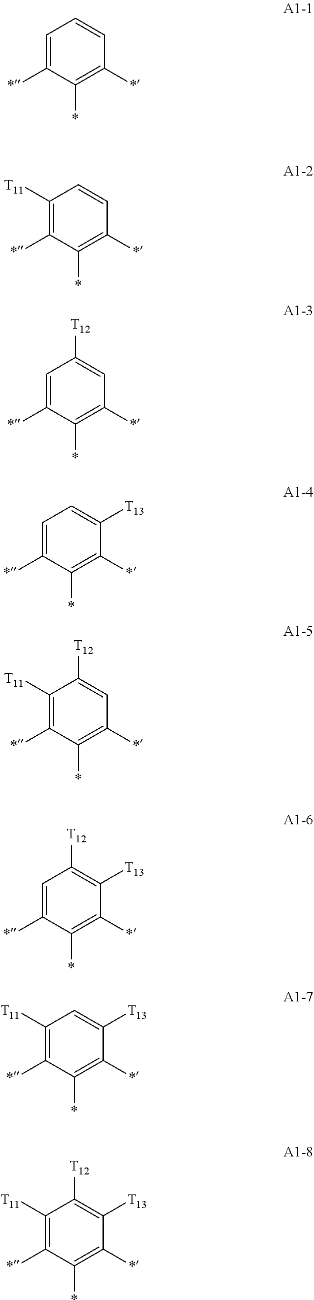

wherein, in Formulae A1-1 to A1-8,
T₁₁ to T₁₃ may each independently be:
a C₁-C₂₀ alkyl group that is unsubstituted or substituted with at least one deuterium; or

a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof,
*′ indicates a binding site to a group represented by

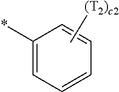

in Formula 1A, and
*″ indicates a binding site to a group represented by

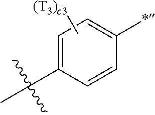

in Formula 1A.

In one or more embodiments, a group represented by

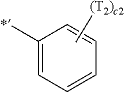

### in Formula 1A may be:

i) one of groups represented by Formulae A2-1 to A2-14; or
ii) one of groups represented by Formulae A2-1 to A2-14 in which at least one hydrogen is substituted with deuterium:

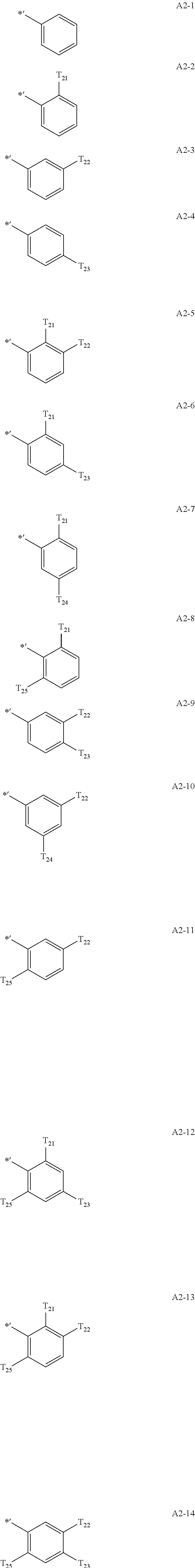

wherein, in Formulae A2-1 to A2-14,
T₂₁ to T₂₅ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
*′ indicates a binding site to a group represented by

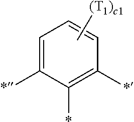

in Formula 1A.

In one or more embodiments, a group represented by

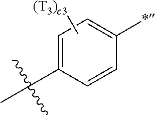

### in Formula 1A may be:

i) one of groups represented by Formulae A3-1 to A3-6; or
ii) one of groups represented by Formulae A3-1 to A3-6 in which at least one hydrogen is substituted with deuterium:

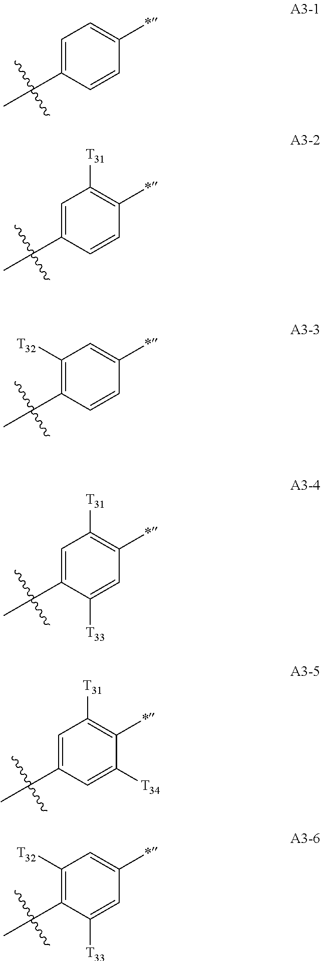

wherein, in Formulae A3-1 to A3-6,
T₃₁ to T₃₄ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof,
*″ indicates a binding site to a group represented by

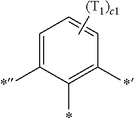

in Formula 1A, and
[symbol] indicates a binding site to a group represented by

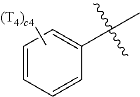

### in Formula 1A.

Formula A3-3 is the same as Formula A3-7

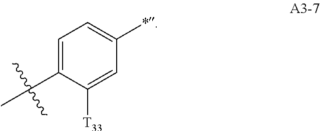

In one or more embodiments, a group represented by

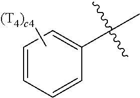

### in Formula 1A may be:

i) one of groups represented by Formulae A4-1 to A4-14; or
ii) one of groups represented by Formulae A4-1 to A4-14 in which at least one hydrogen is substituted with deuterium:

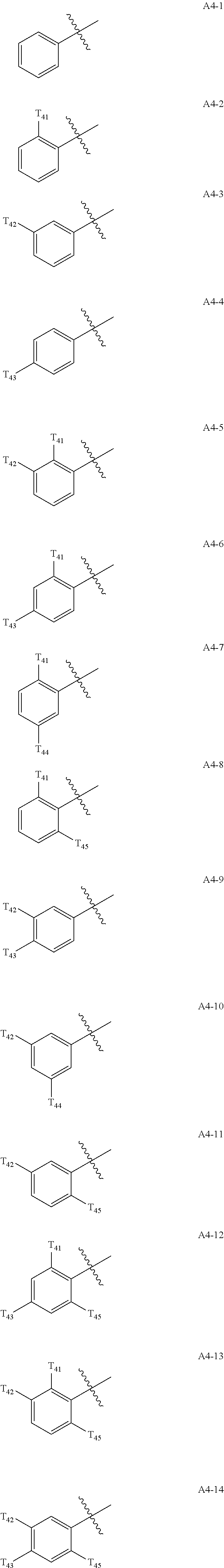

wherein, in Formulae A4-1 to A4-14,
T₄₁ to T₄₅ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
[symbol] indicates a binding site to a group represented by

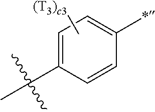

### in Formula 1A.

In one or more embodiments, Ar₁ (or a group represented by Formula 1A) may be a C₄-C₁₀ alkyl group that is unsubstituted or substituted with at least one deuterium (for example, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, or a tert-decyl group, each unsubstituted or substituted with at least one deuterium, or in one or more embodiments, a group represented by one of Formulae X-7 to X-30), and the number of the C₄-C₁₀ alkyl group that is unsubstituted or substituted with at least one deuterium, included in Ar₁, may be 2 or more (for example, 2 to 15).

In one or more embodiments, Ar₁ in Formula 1 may be:
i) one of (e.g., selected from among) groups represented by Formulae TP-1 to TP-228; or
ii) one of (e.g., selected from among) groups represented by Formulae TP-1 to TP-228 in which at least one hydrogen is substituted with deuterium:

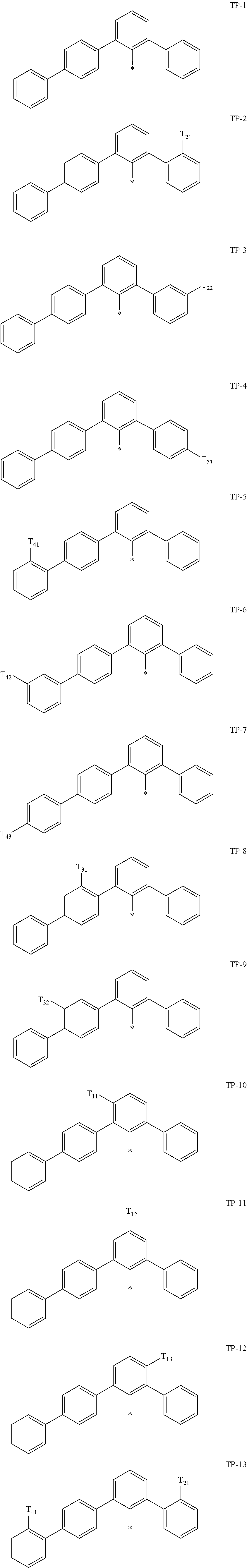

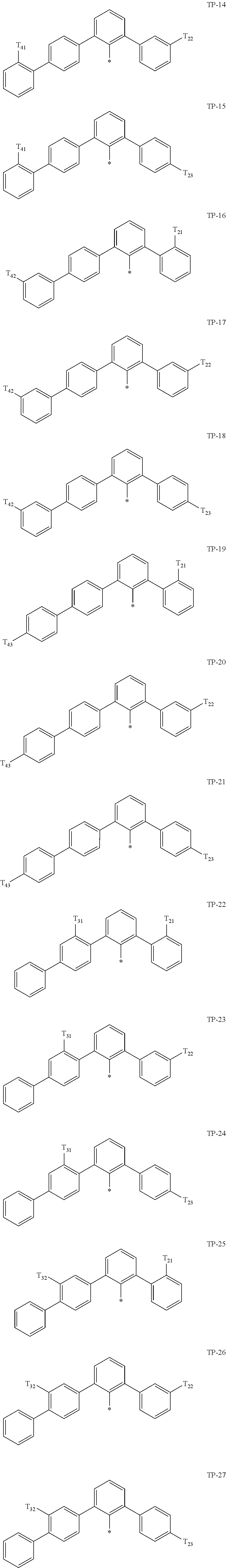

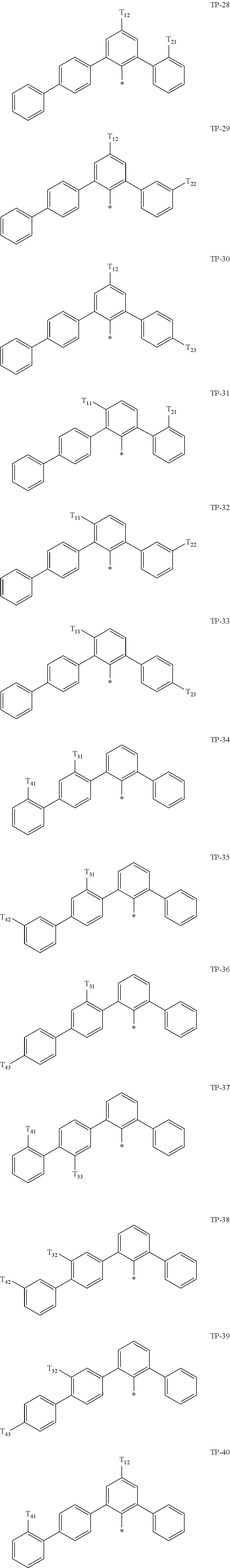

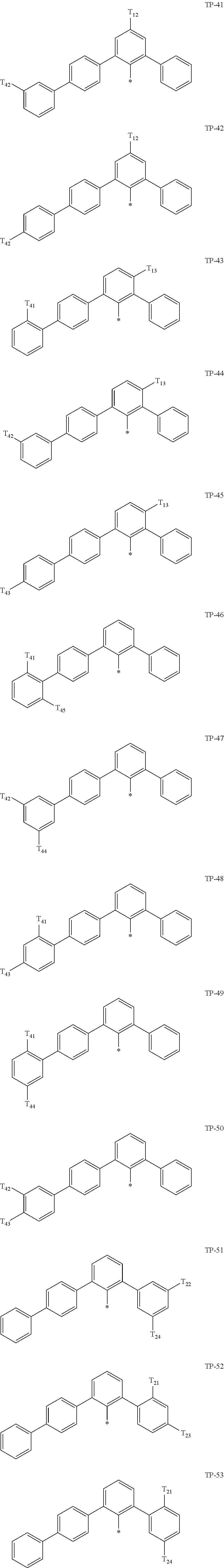

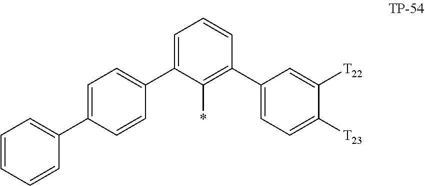

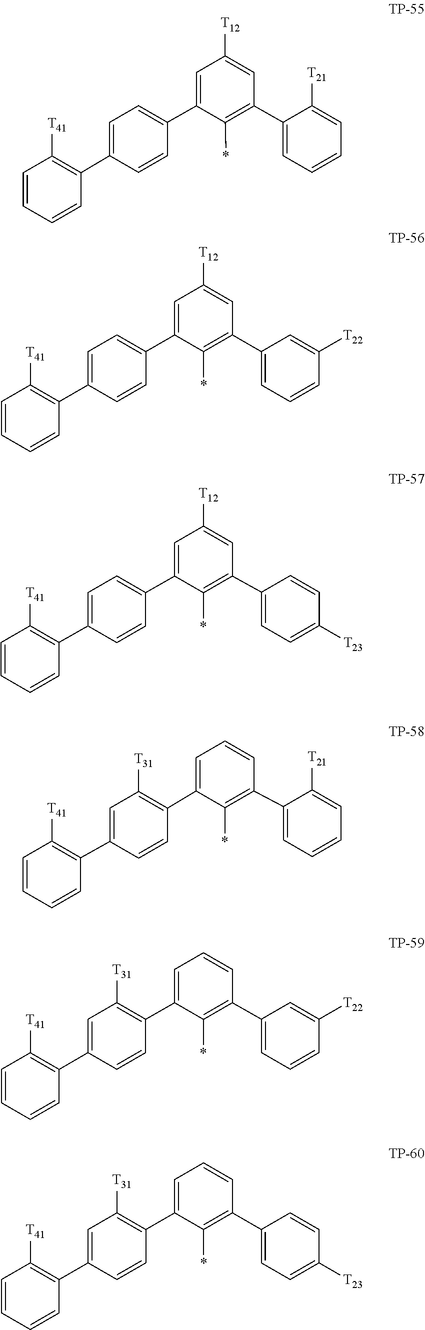

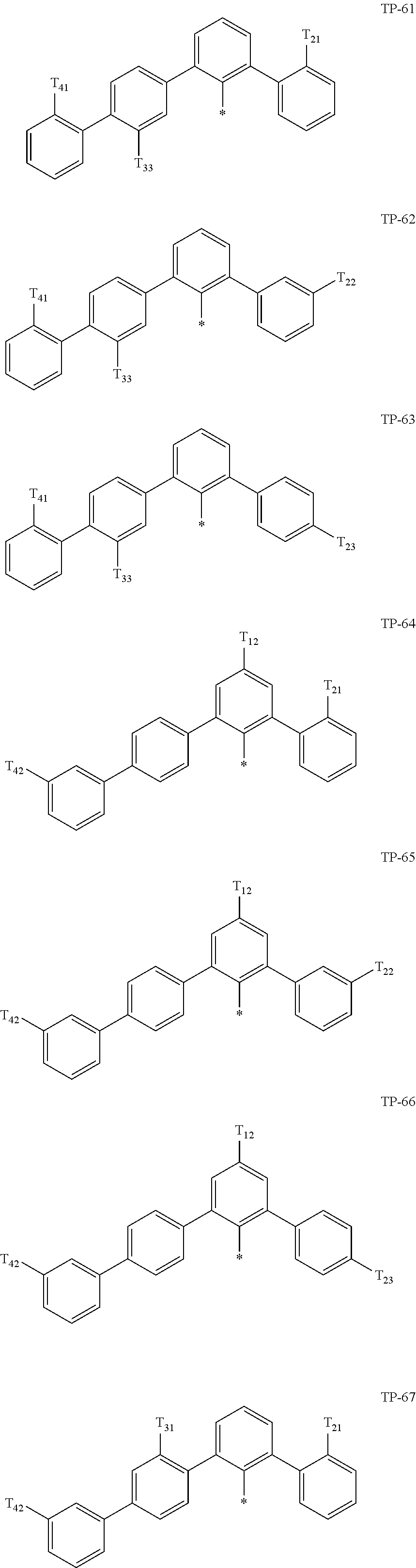

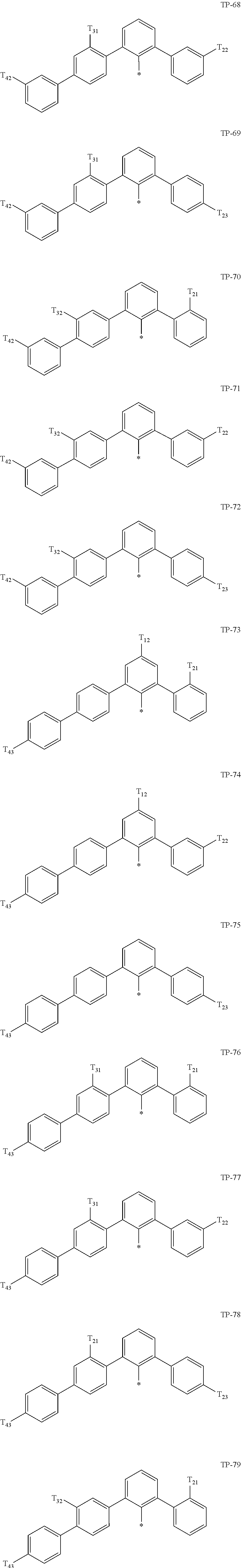

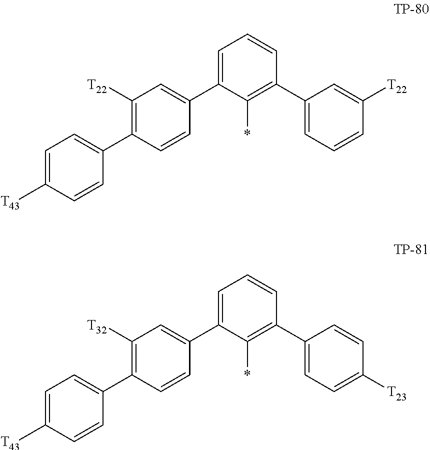

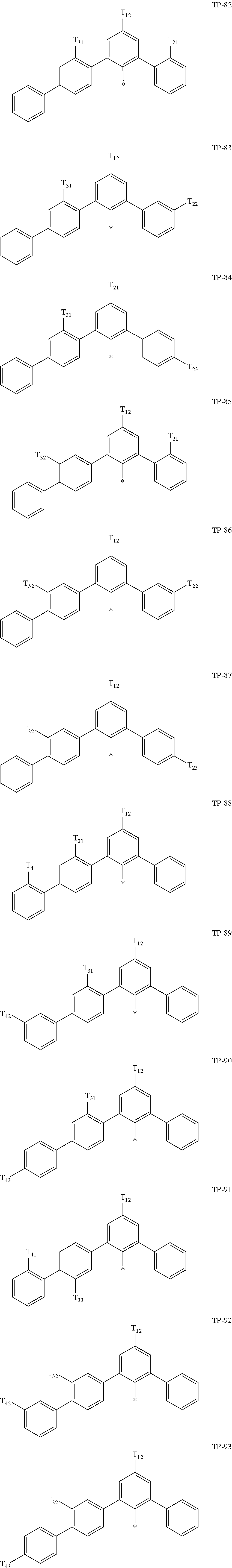

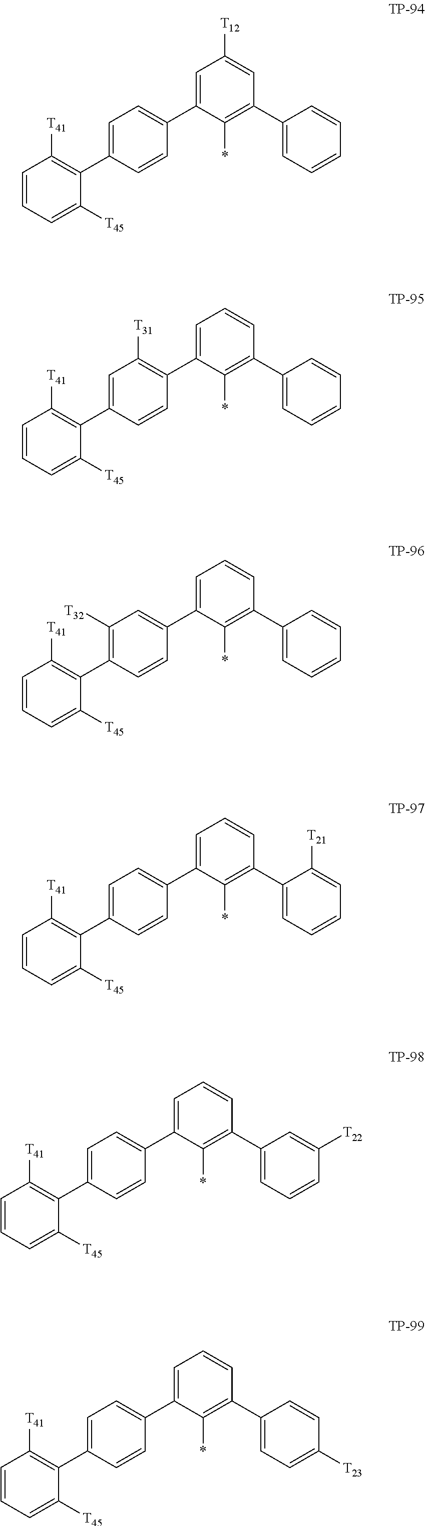

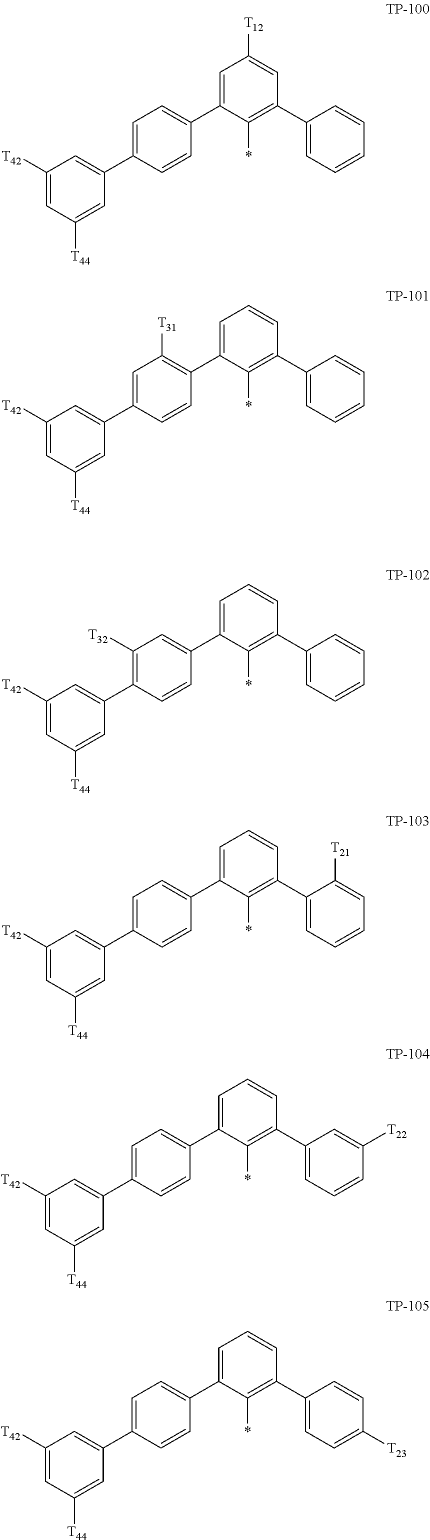

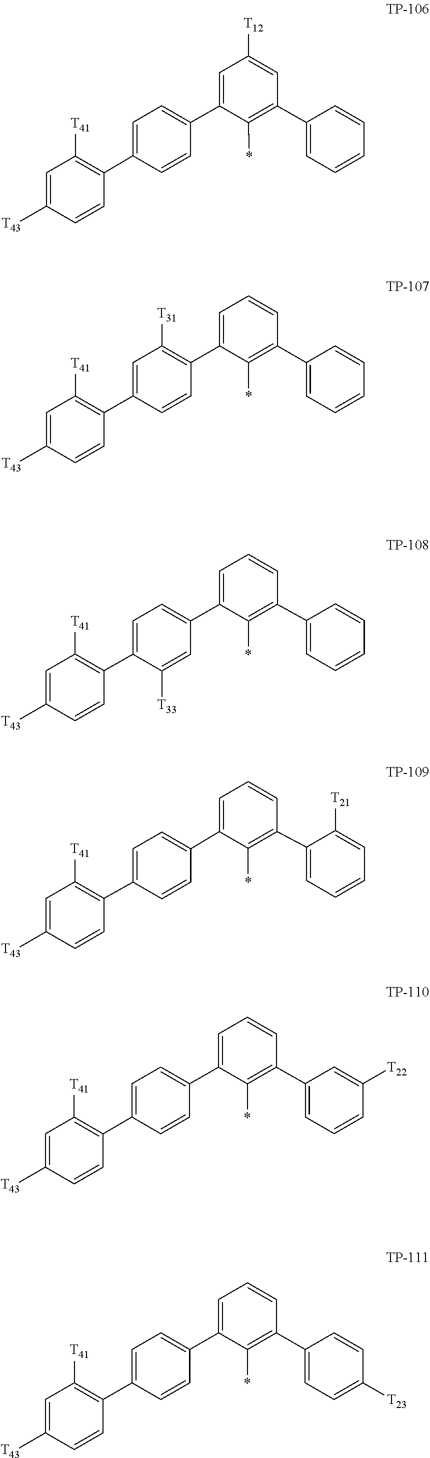

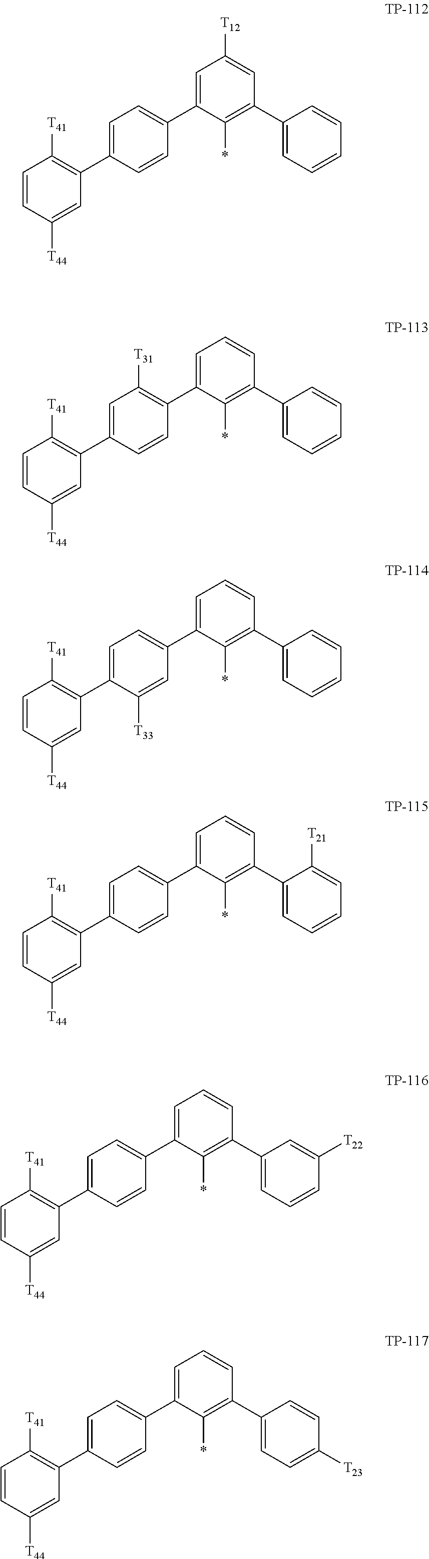

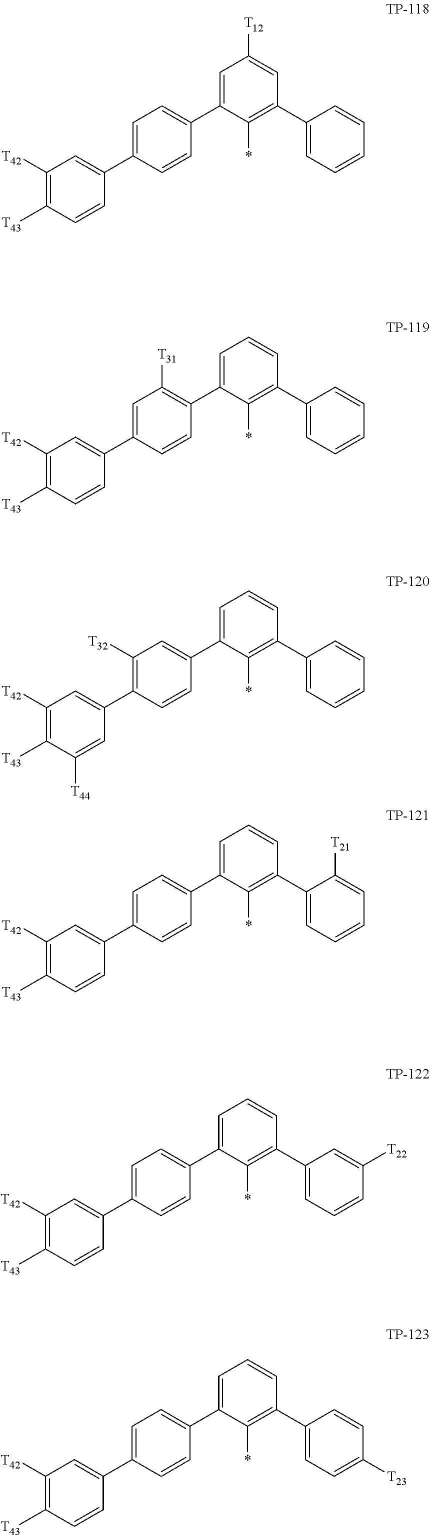

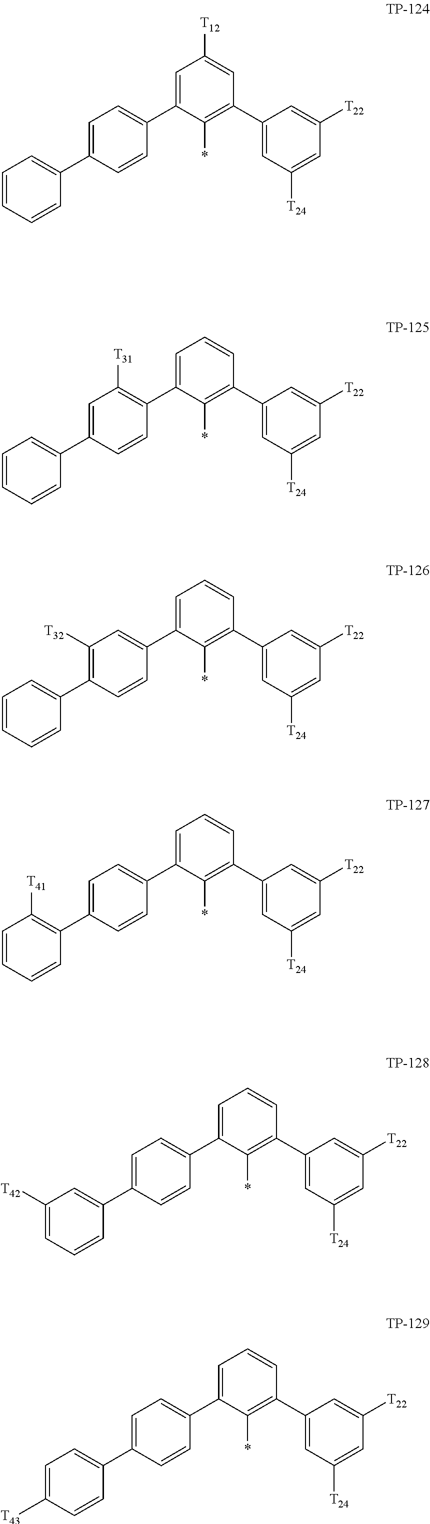

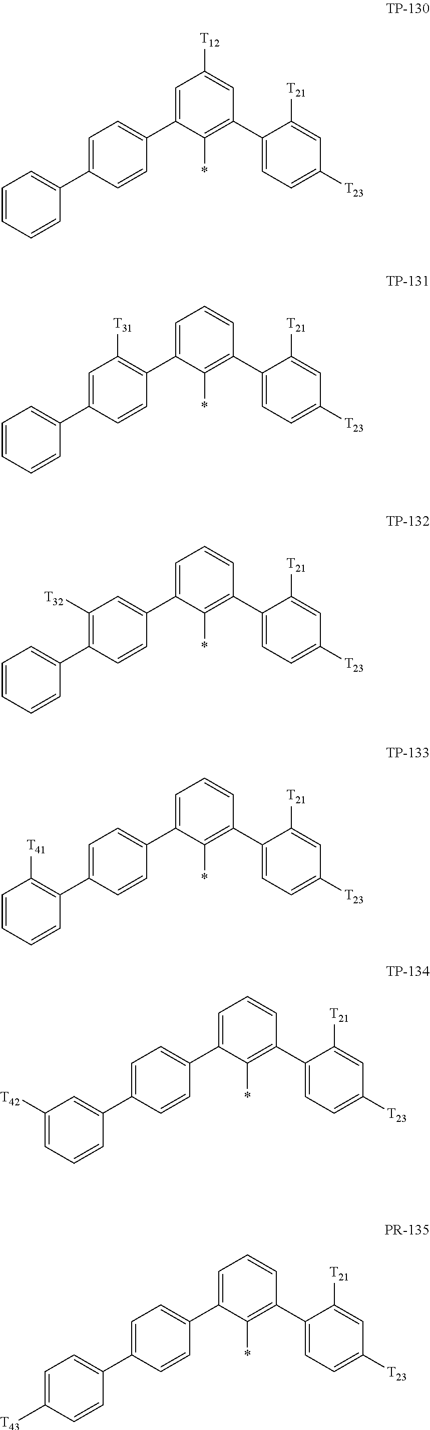

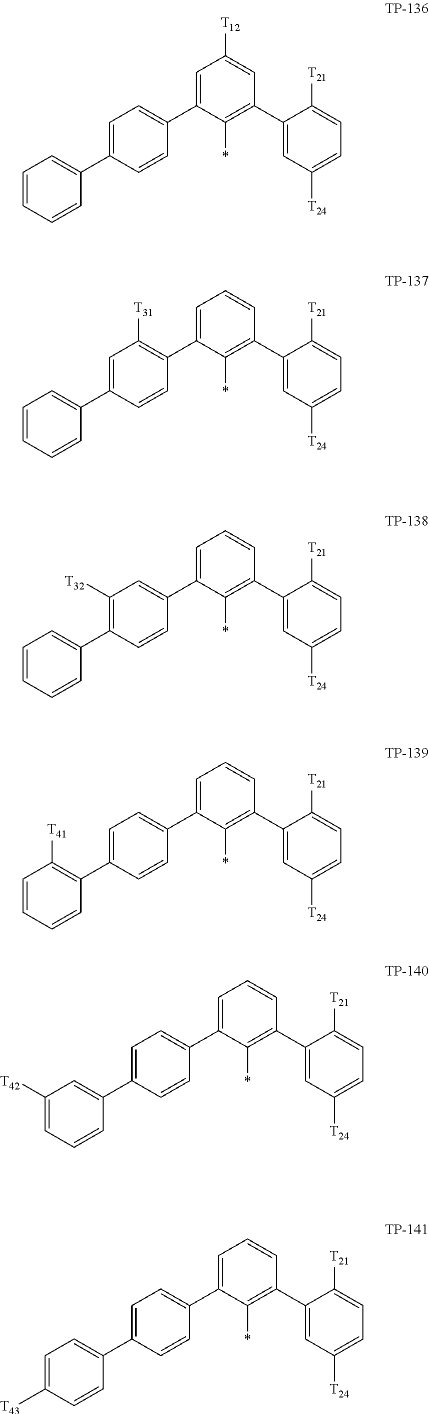

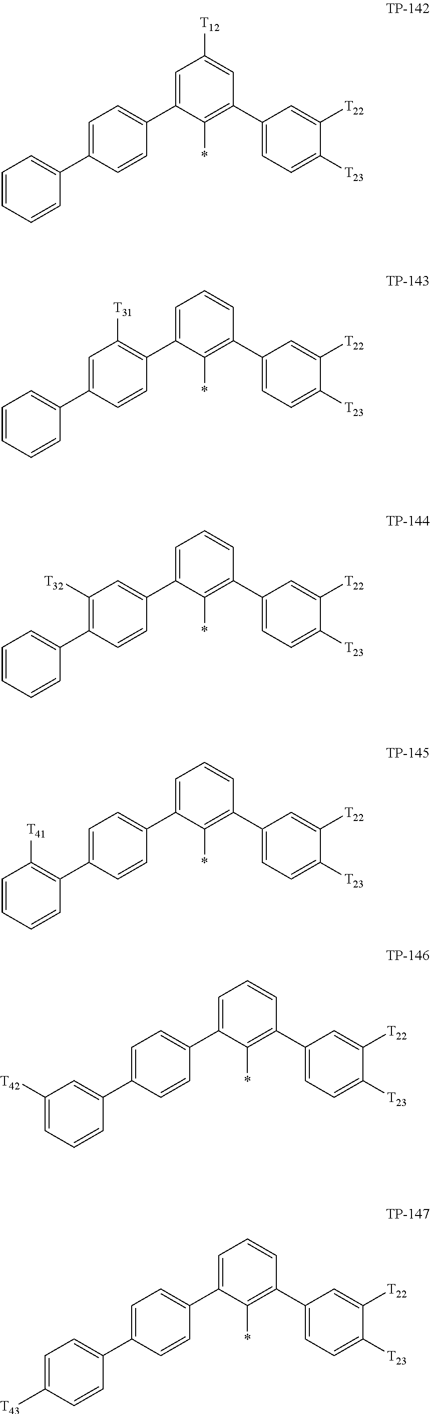

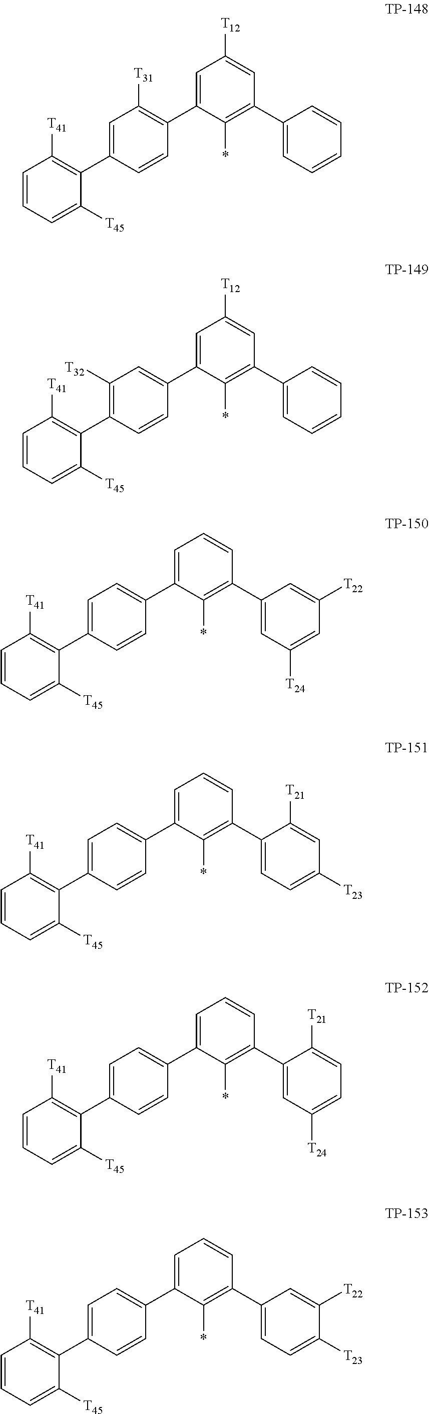

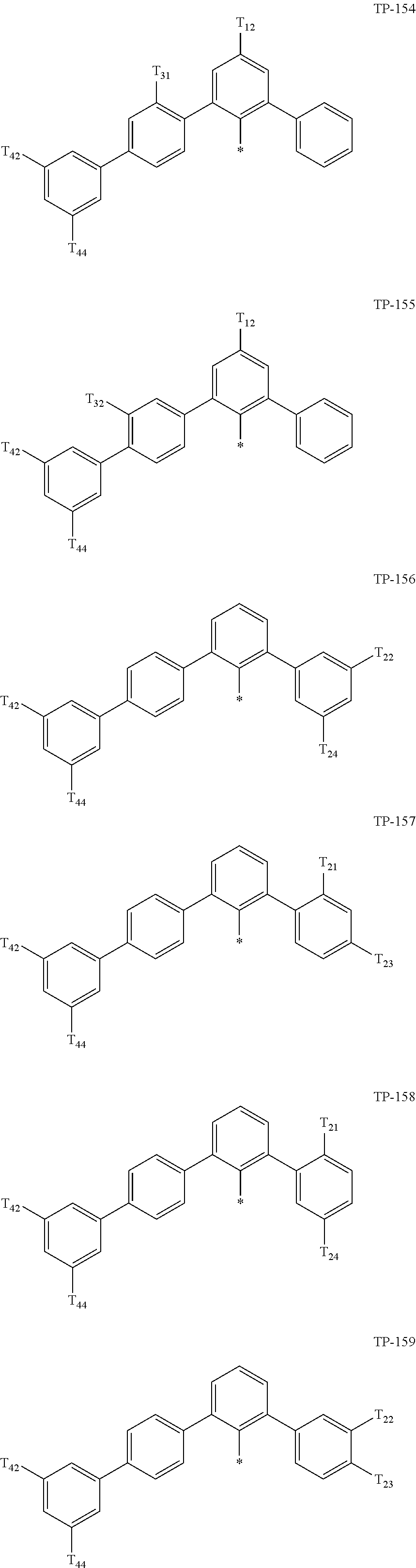

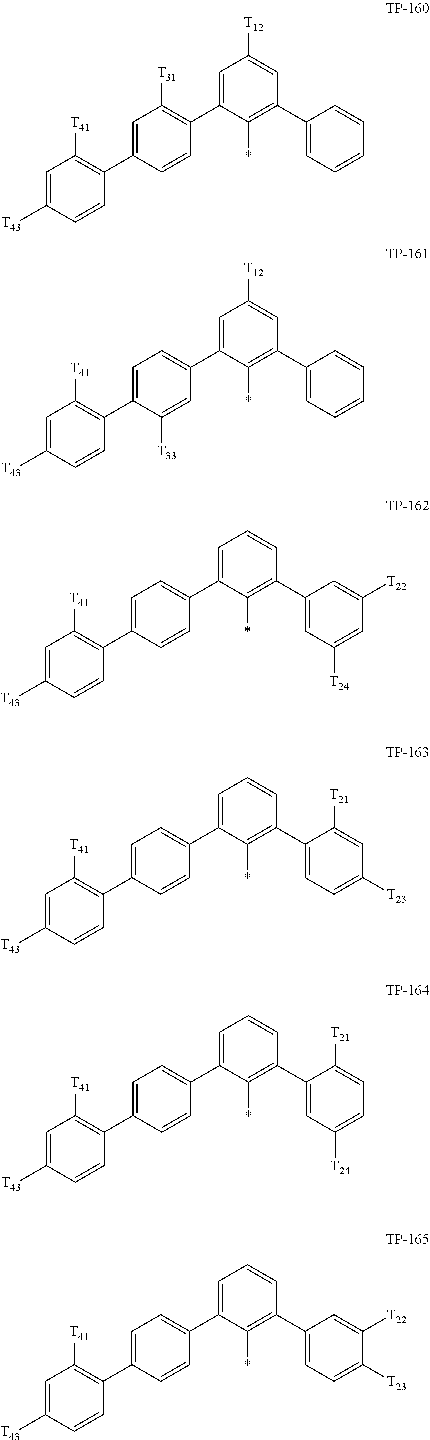

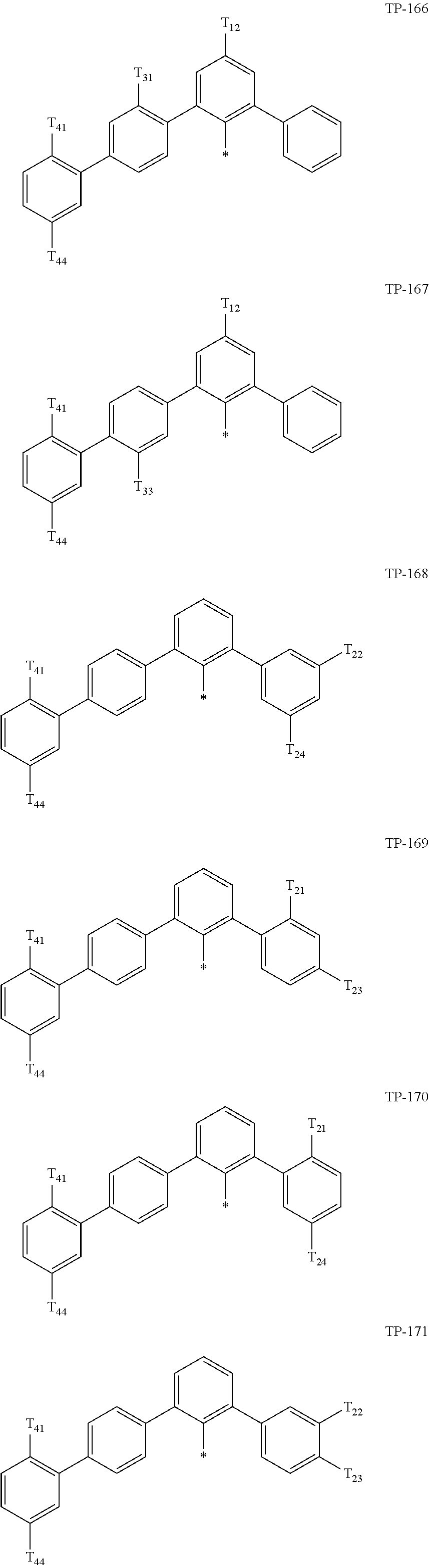

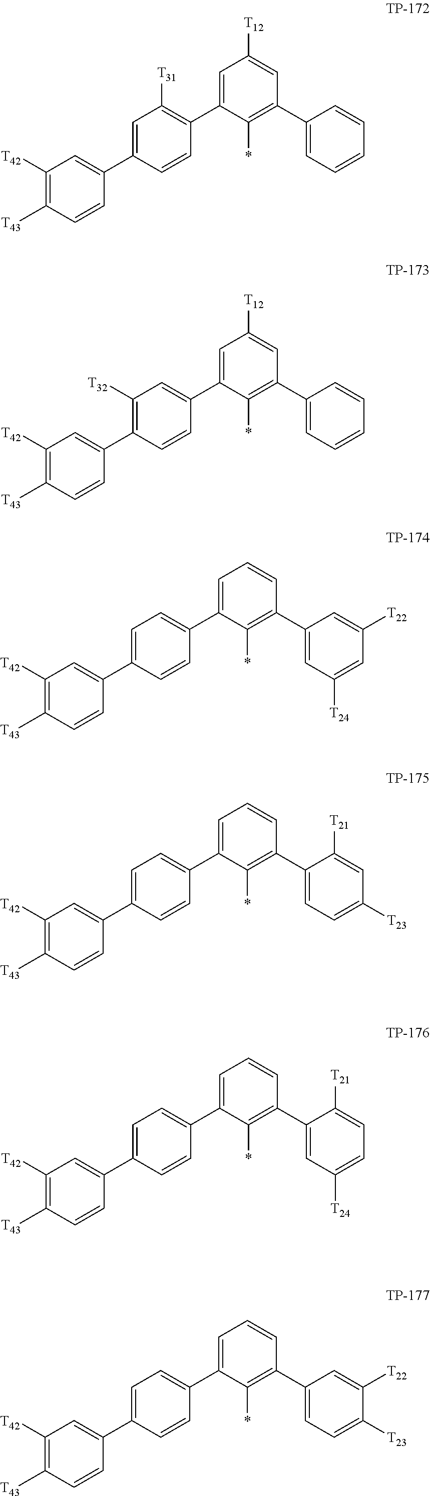

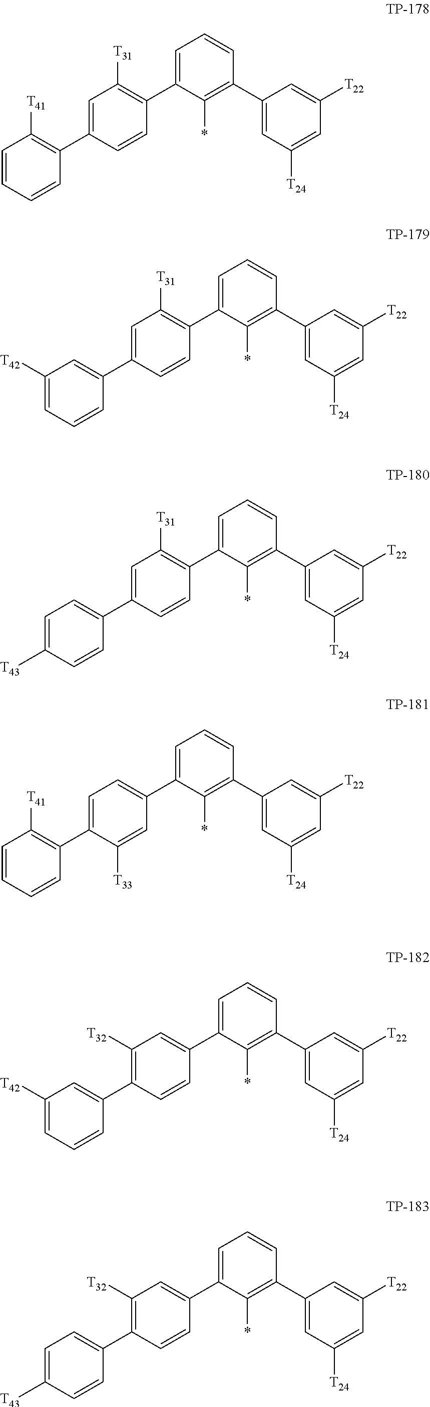

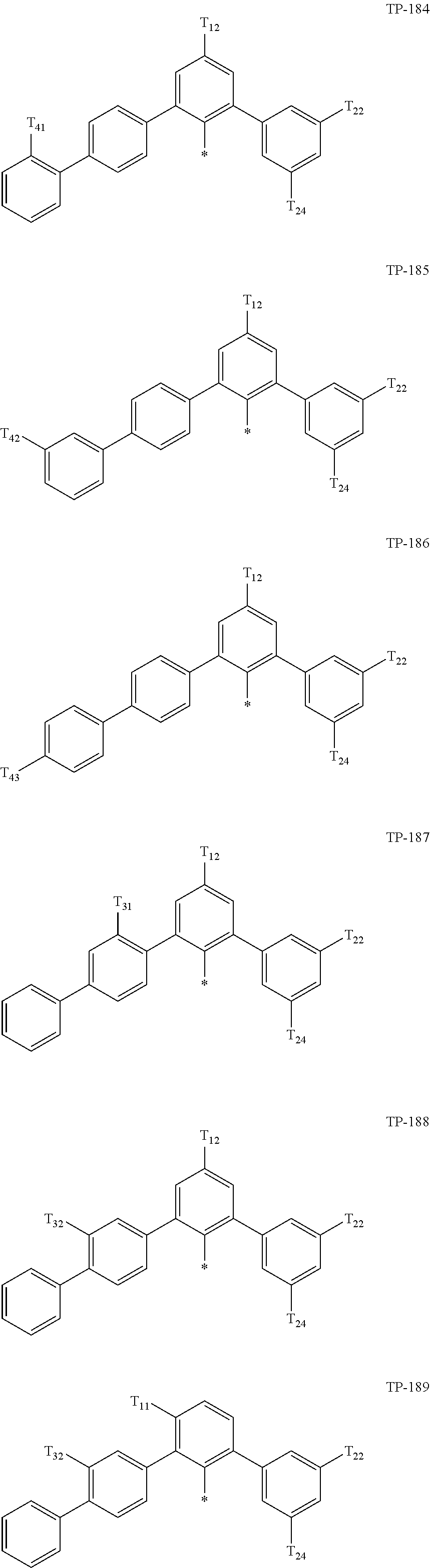

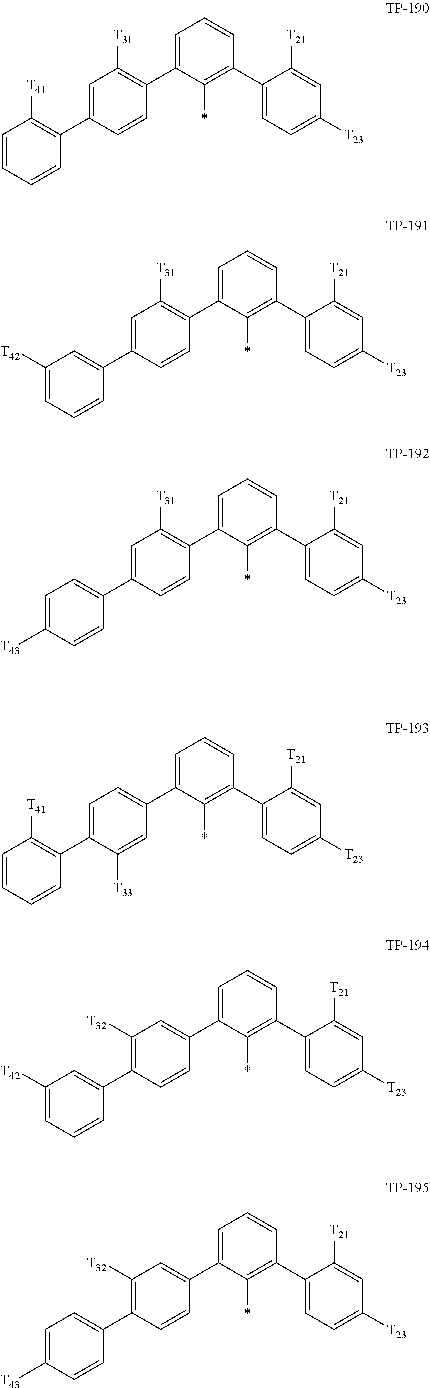

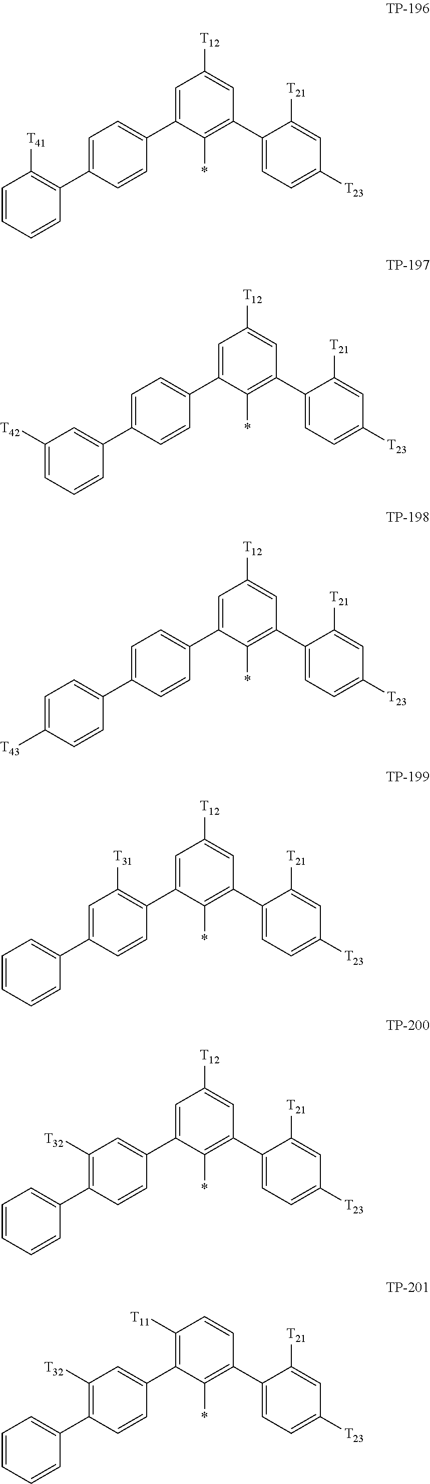

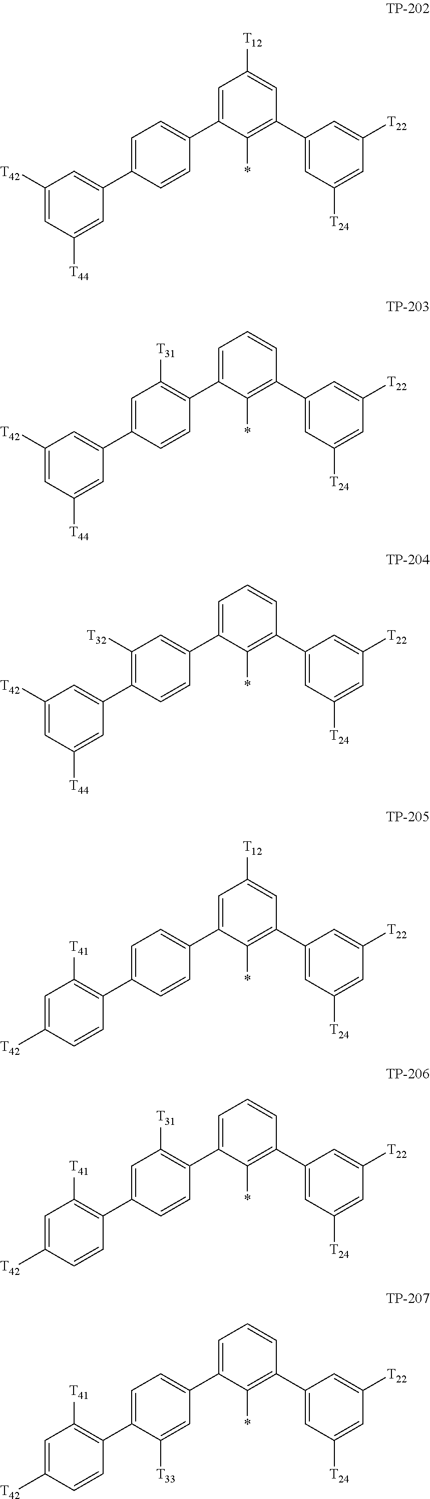

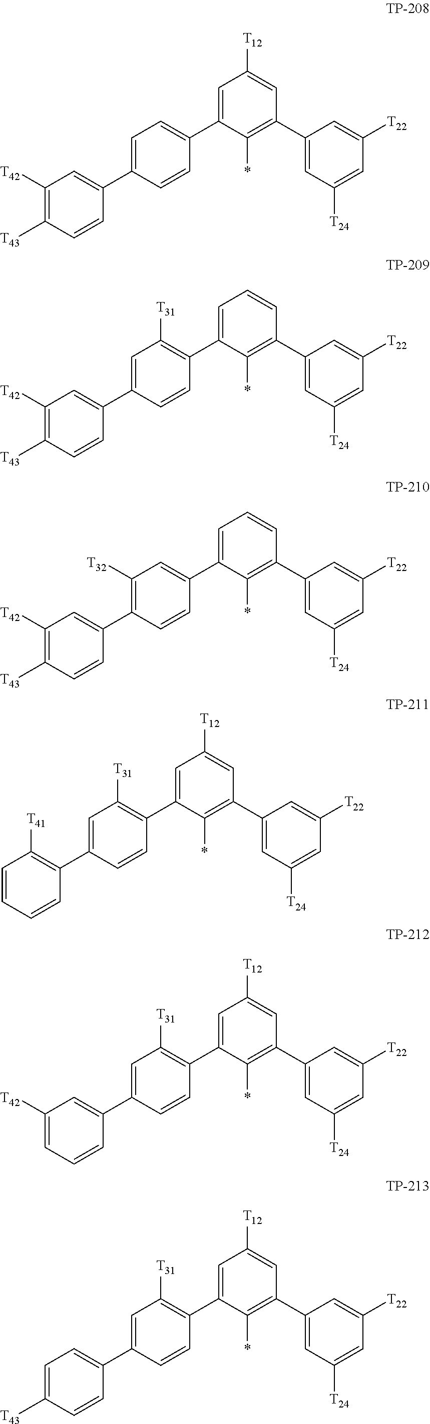

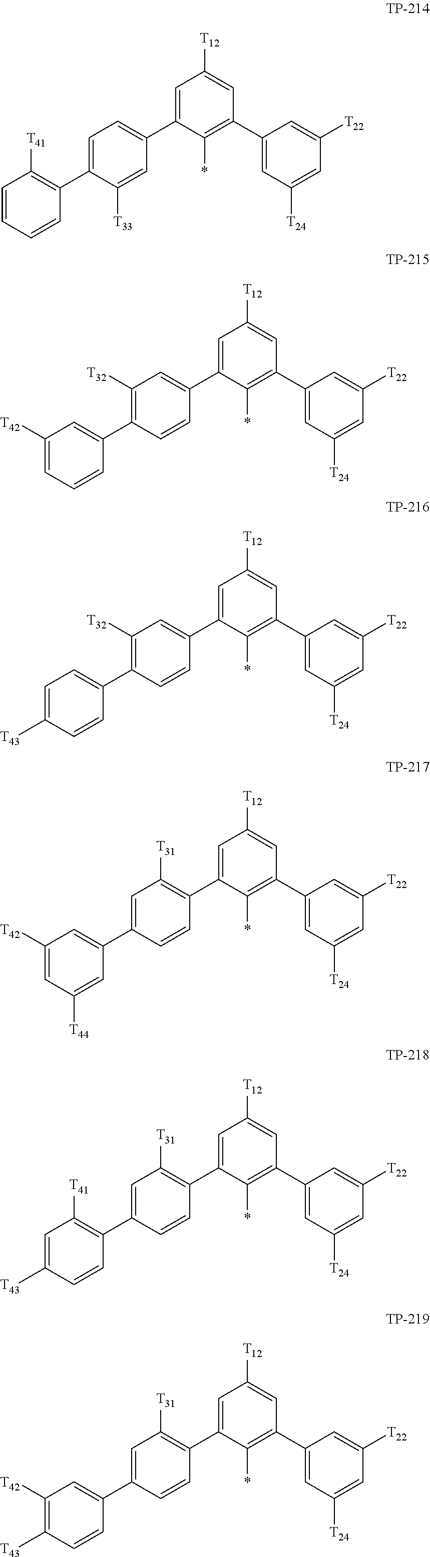

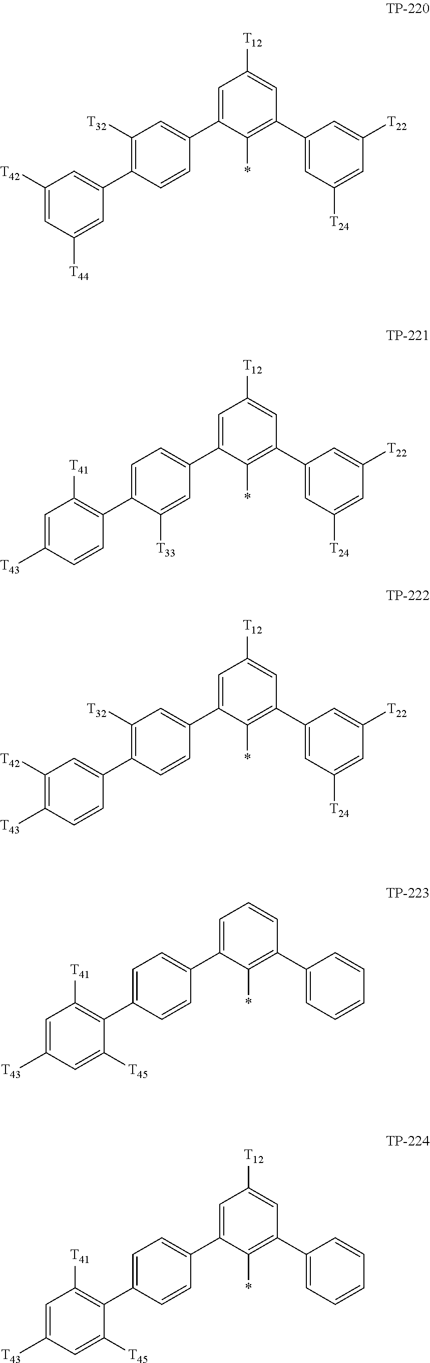

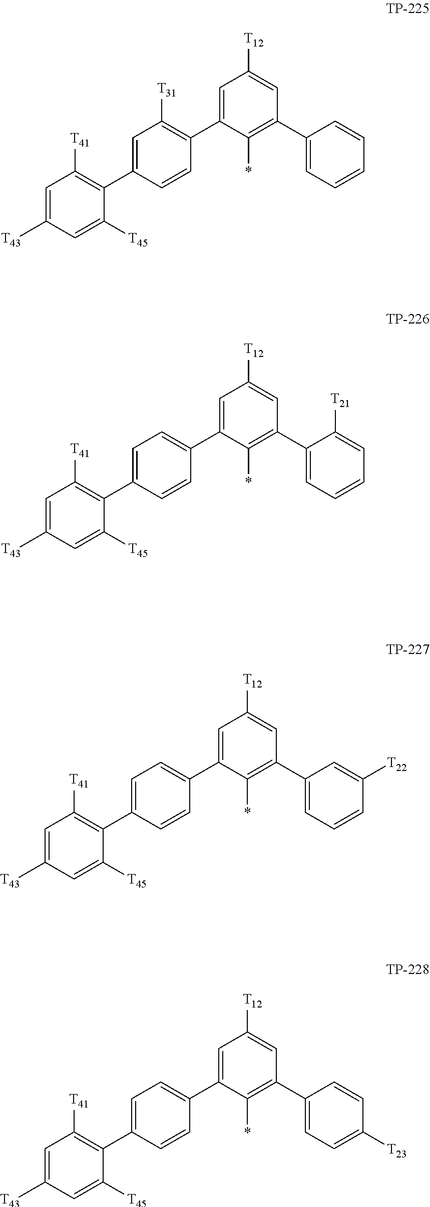

wherein, in Formulae TP-1 to TP-228,
T₁₁ to T₁₃, T₂₁ to T₂₄, T₃₁ to T₃₃, and T₄₁ to T₄₅ may each independently be:
a C₁-C₂₀ alkyl group that is unsubstituted or substituted with at least one deuterium; or
a C₆-C₂₀ aryl group (for example, a phenyl group) that is unsubstituted or substituted with deuterium, a C₁-C₂₀ alkyl group, a deuterated C₁-C₂₀ alkyl group, or a (e.g., any) combination thereof, and
*′ indicates a binding site to ring CY₁ in Formula 1.

The expression “one of groups represented by Formula X in which at least one hydrogen is substituted with deuterium” refers to a group in which at least one of “all” hydrogen present in Formula X is substituted with deuterium.

For example, examples of “a group represented by Formula TP-51 in which at least one hydrogen is substituted with deuterium” may include (e.g., be represented by) Formulae TP-51(1) to TP-51(6):

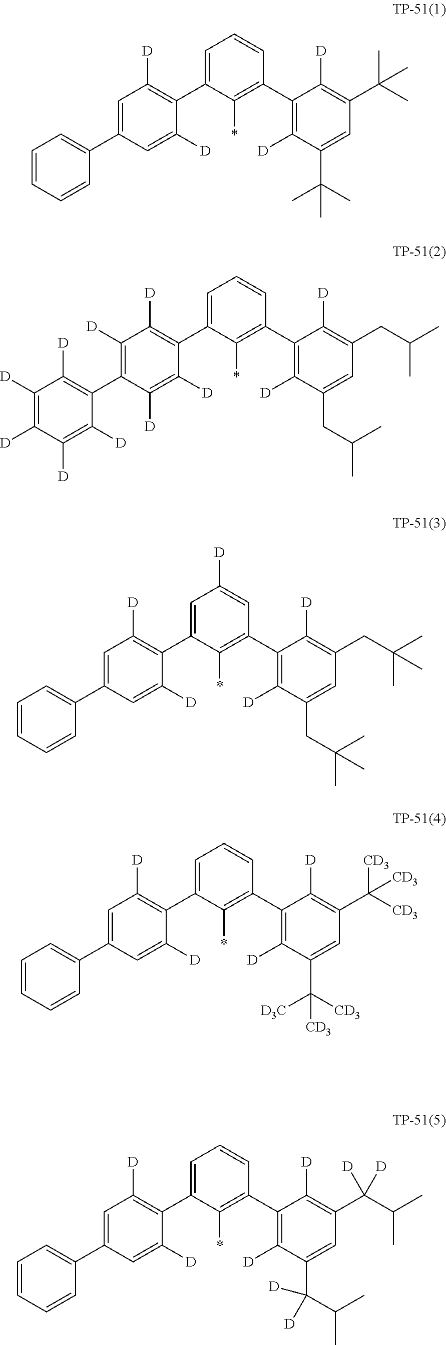

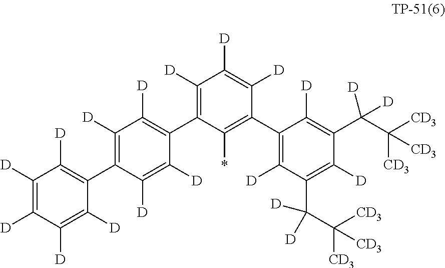 [SMILES: *c1c(-c2c([2H])c([2H])c(-c3c([2H])c([2H])c([2H])c([2H])c3[2H])c([2H])c2[2H])c([2H])c([2H])c([2H])c1-c1c([2H])c(C([2H])([2H])C(C([2H])([2H])[2H])(C([2H])([2H])[2H])C([2H])([2H])[2H])c([2H])c(C([2H])([2H])C(C([2H])([2H])[2H])(C([2H])([2H])[2H])C([2H])([2H])[2H])c1[2H]]

wherein two or more selected from among R₁, R₂, R₃, R₄, Z₅₁ₐ, Z_{51b}, Z₅₂ₐ, Z_{52b}, T₁, T₂, T₃, and T₄ in Formulae 1 and 1A may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ.

“*” as utilized herein indicates a binding site to a neighboring atom, unless otherwise stated.

In one or more embodiments, the organometallic compound represented by Formula 1 may be an organometallic compound represented by Formula 1-1 or an organometallic compound represented by Formula 1-2:

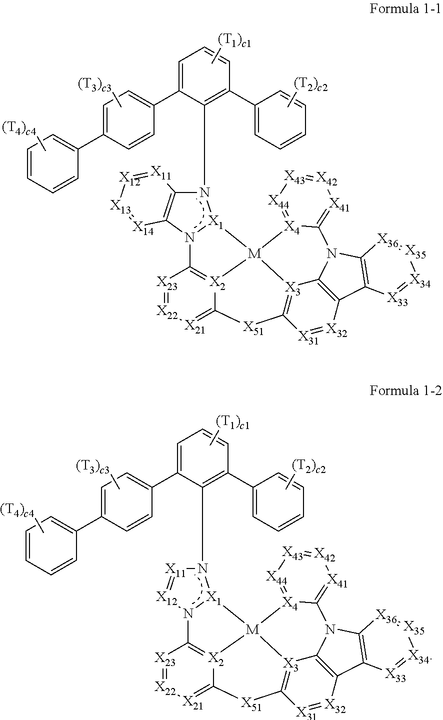

M, X₁ to X₄, X₅₁, T₁ to T₄, and c1 to c4 are each as described herein,
X₁₁ may be C(R₁₁) or N, X₁₂ may be C(R₁₂) or N, X₁₃ may be C(R₁₃) or N, and X₁₄ may be C(R₁₄) or N,
R₁₁ to R₁₄ are each as described in connection with R₁, and two or more R₁₁ to R₁₄ may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₂₁ may be C(R₂₁) or N, X₂₂ may be C(R₂₂) or N, and X₂₃ may be C(R₂₃) or N,
R₂₁ to R₂₃ are each as described in connection with R₂, and two or more R₂₁ to R₂₃ may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₃₁ may be C(R₃₁) or N, X₃₂ may be C(R₃₂) or N, X₃₃ may be C(R₃₃) or N, X₃₄ may be C(R₃₄) or N, X₃₅ may be C(R₃₅) or N, and X₃₆ may be C(R₃₆) or N,
R₃₁ to R₃₆ are each as described in connection with R₃, and two or more R₃₁ to R₃₆ may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₄₁ may be C(R₄₁) or N, X₄₂ may be C(R₄₂) or N, X₄₃ may be C(R₄₃) or N, and X₄₄ may be C(R₄₄) or N,
R₄₁ to R₄₄ are each as described in connection with R₄, and two or more R₄₁ to R₄₄ may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
a group represented by

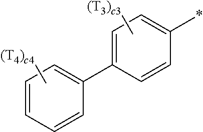

and a group represented by

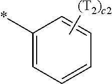

may be different from each other, and
* indicates a binding site to a neighboring atom.

The description of Formula 1 may be applied to Formulae 1-1 and 1-2.

Descriptions of Ar₁ and descriptions of Formula 1A may be applied to a group represented by

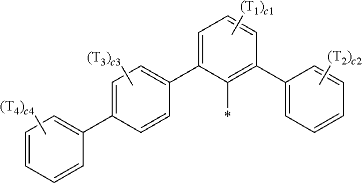

### in Formulae 1-1 and 1-2.

In one or more embodiments, X₄₃ in Formula 1-1 and 1-2 may be C(R₄₃), wherein R₄₃ may be:
hydrogen, deuterium, —F, or a cyano group; or
a C₁-C₂₀ alkyl group that is unsubstituted or substituted with deuterium, —F, a cyano group, or a (e.g., any) combination thereof.

In one or more embodiments, when, in Formulae 1-1 and 1-2, T₁, T₃, and T₄ are each hydrogen, c2 is 1, and T₂ is a tert-butyl group, then Formulae 1-1 and 1-2 may satisfy Condition G2:

### Condition G2

X₄₃ is C(R₄₃),
wherein R₄₃ is:
hydrogen, deuterium, —F, or a cyano group; or
a C₁-C₂₀ alkyl group that is unsubstituted or substituted with deuterium, —F, a cyano group, or a (e.g., any) combination thereof.

In one or more embodiments, in Formulae 1-1 and 1-2, X₁₁ may be C(R₁₁), X₁₂ may be C(R₁₂), X₁₃ may be C(R₁₃), X₁₄ may be C(R₁₄), X₂₁ may be C(R₂₁), X₂₂ may be C(R₂₂), X₂₃ may be C(R₂₃), X₃₁ may be C(R₃₁), X₃₂ may be C(R₃₂), X₃₃ may be C(R₃₃), X₃₄ may be C(R₃₄), X₃₅ may be C(R₃₅), X₃₆ may be C(R₃₆), X₄₁ may be C(R₄₁), X₄₂ may be C(R₄₂), and X₄₃ may be C(R₄₃), R₁₁ to R₁₄, R₂₁ to R₂₃, R₃₁ to R₃₆, and R₄₁ to R₄₃ may be the same as described herein, and
Each of Formulae 1-1 and 1-2 may satisfy at least one selected from among Condition H1 to Condition H4:

### Condition H1

at least one of R₁₁ to R₁₄ in Formula 1-1 is deuterium or a deuterium-containing group, and at least one of R₁₁ and R₁₂ in Formula 1-2 is deuterium or a deuterium-containing group;

### Condition H2

at least one of R₂₁ to R₂₃ is deuterium or a deuterium-containing group;

### Condition H3

at least one of R₃₁ to R₃₆ is deuterium or a deuterium-containing group; and

### Condition H4

at least one of R₄₁ to R₄₄ is deuterium or a deuterium-containing group.

In one or more embodiments, a group represented by

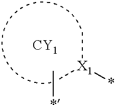

in Formula 1 may be a group represented by one of Formulae CY1-1 to CY1-42:

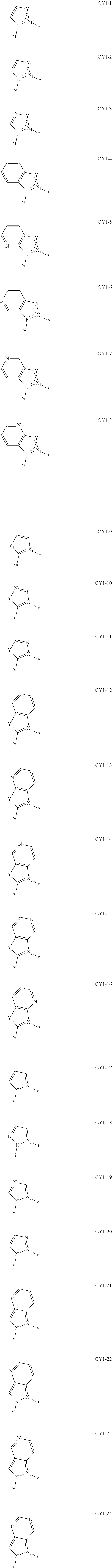

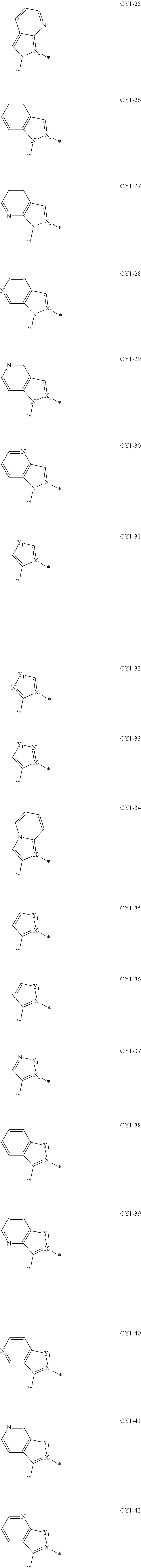

wherein, in Formulae CY1-1 to CY1-42,
X₁ is as described herein,
Y₁ may include O, S, N, C, or Si,
* indicates a binding site to M in Formula 1, and
*′ indicates a binding site to a neighboring atom in Formula 1.

In one or more embodiments, X₁ in Formulae CY1-1 to CY1-8 may be C, and X₁ in Formulae CY1-9 to CY1-42 may be N.

In one or more embodiments, a group represented by

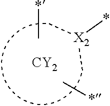

in Formula 1 may be a group represented by one of Formulae CY2-1 to CY2-11:

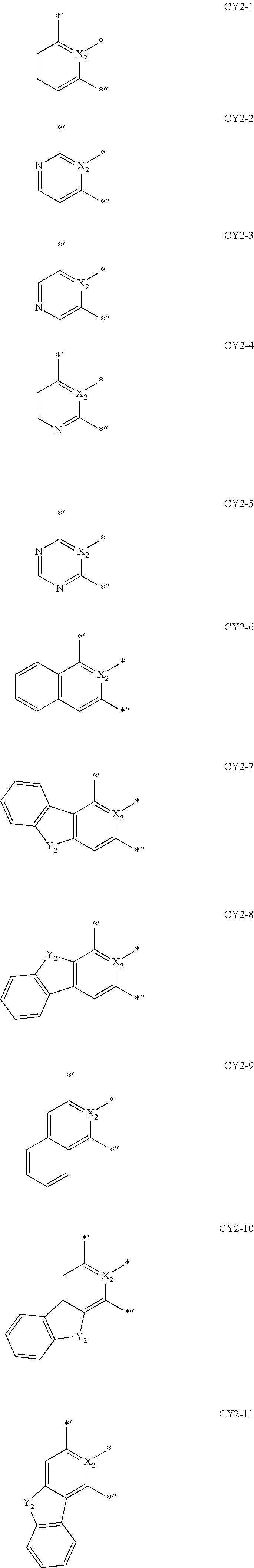

wherein, in Formulae CY2-1 to CY2-11,
X₂ is as described herein,
Y₂ may include O, S, N, C, or Si,
* indicates a binding site to M in Formula 1,
*′ indicates a binding site to ring CY₁ in Formula 1, and
*″ indicates a binding site to X₅₁ in Formula 1.

In one or more embodiments, a group represented by

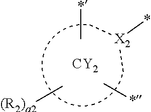

in Formula land a group represented by

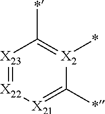

in Formulae 1-1 and 1-2 may each independently be a group represented by one of Formulae CY2(1) to CY2(26):

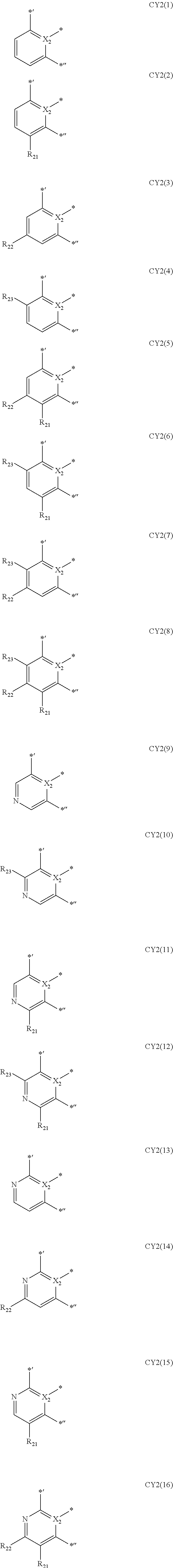

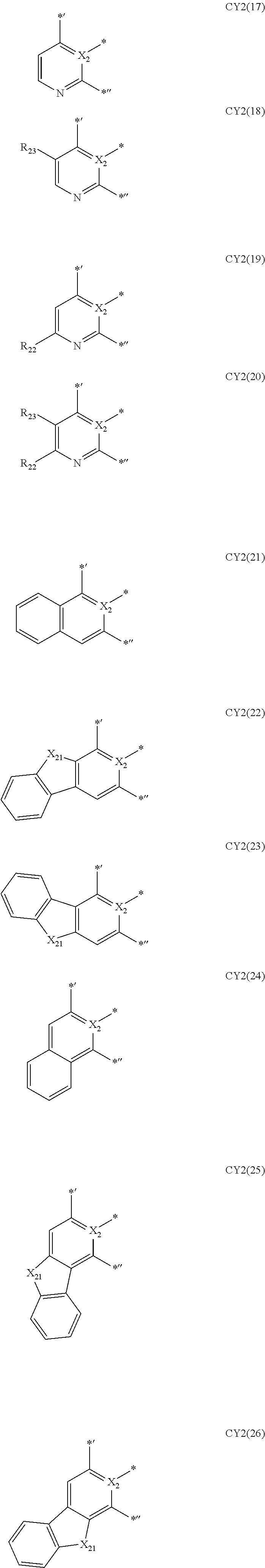

wherein, in Formulae CY2(1) to CY2(26),
X₂ is as described herein,
X₂₁ may be O, S, N(R₂₀), C(R₂₀ₐ)(R_{20b}), or Si(R₂₀ₐ)(R_{20b}),
R₂₀, R₂₀ₐ, R_{20b}, and R₂₁ to R₂₃ are each as described in connection with R₂, and R₂₁ to R₂₃ may each not be hydrogen,
* indicates a binding site to M in Formula 1,
*′ indicates a binding site to ring CY₁ in Formula 1, and
*″ indicates a binding site to X₅₁ in Formula 1.

In one or more embodiments, a group represented by

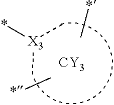

in Formula 1 may be a group represented by one of Formulae CY3-1 to CY3-23:

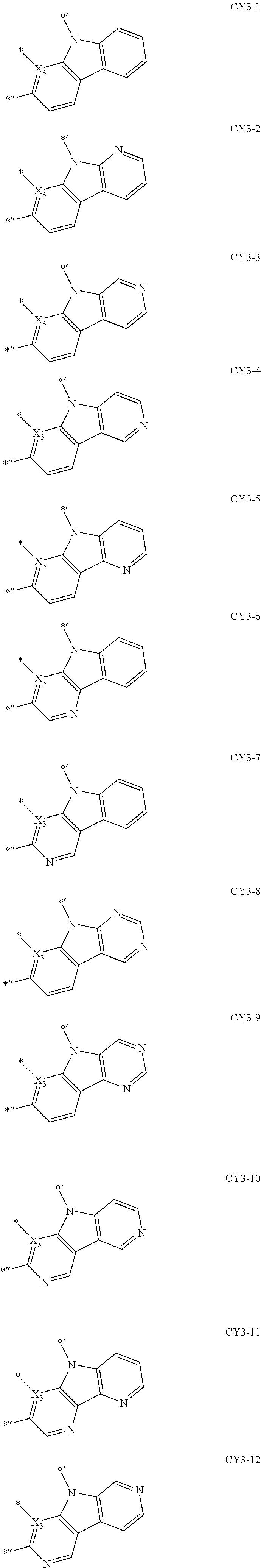

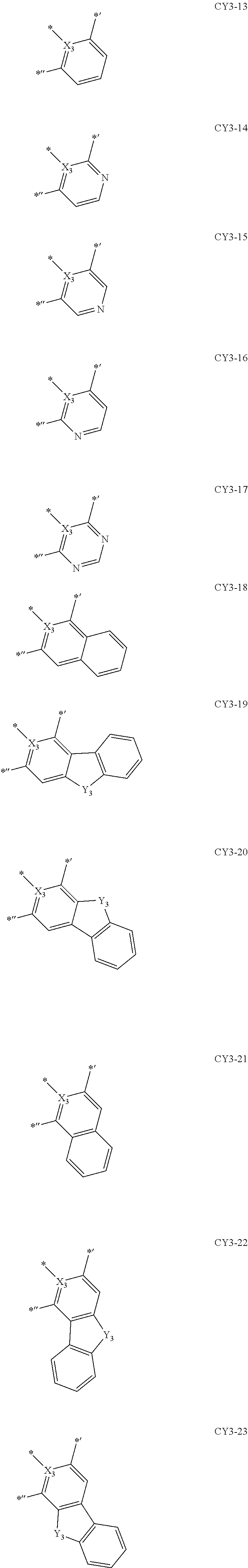

wherein, in Formulae CY3-1 to CY3-23,
X₃ is as described herein,
Y₃ may include O, S, N, C, or Si,
* indicates a binding site to M in Formula 1,
*′ indicates a binding site to X₅₂ in Formula 1, and
*″ indicates a binding site to X₅₁ in Formula 1.

In one or more embodiments, a group represented by

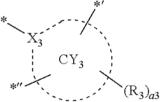

in Formula 1 may be a group represented by one of Formulae CY3(1) to CY3(20), and a group represented by

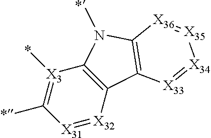

in Formulae 1-1 and 1-2 may be a group represented by one of Formulae CY3(1) to CY₃ (12):

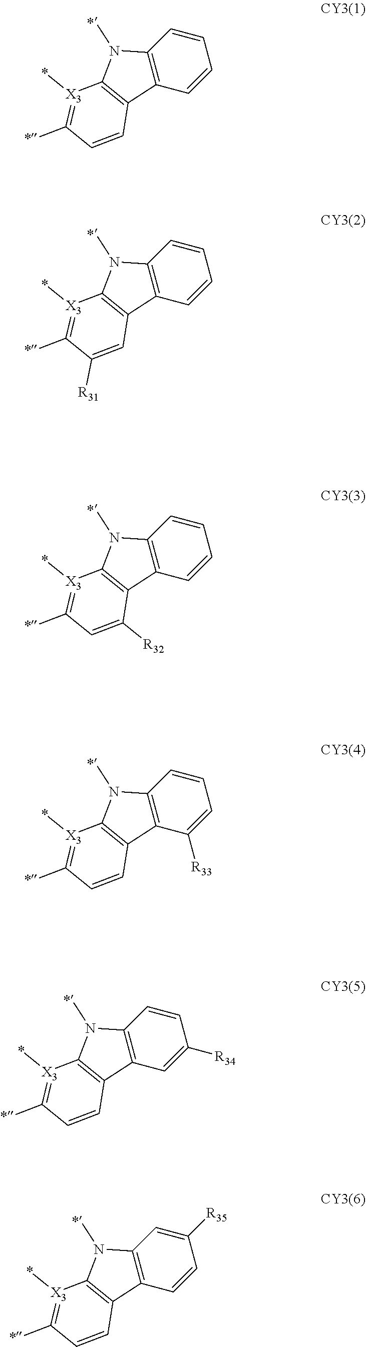

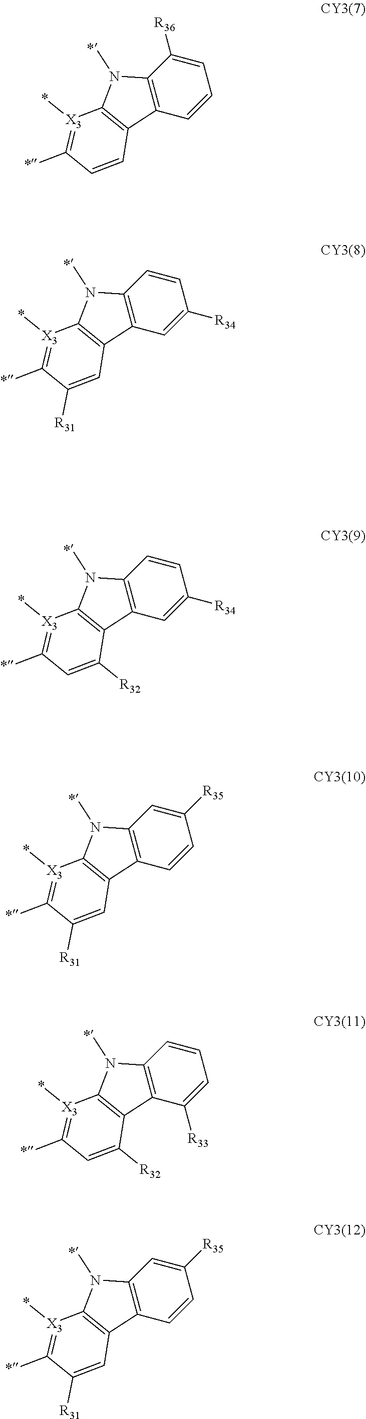

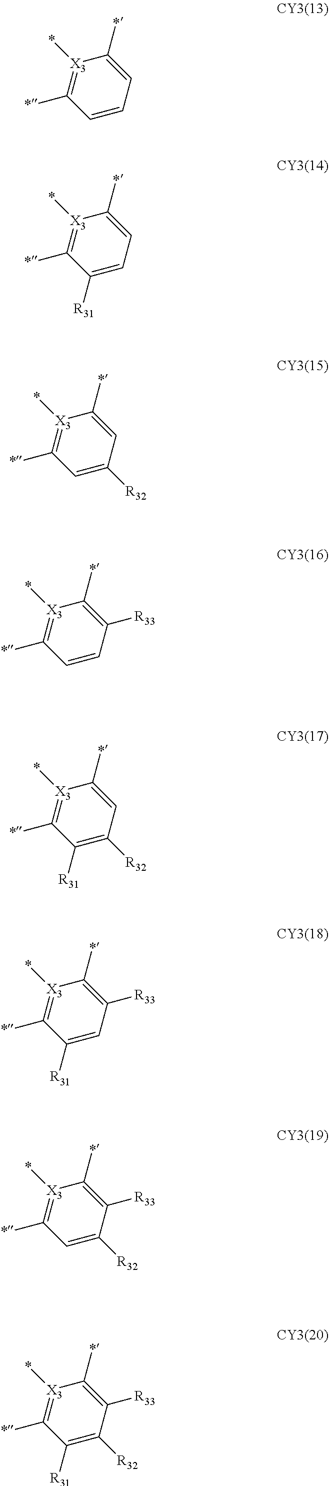

wherein, in Formulae CY3(1) to CY3(20),
X₃ is as described herein,
R₃₁ to R₃₆ are each as described in connection with R₃, wherein R₃₁ to R₃₆ may each not be hydrogen,
* indicates a binding site to M in Formula 1,
*′ indicates a binding site to X₅₂ in Formula 1, and
*″ indicates a binding site to X₅₁ in Formula 1.

In one or more embodiments, a group represented by

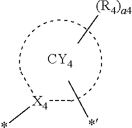

in Formula 1 may be a group represented by one of CY4(1) to CY4(16):

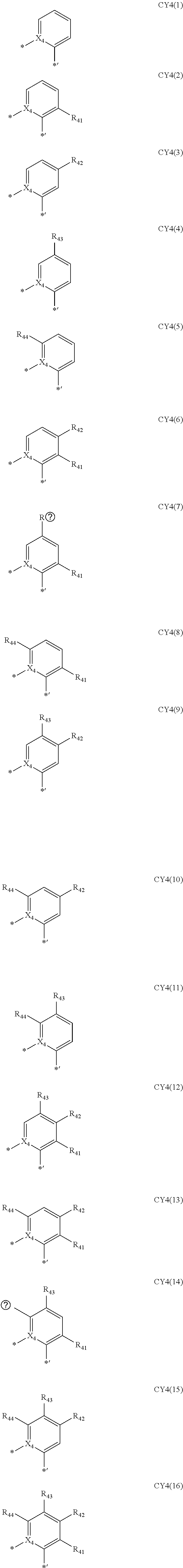

wherein, in Formulae CY4(1) to CY4(16),
X₄ is as described herein,
R₄₁ to R₄₄ are each as described in connection with R₄, and R₄₁ to R₄₄ may each not be hydrogen,
* indicates a binding site to M in Formula 1, and
*′ indicates a binding site to X₅₂ in Formula 1.

Ar₁ in Formula 1 may be a group represented by Formula 1A:

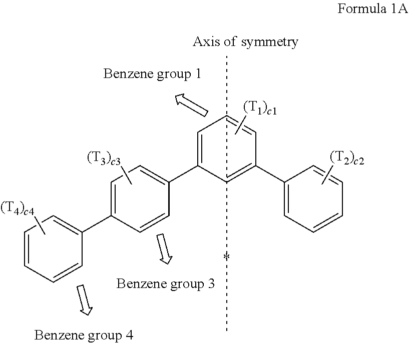

wherein, Formula 1A includes a “Benzene group 4” bonded to the para-position in a “Benzene group 3” with respect to carbon which is bonded to a “Benzene group 1.” In some embodiments, in Formula 1A, a group represented by

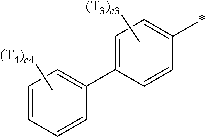

and a group represented by

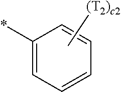

may be different from each other. In other words, Formula 1A has an asymmetric structure with respect to the axis of symmetry.

Accordingly, 1) the intramolecular movement of Formula 1A is suppressed or reduced and Stoke's shift is reduced, thereby increasing the PLQY of the organometallic compound represented by Formula 1, 2) during formation of a film including the organometallic compound, the intramolecular packing effect is reduced, thereby lowering the sublimation temperature and deposition temperature, and 3) interference between other substituents in the molecule of the organometallic compound is minimized or reduced by the “Benzene group 3” and the “Benzene group 4.” Thus, the non-radiative decay rate (Knr) and Dexter energy transfer of a light-emitting device including the organometallic compound represented by Formula 1 are reduced, and thus, the luminescence efficiency and/or lifespan of the light-emitting device may be improved.

In one or more embodiments, Formula 1A may further include at least one C₁-C₂₀ alkyl group that is unsubstituted or substituted with deuterium. Accordingly, the asymmetry and bulkiness of Formula 1A may be increased, and thus, the luminescence efficiency and/or lifespan of a light-emitting device including the organometallic compound may be further improved.

In one or more embodiments, b51 to b53 in Formula 2 indicate the number of L₅₁ to the number of L₅₃, respectively, and may each be an integer from 1 to 5. When b51 is 2 or more, two or more of L₅₁ may be identical to or different from each other, when b52 is 2 or more, two or more of L₅₂ may be identical to or different from each other, and when b53 is 2 or more, two or more of L₅₃ may be identical to or different from each other. In one or more embodiments, b51 to b53 may each independently be 1 or 2.

L₅₁ to L₅₃ in Formula 2 may each independently be:
a single bond; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxacilline group, a dibenzothiacilline group, a dibenzodihydroazacilline group, a dibenzodihydrodicilline group, a dibenzodihydrocilline group, a dibenzodioxane group, a dibenzooxathiene group, a dibenzooxazine group, a dibenzopyran group, a dibenzodithiine group, a dibenzothiazine group, a dibenzothiopyran group, a dibenzocyclohexadiene group, a dibenzodihydropyridine group, or a dibenzodihydropyrazine group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or a (e.g., any) combination thereof, and
Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In one or more embodiments, in Formula 2, a bond between L₅₁ and R₅₁, a bond between L₅₂ and R₅₂, a bond between L₅₃ and R₅₃, a bond between two or more L₅₁, a bond between two or more L₅₂, a bond between two or more L₅₃, a bond between L₅₁ and carbon between X₅₄ and X₅₅ in Formula 2, a bond between L₅₂ and carbon between X₅₄ and X₅₆ in Formula 2, and a bond between L₅₃ and carbon between X₅₅ and X₅₆ in Formula 2 may each be a “carbon-carbon single bond.”

In Formula 2, X₅₄ may be N or C(R₅₄), X₅₅ may be N or C(R₅₅), X₅₆ may be N or C(R₅₆), and at least one of X₅₄ to X₅₆ may be N. R₅₄ to R₅₆ are each as described herein. In one or more embodiments, two or three of X₅₄ to X₅₆ may be N.

R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} as utilized herein may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Q₁ to Q₃ are each as described herein.

For example, i) R₁ to R₄, Z₅₁a, Z₅₁b, Z₅₂ₐ, Z_{52b}, and T₁ to T₄ in Formula 1, ii) R₅₁ to R₅₆, R₇₁ to R₇₄, R₈₁ to R₈₅, R₈₂ₐ, R_{82b}, R₈₃ₐ, R_{83b}, R₈₄ₐ and R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in Formulae 2, 3-1 to 3-5, 502, and 503, and iii) R₁₀ₐ may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or a (e.g., any) combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzothiazolyl group, a benzoisoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or a (e.g., any) combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or a (e.g., any) combination thereof:

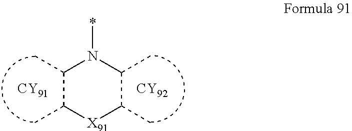

wherein, in Formula 91,
ring CY₉₁ and ring CY₉₂ may each independently be a C₅-C₃₀ carbocyclic group that is unsubstituted or substituted with at least one R₁₀ₐ or a C₁-C₃₀ heterocyclic group that is unsubstituted or substituted with at least one R₁₀ₐ,
X₉₁ may be a single bond, O, S, N(R₉₁), B(R₉₁), C(R₉₁ₐ)(R_{11b}), or Si(R₉₁ₐ)(R_{11b}),
R₉₁, R₁₁ₐ, and R_{91b} are each as described in connection with R₈₂, R₈₂ₐ, and R_{82b}, respectively,
R₁₀ₐ is as described herein, and
* indicates a binding site to a neighboring atom.

For example, in Formula 91,
ring CY₉₁ and ring CY₉₂ may each independently be a benzene group, a pyridine group, a pyrimidine group, a pyrazine group, a pyridazine group, or a triazine group, each unsubstituted or substituted with at least one R₁₀ₐ,
R₁₁, R₁₁ₐ, and R_{91b} may each independently be:
hydrogen or a C₁-C₁₀ alkyl group; or
a phenyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or a (e.g., any) combination thereof.

In one or more embodiments, i) R₁ to R₄, Z₅₁ₐ, Z_{51b}, Z₅₂ₐ, Z_{52b}, and T₁ to T₄ in Formula 1, ii) R₅₁ to R₅₆, R₇₁ to R₇₄, R₈₁ to R₈₅, R₈₂ₐ, R_{82b}, R₈₃ₐ, R_{83b}, R₈₄ₐ and R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in Formulae 2, 3-1 to 3-5, 502, and 503, and iii) R₁₀ₐ may each independently be hydrogen, deuterium, —F, a cyano group, a nitro group, —CH₃, —CD₃, —CD₂H, —CDH₂, —CF₃, —CF₂H, —CFH₂, a group represented by one of Formulae 9-1 to 9-19, a group represented by one of Formulae 10-1 to 10-246, —C(Q₁)(Q₂)(Q₃), —Si(Q₁)(Q₂)(Q₃), or —P(═O)(Q₁)(Q₂) (Q₁ to Q are each as described herein):

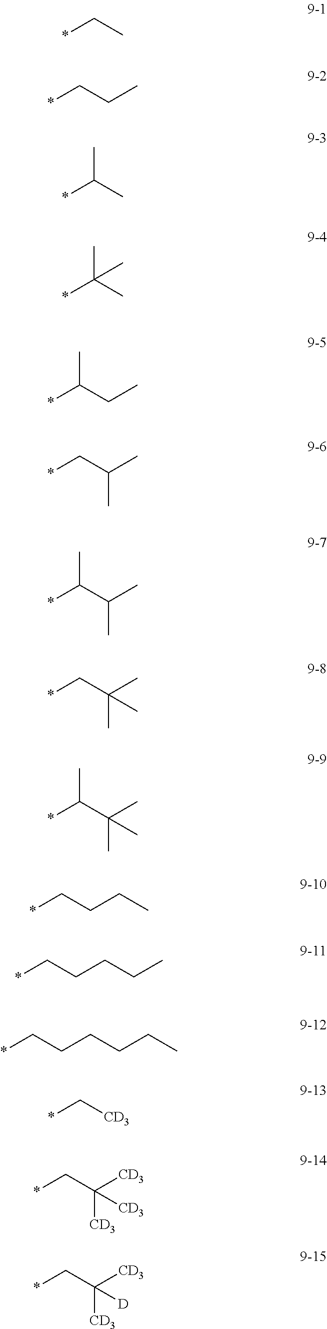

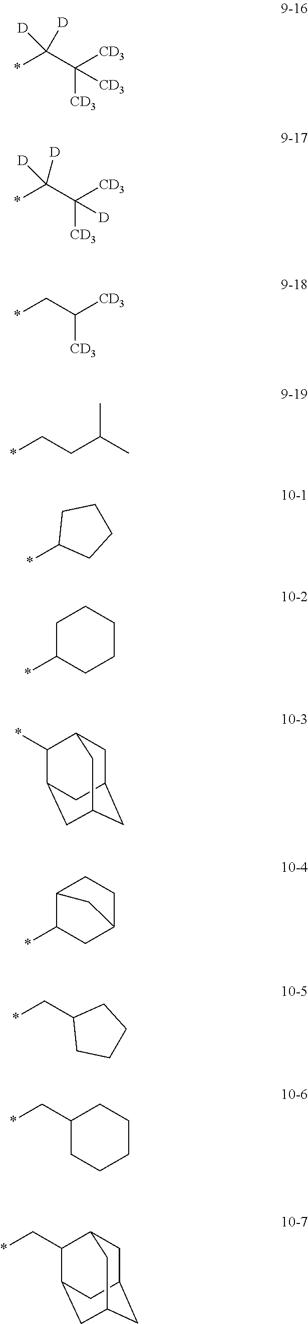

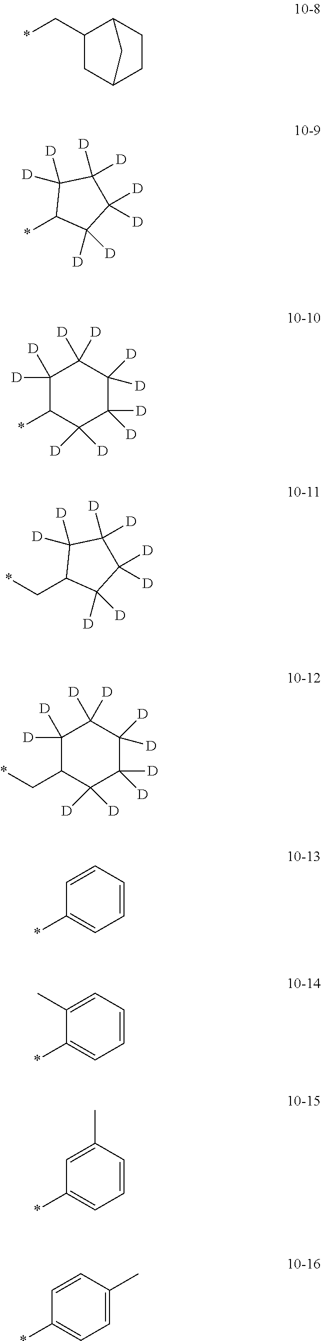

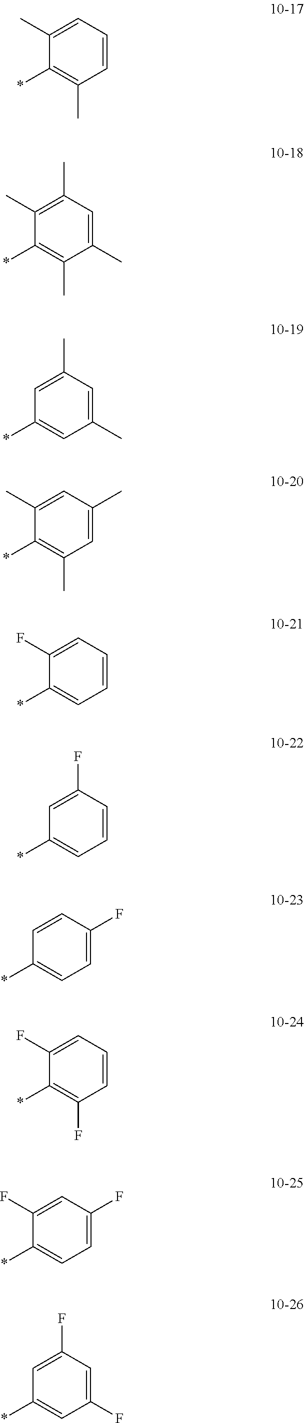

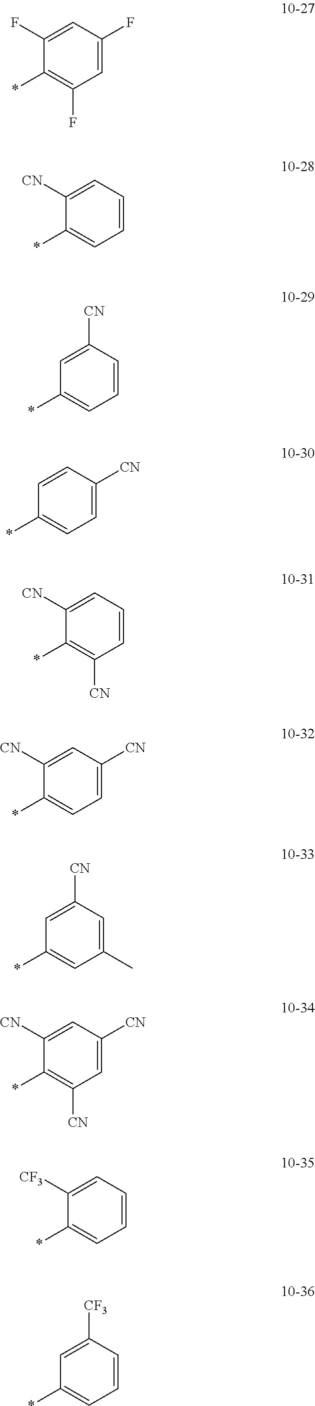

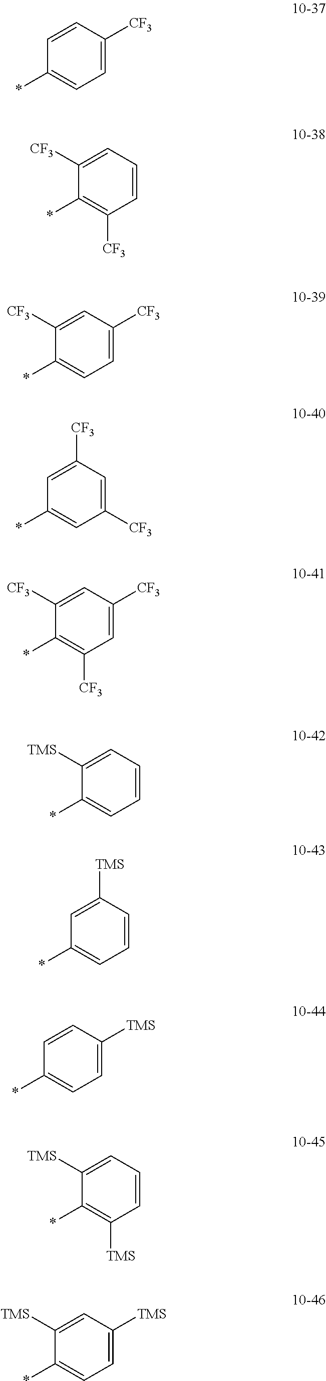

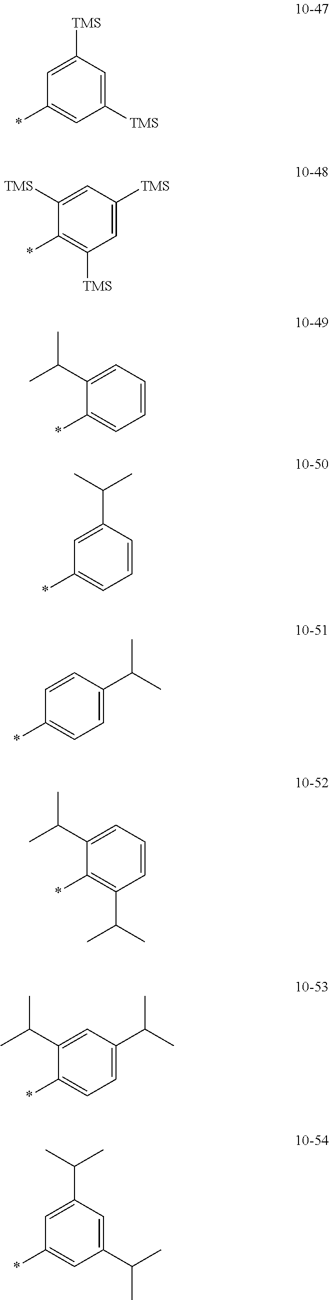

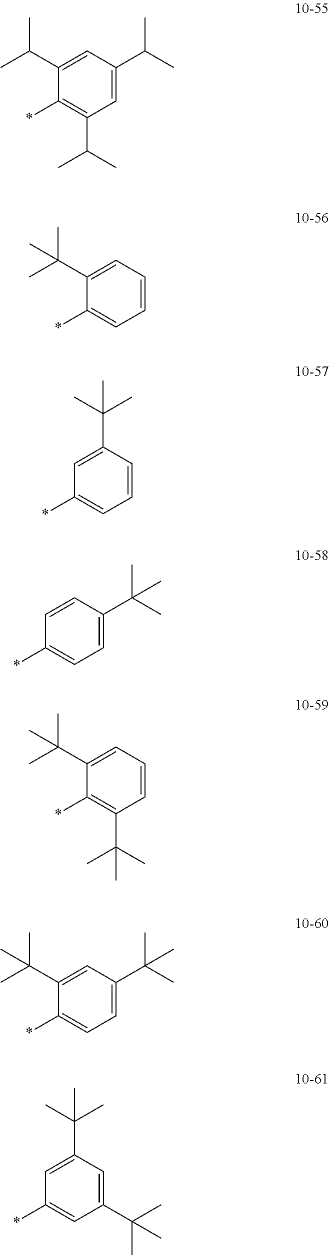

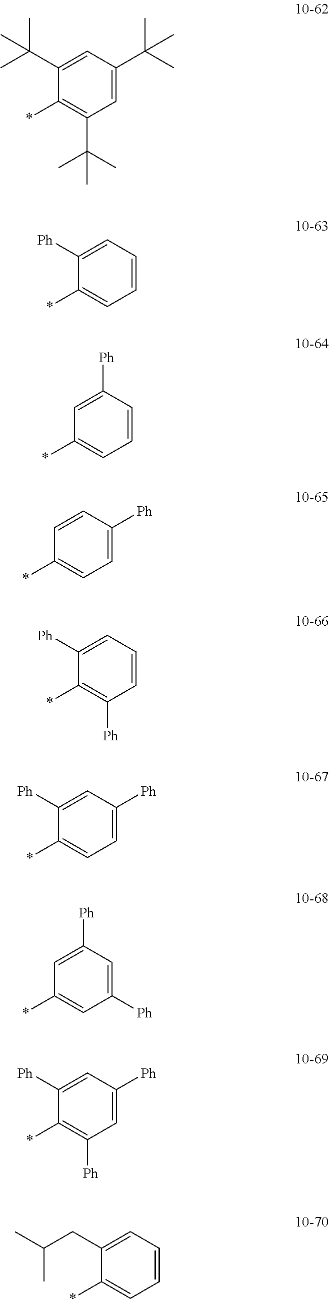

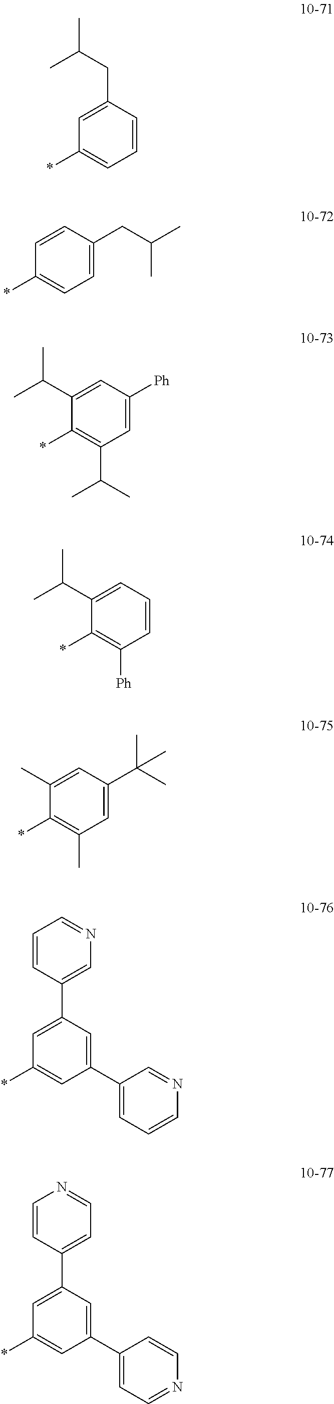

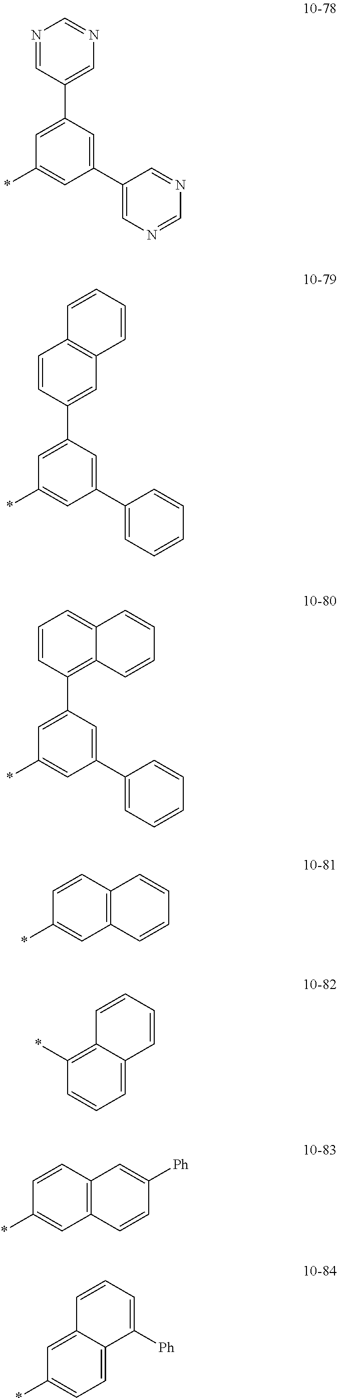

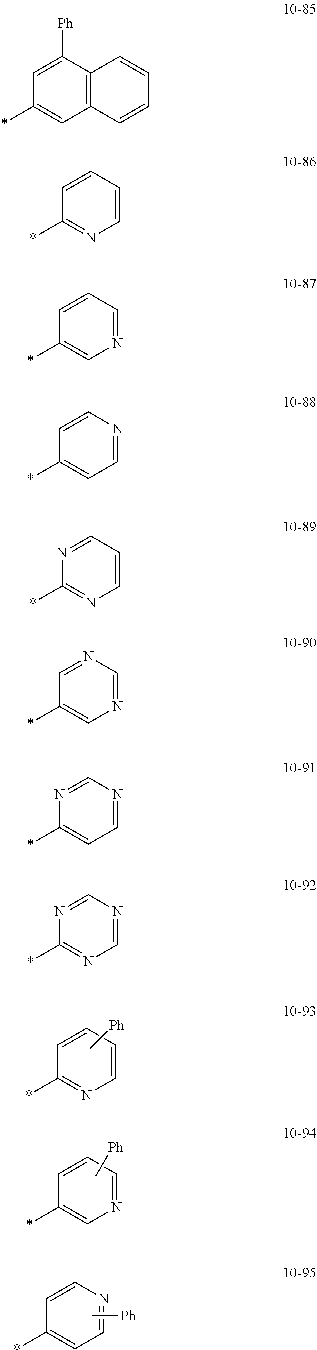

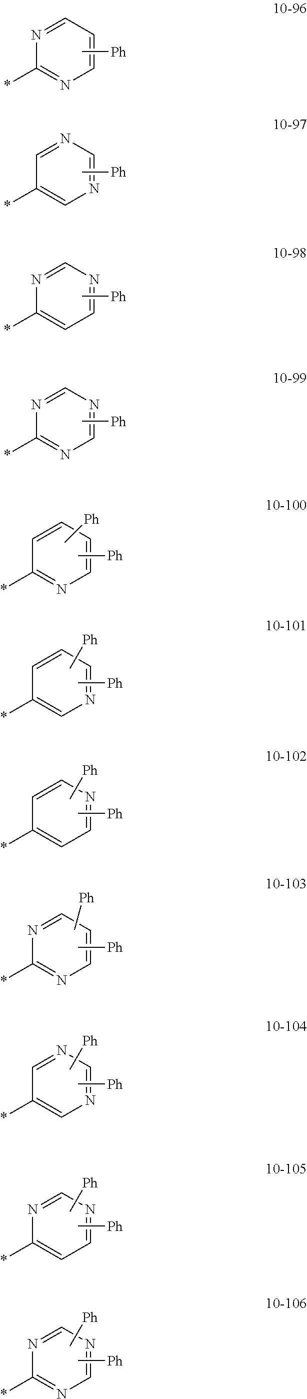

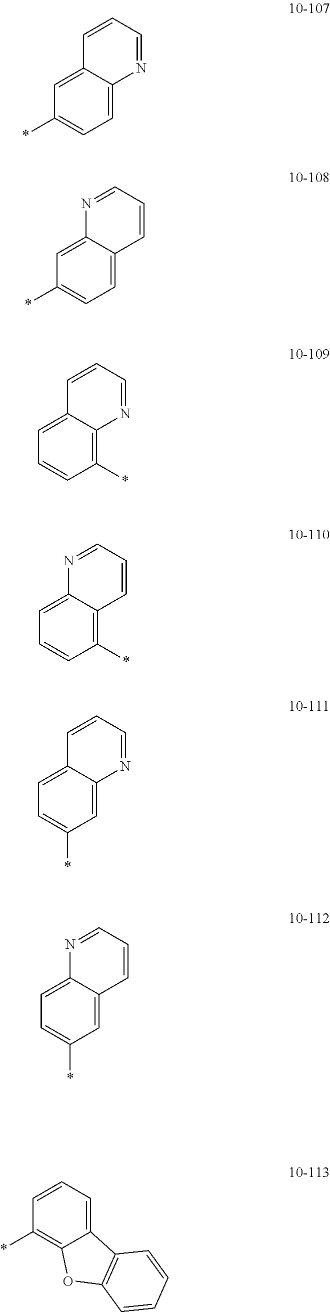

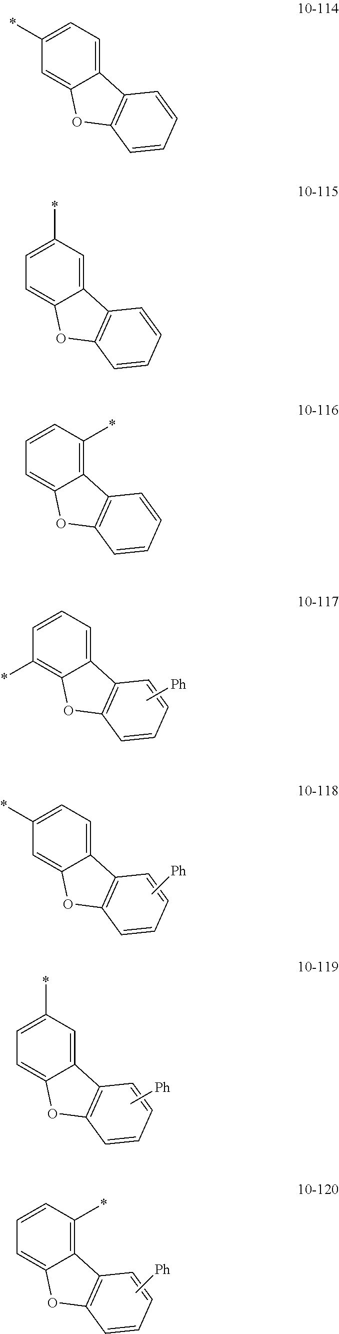

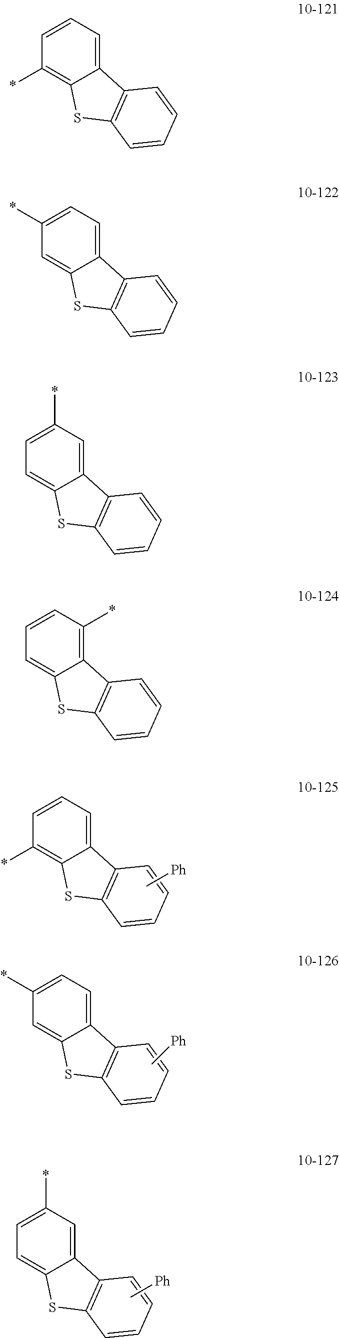

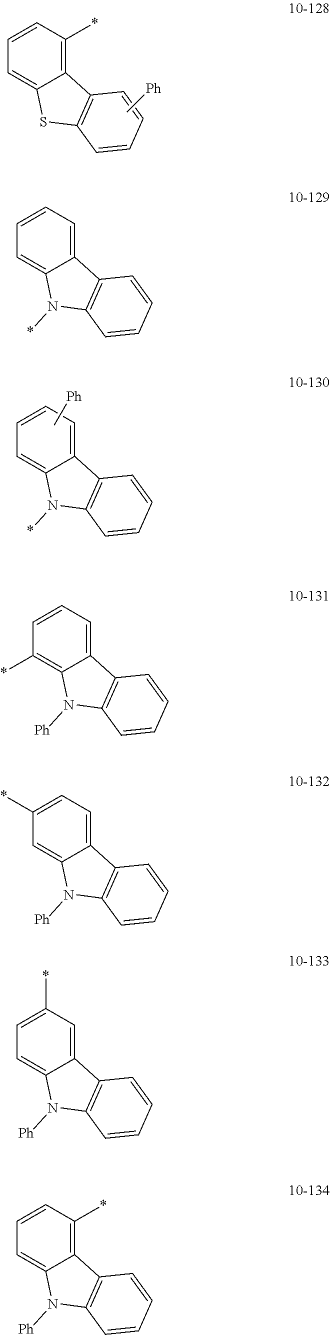

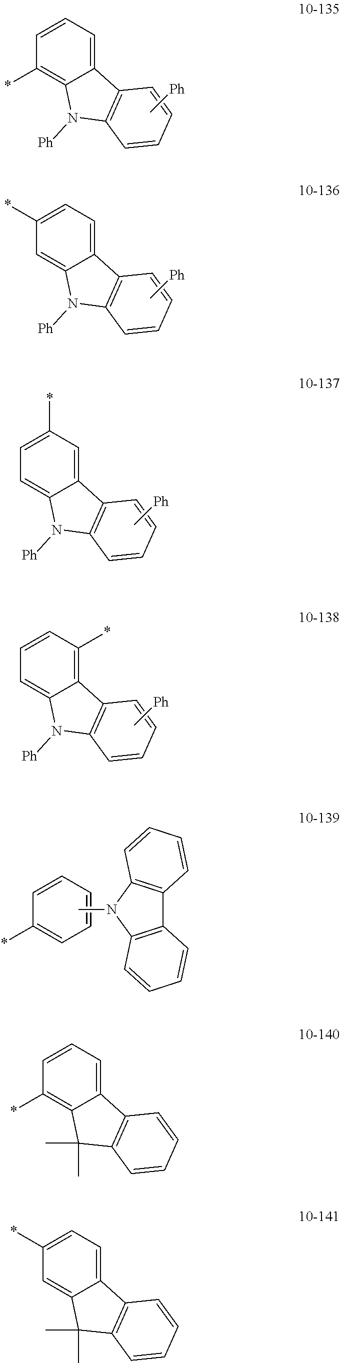

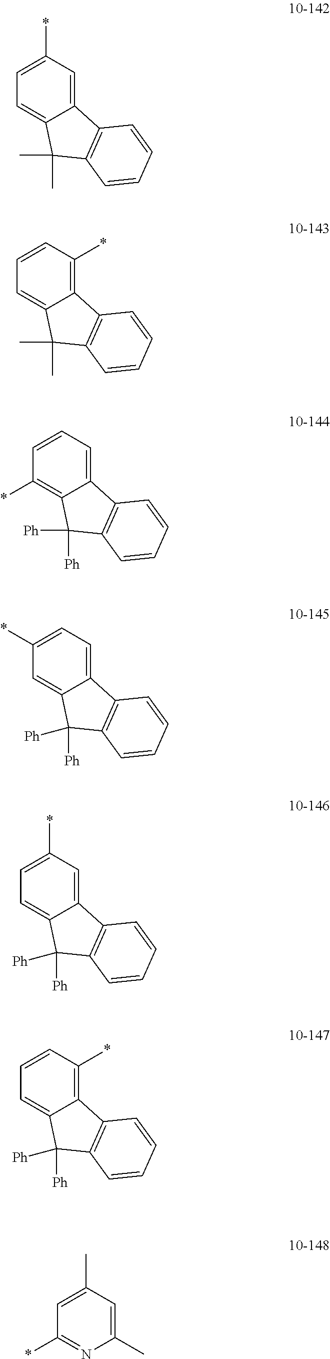

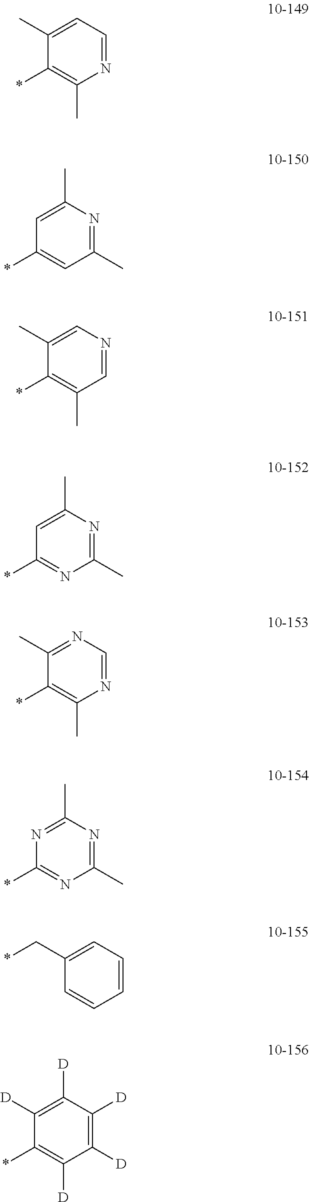

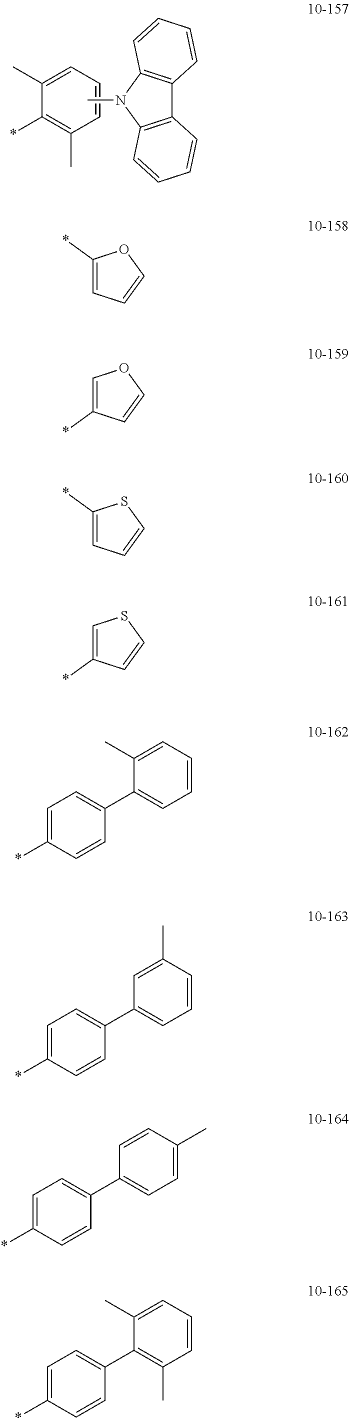

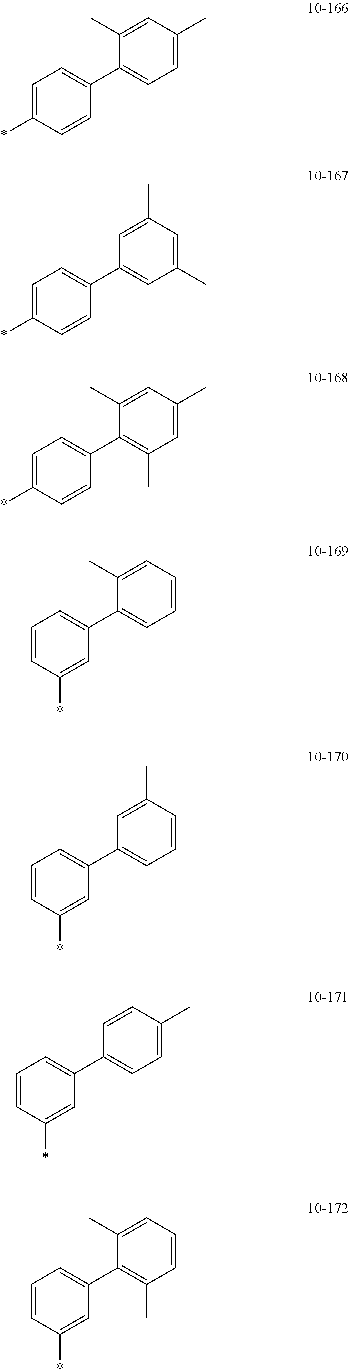

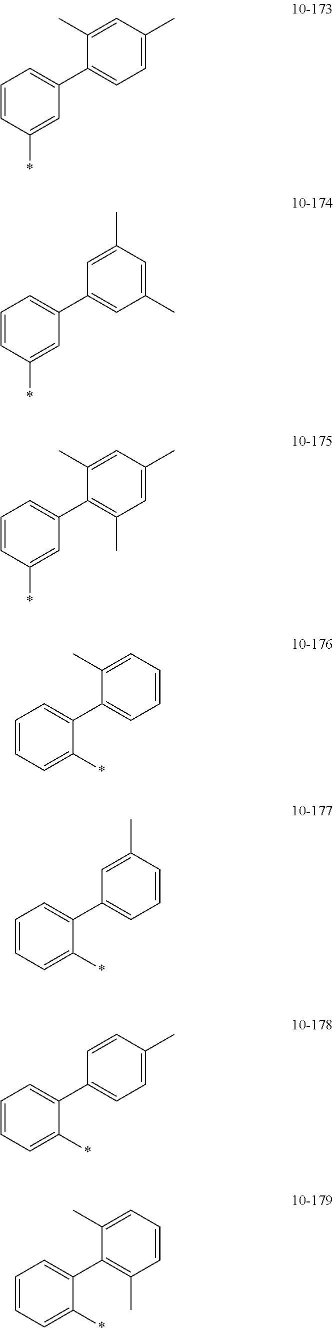

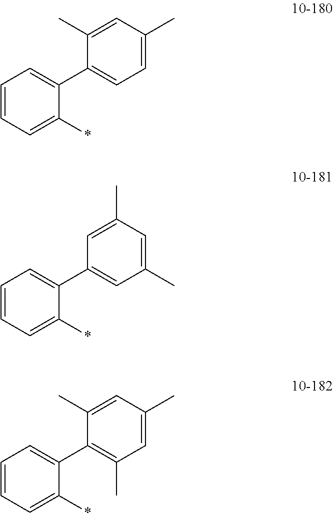

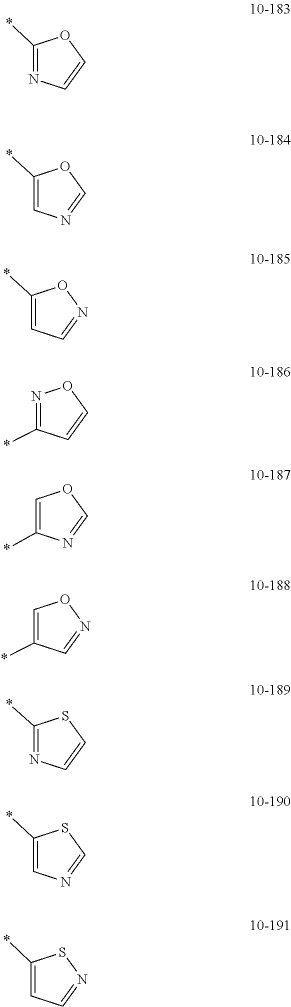

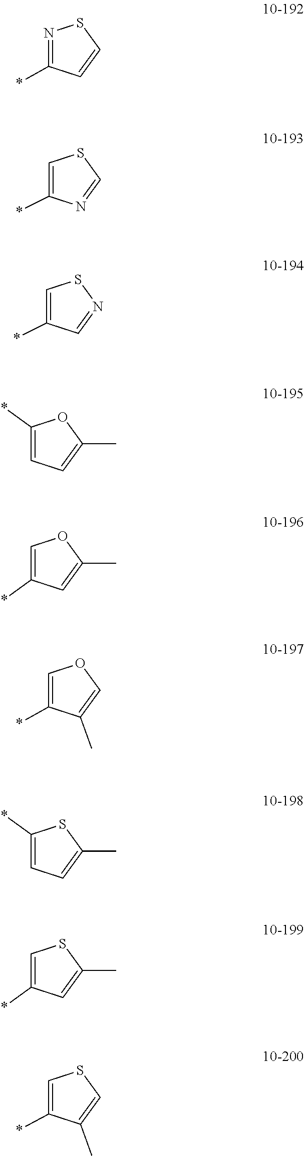

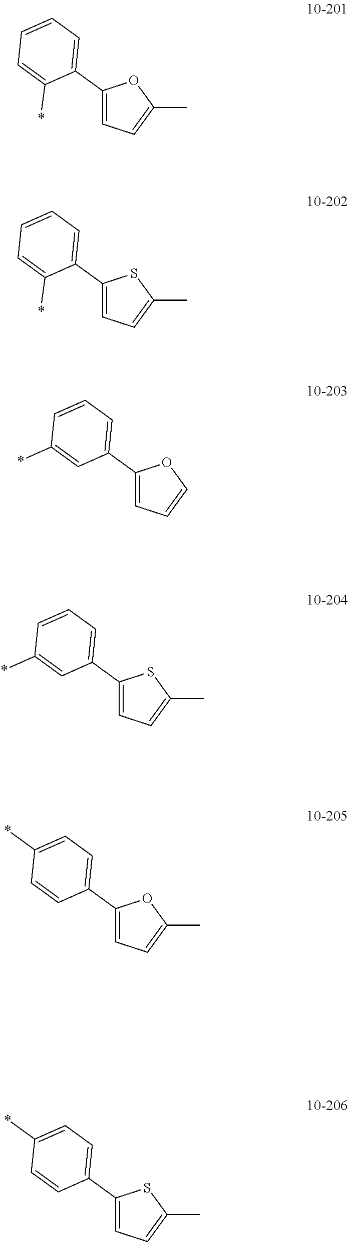

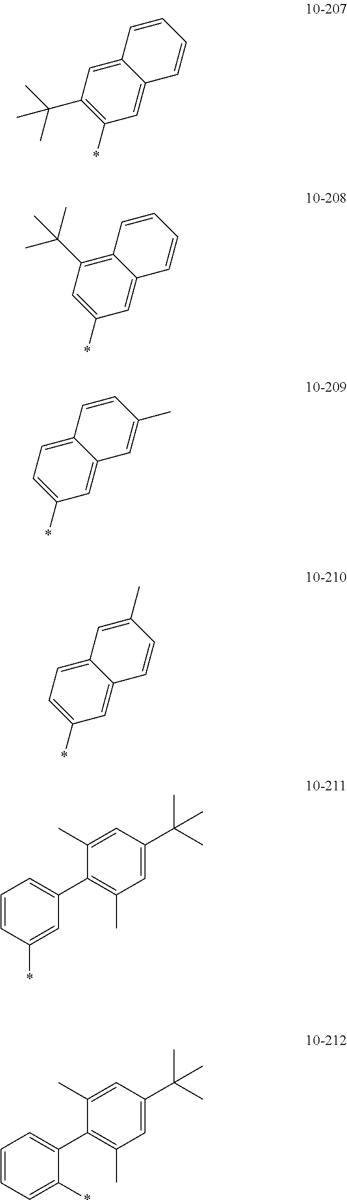

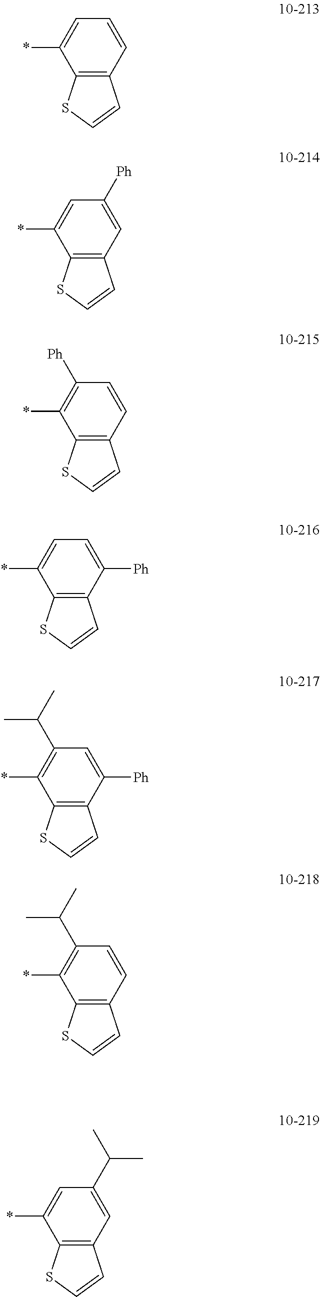

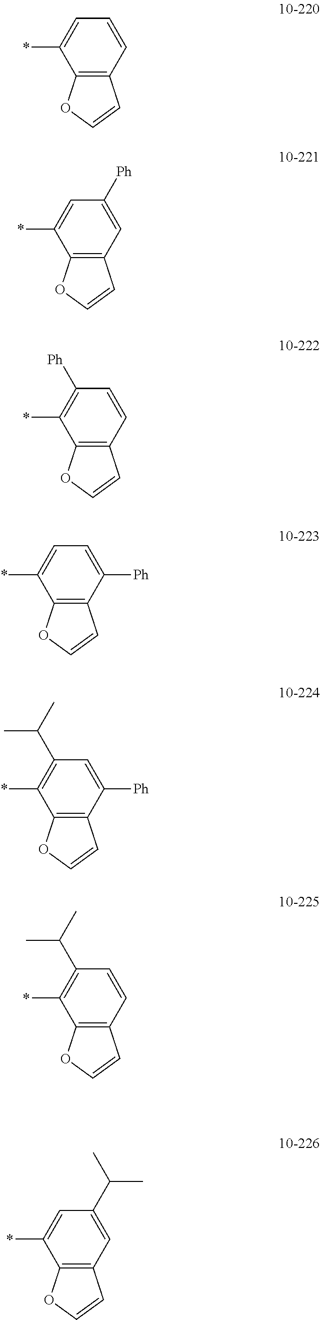

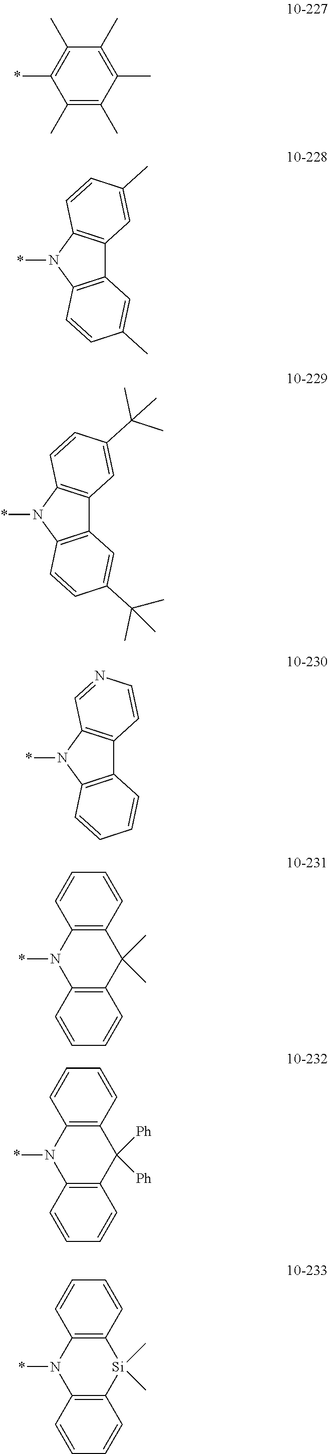

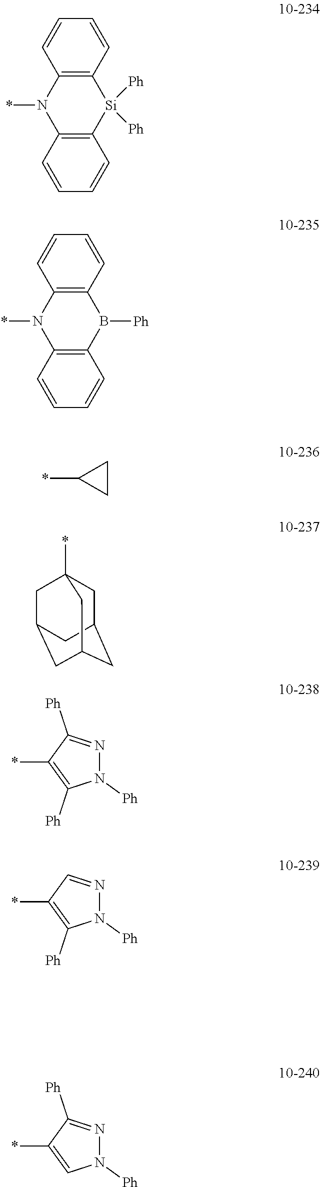

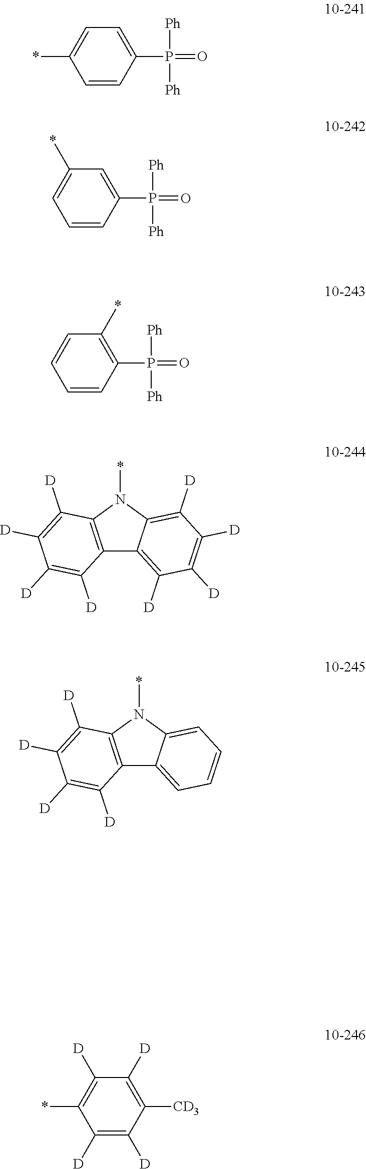

wherein, in Formulae 9-1 to 9-19 and 10-1 to 10-246, * indicates a binding site to a neighboring atom, “D” represents a deuterium atom, “Ph” represents a phenyl group, and “TMS” represents a trimethylsilyl group.

In Formulae 3-1 to 3-5, 502, and 503, a71 to a74 and a501 to a504 indicate the number of R₇₁ to the number of R₇₄ and the number of R₅₀₁ to the number of R₅₀₄, respectively, and may each independently be an integer from 0 to 20. When a71 is 2 or more, two or more of R₇₁ may be identical to or different from each other, when a72 is 2 or more, two or more of R₇₂ may be identical to or different from each other, when a73 is 2 or more, two or more of R₇₃ may be identical to or different from each other, when a74 is 2 or more, two or more of R₇₄ may be identical to or different from each other, when a501 is 2 or more, two or more of R₅₀₁ may be identical to or different from each other, when a502 is 2 or more, two or more of R₅₀₂ may be identical to or different from each other, when a503 is 2 or more, two or more of R₅₀₃ may be identical to or different from each other, and when a504 is 2 or more, two or more of R₅₀₄ may be identical to or different from each other. a71 to a74 and a501 to a504 may each independently be an integer from 0 to 8.

Each of a group represented by *-(L₅₁)_{b51}-R₅₁ and a group represented by *-(L₅₂)_{b52}-R₅₂ in Formula 2 may not be a phenyl group.

In one or more embodiments, a group represented by *-(L₅₁)_{b51}-R₅₁ and a group represented by *-(L₅₂)_{b52}-R₅₂ in Formula 2 may be identical to each other.

In one or more embodiments, a group represented by *-(L₅₁)_{b51}-R₅₁ and a group represented by *-(L₅₂)_{b52}-R₅₂ in Formula 2 may be different from each other.

In one or more embodiments, in Formula 2, b51 and b52 may each be 1, 2, or 3, and L₅₁ and L₅₂ may each independently be a benzene group, a pyridine group, a pyrimidine group, a pyridazine group, a pyrazine group, or a triazine group, each unsubstituted or substituted with at least one R₁₀ₐ.

In one or more embodiments, R₅₁ and R₅₂ in Formula 2 may each independently be a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), or —Si(Q₁)(Q₂)(Q₃), and
Q₁ to Q₃ may each independently be a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a (e.g., any) combination thereof.

In one or more embodiments,
a group represented by *-(L₅₁)_{b51}-R₅₁ in Formula 2 may be a group represented by one of Formulae CY51-1 to CY51-26, and/or
a group represented by *-(L₅₂)_{b52}-R₅₂ in Formula 2 may be a group represented by one of Formulae CY52-1 to CY52-26, and/or
a group represented by *-(L₅₃)_{b53}-R₅₃ in Formula 2 may be a group represented by one of Formulae CY53-1 to CY53-27, —C(Q₁)(Q₂)(Q₃), or —Si(Q₁)(Q₂)(Q₃) (Q₁ to Q₃ may be the same as described herein):

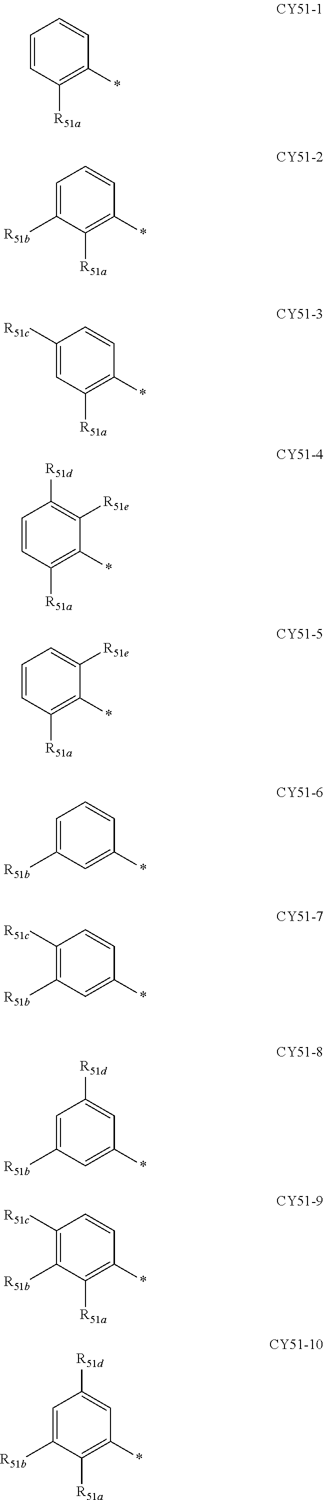

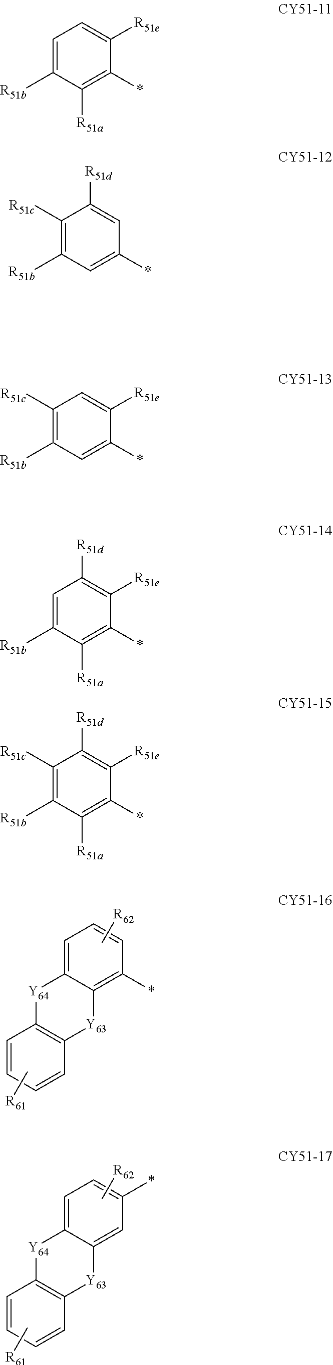

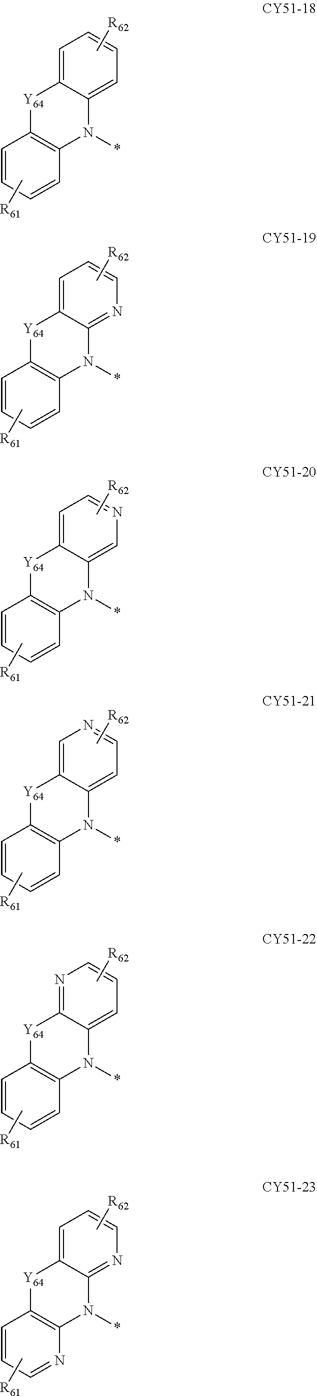

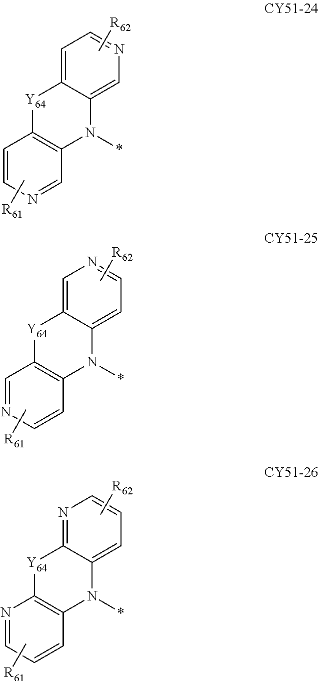

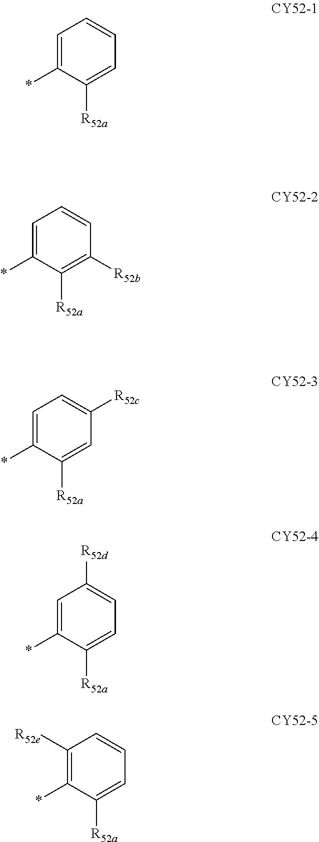

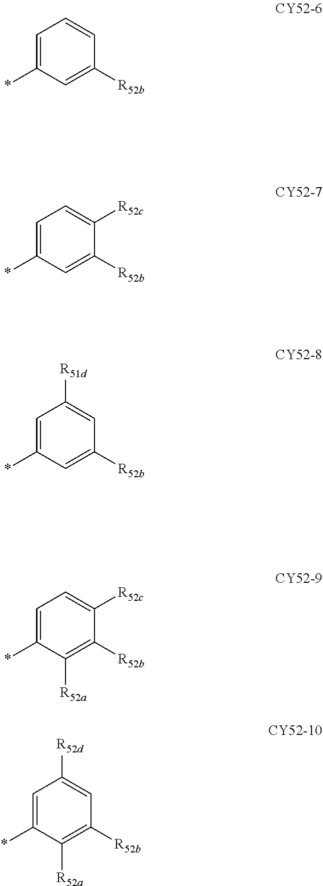

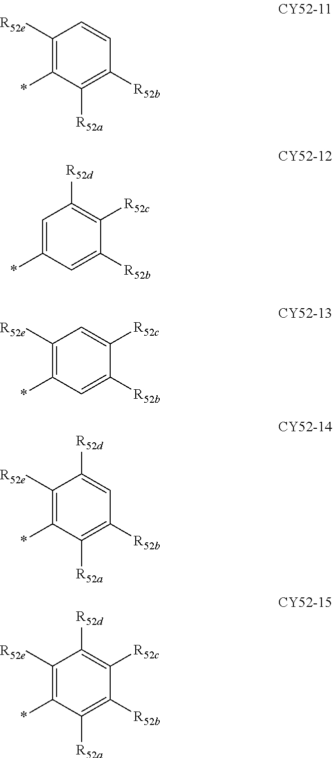

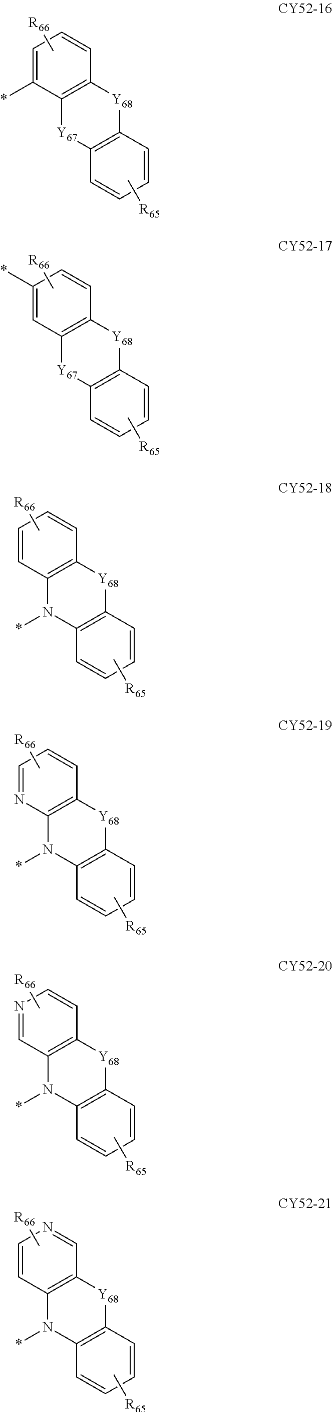

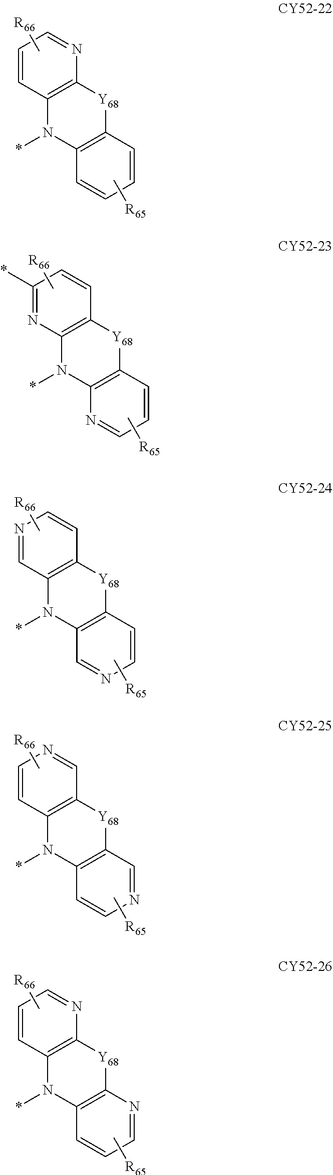

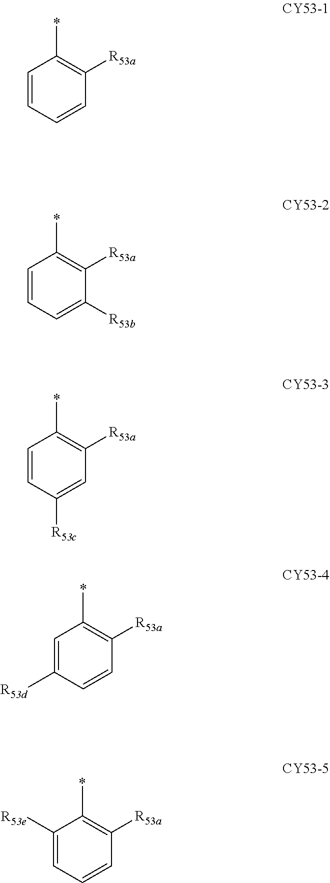

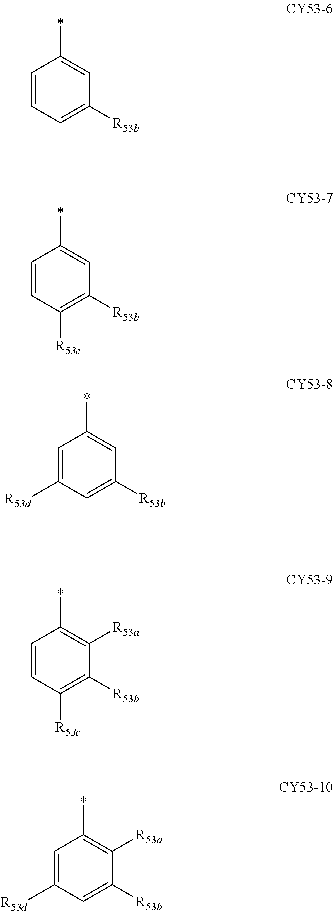

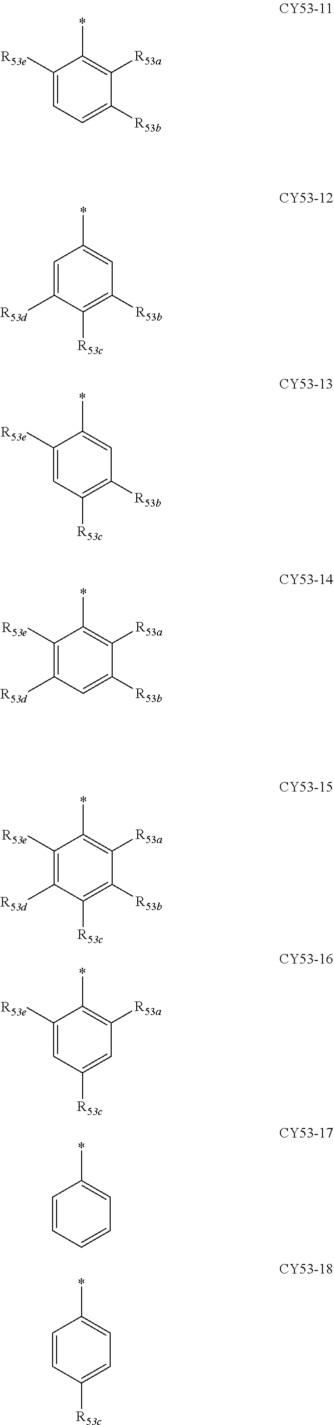

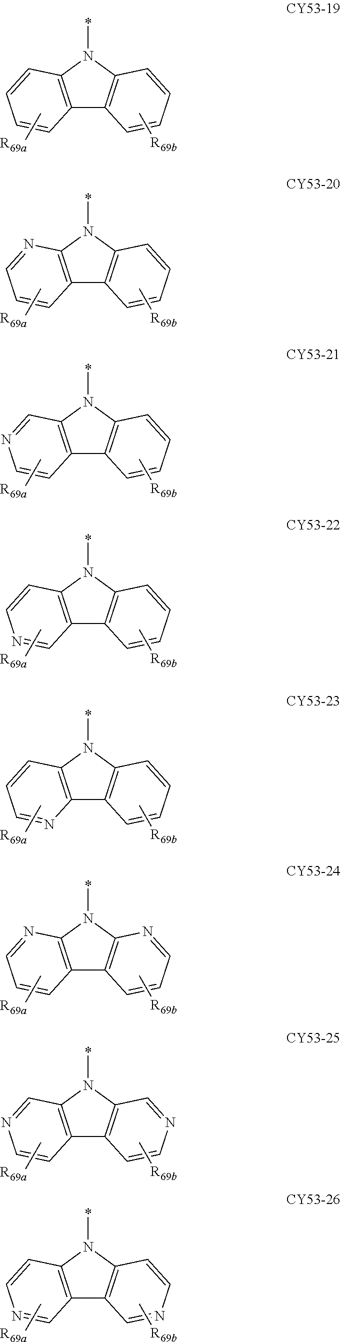

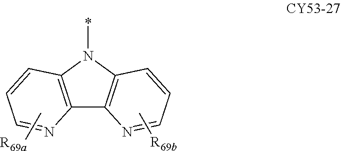

wherein, in Formulae CY51-1 to CY51-26, CY52-1 to CY52-26, and CY53-1 to CY53-27,
Y₆₃ may be a single bond, O, S, N(R₆₃), B(R₆₃), C(R₃₆₃ₐ)(R_{363b}), or Si(R₆₃ₐ)(R_{63b}),
Y₆₄ may be a single bond, O, S, N(R₆₄), B(R₆₄), C(R₆₄ₐ)(R_{64b}), or Si(R₆₄ₐ)(R_{64b}),
Y₆₇ may be a single bond, O, S, N(R₆₇), B(R₆₇), C(R₆₇ₐ)(R_{67b}), or Si(R₆₇ₐ)(R_{67b}),
Y₆₈ may be a single bond, O, S, N(R₆₈), B(R₆₈), C(R₆₈ₐ)(R_{68b}), or Si(R₆₈ₐ)(R_{68b}),
each of Y₆₃ and Y₆₄ in Formulae CY51-16 and CY51-17 may not be a single bond simultaneously (e.g., at the same time),
each of Y₆₇ and Y₆₈ in Formulae CY52-16 and CY52-17 may not be a single bond simultaneously (e.g., at the same time),
R₅₁ₐ to R₅₁ₑ, R₆₁ to R₆₄, R₆₃ₐ, R_{63b}, R₆₄ₐ, and R_{64b} are each as described in connection with R₅₁, wherein R₅₁ₐ to R₅₁ₑ may not each be hydrogen,
R₅₂ₐ to R₅₂ₑ, R₆₅ to R₆₈, R₆₇ₐ, R_{67b}, R₆₈ₐ, and R_{68b} are each as described in connection with R₅₂, wherein R₅₂ₐ to R₅₂ₑ may not each be hydrogen,
R₅₃ₐ to R₅₃ₑ, R₆₉ₐ, and R_{69b} are each as described in connection with R₅₃, and R₅₃ₐ to R₅₃ₑ may not each be hydrogen, and
* indicates a binding site to a neighboring atom.

In one or more embodiments,
R₅₁ₐ to R₅₁ₑ and R₅₂ₐ to R₅₂ₑ in Formulae CY51-1 to CY51-26 and Formulae CY52-1 to CY52-26 may each independently be:
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or a (e.g., any) combination thereof; or
—C(Q₁)(Q₂)(Q₃) or —Si(Q₁)(Q₂)(Q₃), and
Q₁ to Q₃ may each independently be a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or a (e.g., any) combination thereof,
in Formulae CY51-16 and CY51-17, i) Y₆₃ may be O or S, and Y₆₄ may be Si(R₆₄ₐ)(R_{64b}), or ii) Yes may be Si(R₆₃ₐ)(R_{63b}), and Y₆₄ may be O or S, and
in Formulae CY52-16 and CY52-17, i) Y₆₇ may be O or S, and Yes may be Si(R₆₈ₐ)(R_{68b}), or ii) Y₆₇ may be Si(R₆₇ₐ)(R_{67b}), and Yes may be O or S.

In Formulae 3-1 to 3-5, L₈₁ to L₈₅ may each independently be:
a single bond; or
*—C(Q₄)(Q₅)-*′ or *—Si(Q₄)(Q₅)-*′, * and *′ each indicate a binding site to a neighboring atom; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or a (e.g., any) combination thereof, and
Q₄, Q₅, and Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In one or more embodiments, a group represented by

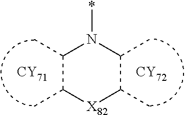

in Formulae 3-1 and 3-2 may be a group represented by one of Formulae CY71-1(1) to CY71-1(8), and/or
a group represented by

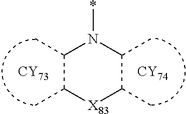

in Formulae 3-1 and 3-3 may be a group represented by one of Formulae CY71-2(1) to CY71-2(8), and/or
a group represented by

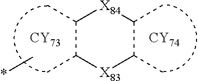

in Formulae 3-2 and 3-4 may be a group represented by one of Formulae CY71-3(1) to CY71-3(32), and/or
a group represented by

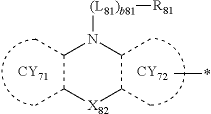

in Formulae 3-3 to 3-5 may be a group represented by one of Formulae CY71-4(1) to CY71-4(32), and/or
a group represented by

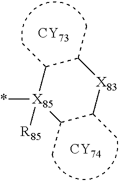

in Formula 3-5 may be a group represented by one of Formulae CY71-5(1) to CY71-5(8):

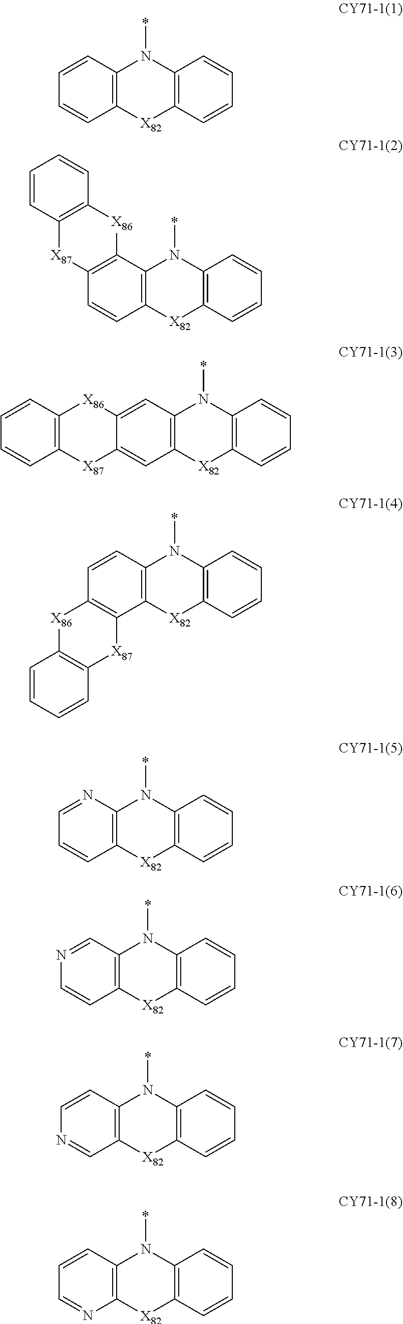

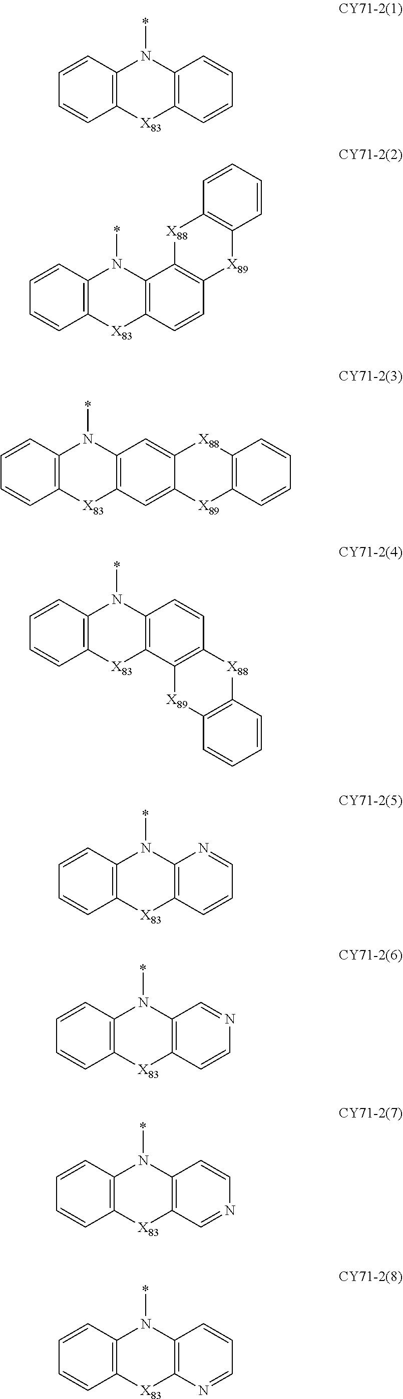

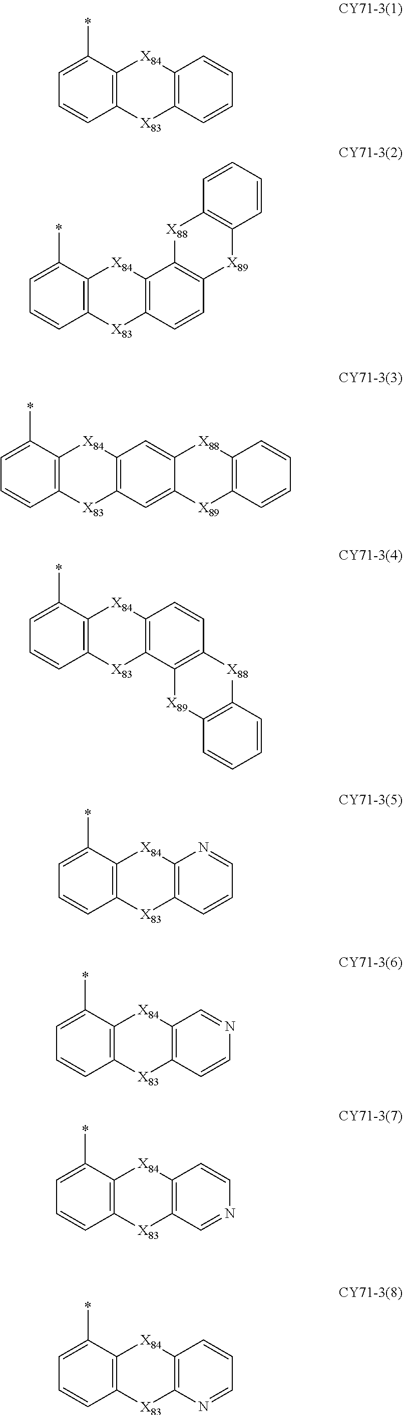

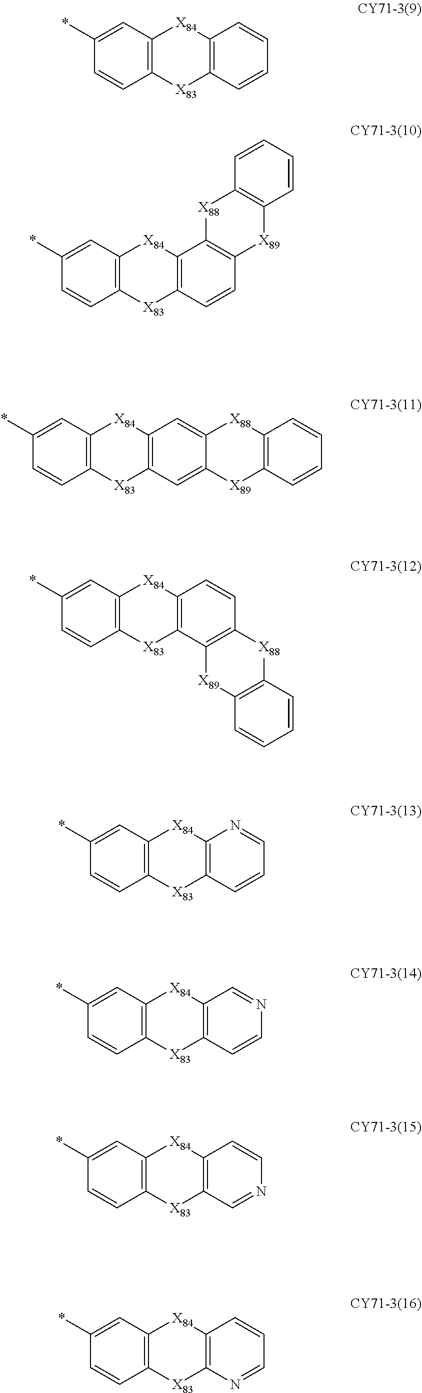

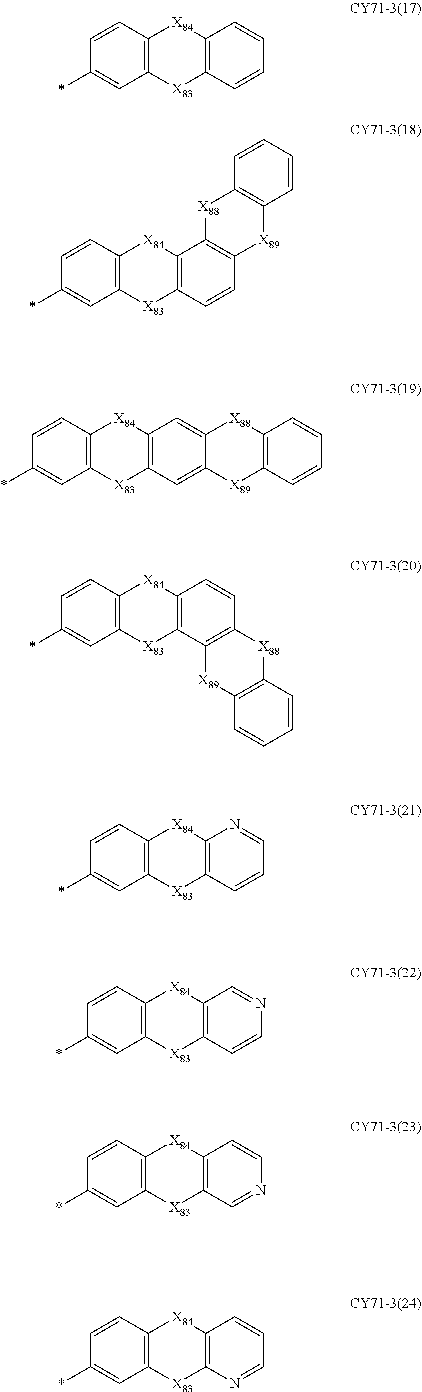

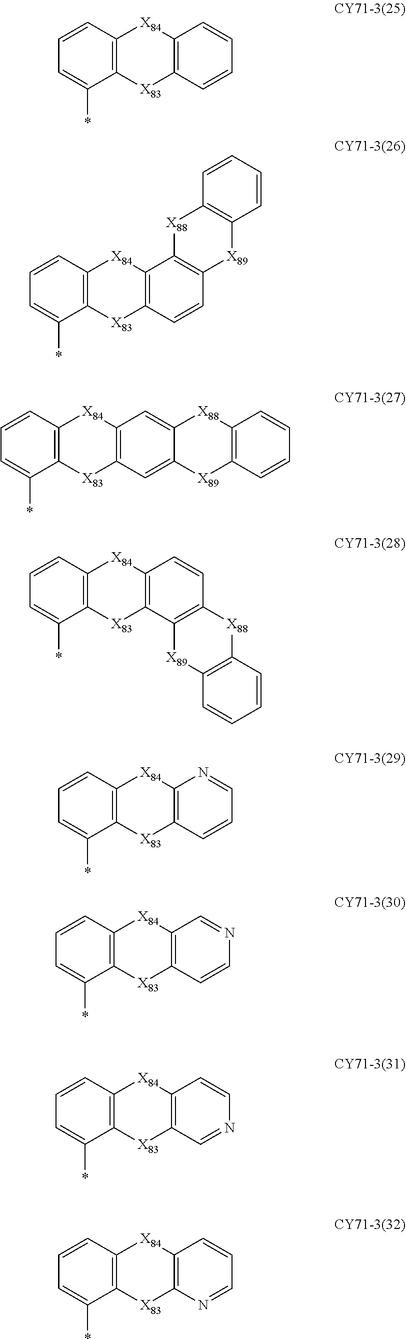

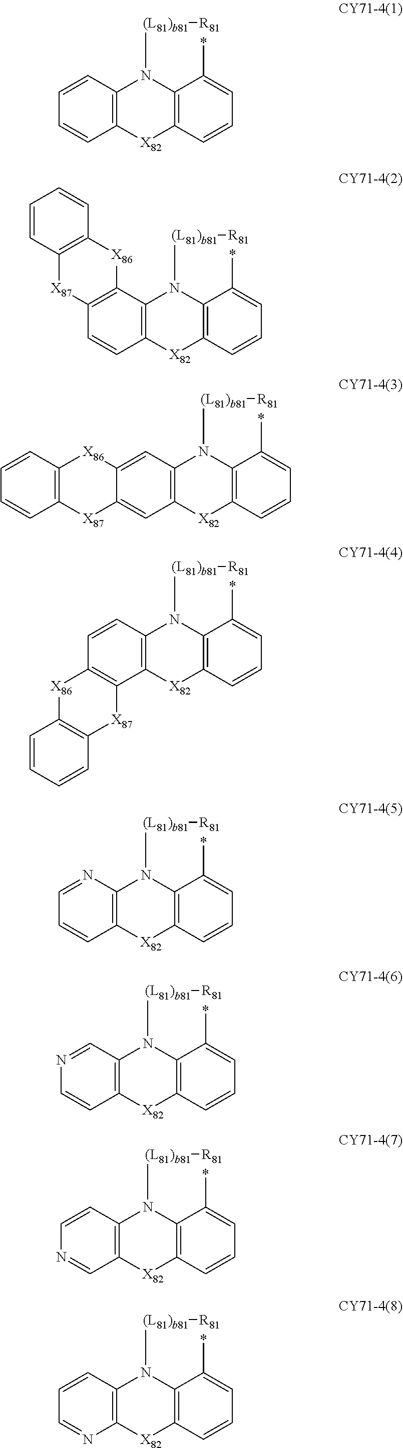

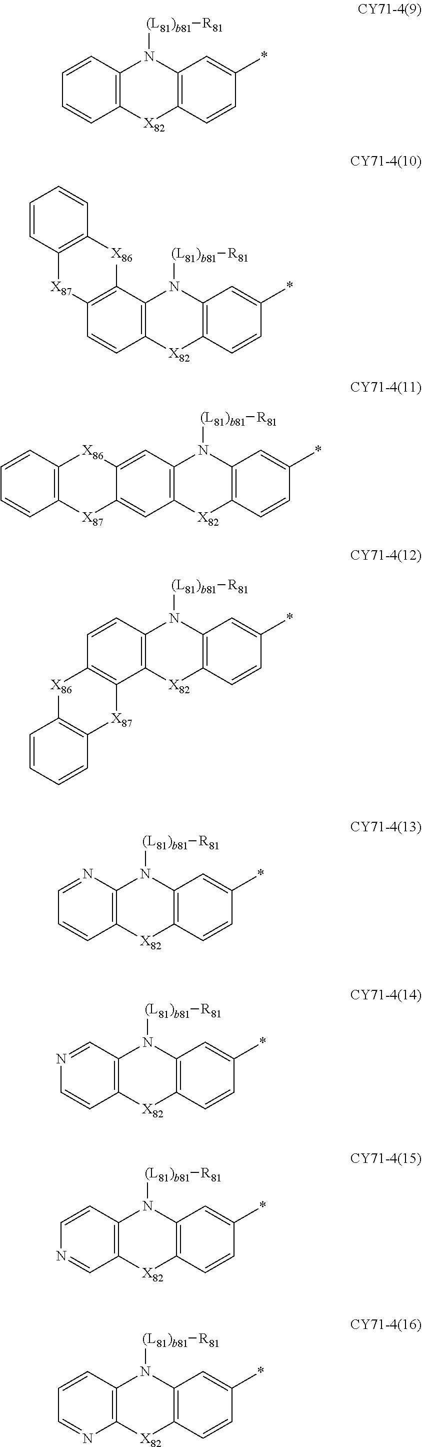

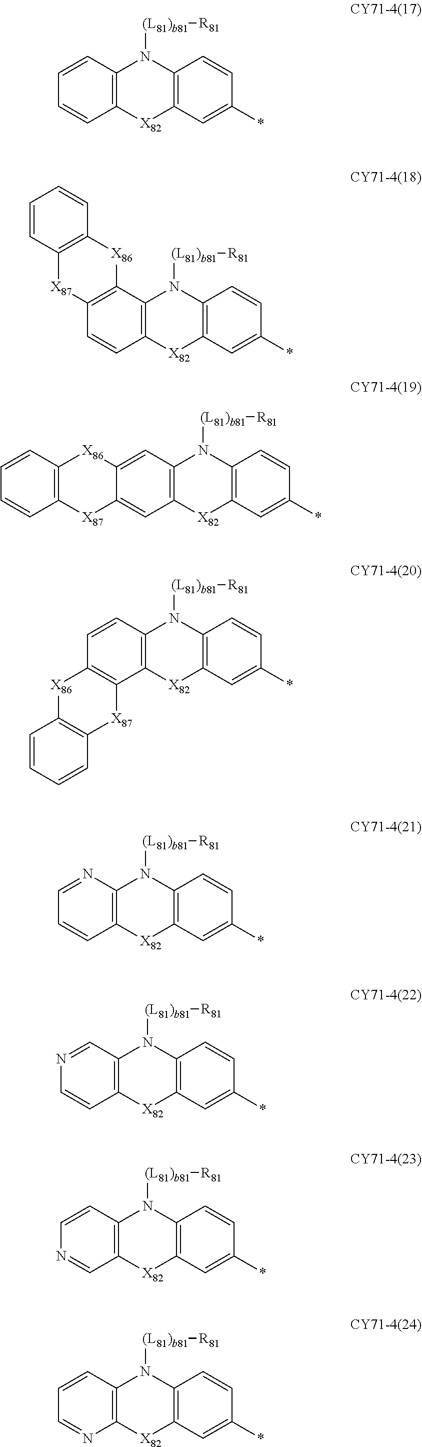

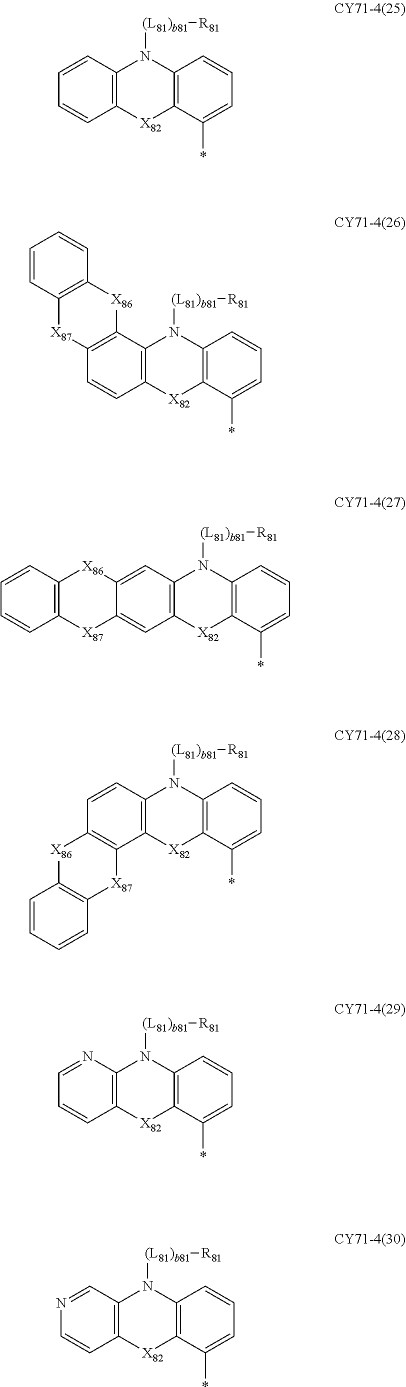

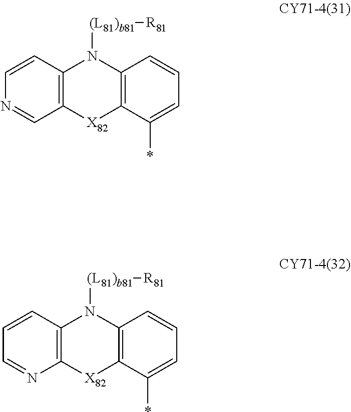

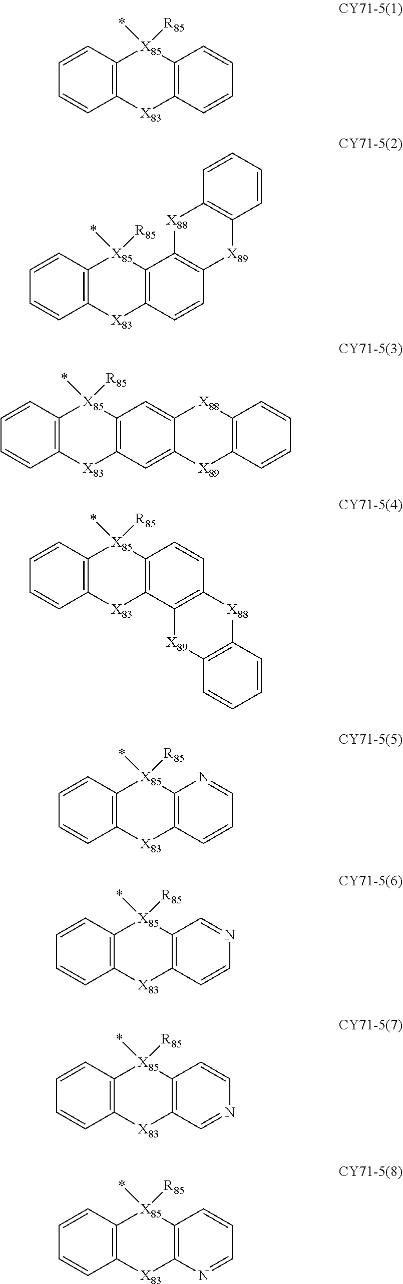

wherein, in Formulae CY71-1(1) to CY71-1(8), CY71-2(1) to CY71-2(8), CY71-3(1) to CY71-3(32), CY71-4(1) to CY71-4(32), and CY71-5(1) to CY71-5(8),
X₈₁ to X₈₅, L₈₁, b81, R₈₁, and R₈₅ are each as described herein,
X₈₆ may be a single bond, O, S, N(R₈₆), B(R₈₆), C(R₈₆ₐ)(R_{86b}), or Si(R₈₆ₐ)(R_{86b}),
X₈₇ may be a single bond, O, S, N(R₈₇), B(R₈₇), C(R₈₇ₐ)(R_{87b}), or Si(R₈₇ₐ)(R_{87b}),
in Formulae CY71-1(1) to CY71-1(8) and CY71-4(1) to CY71-4(32), each of X₈₆ and X₈₇ may not be a single bond at the same time,
X₈₈ may be a single bond, O, S, N(R₈₈), B(R₈₈), C(R₈₈ₐ)(R_{88b}), or Si(R₈₈ₐ)(R_{88b}),
X₈₉ may be a single bond, O, S, N(R₈₉), B(R₈₉), C(R₈₉ₐ)(R_{89b}), or Si(R₈₉ₐ)(R_{89b}),
in Formulae CY71-2(1) to CY71-2(8), CY71-3(1) to CY71-3(32), and CY71-5(1) to CY71-5(8), each of X₈₈ and X₈₉ may not be a single bond at the same time, and
R₈₆ to R₈₉, R₈₆ₐ, R_{86b}, R₈₇ₐ, R_{87b}, R₈₈ₐ, R_{88b}, R₈₉ₐ, and R_{89b} are each as described in connection with R₈₁.

### Examples of Compounds

In one or more embodiments, the organometallic compound represented by Formula 1 may be at least one of Compounds 1 to 344:

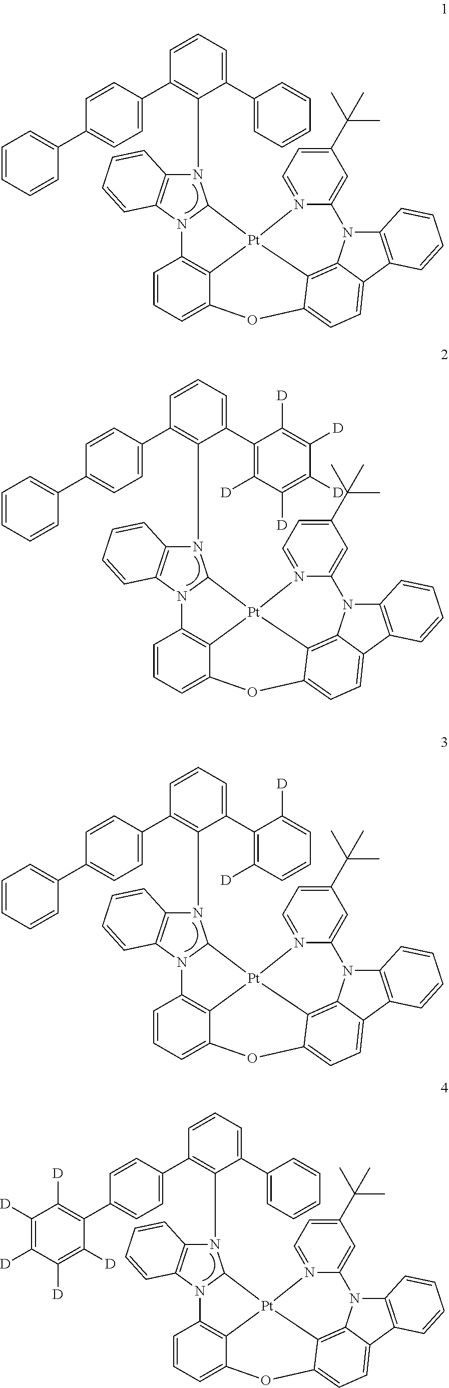

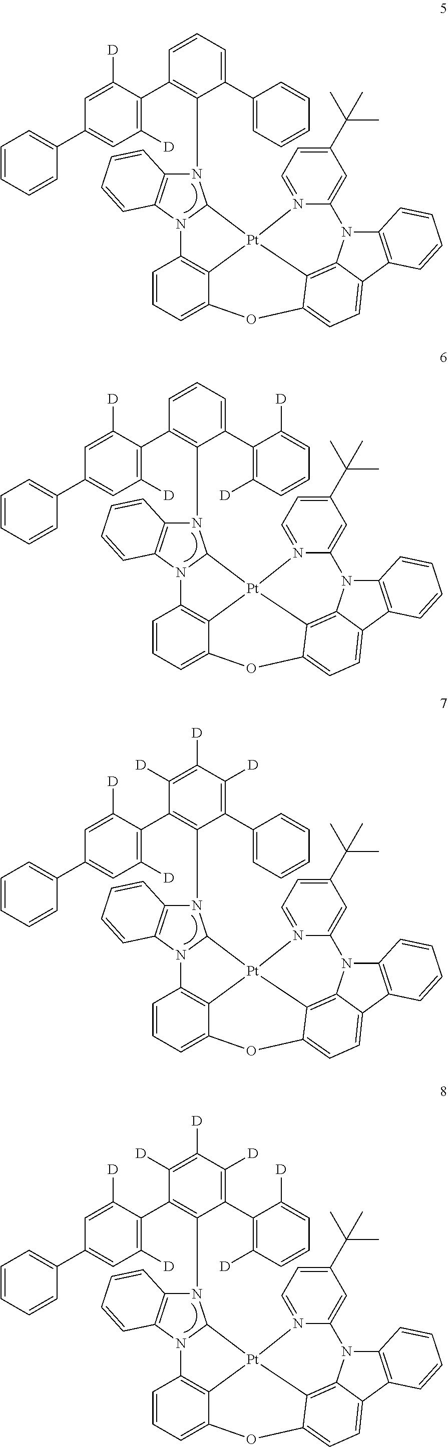

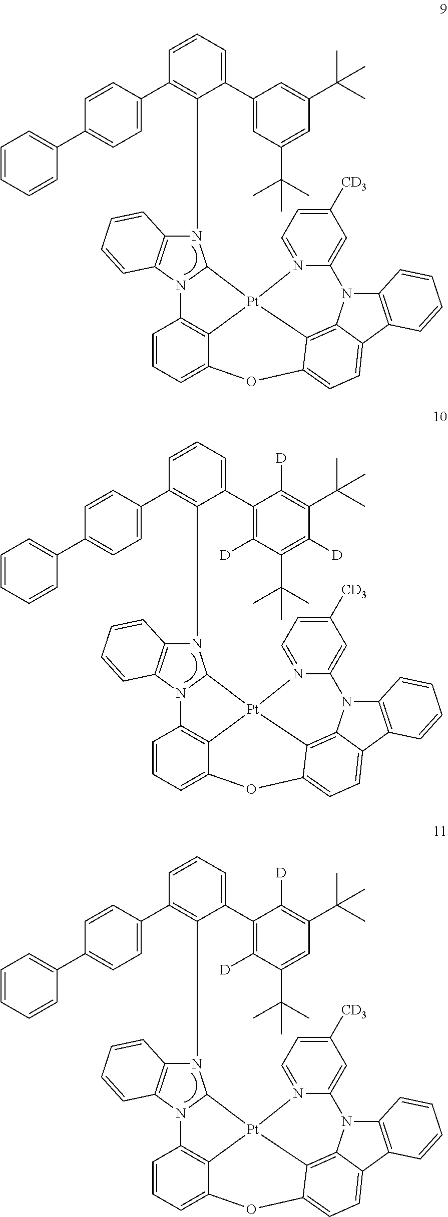

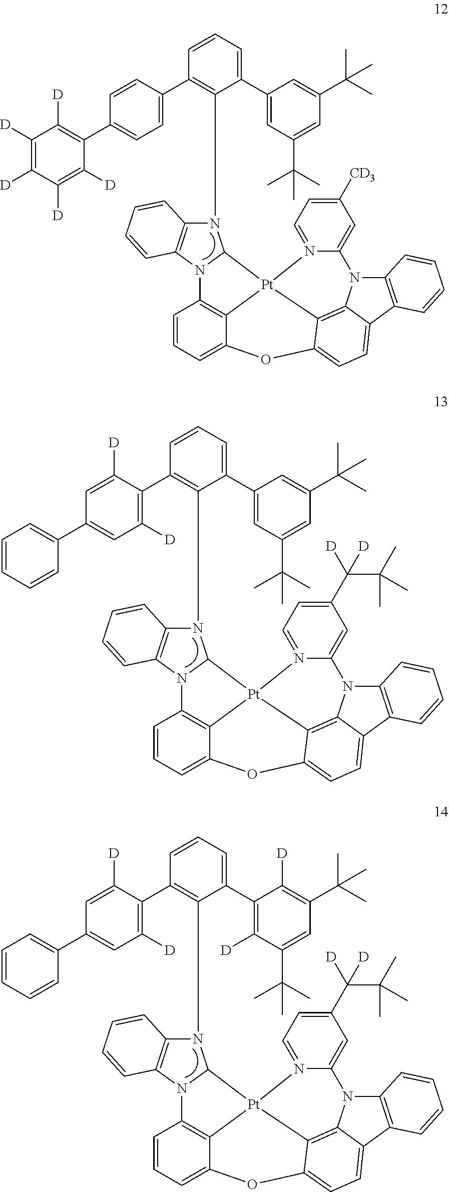

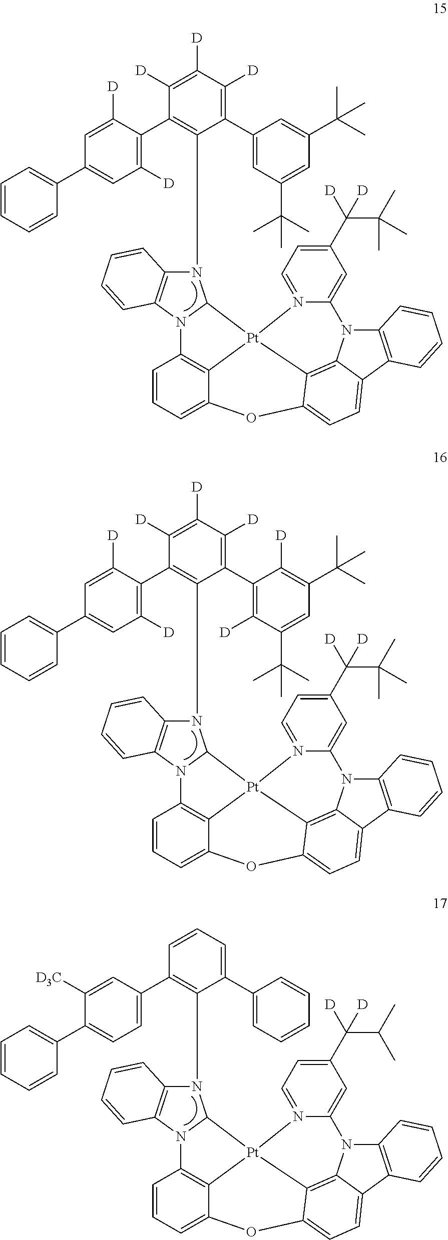

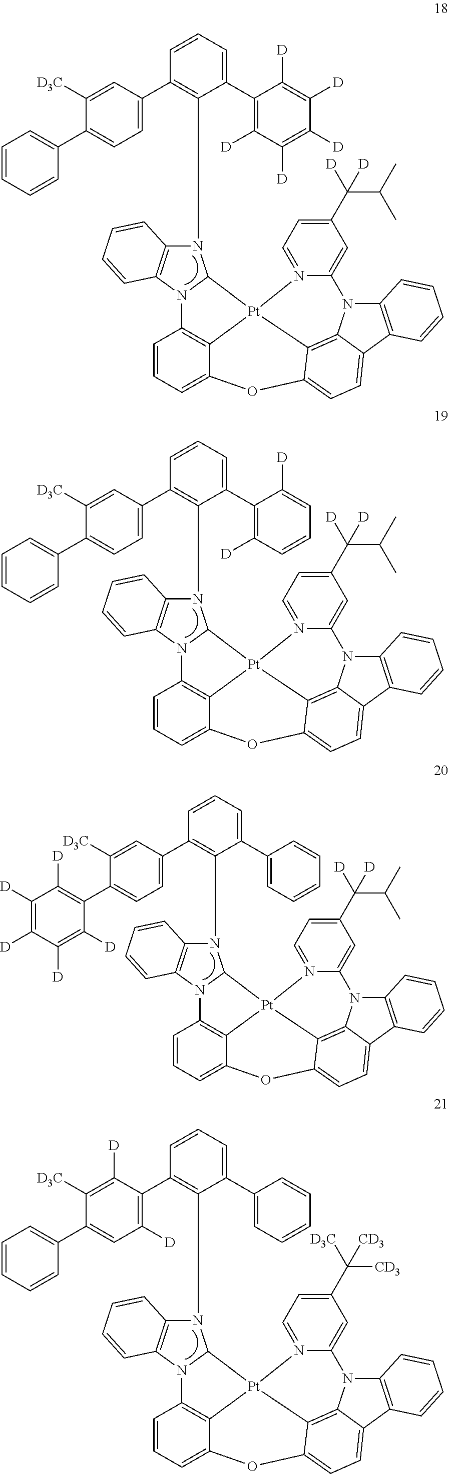

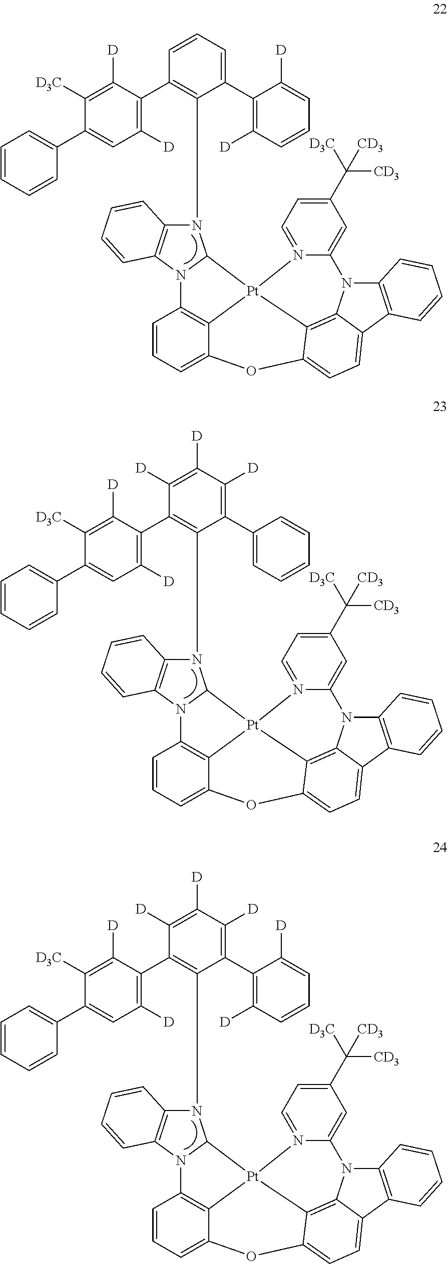

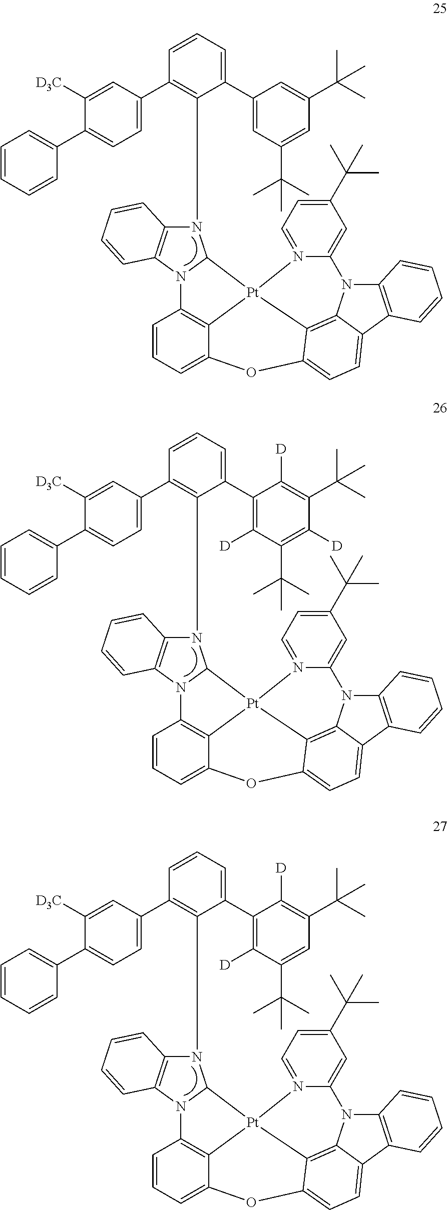

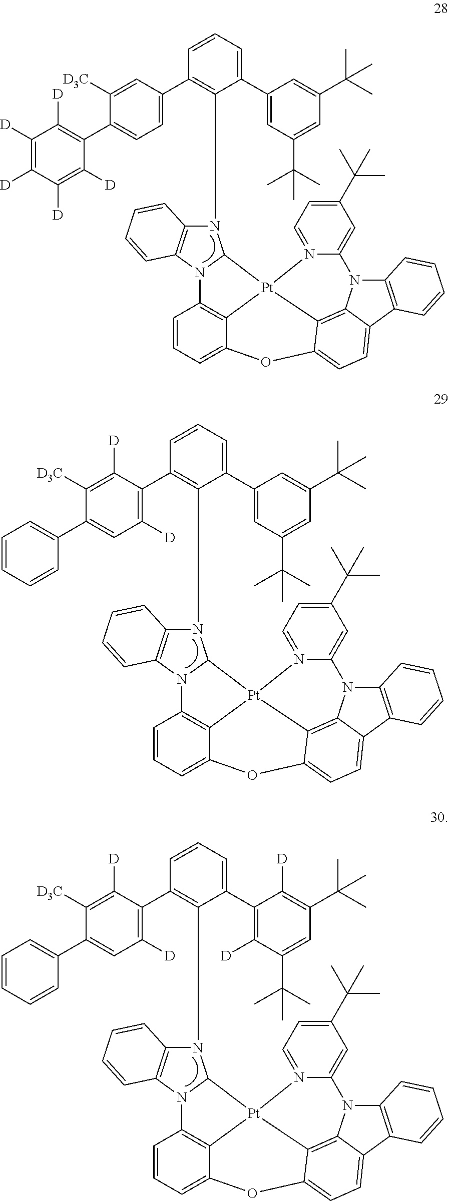

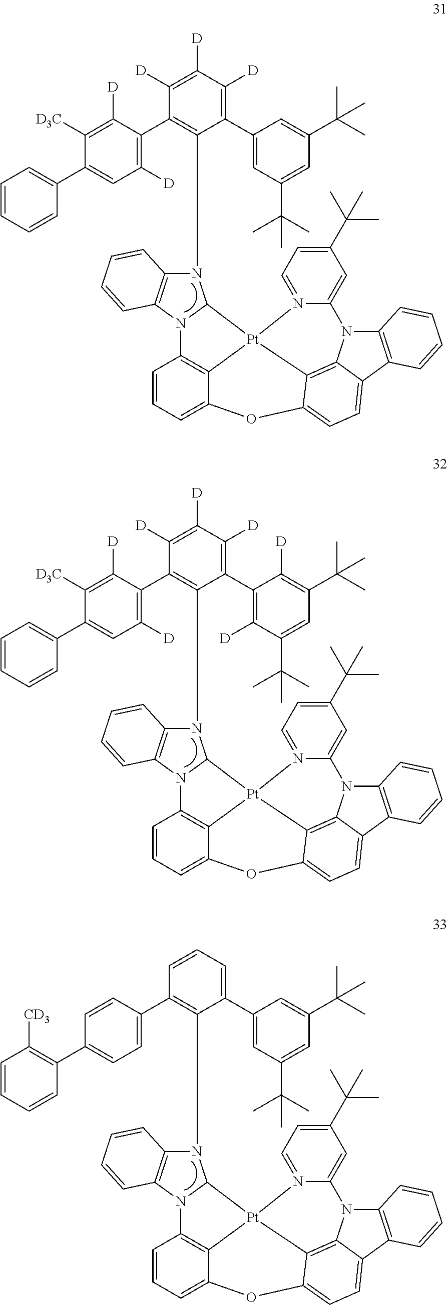

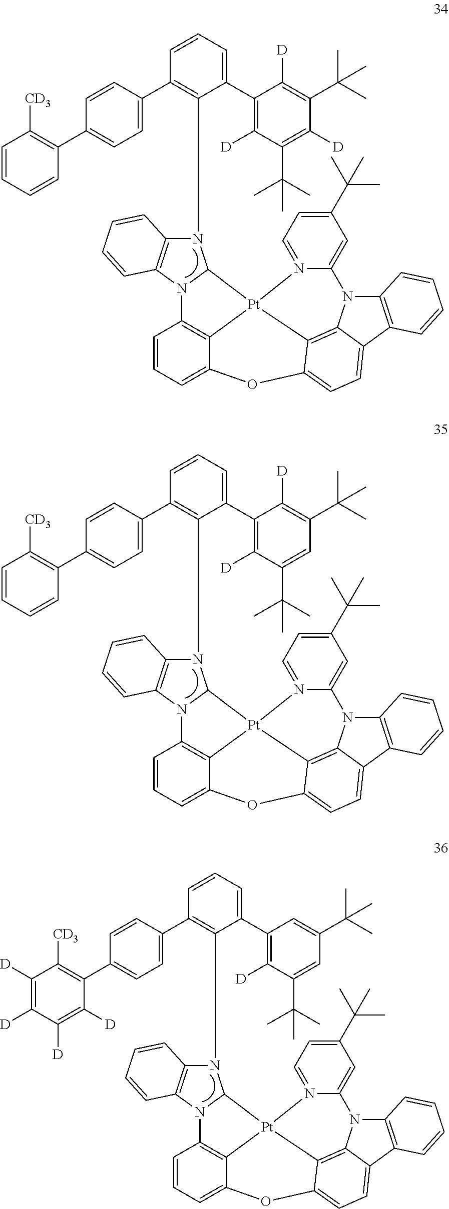

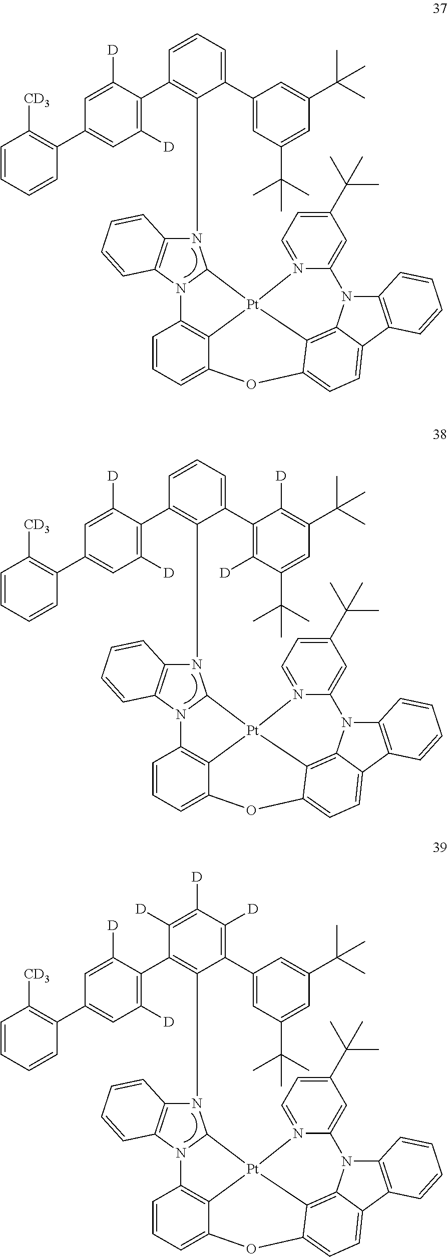

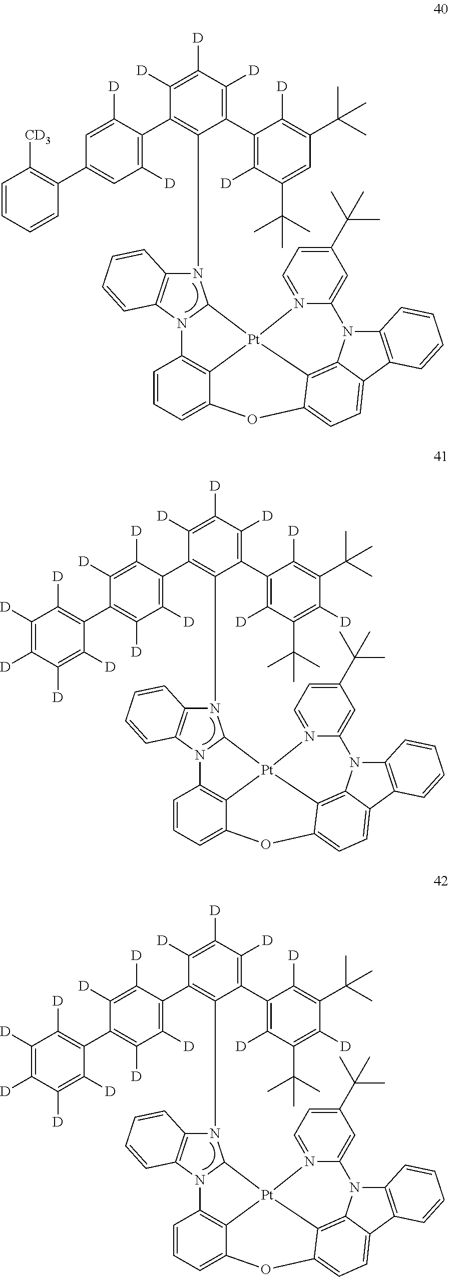

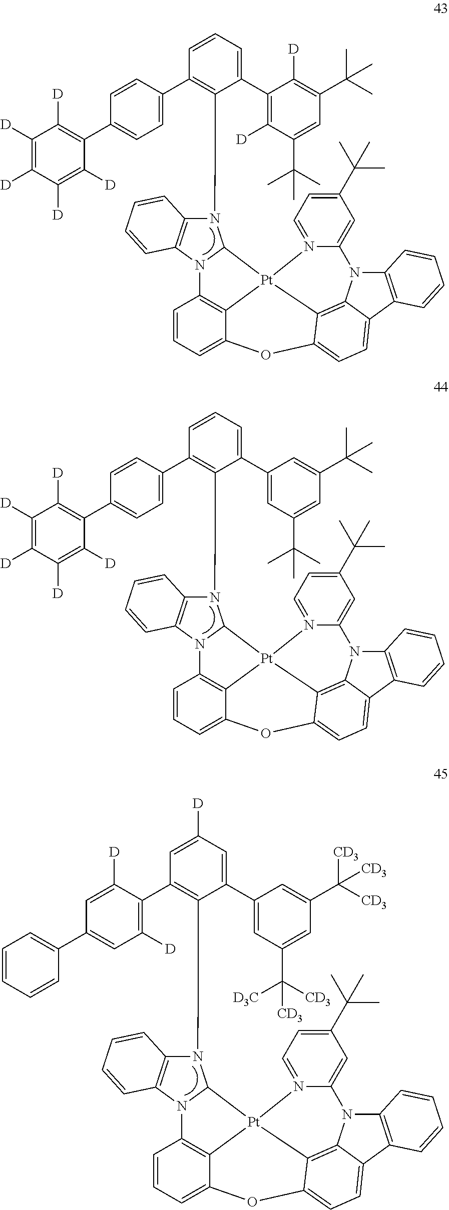

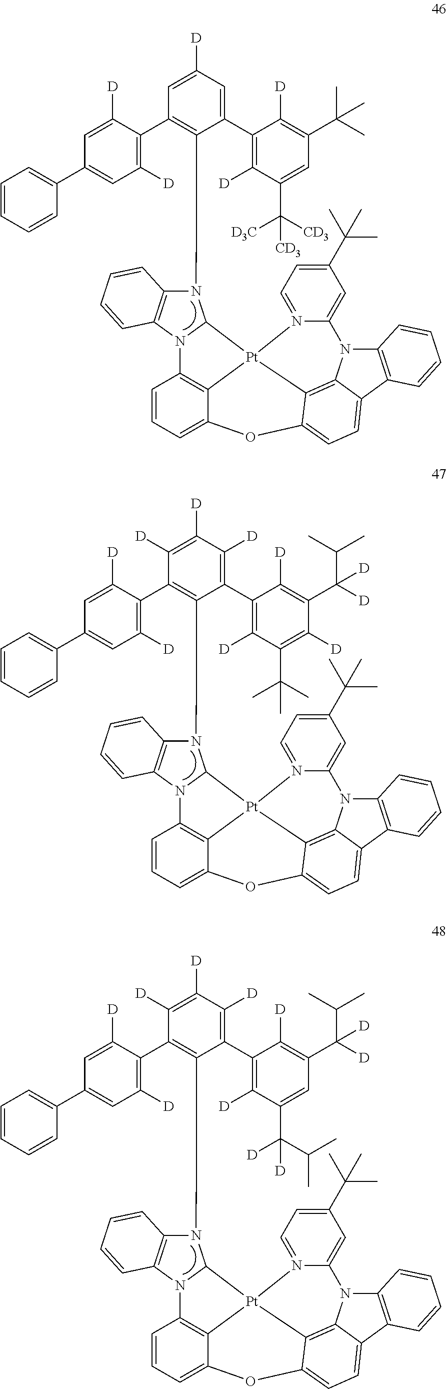

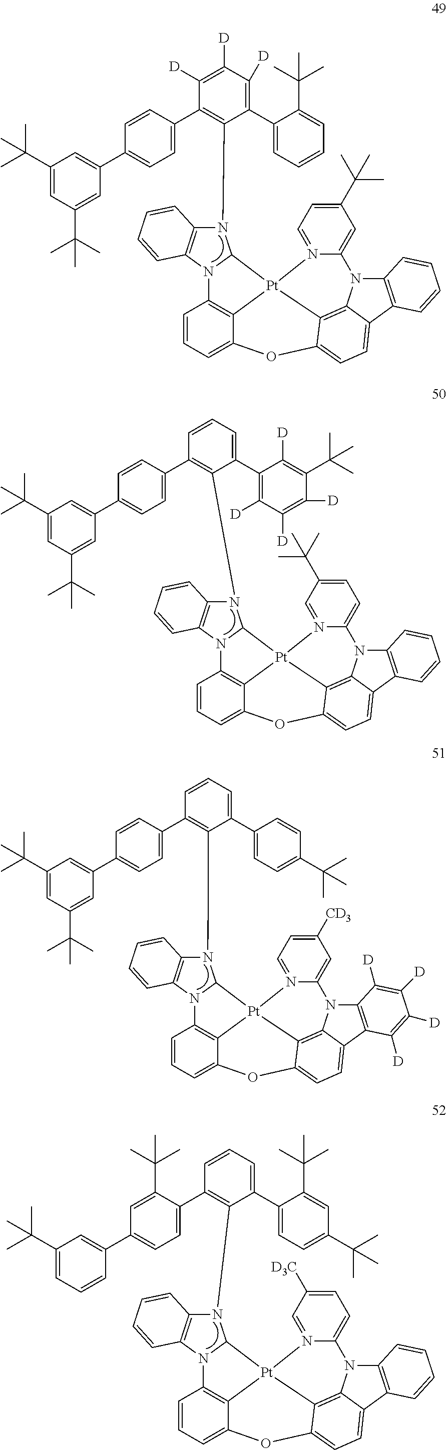

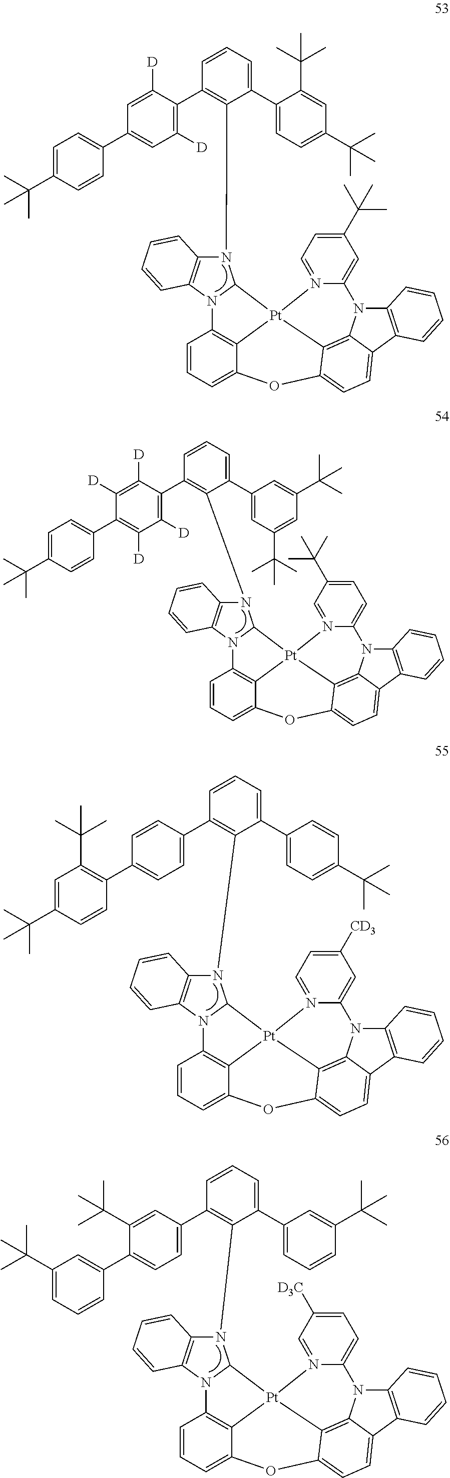

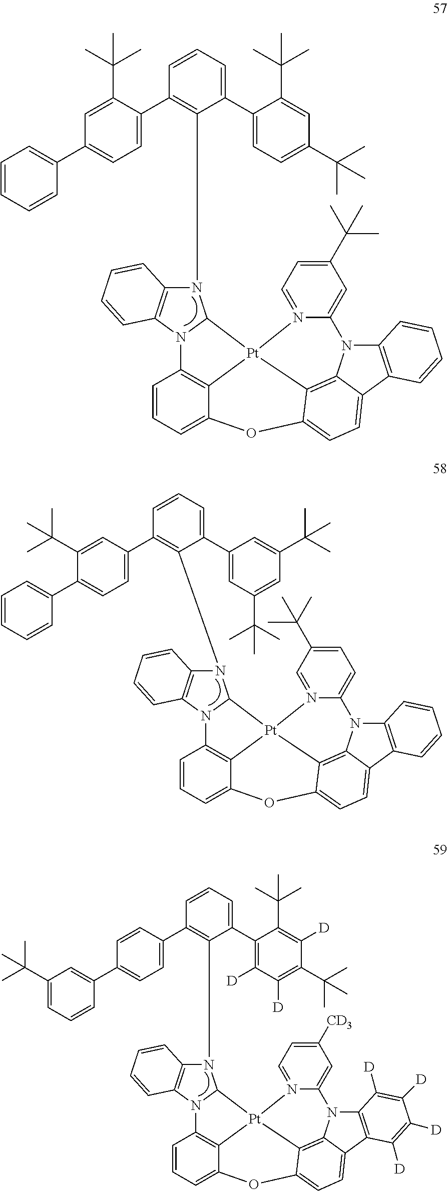

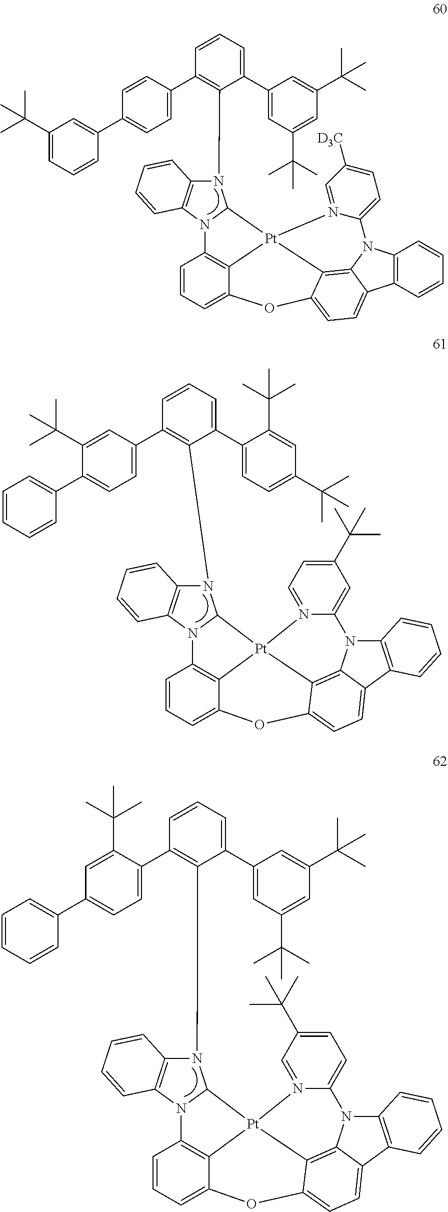

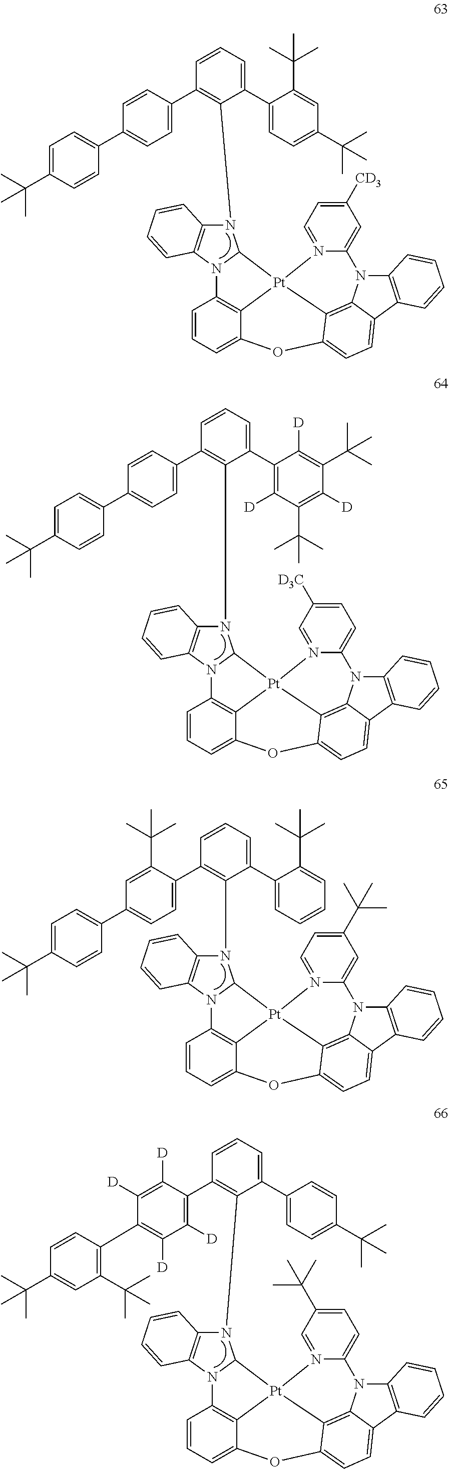

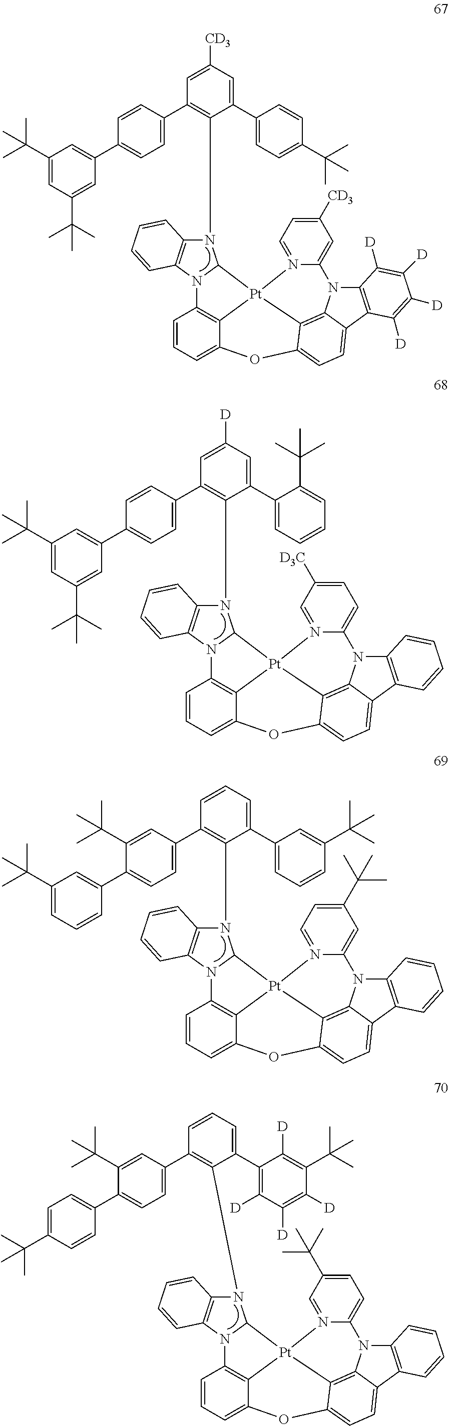

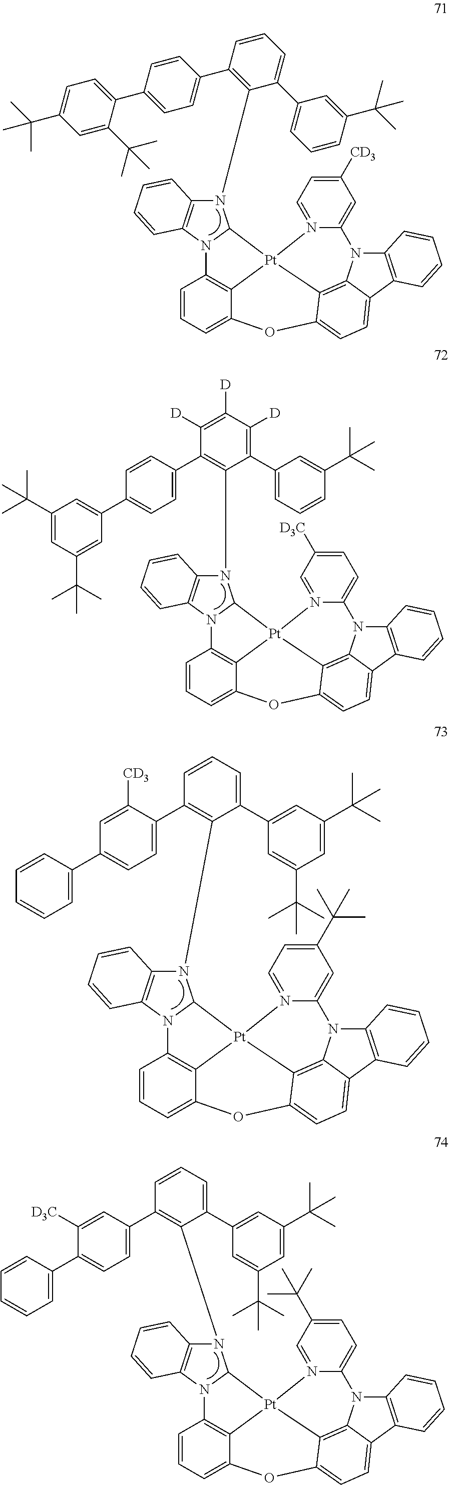

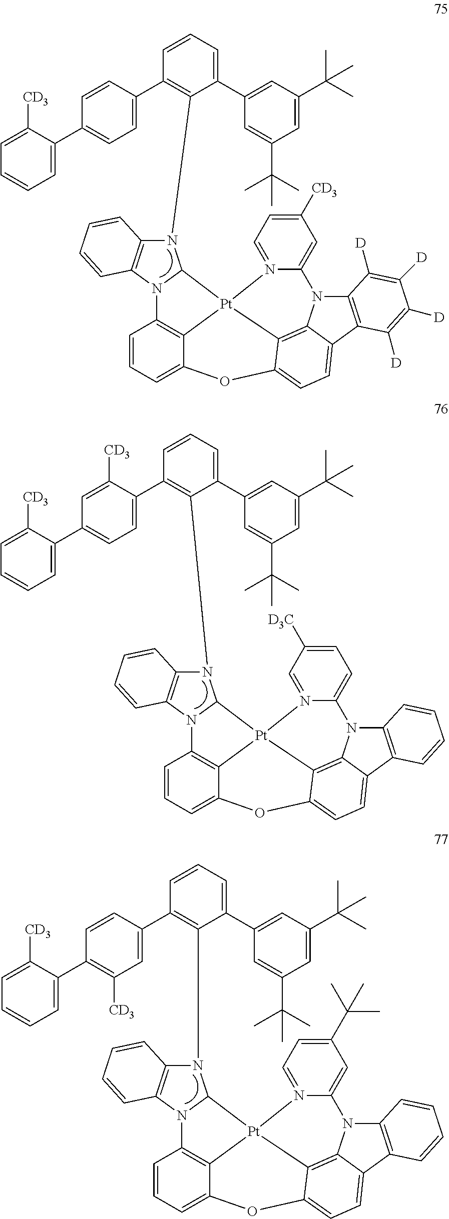

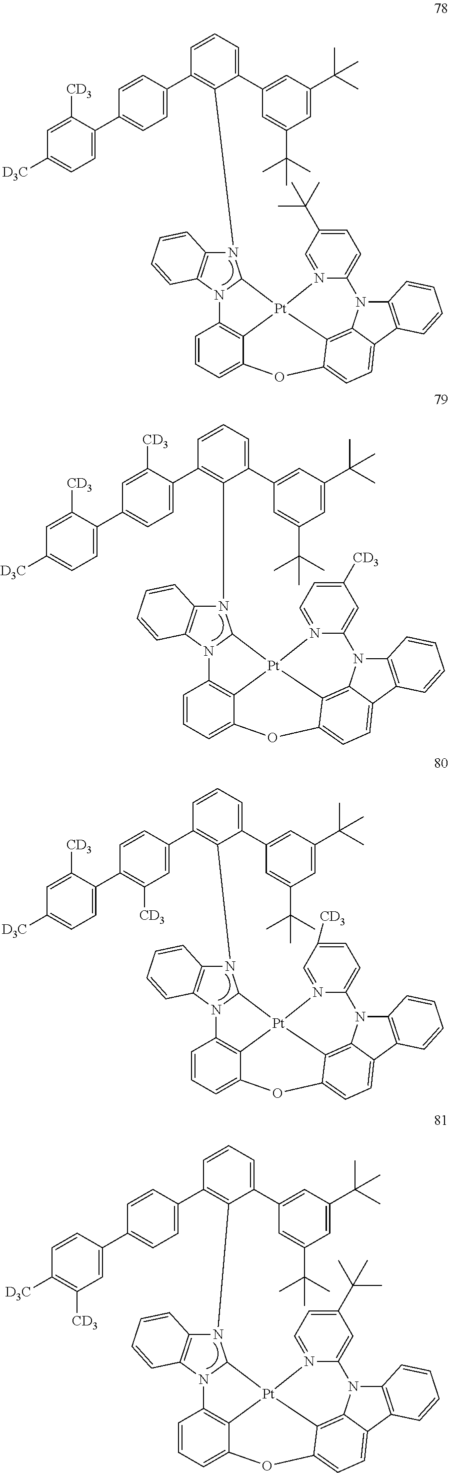

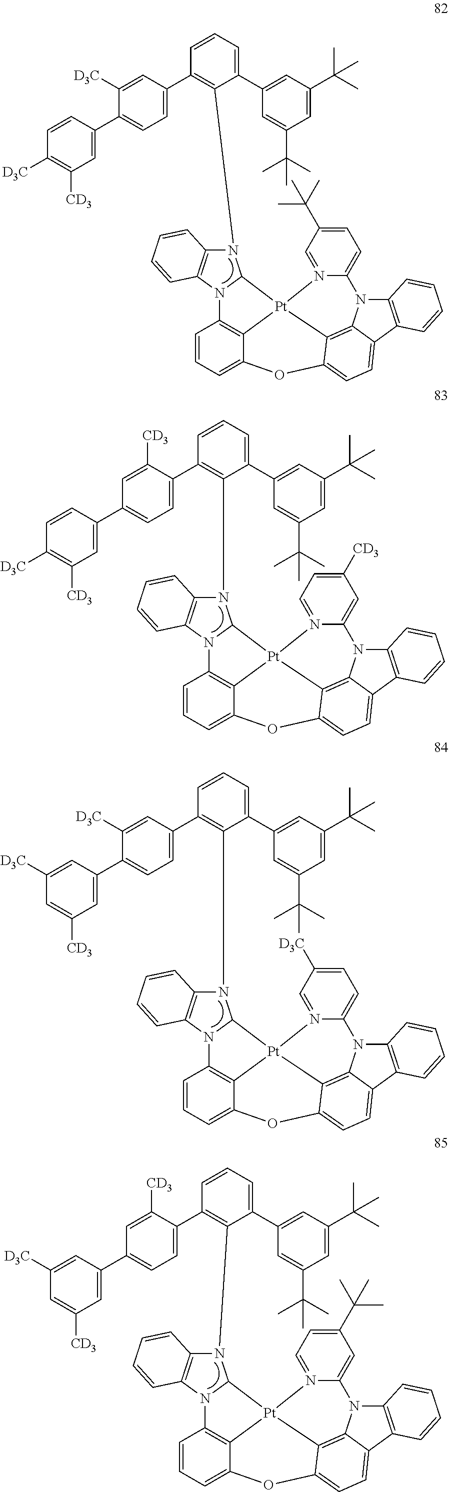

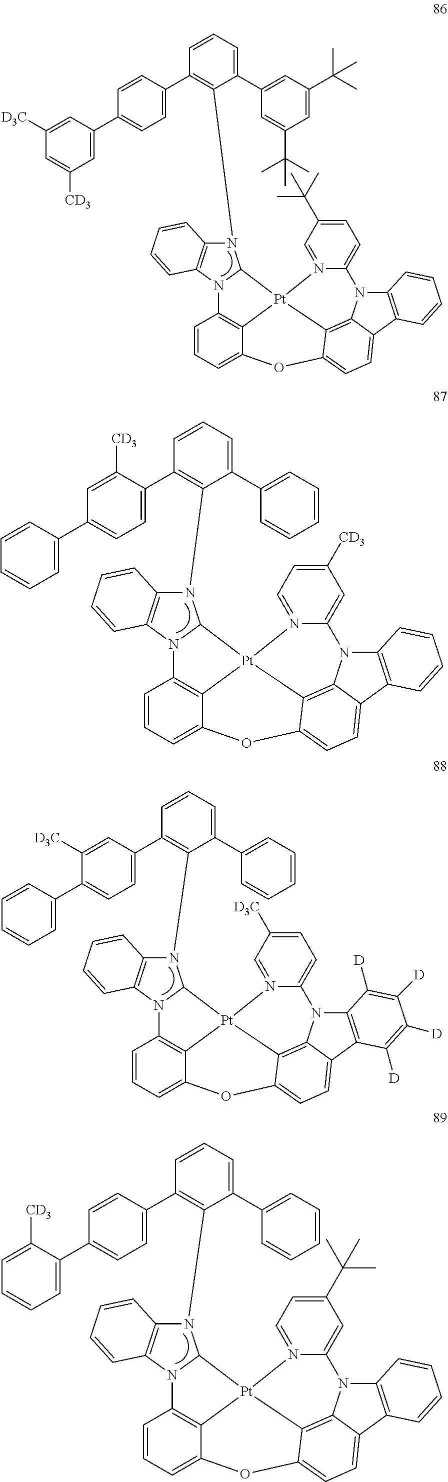

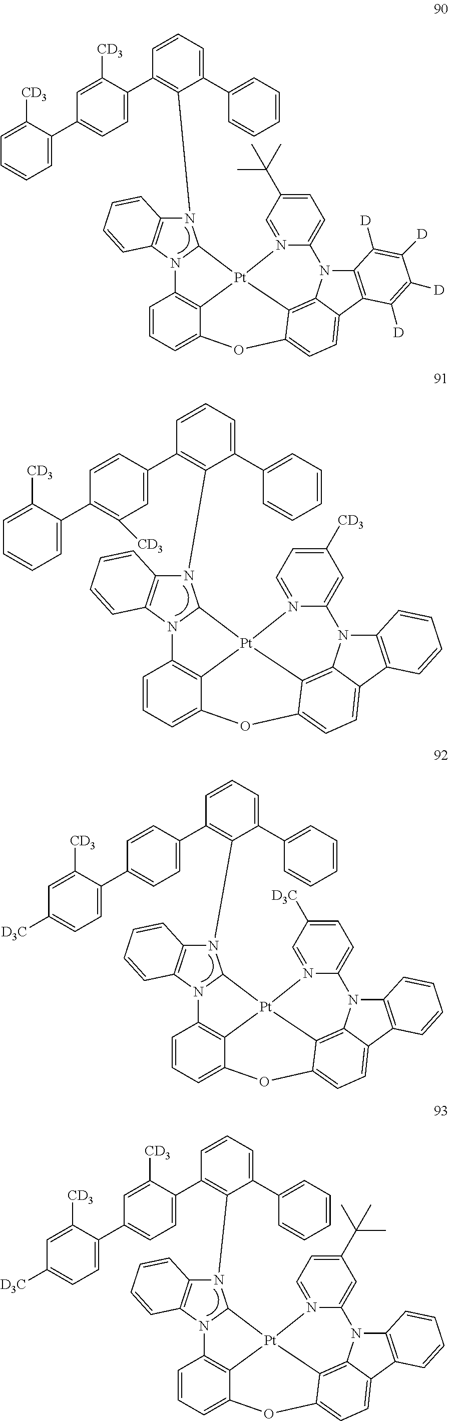

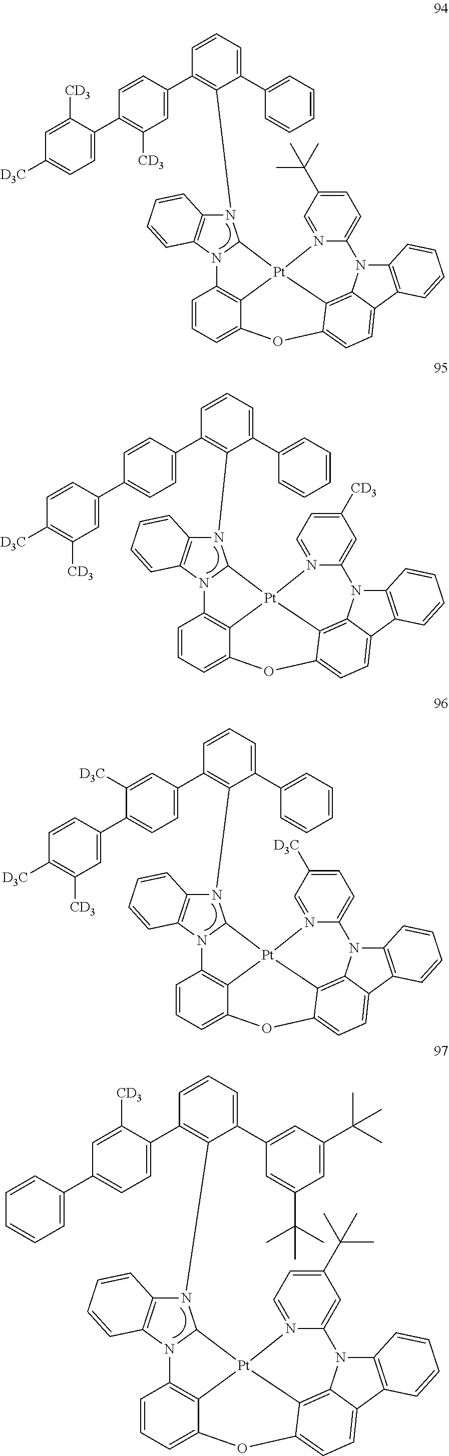

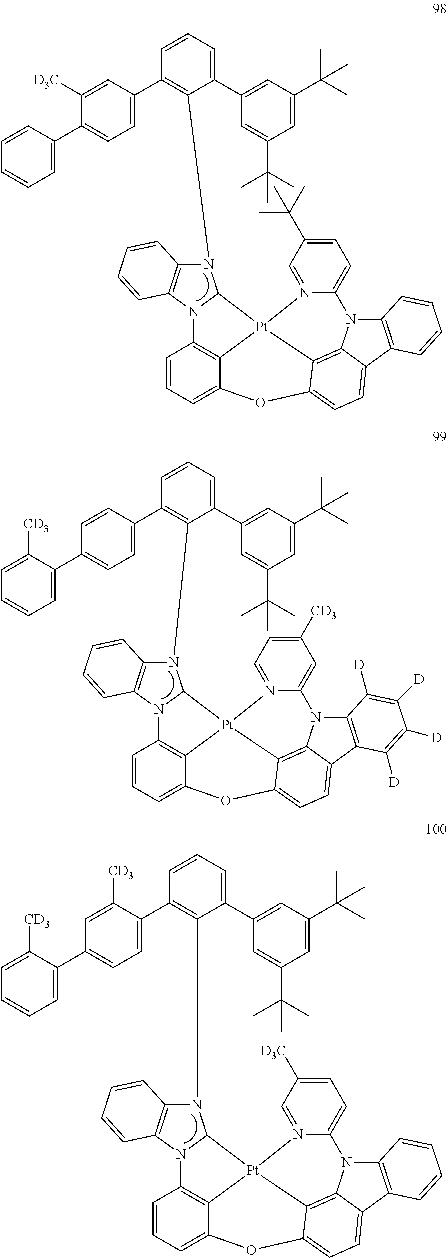

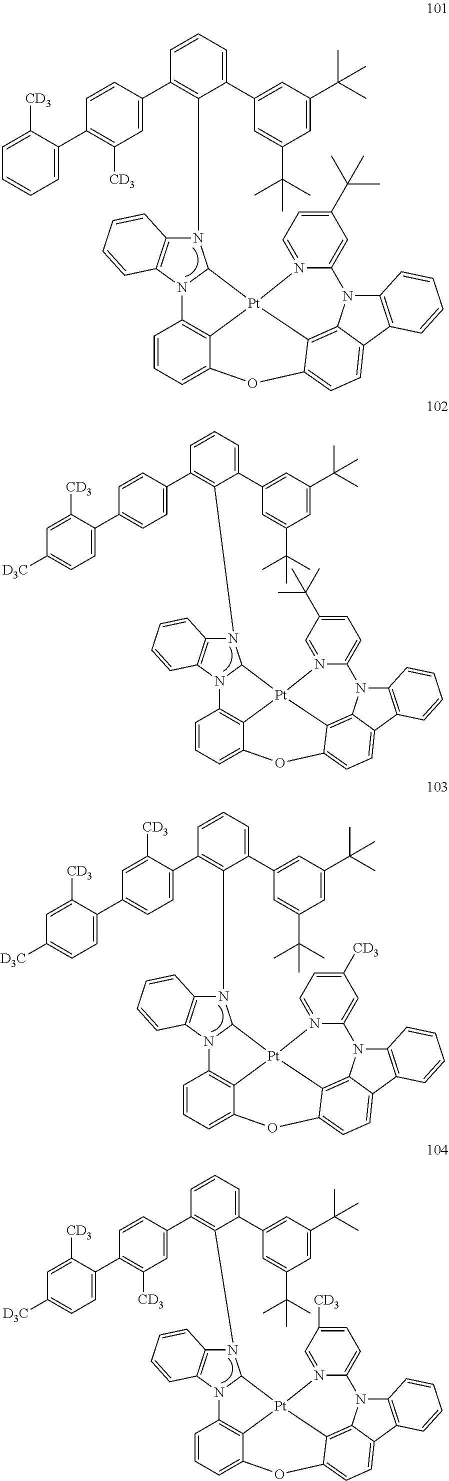

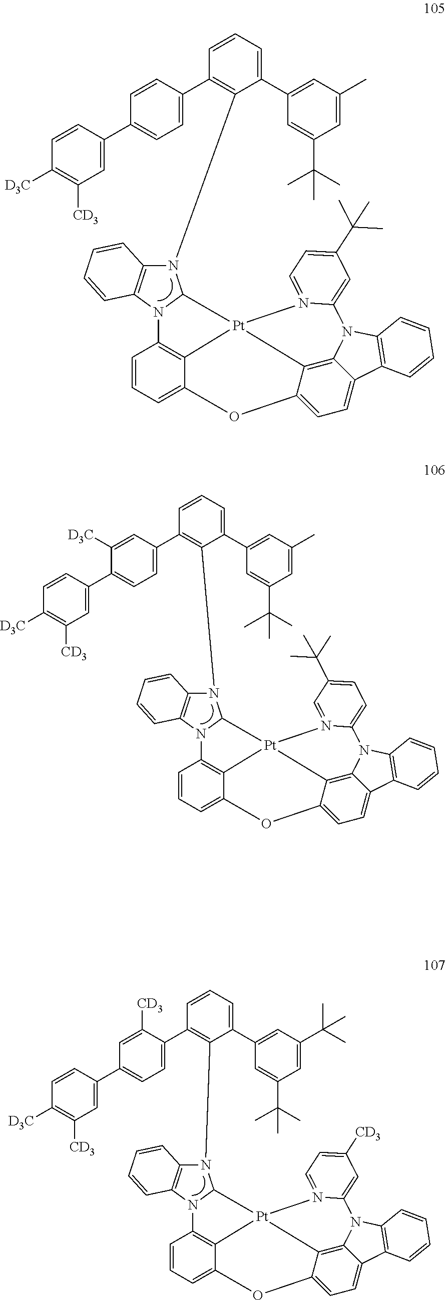

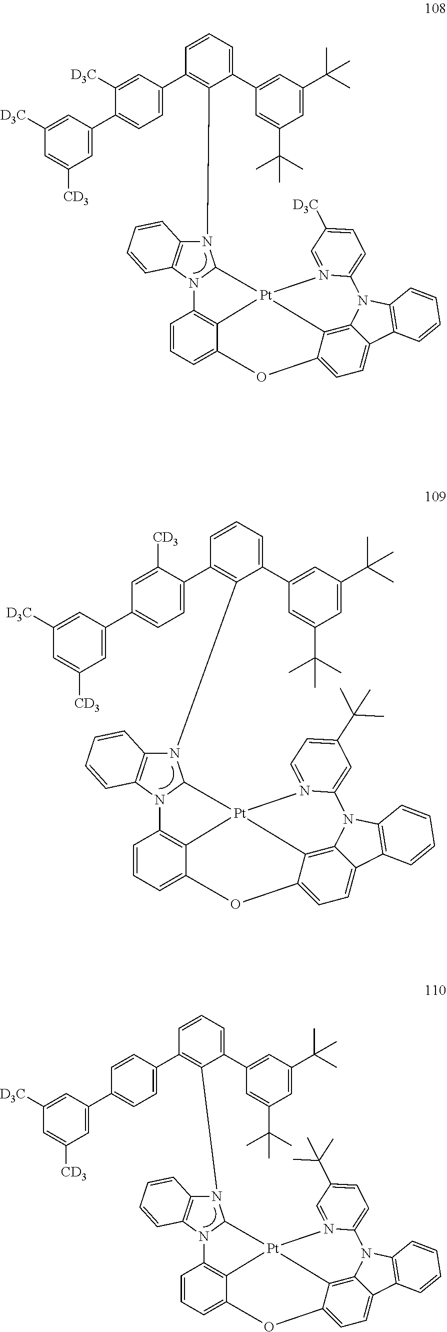

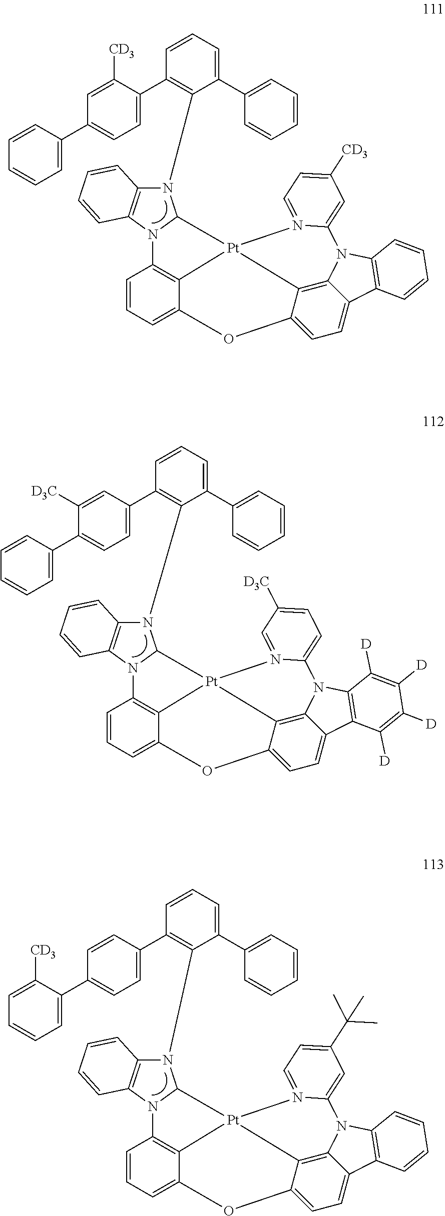

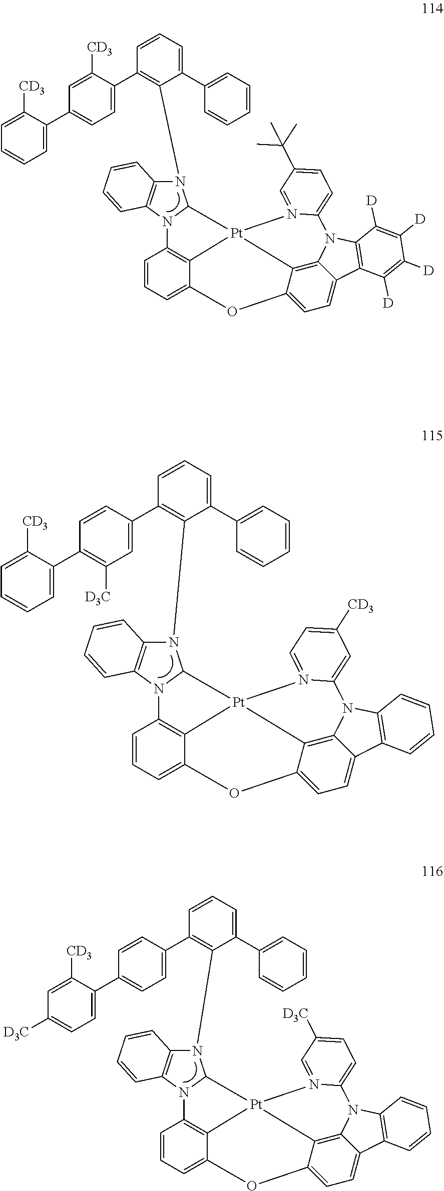

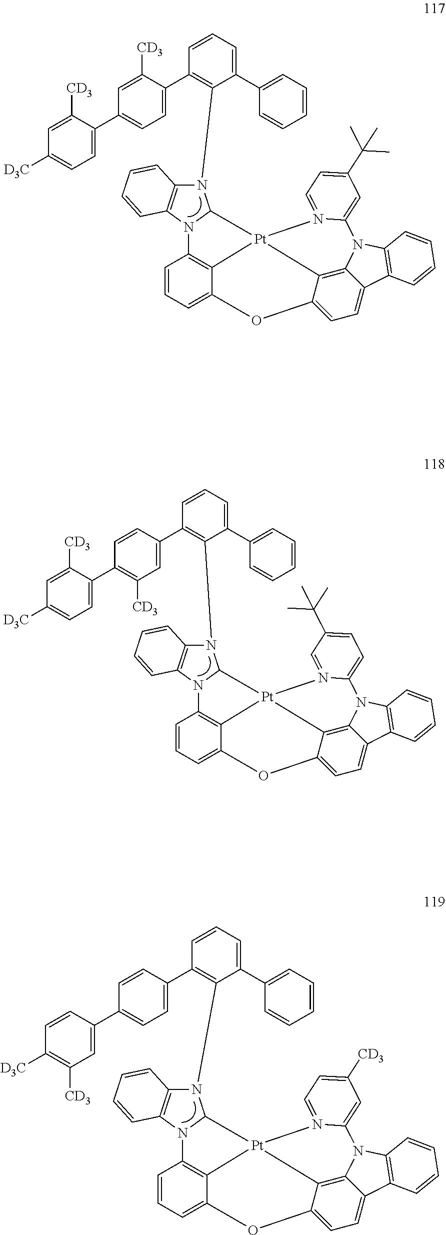

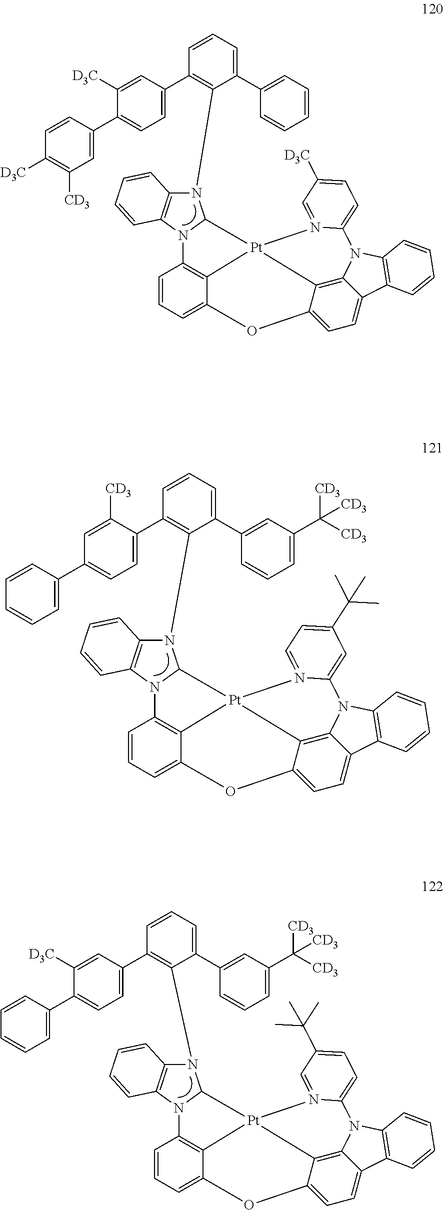

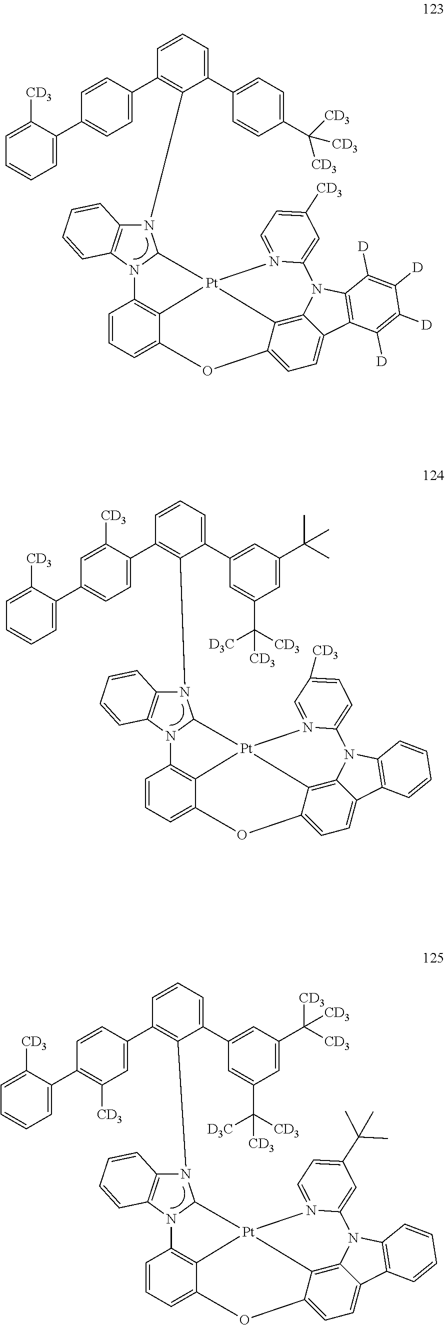

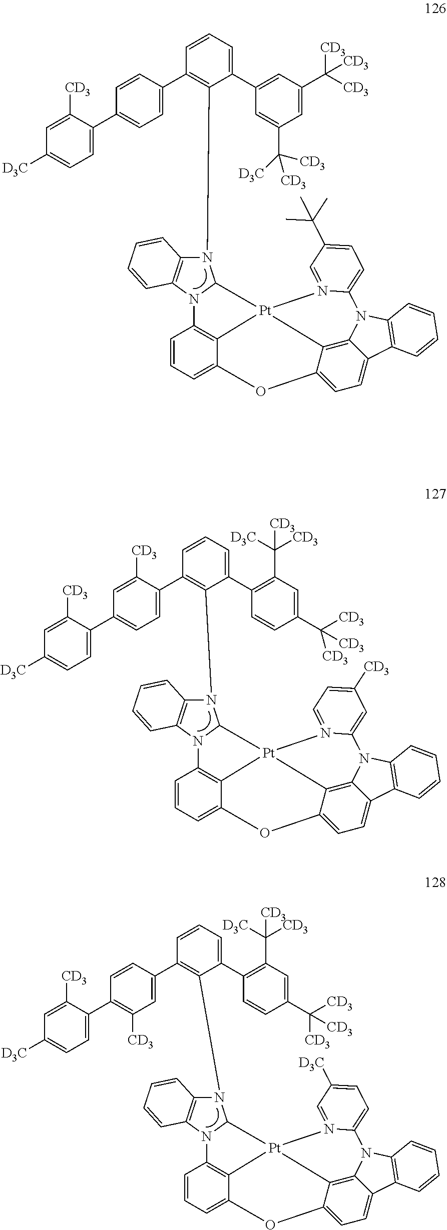

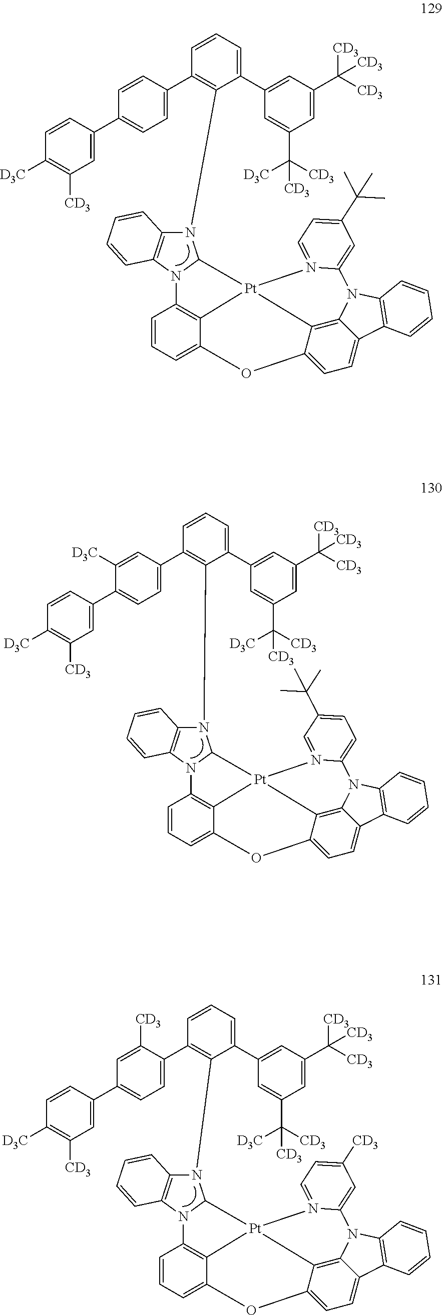

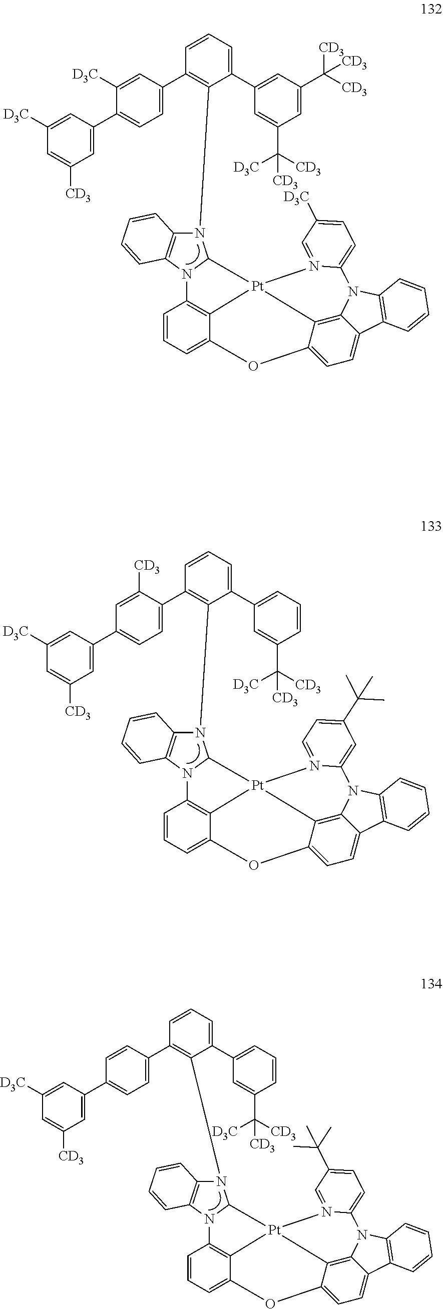

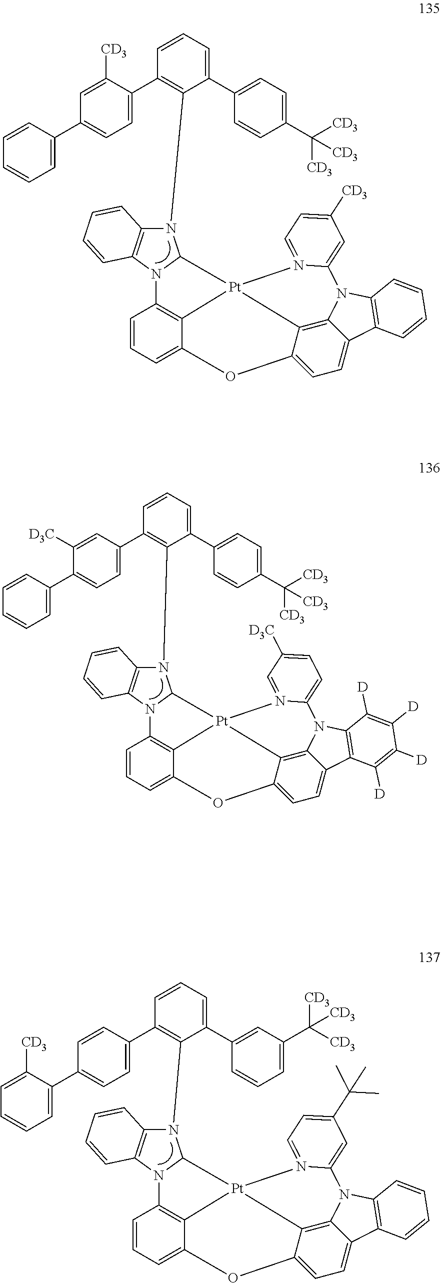

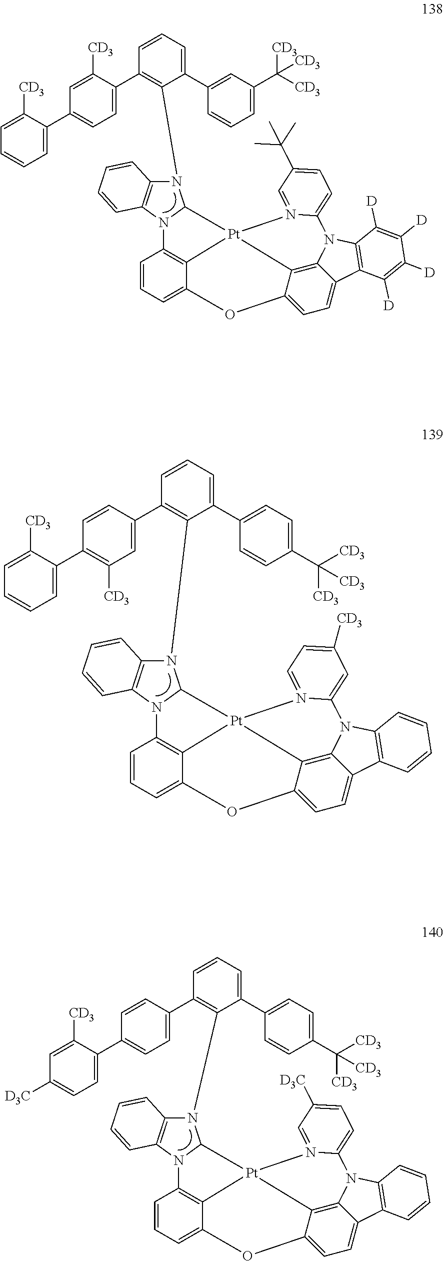

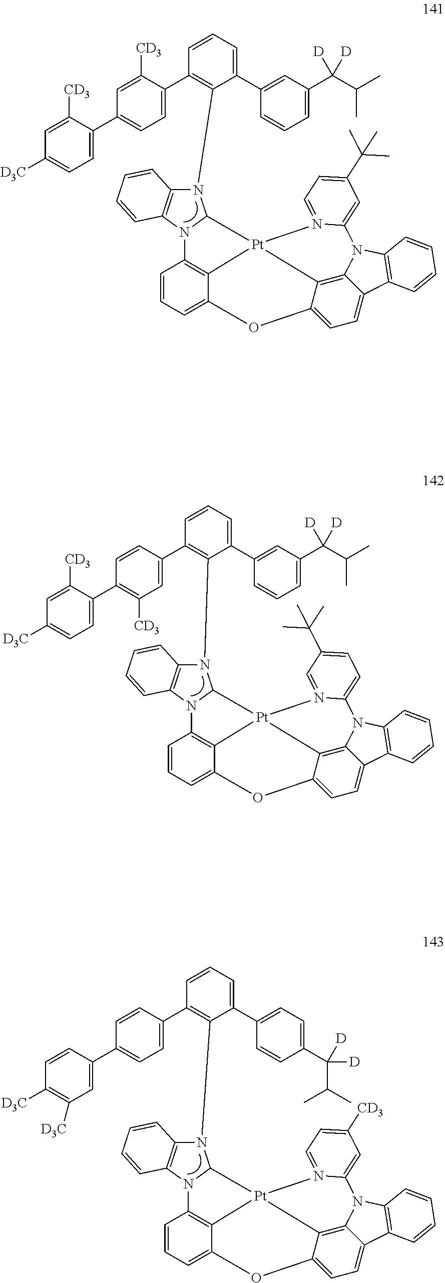

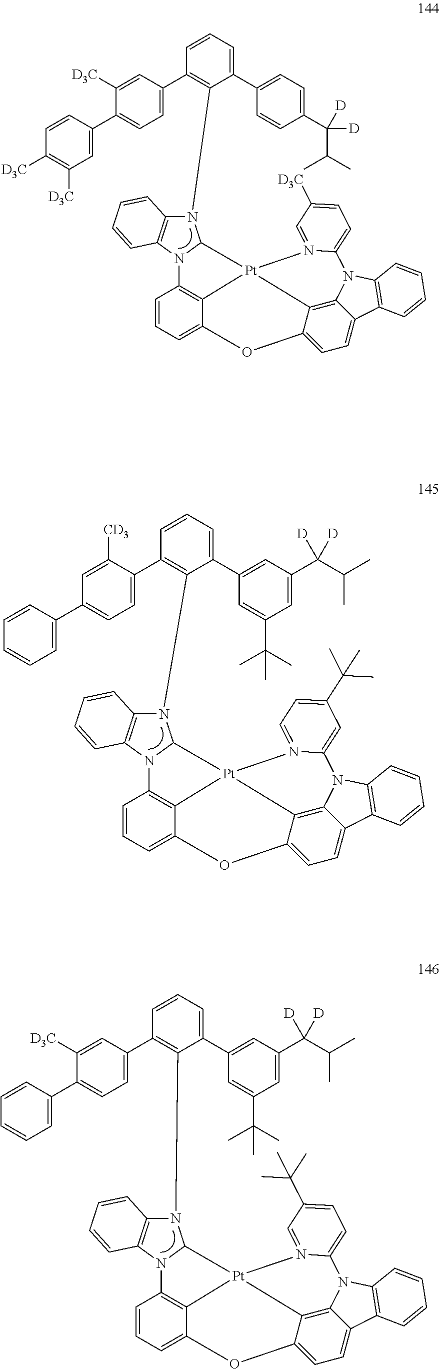

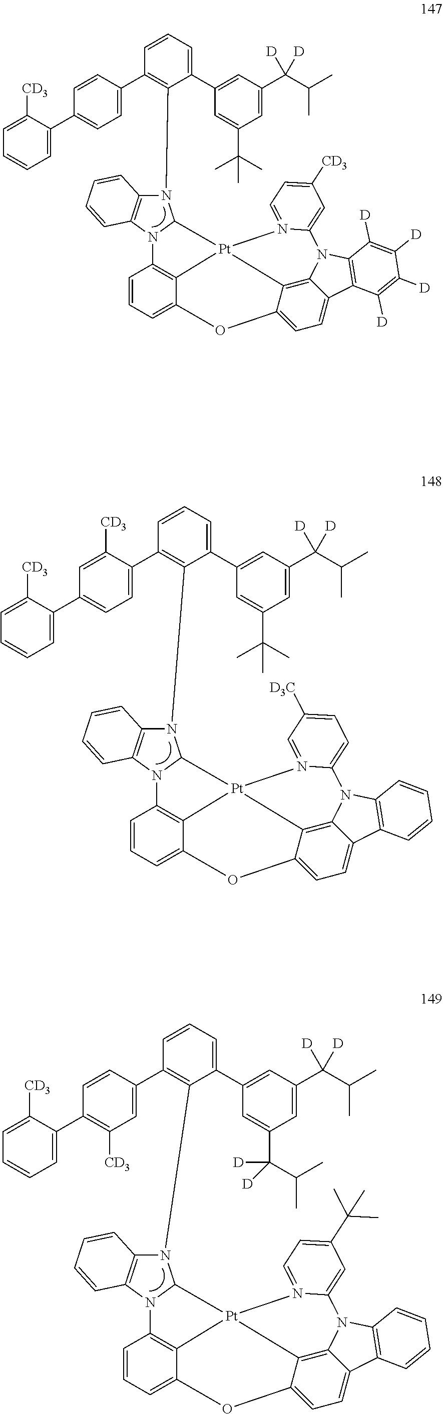

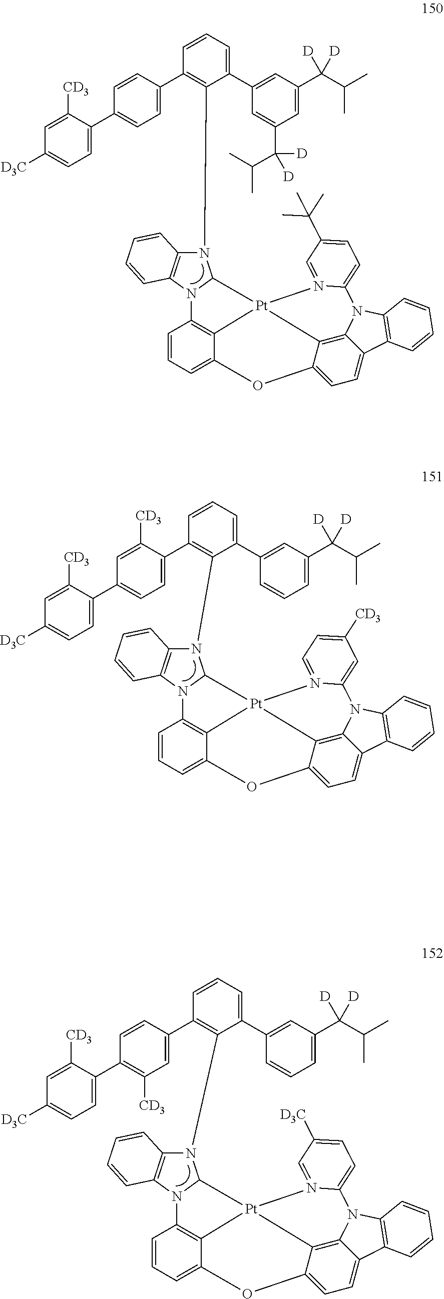

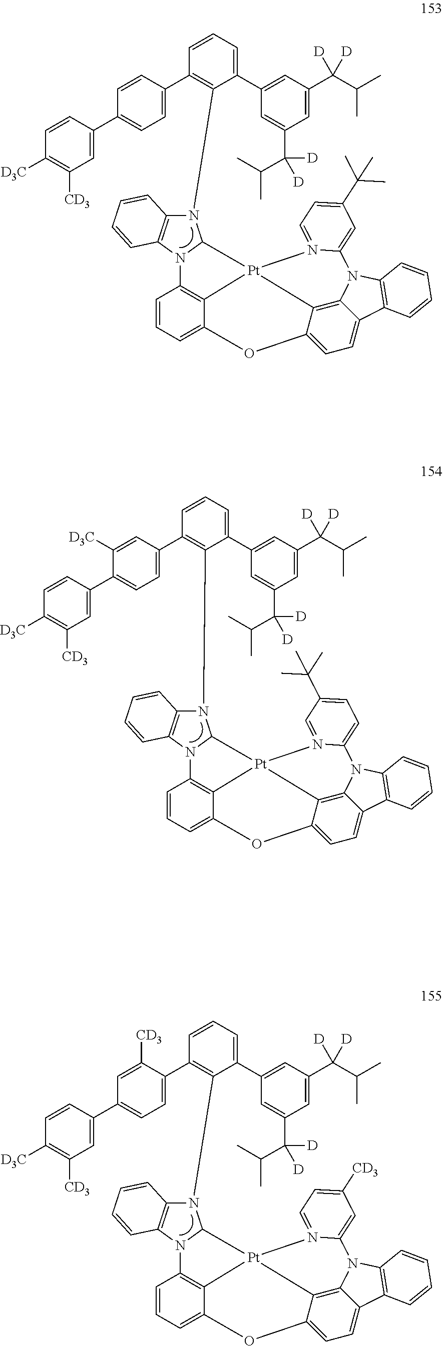

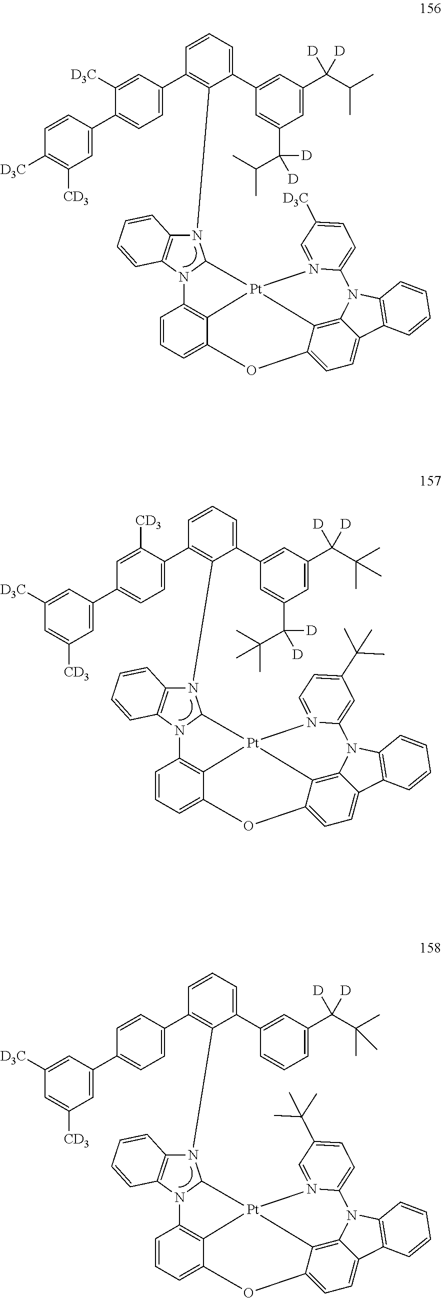

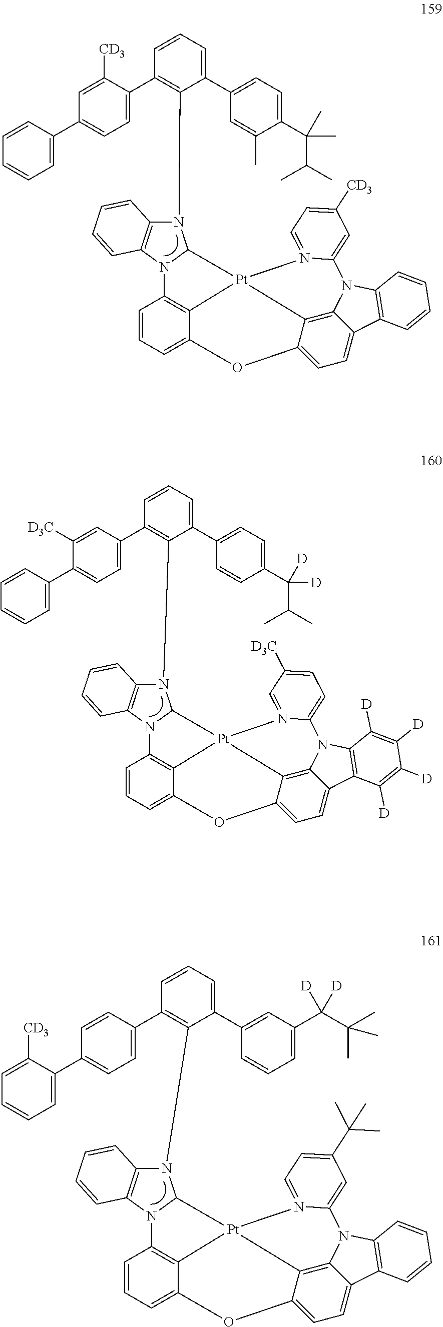

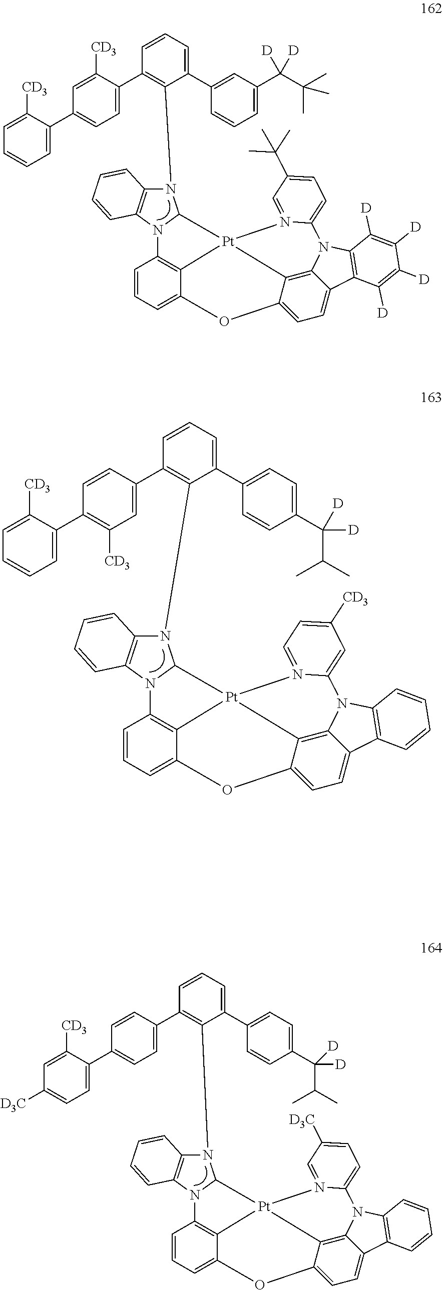

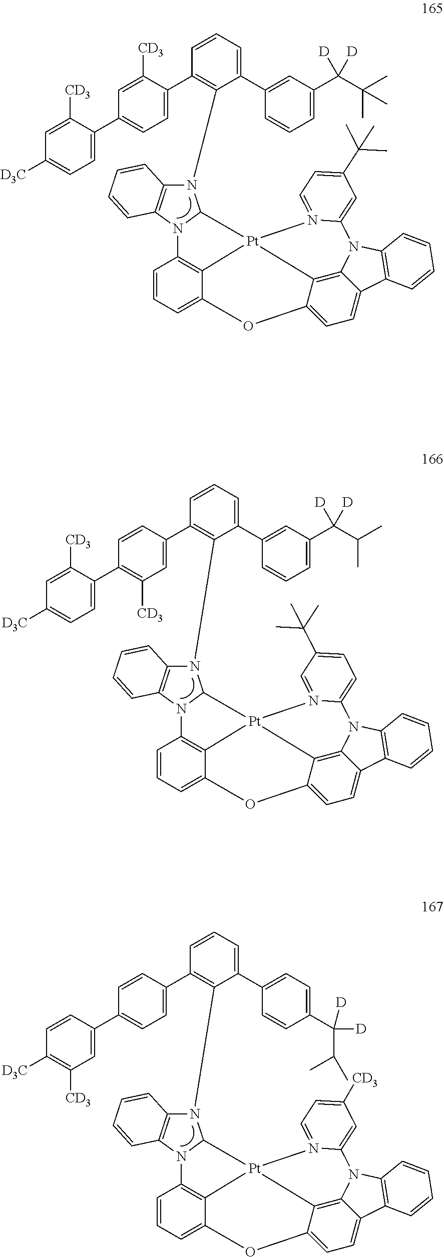

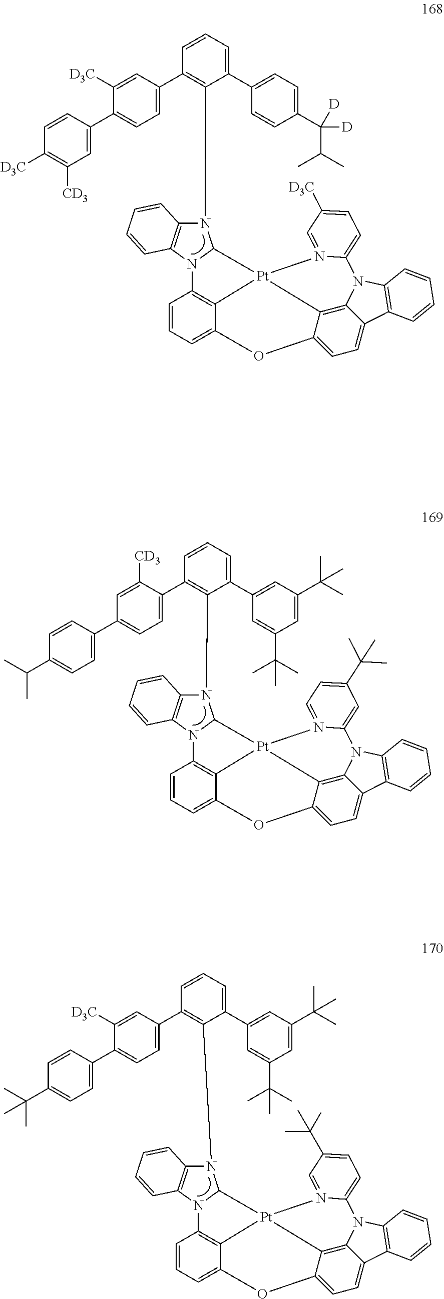

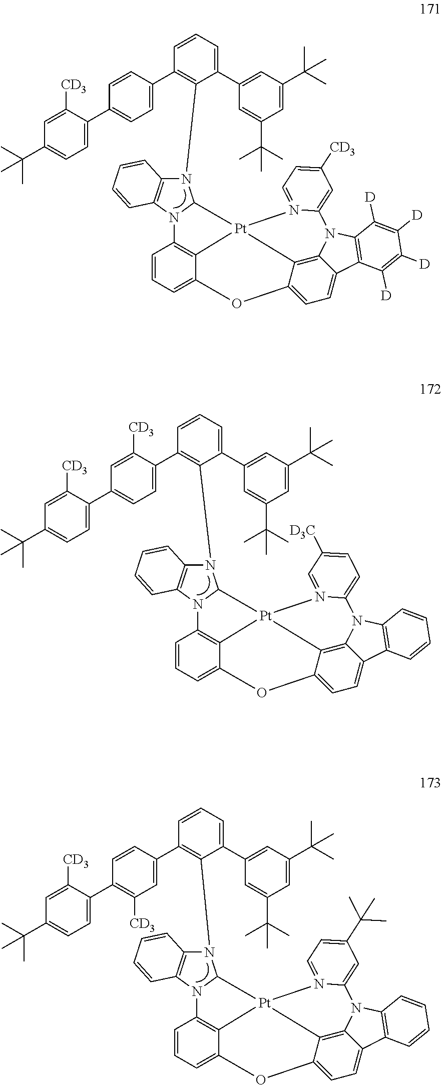

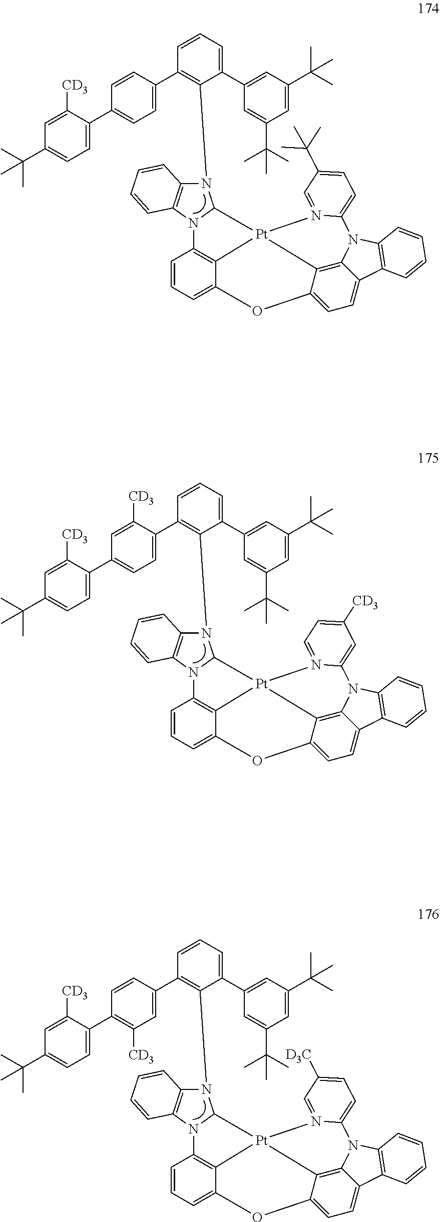

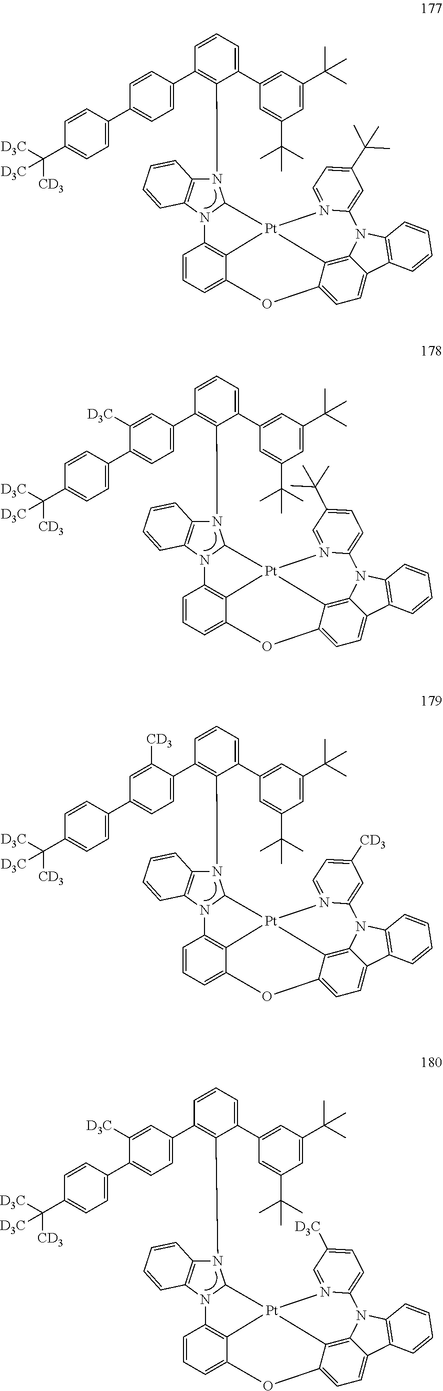

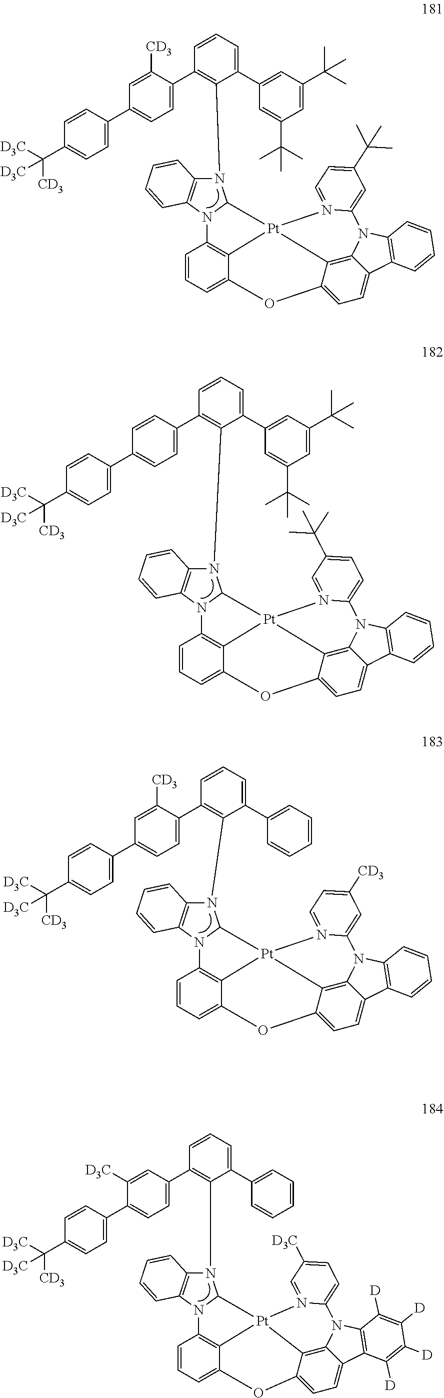

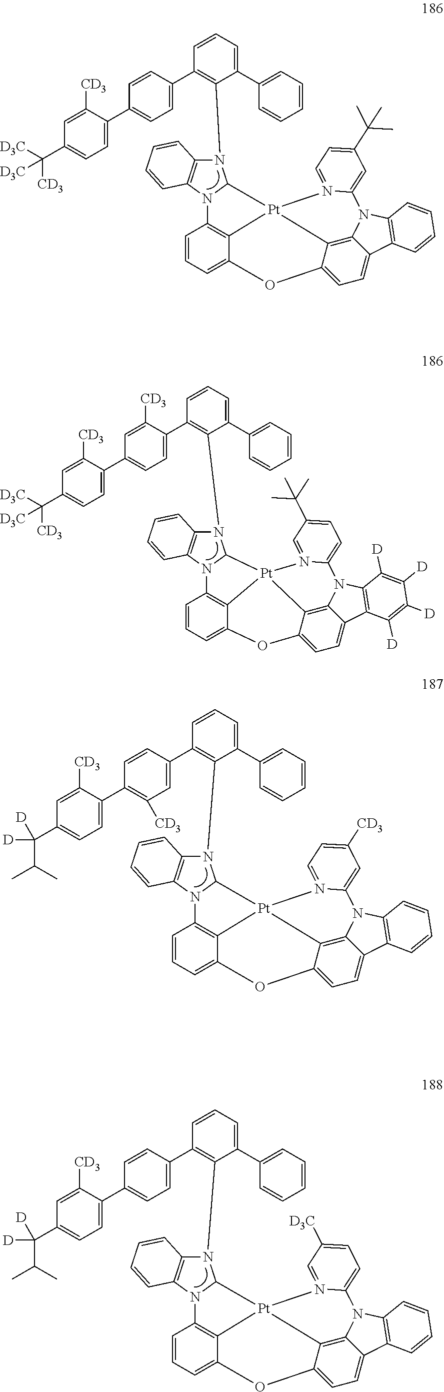

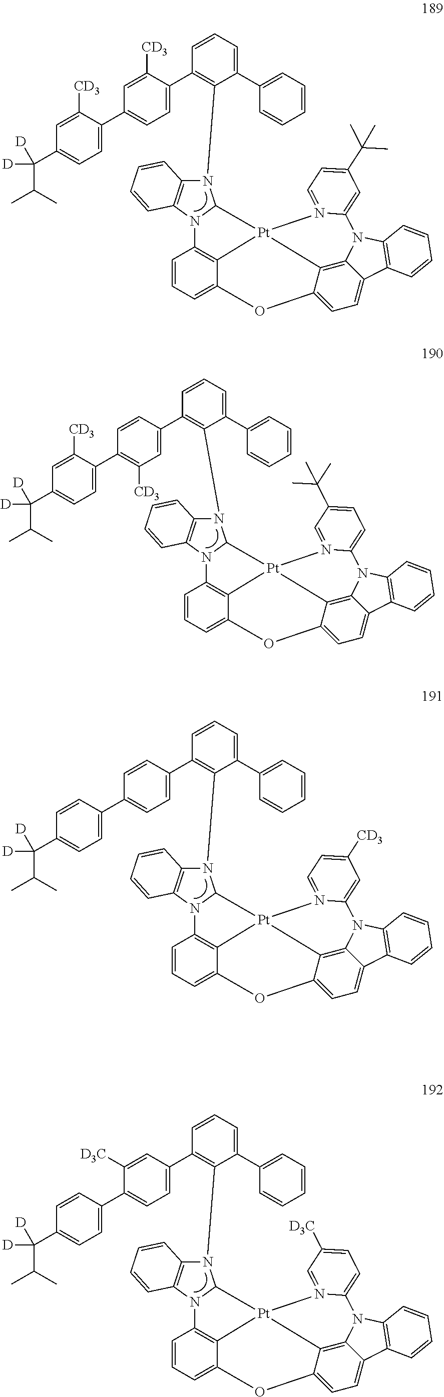

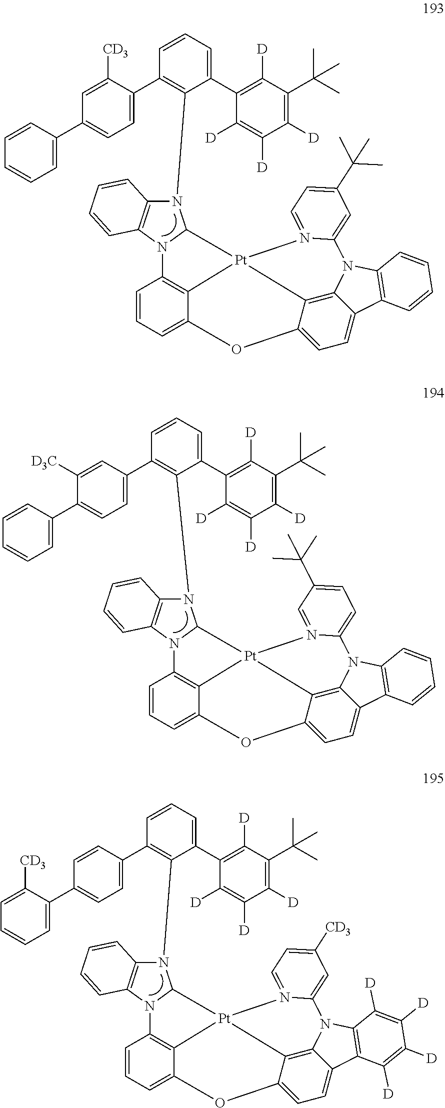

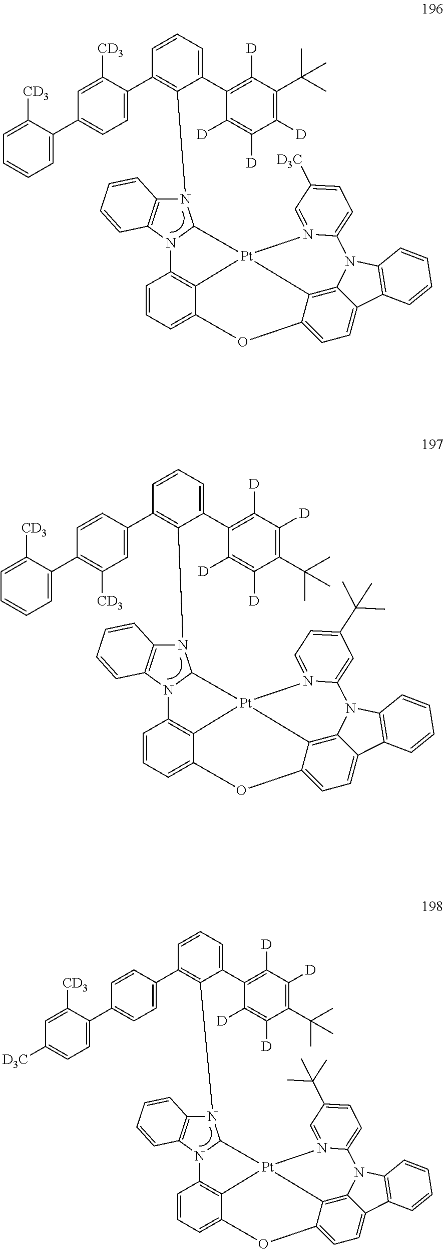

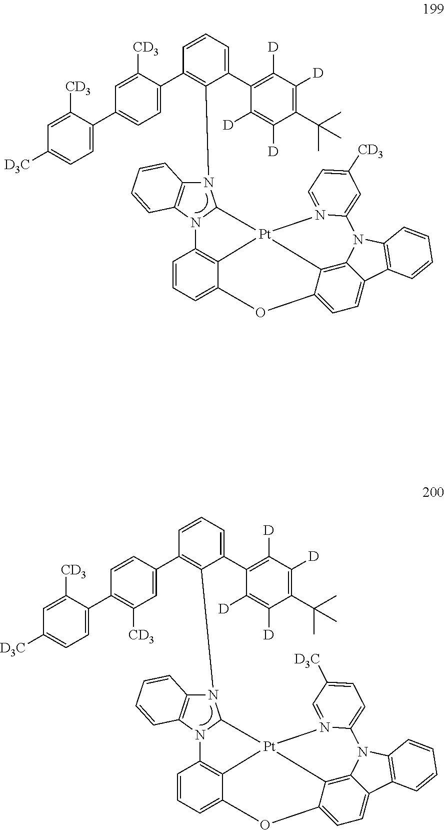

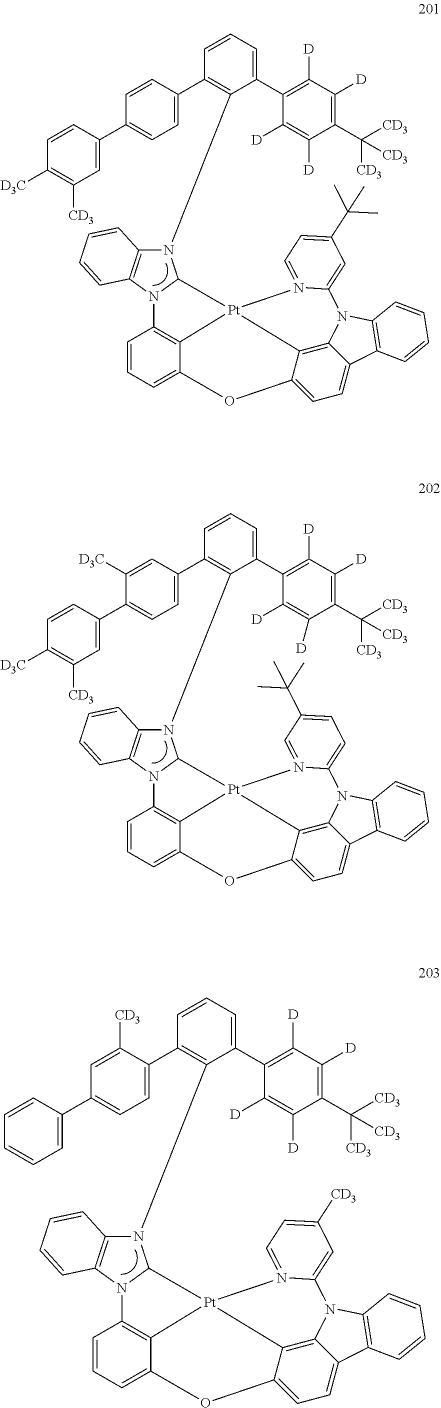

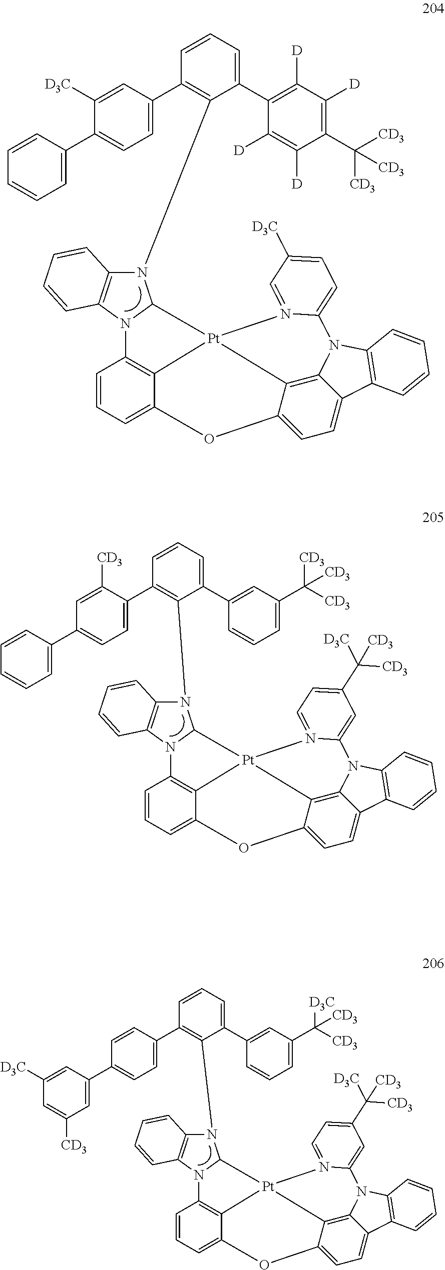

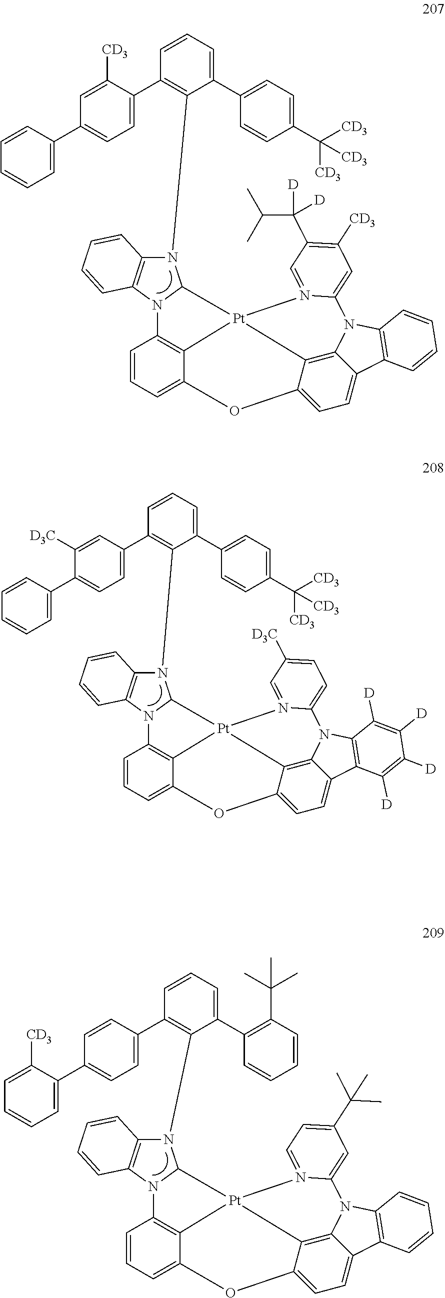

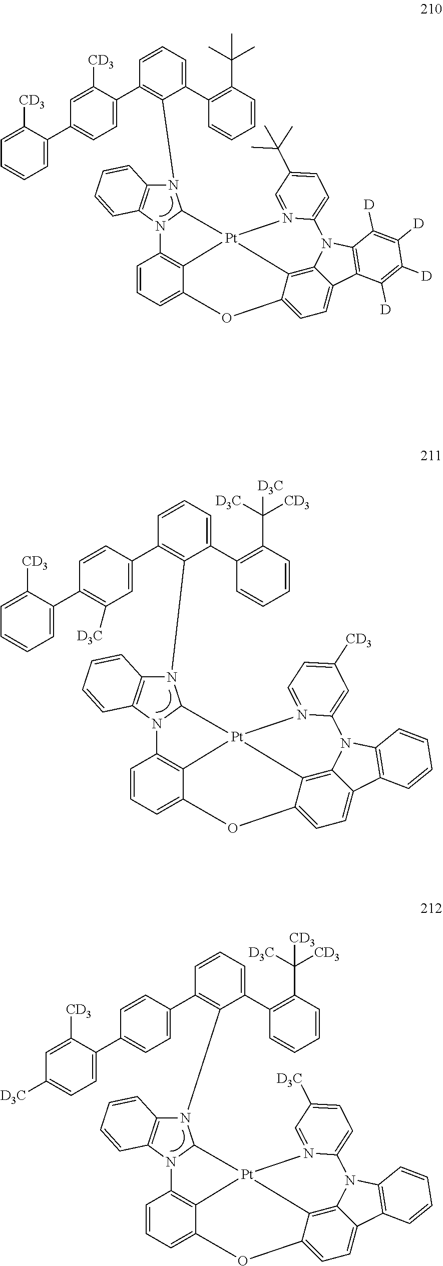

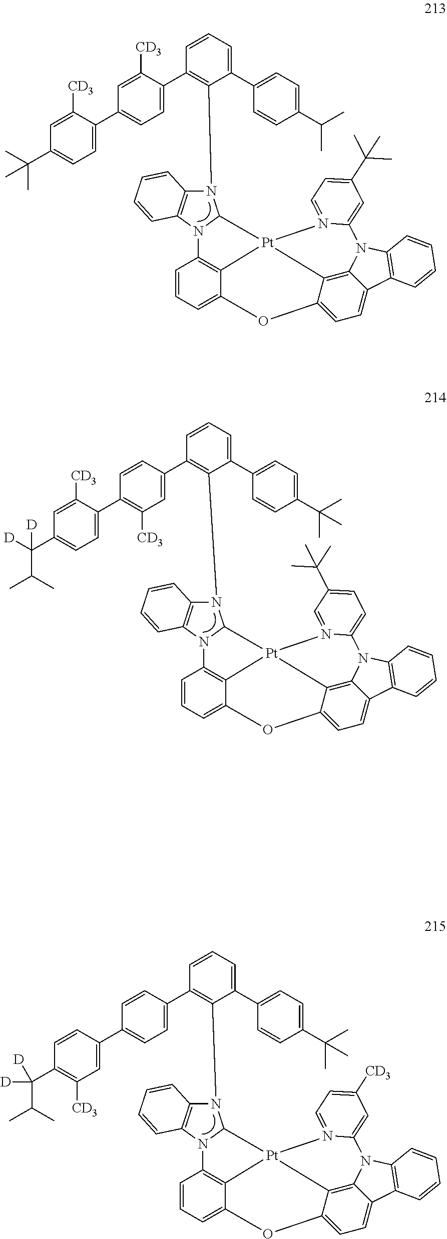

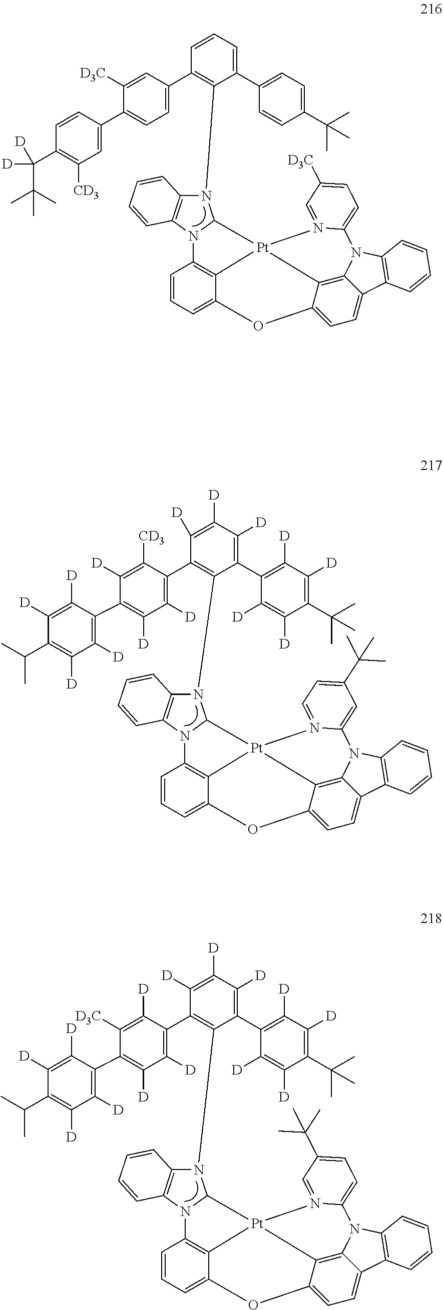

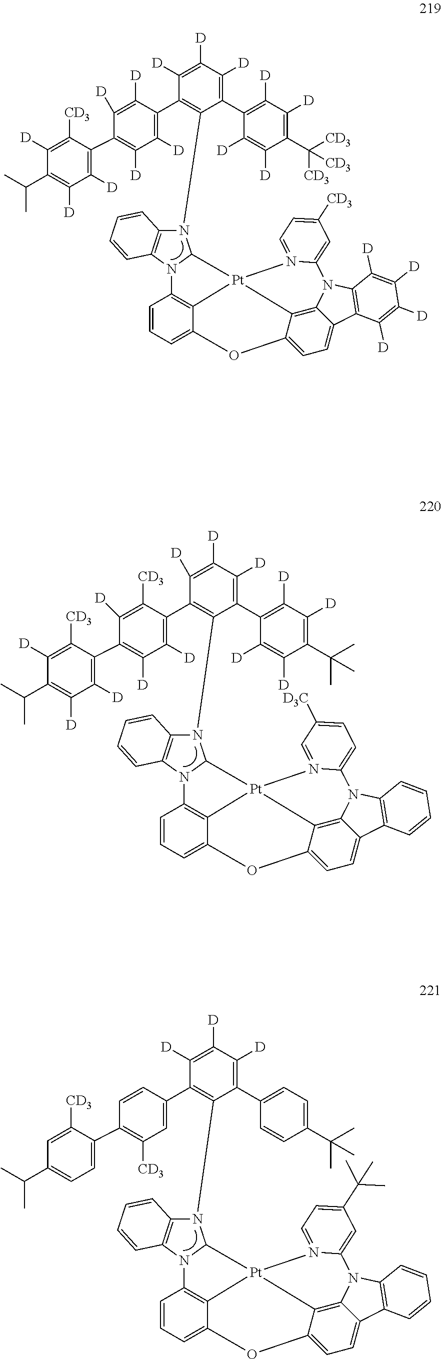

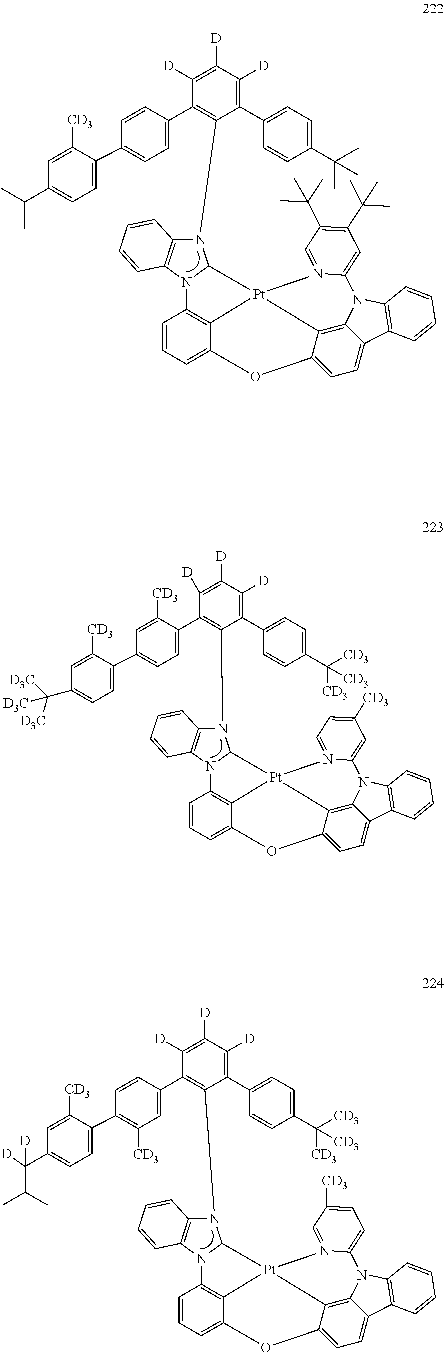

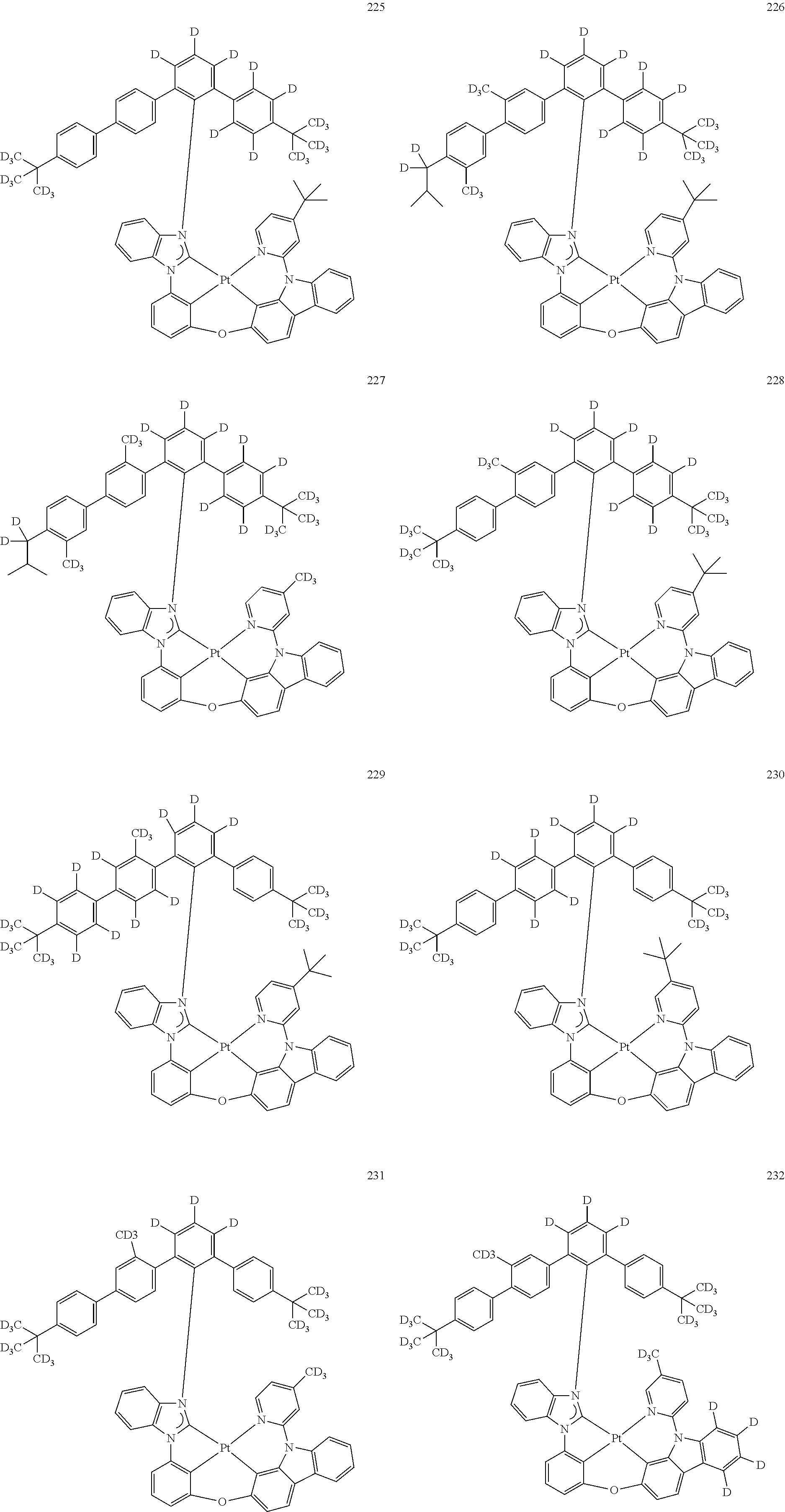

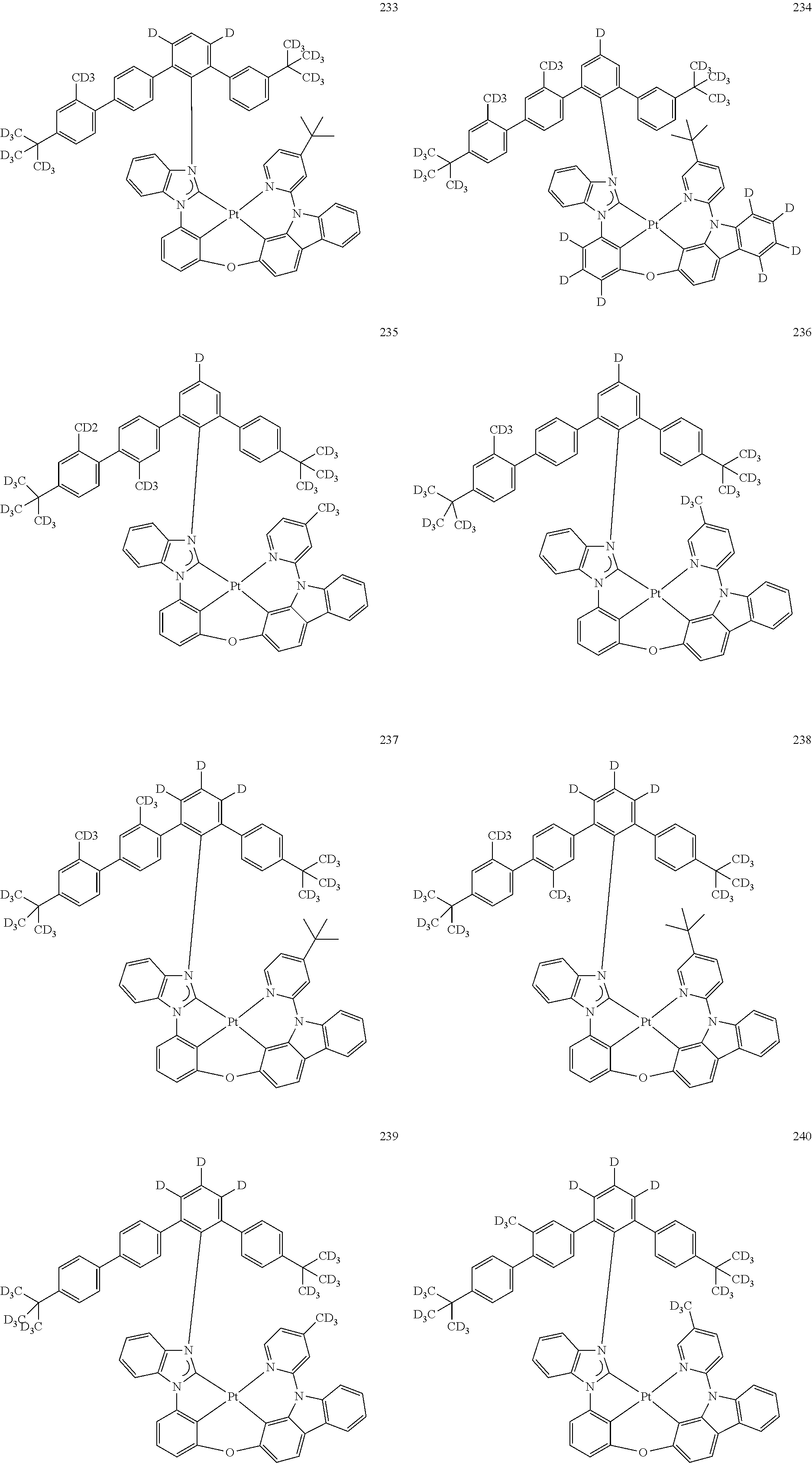

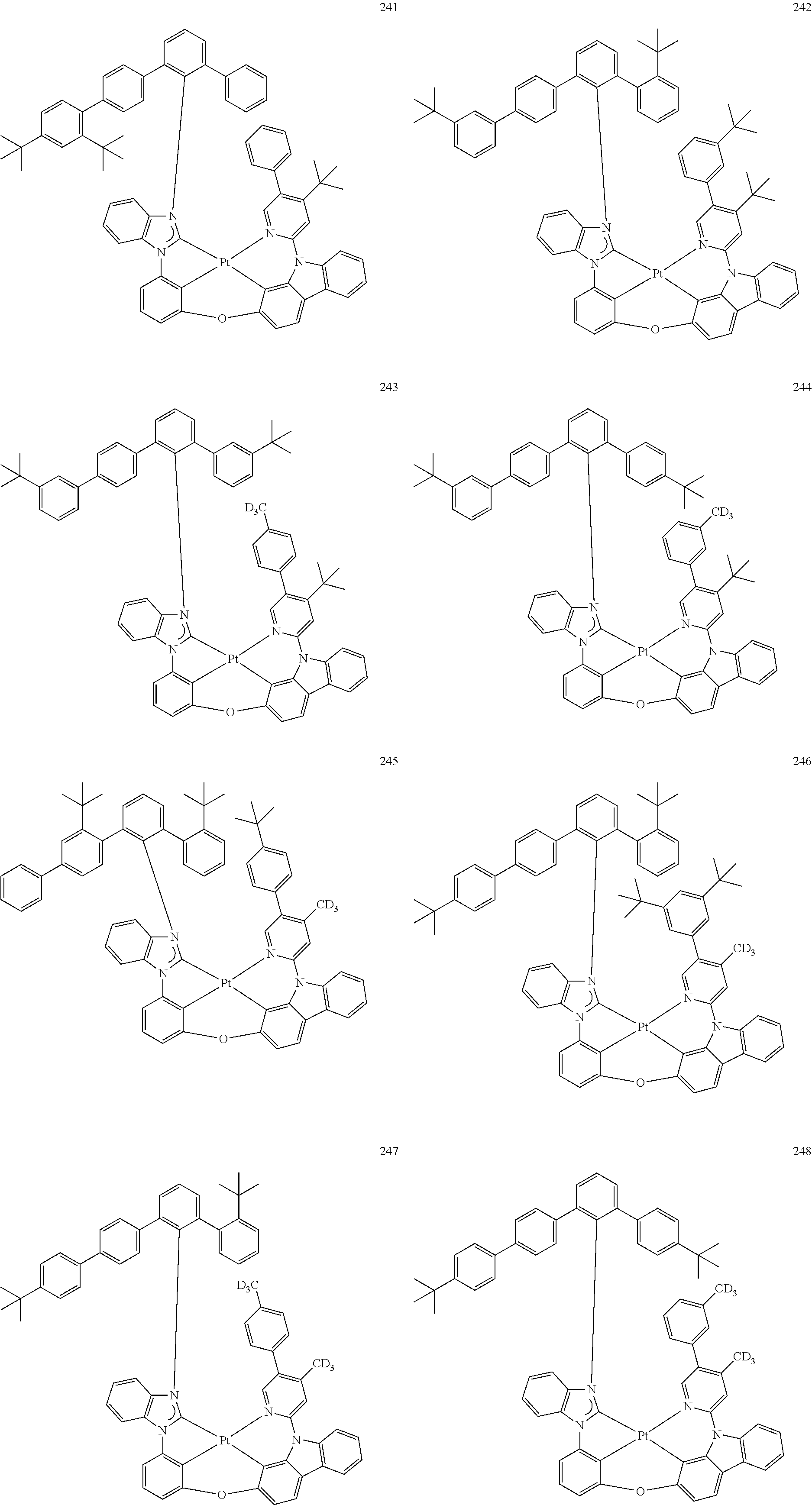

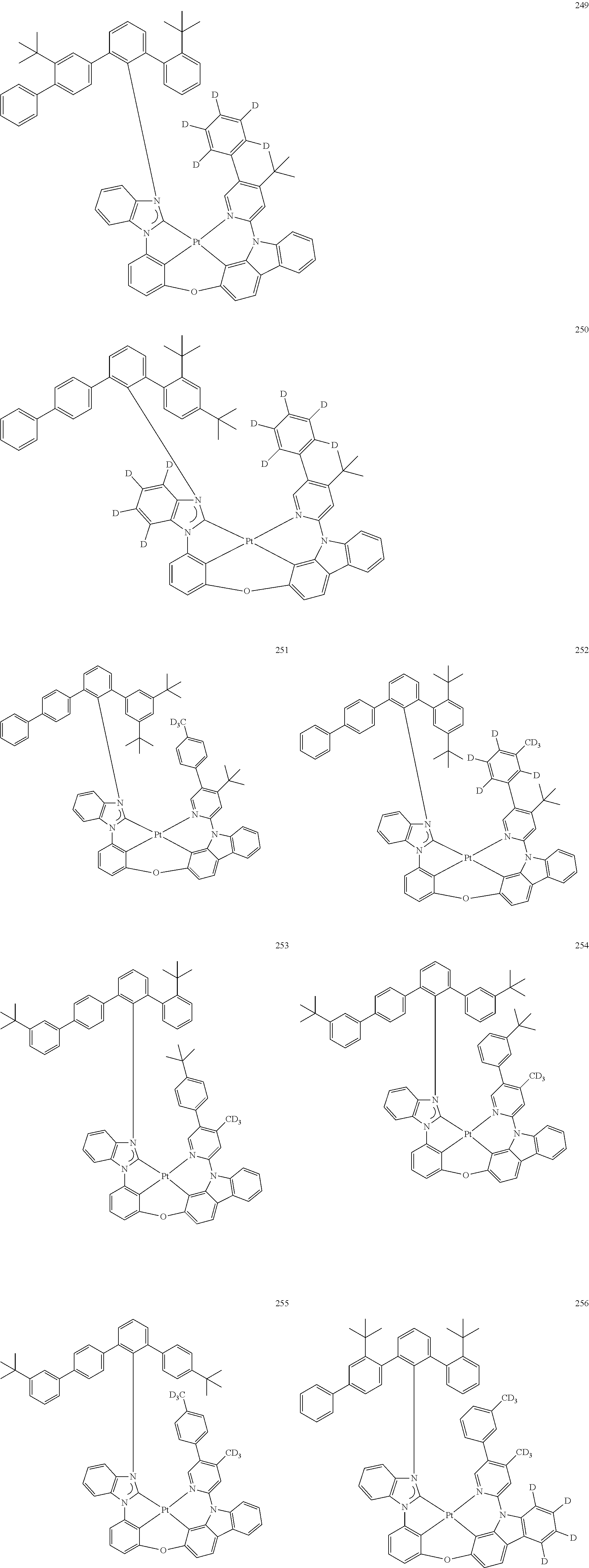

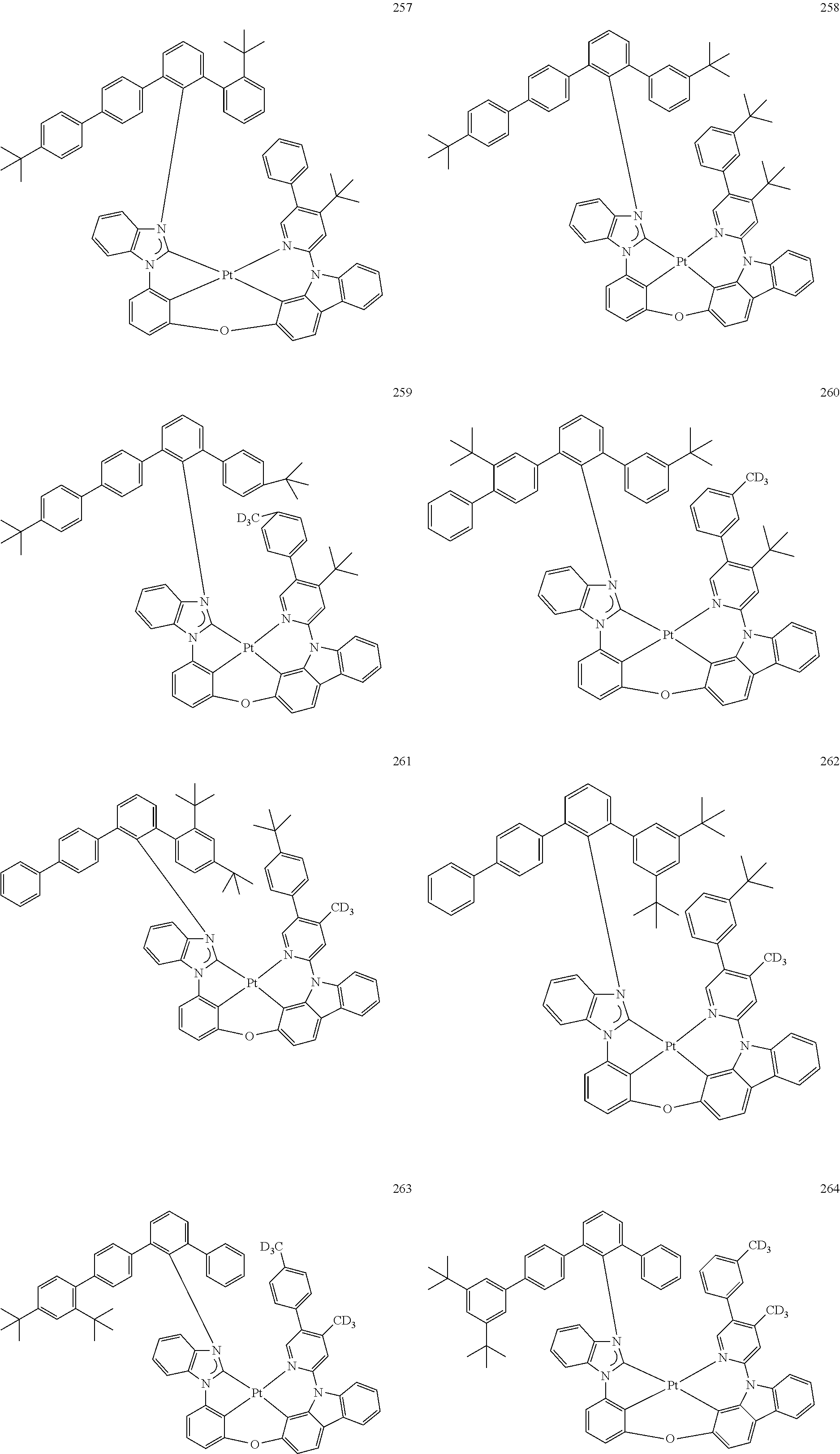

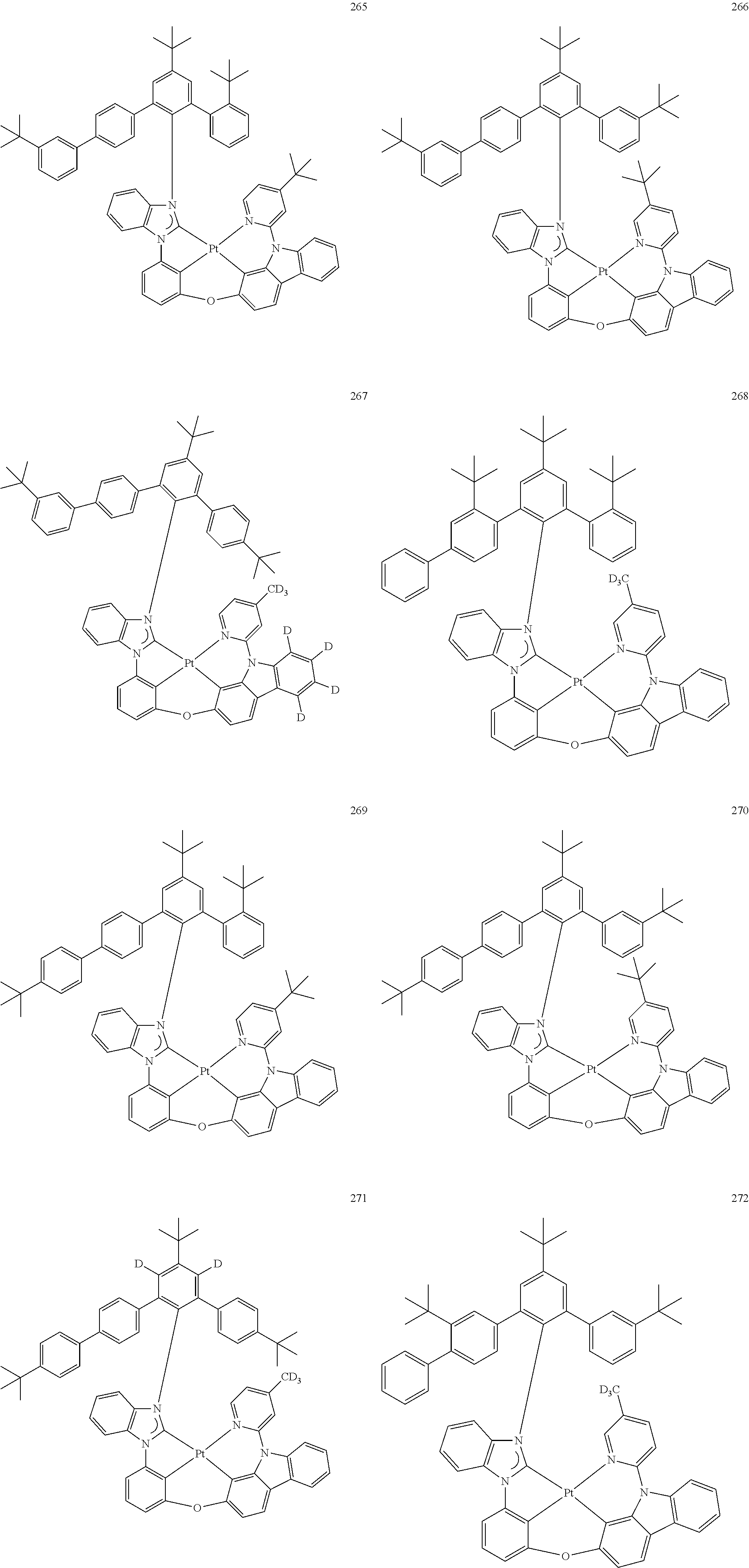

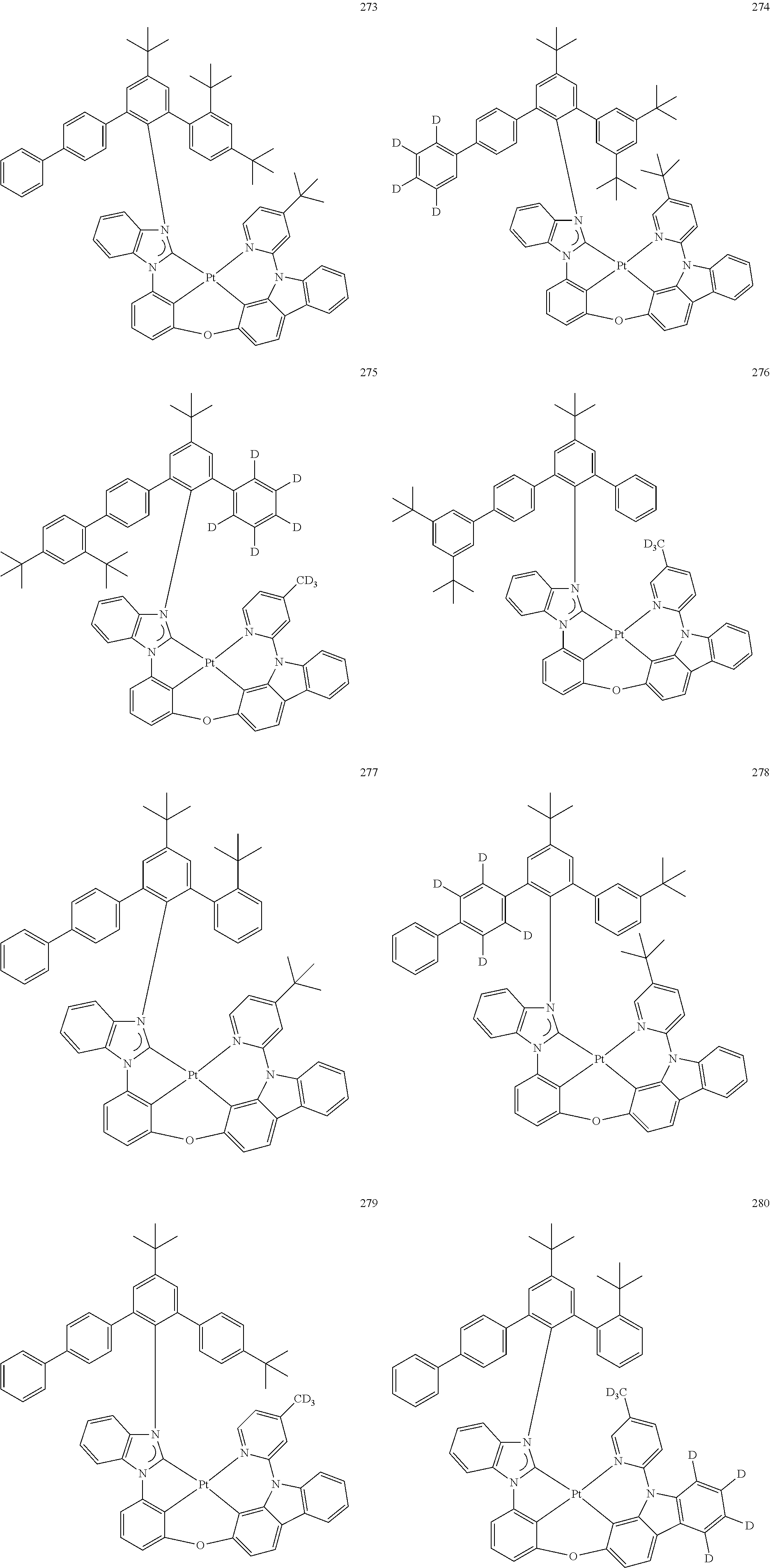

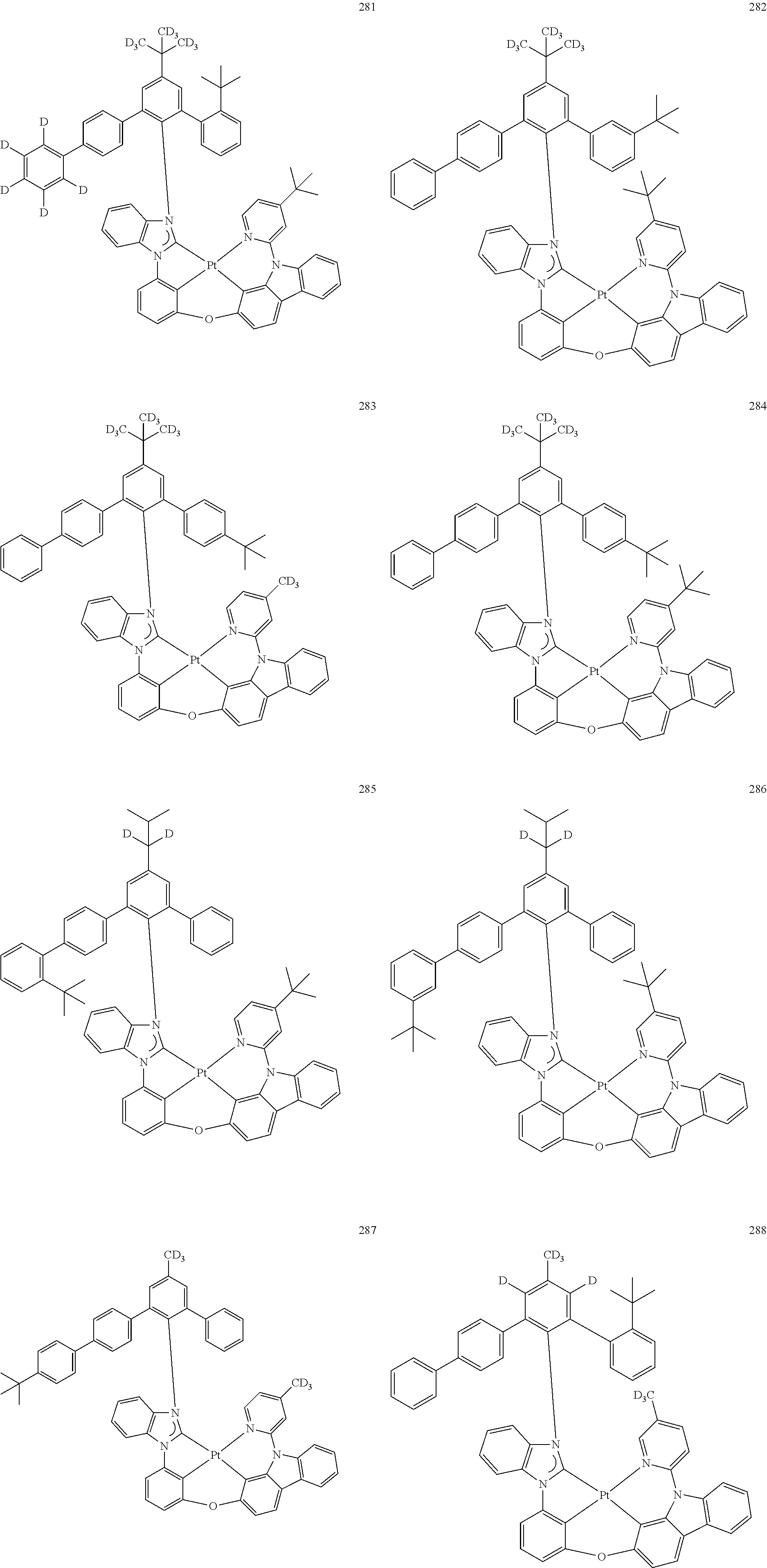

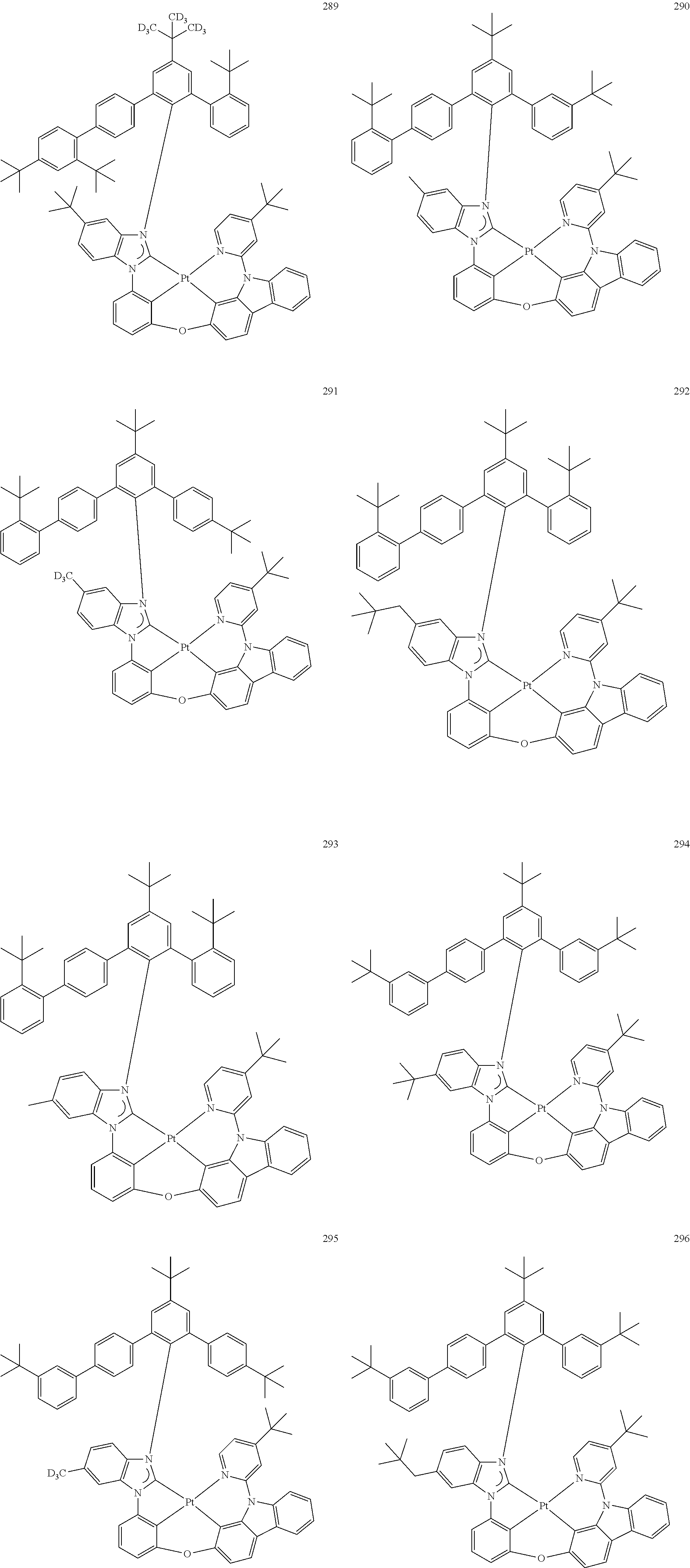

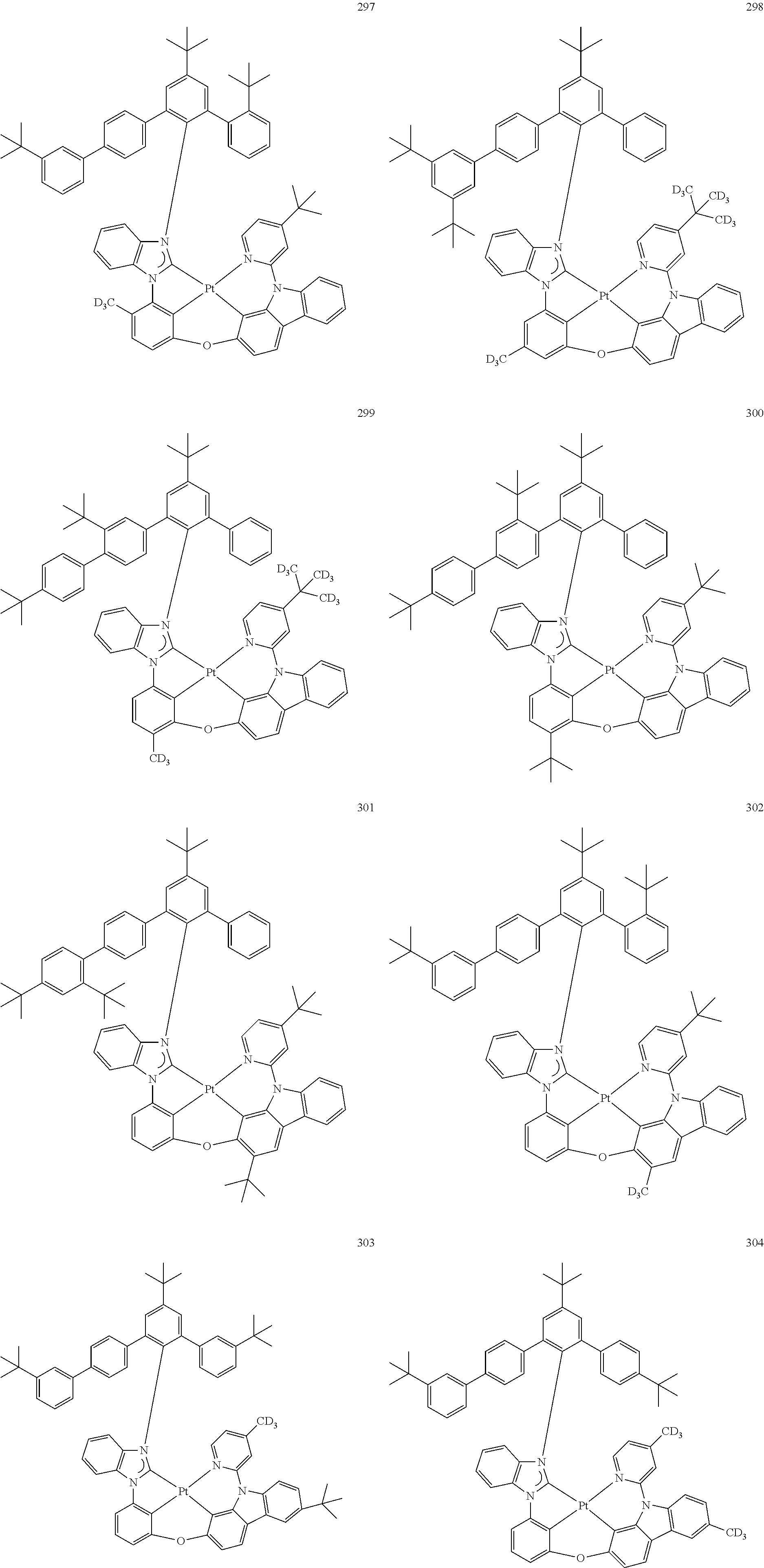

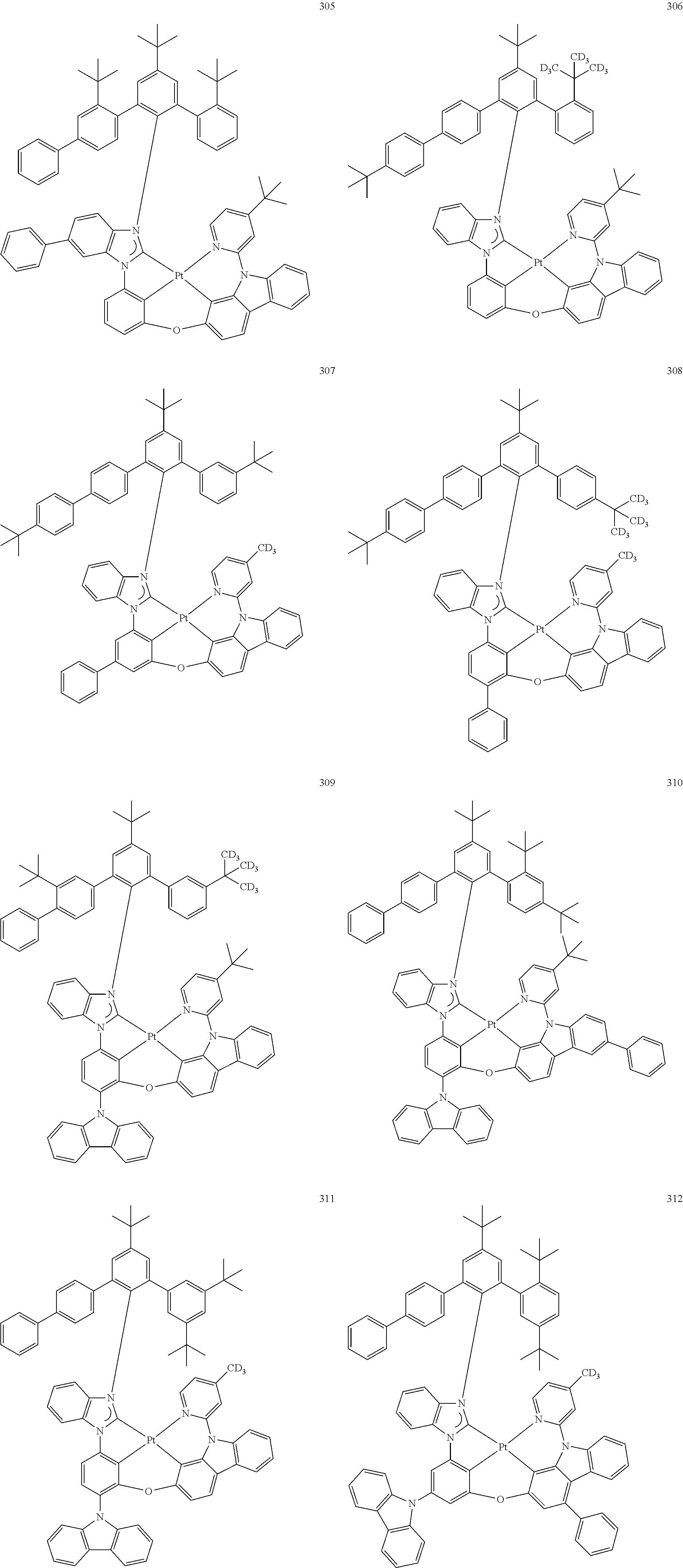

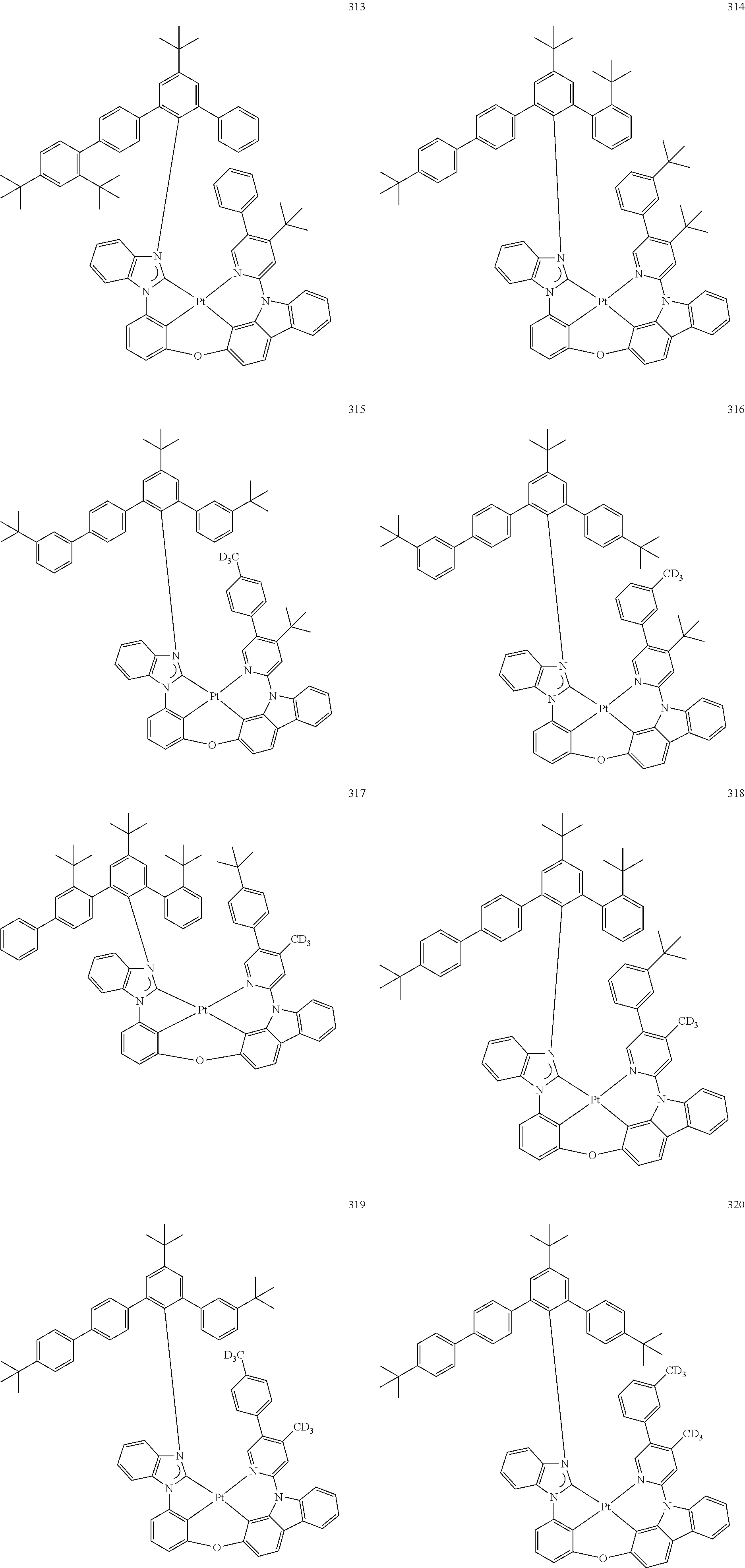

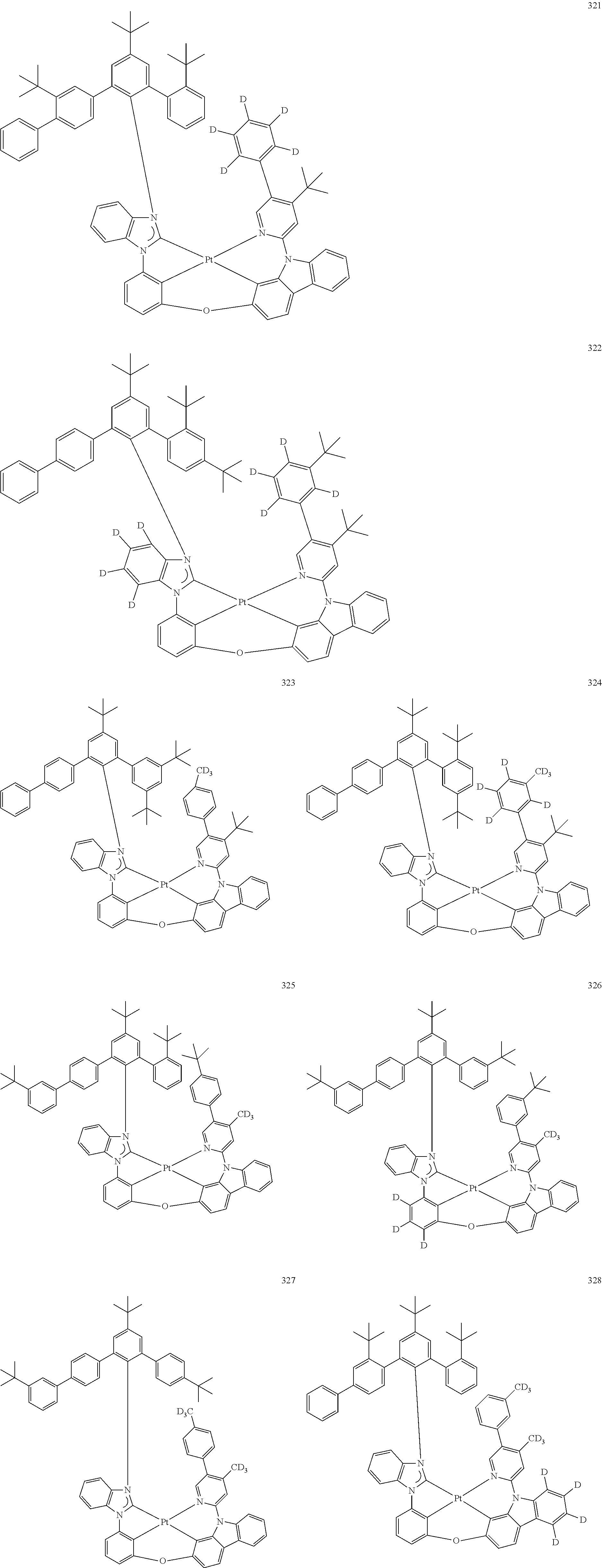

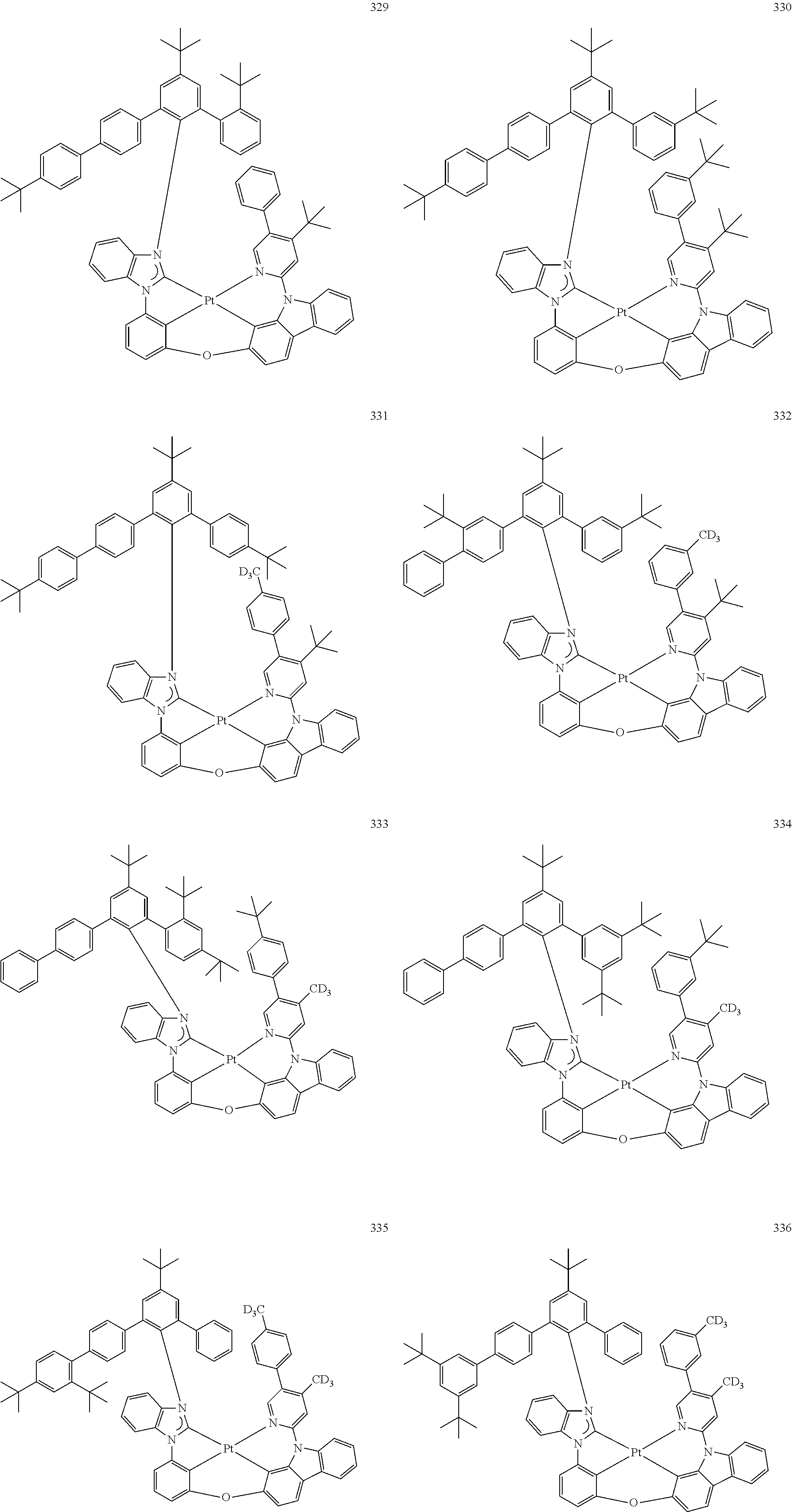

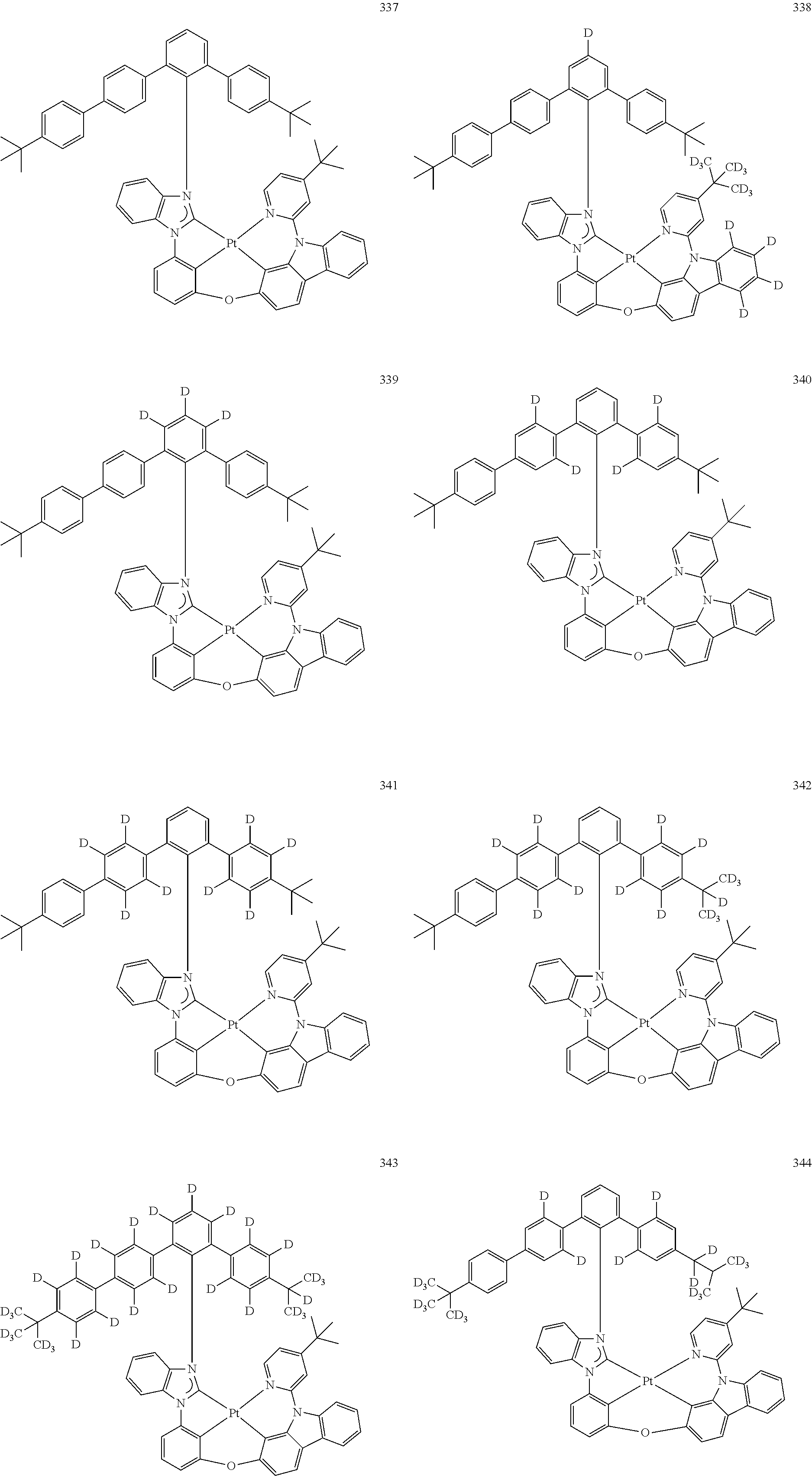

In one or more embodiments, the second compound may be at least one of Compounds ETH1 to ETH100:

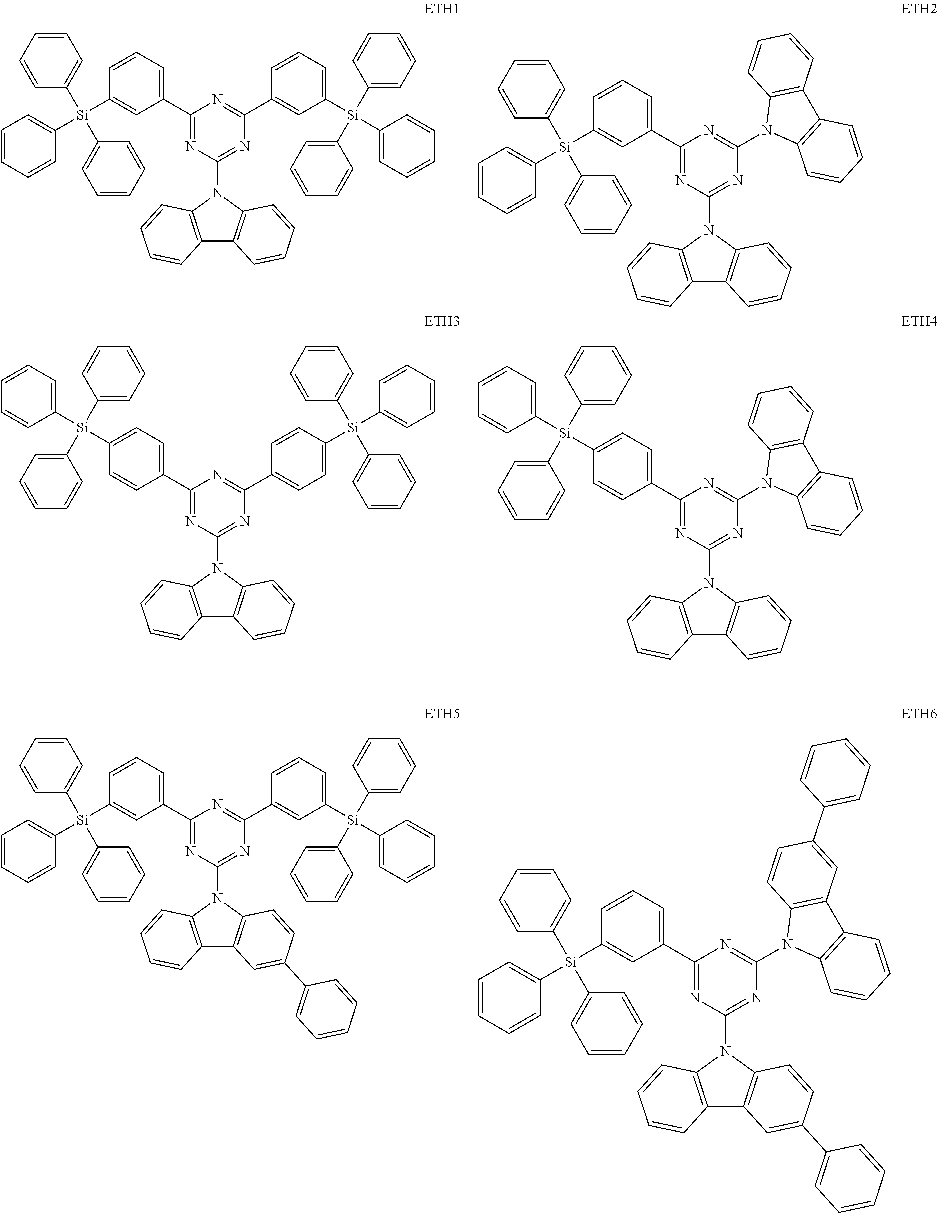

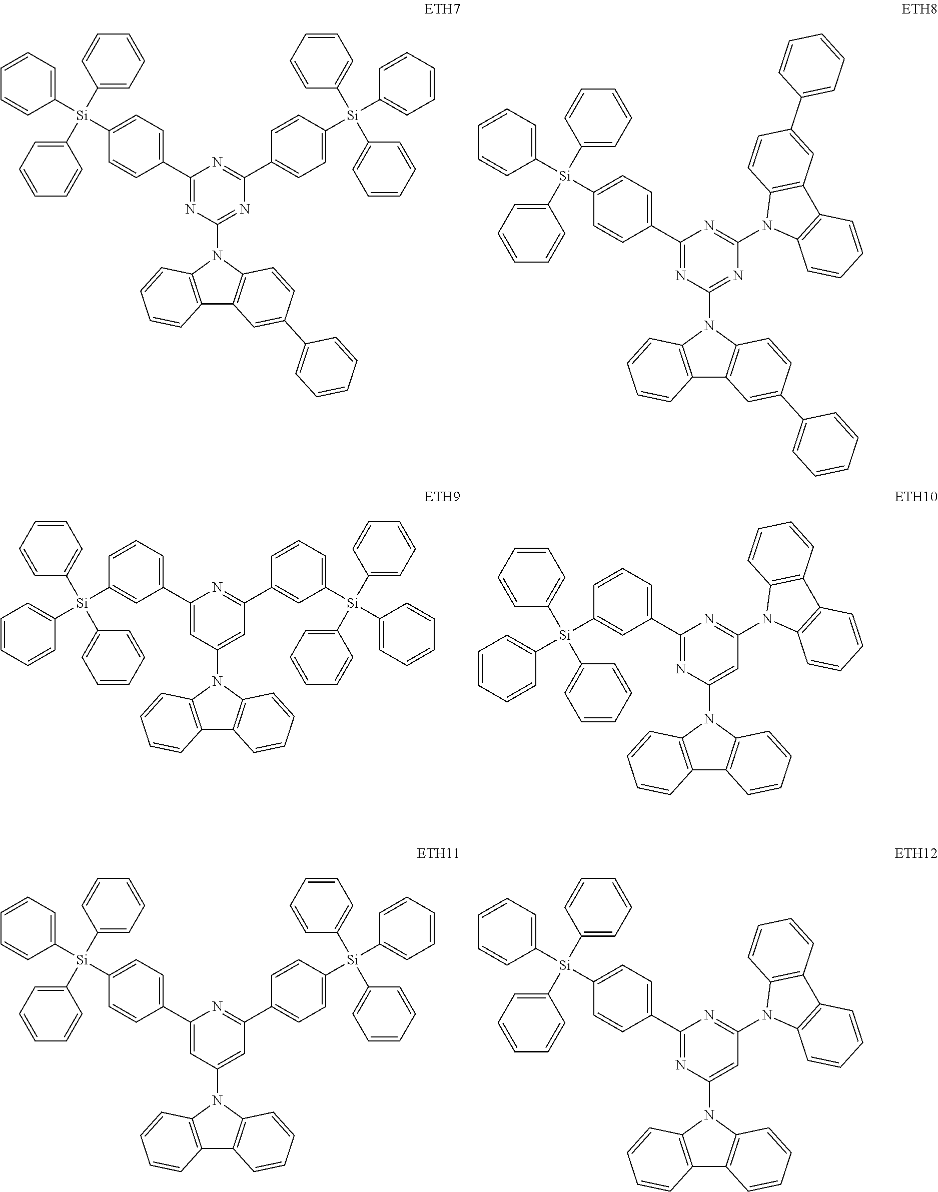

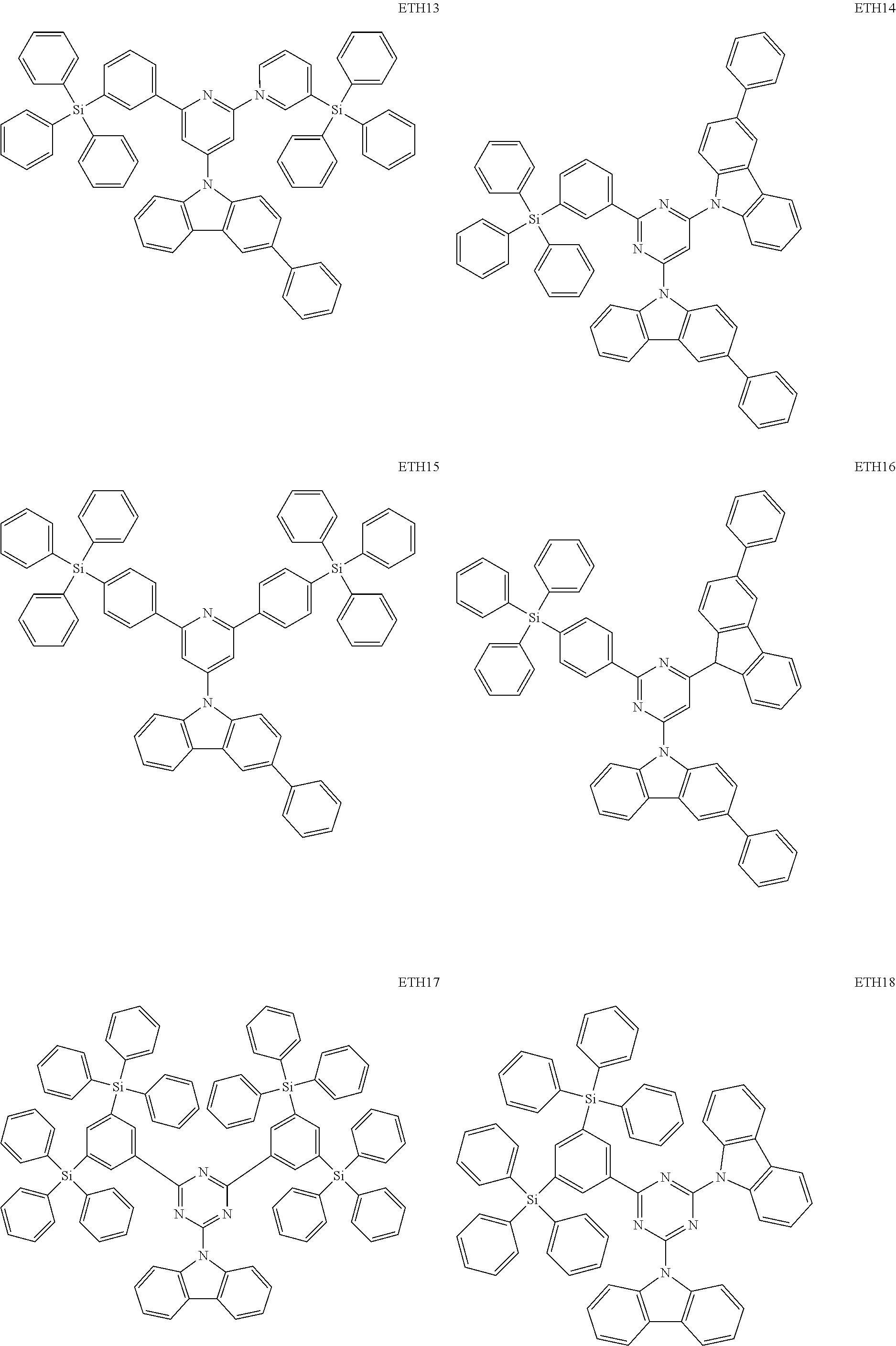

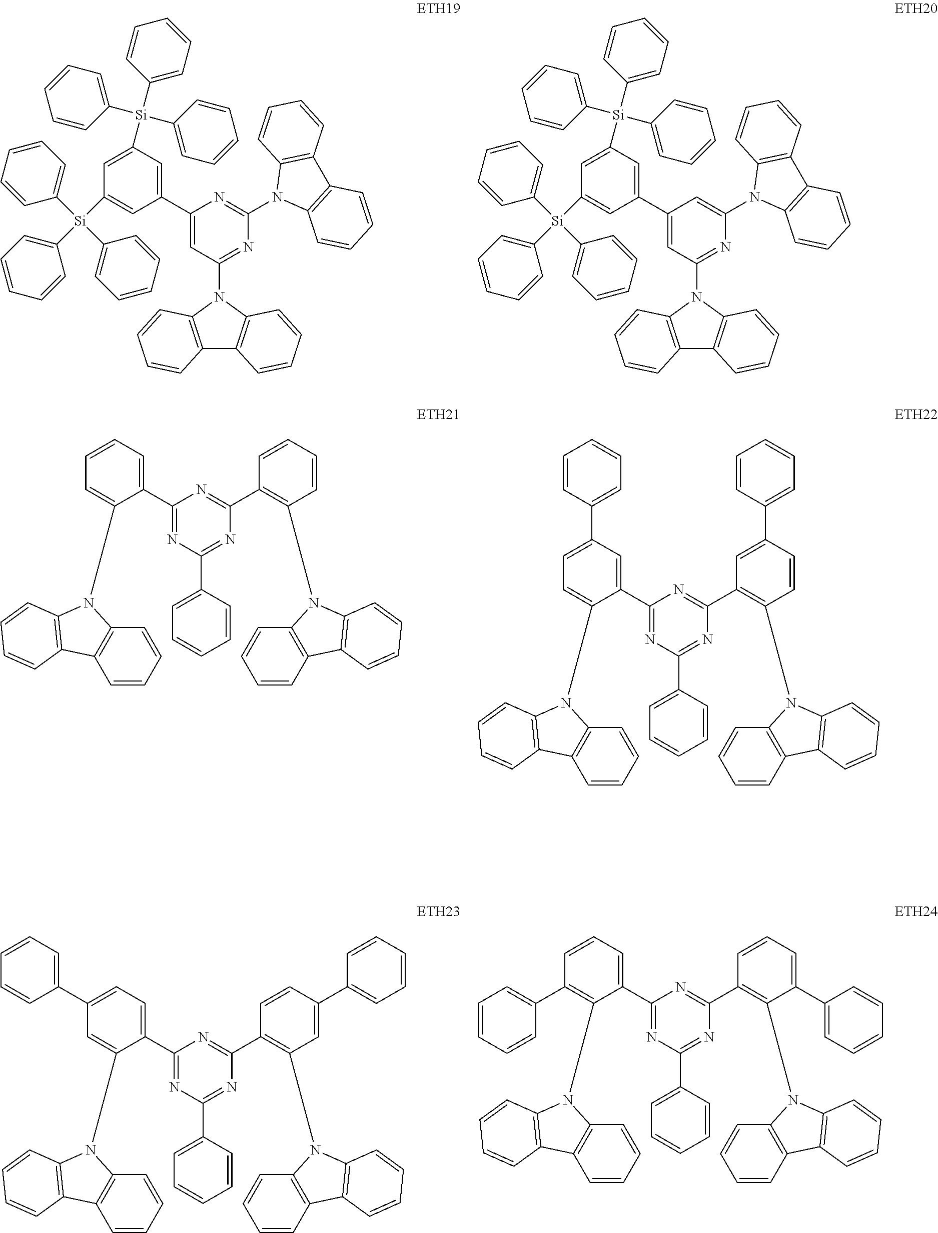

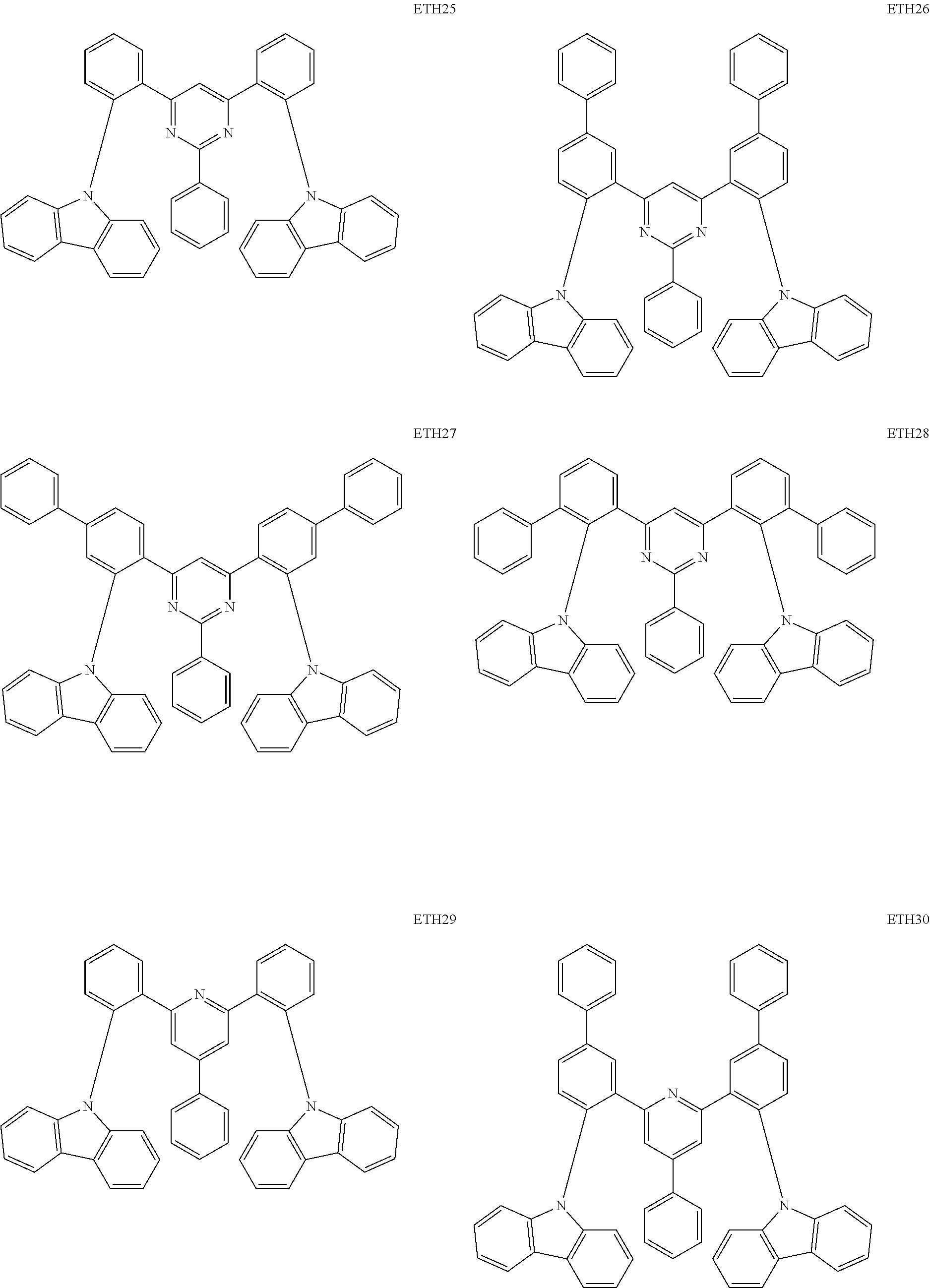

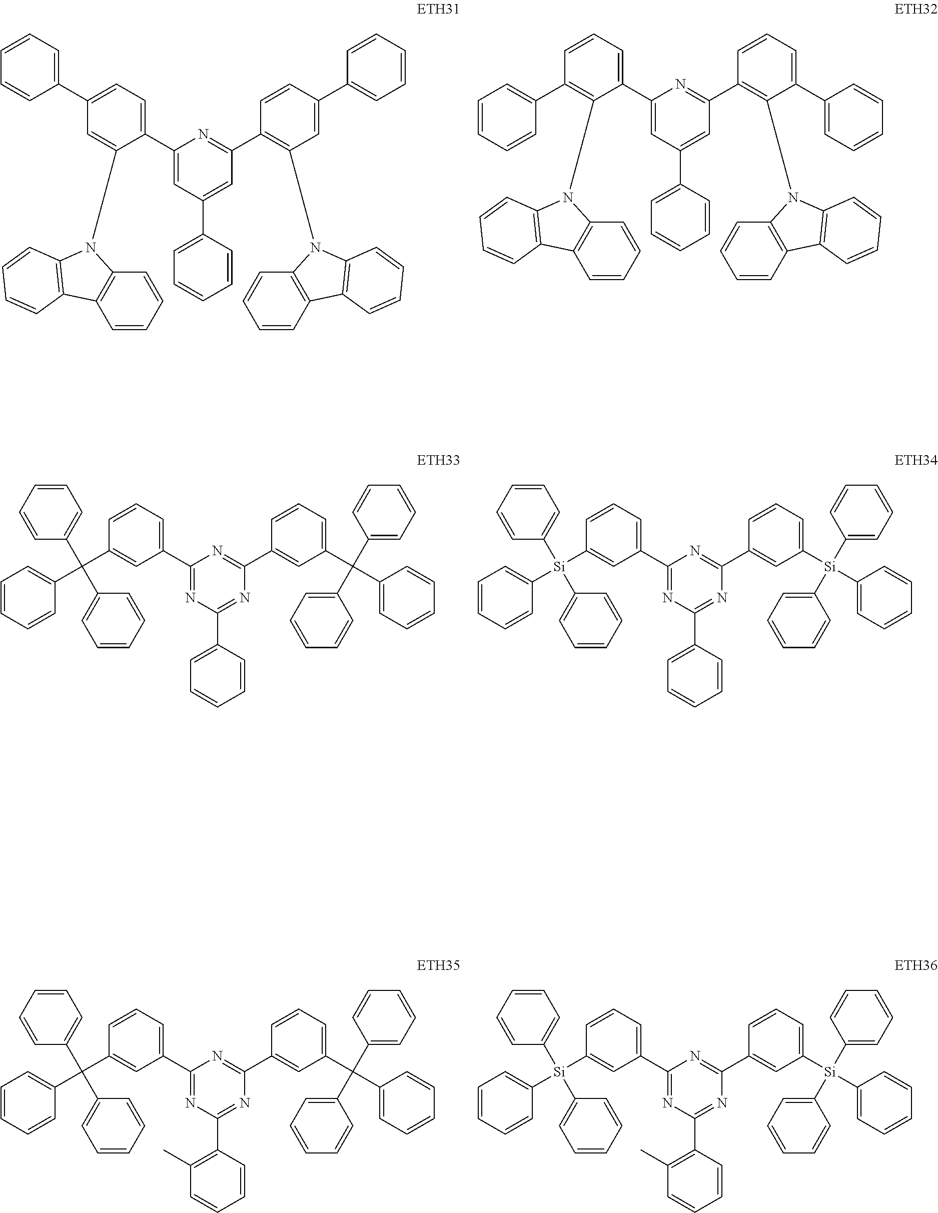

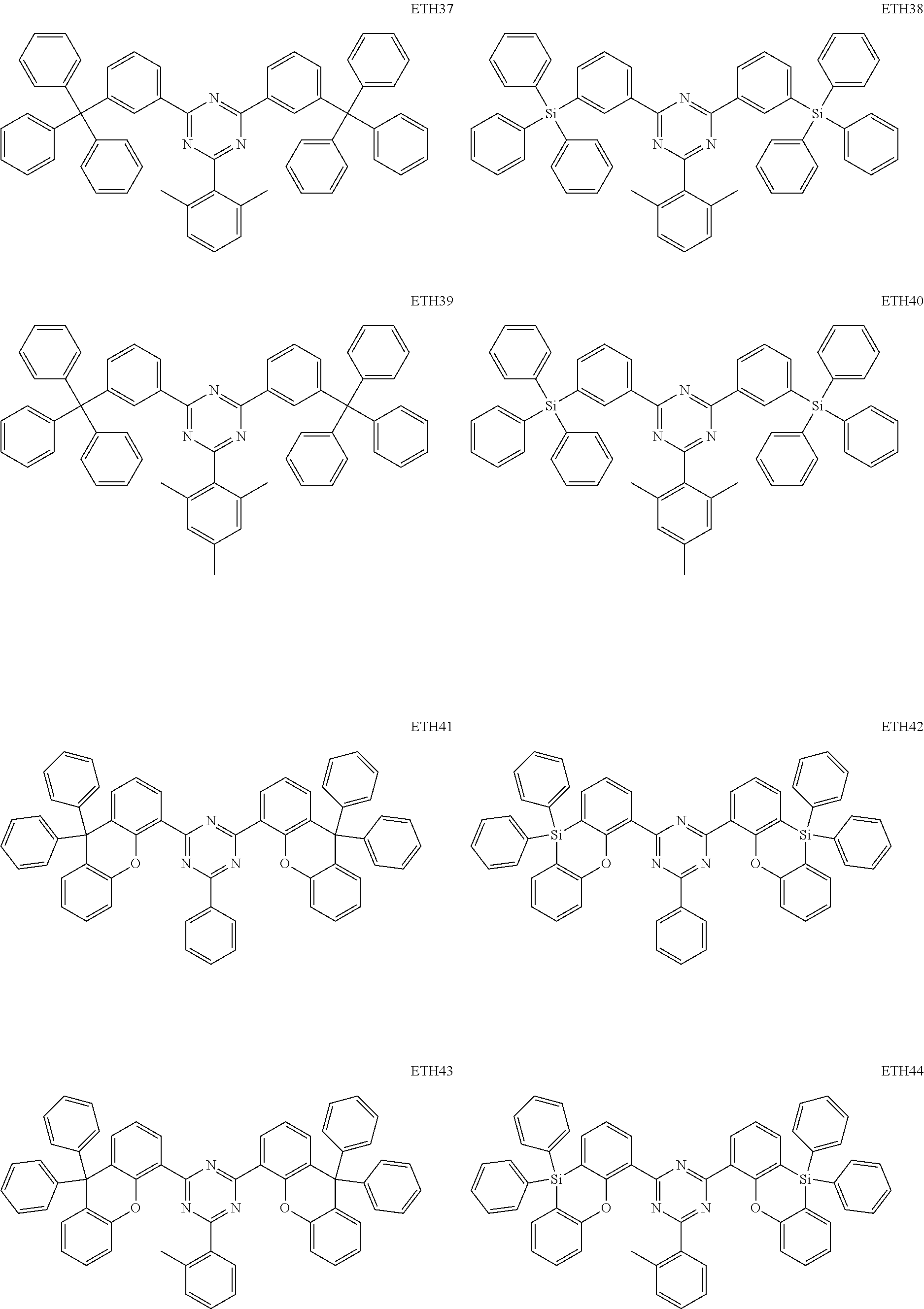

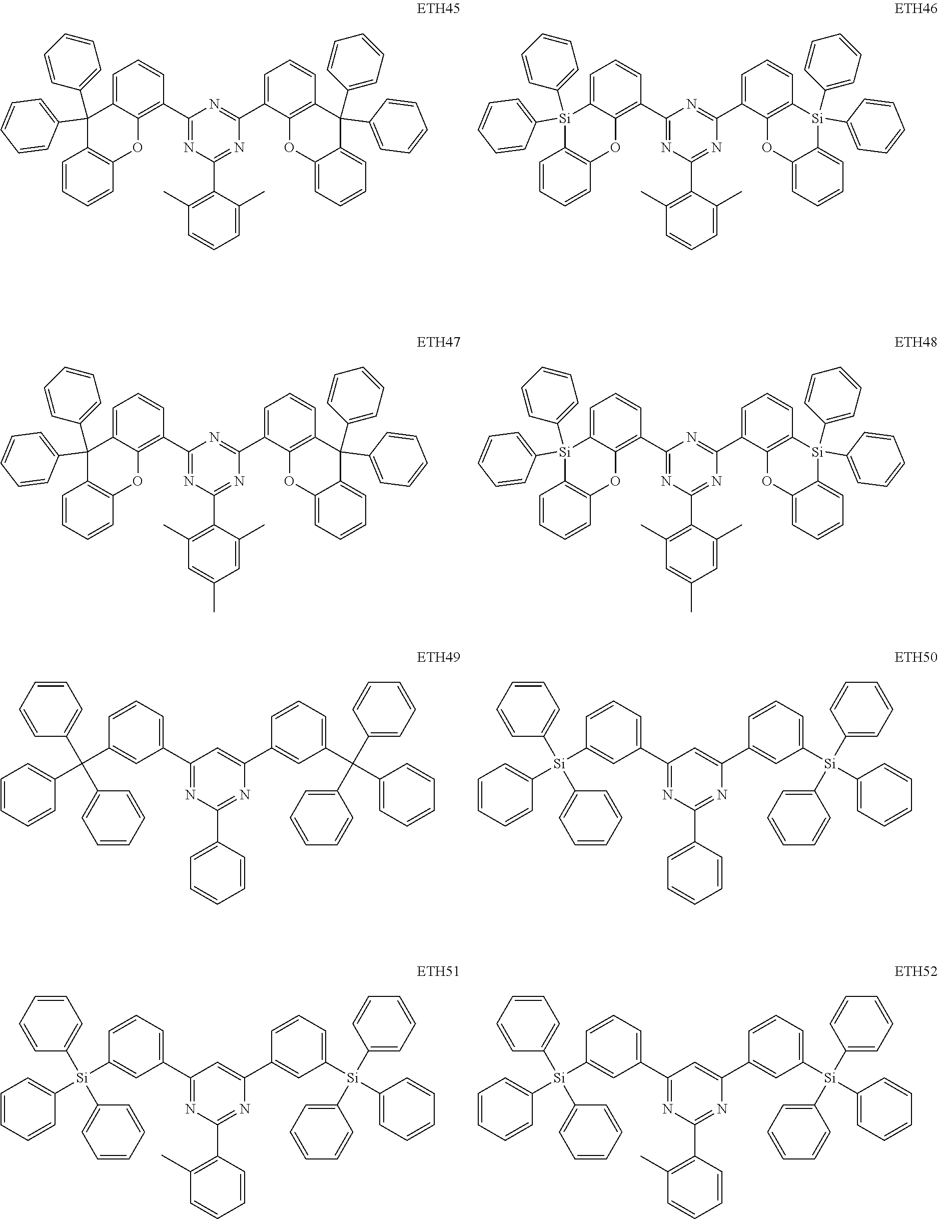

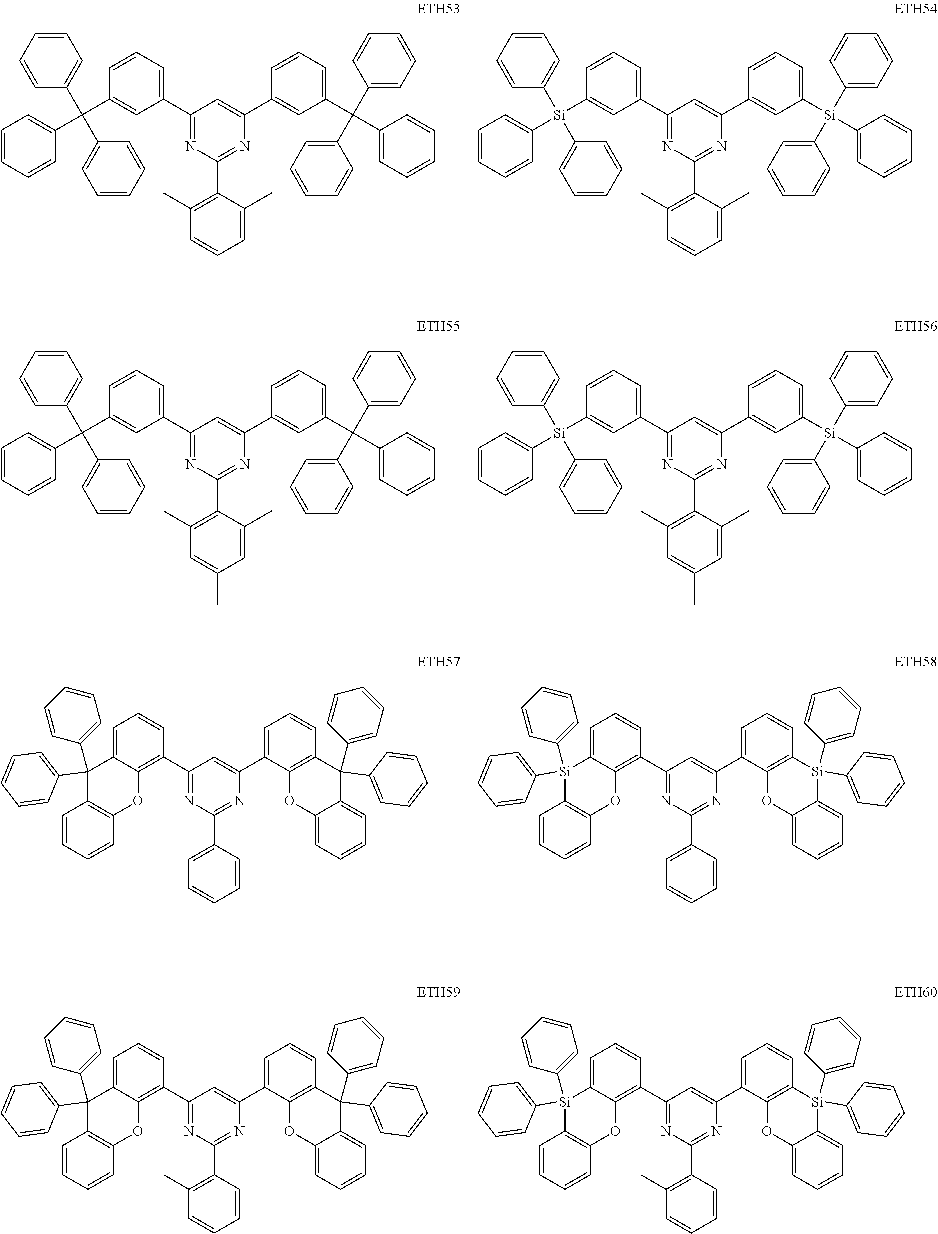

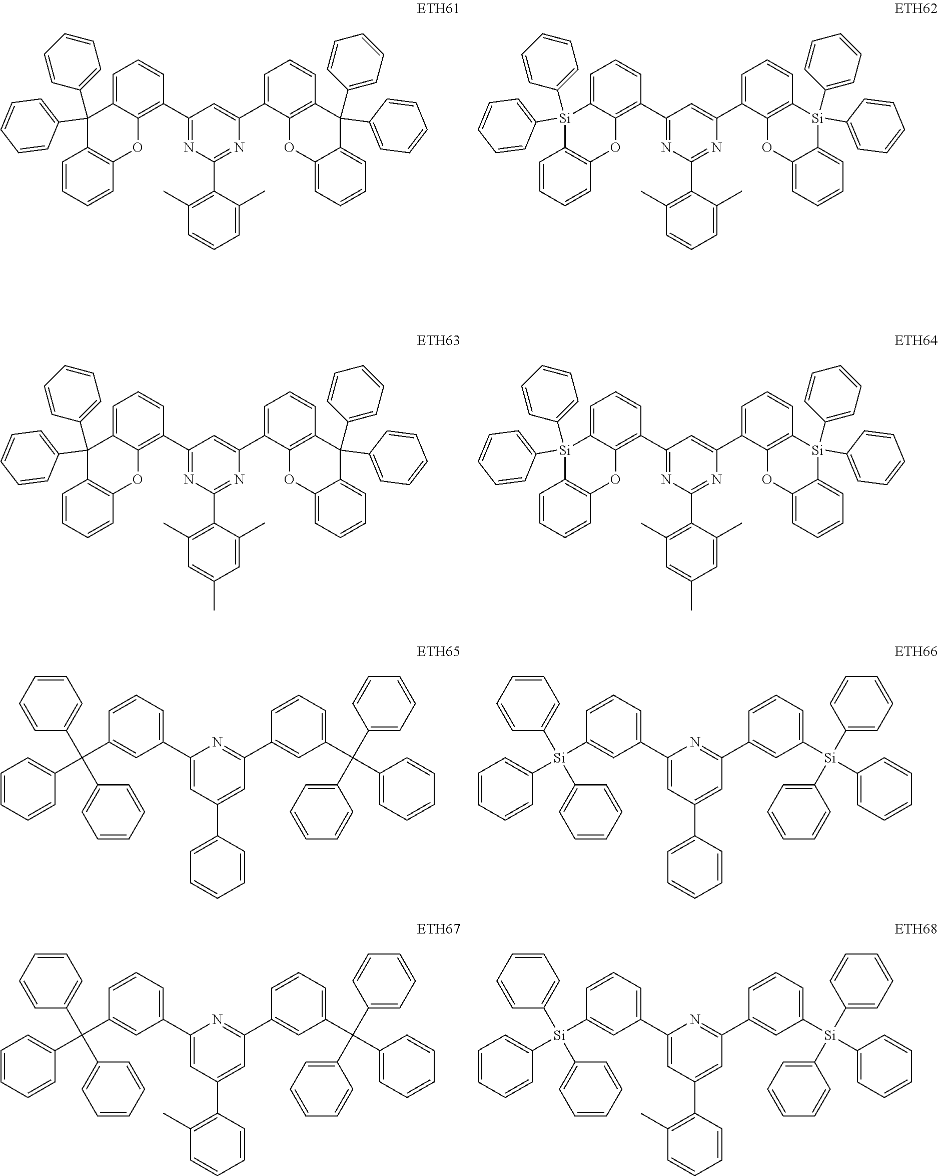

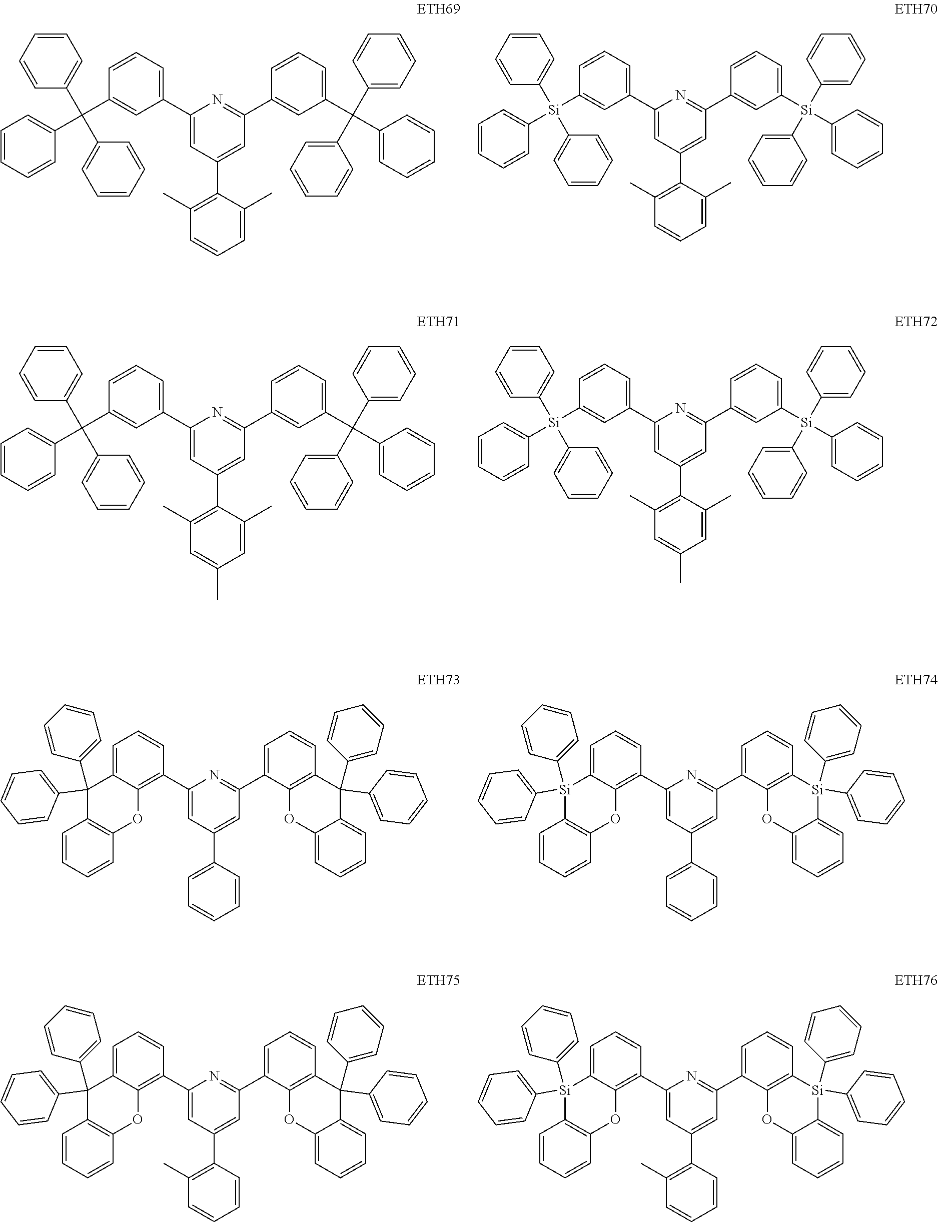

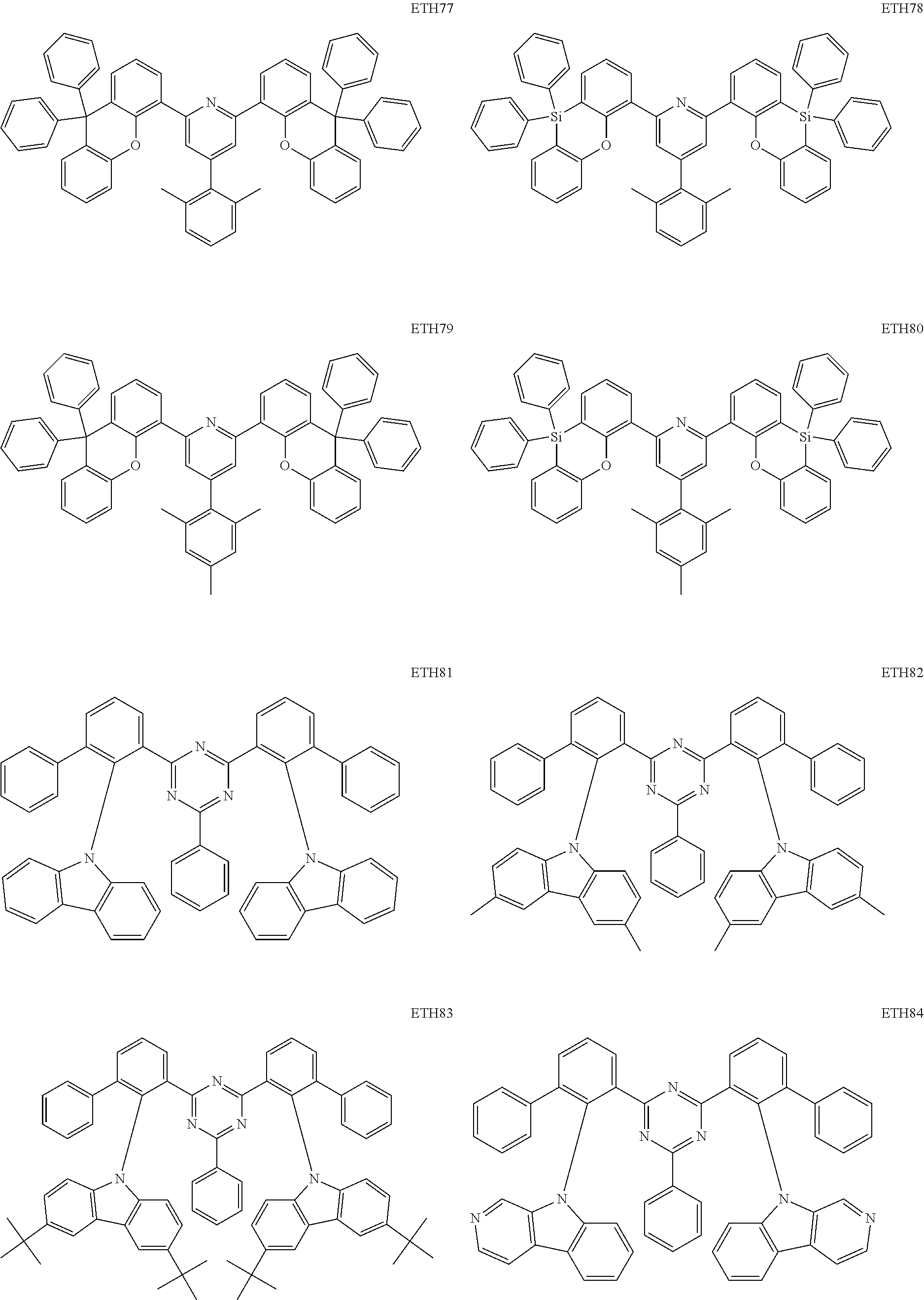

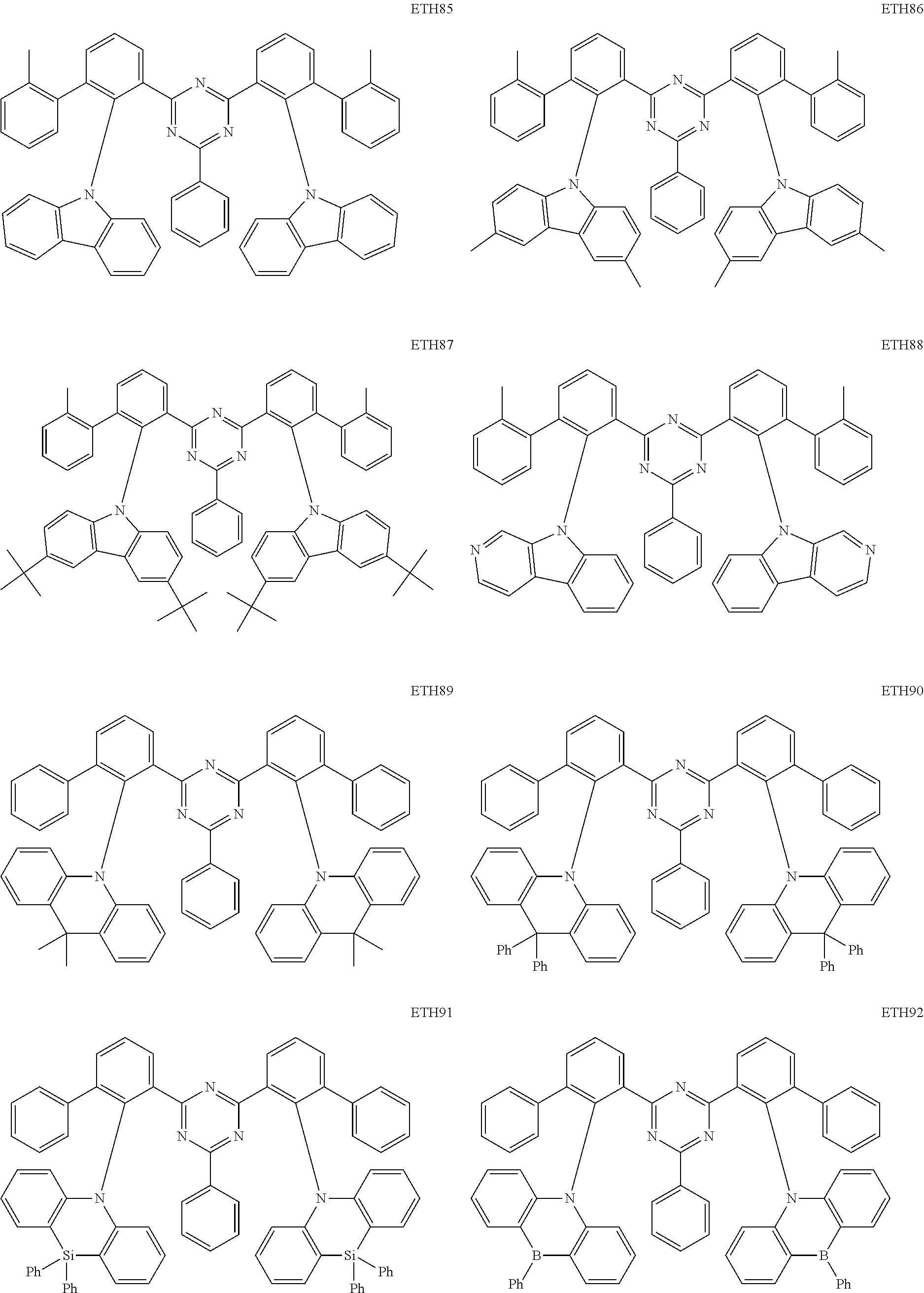

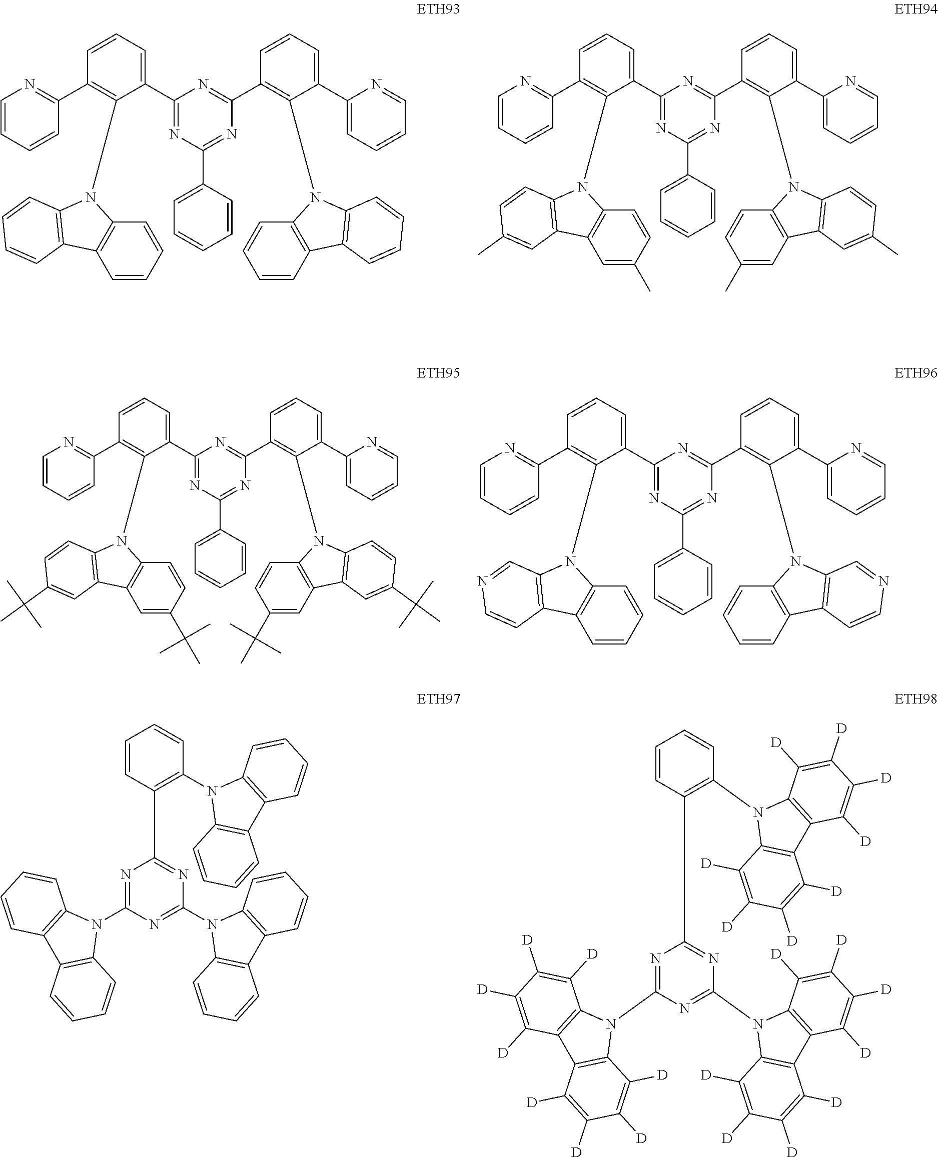

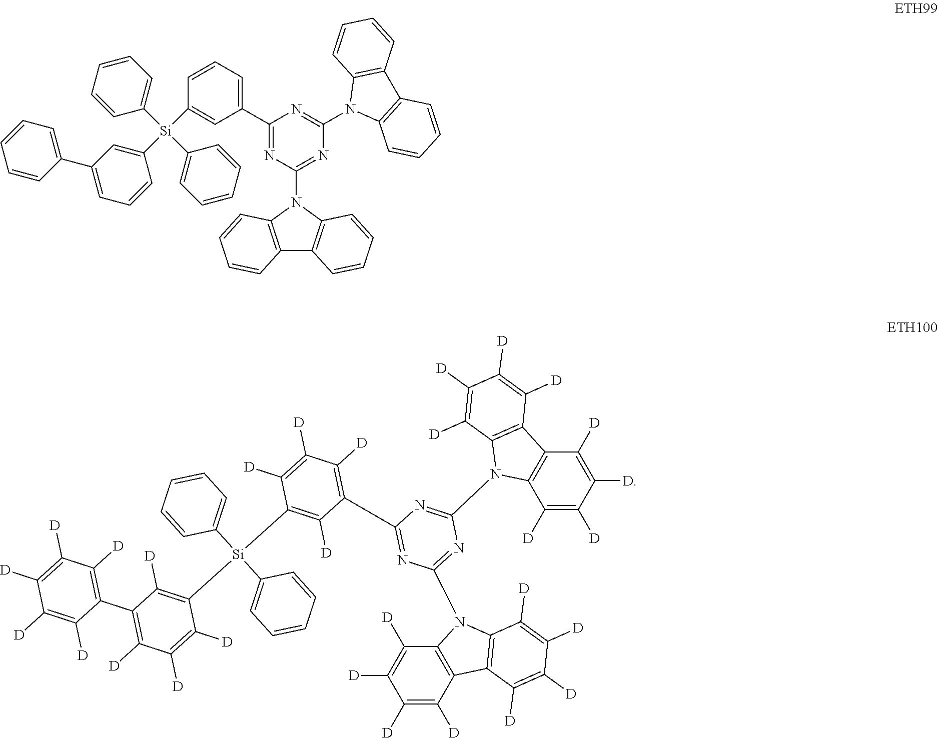

In one or more embodiments, the third compound may be at least one of Compounds HTH1 to HTH46:

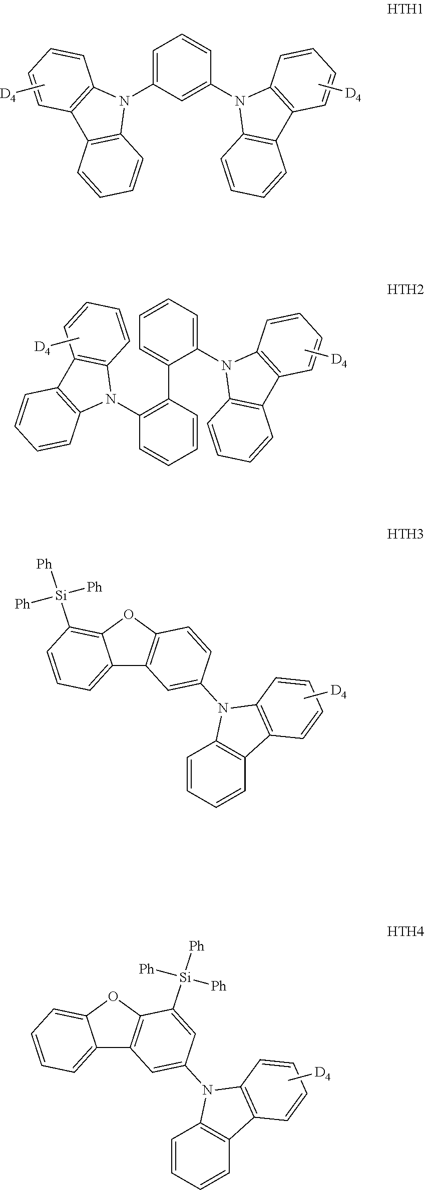

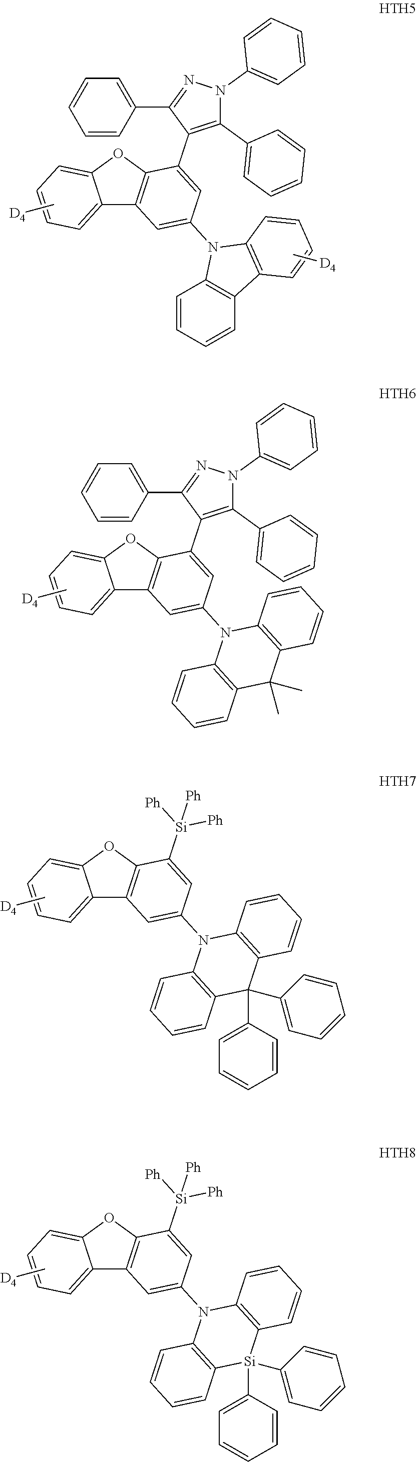

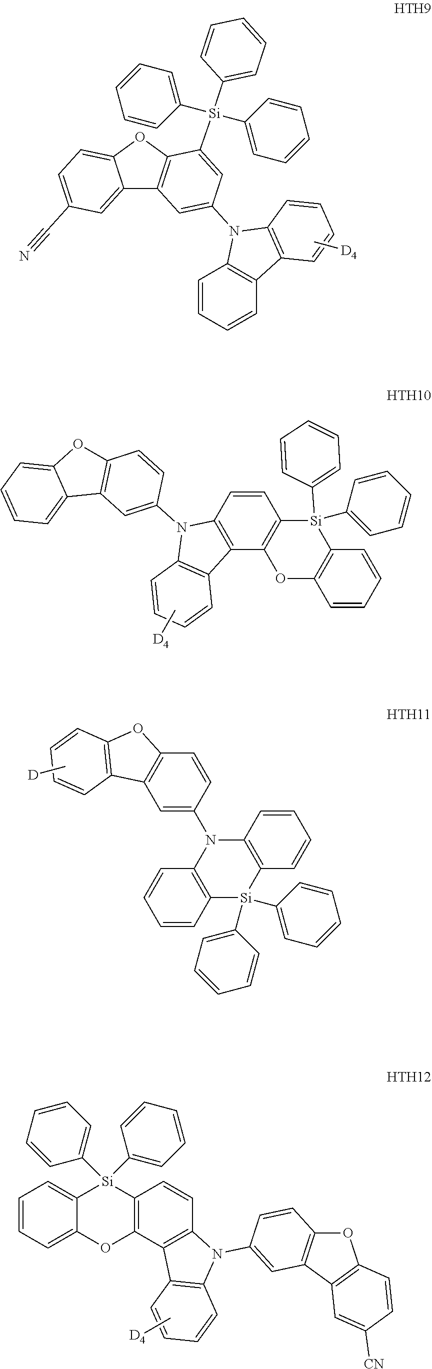

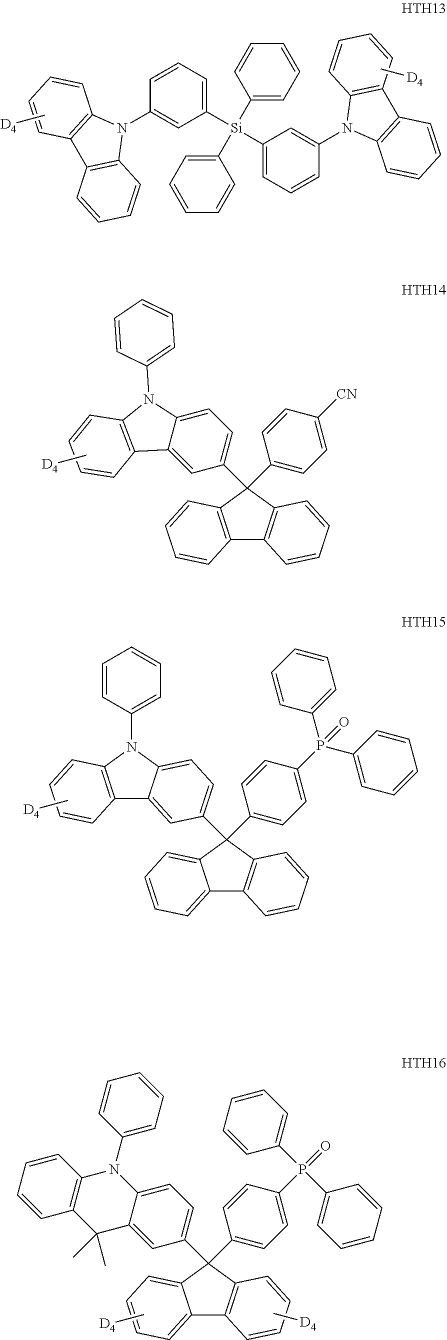

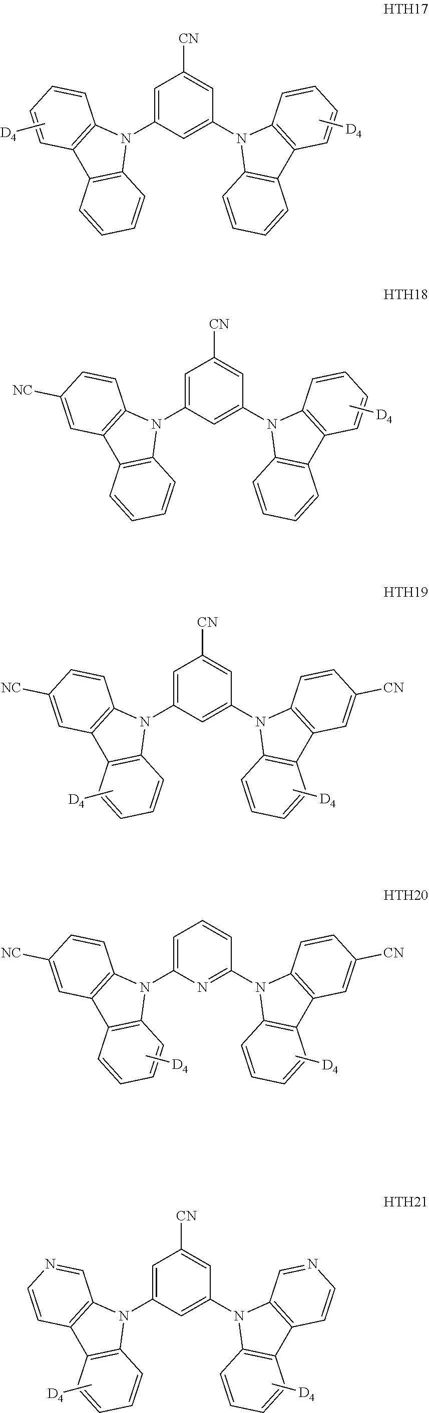

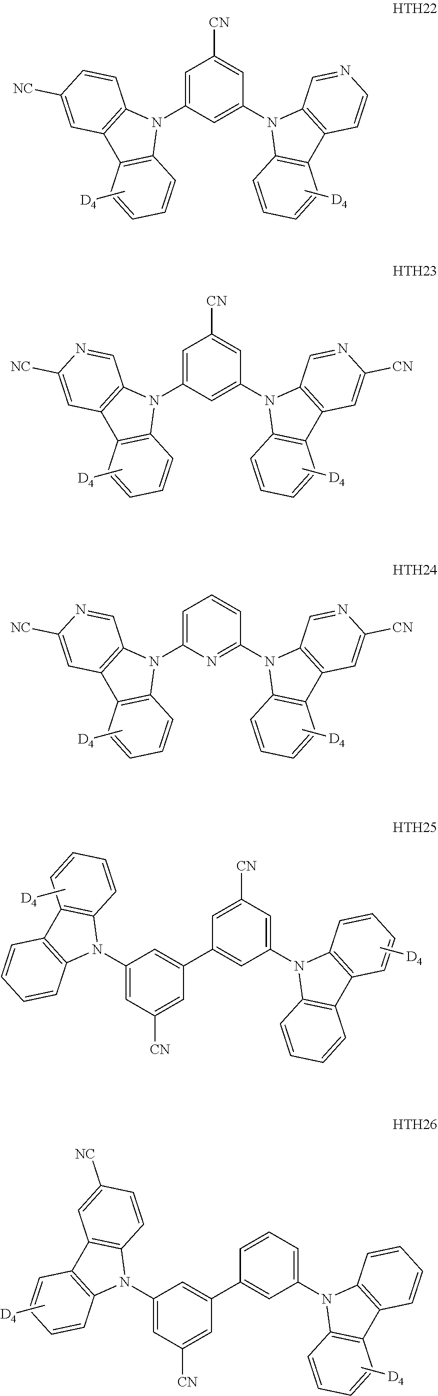

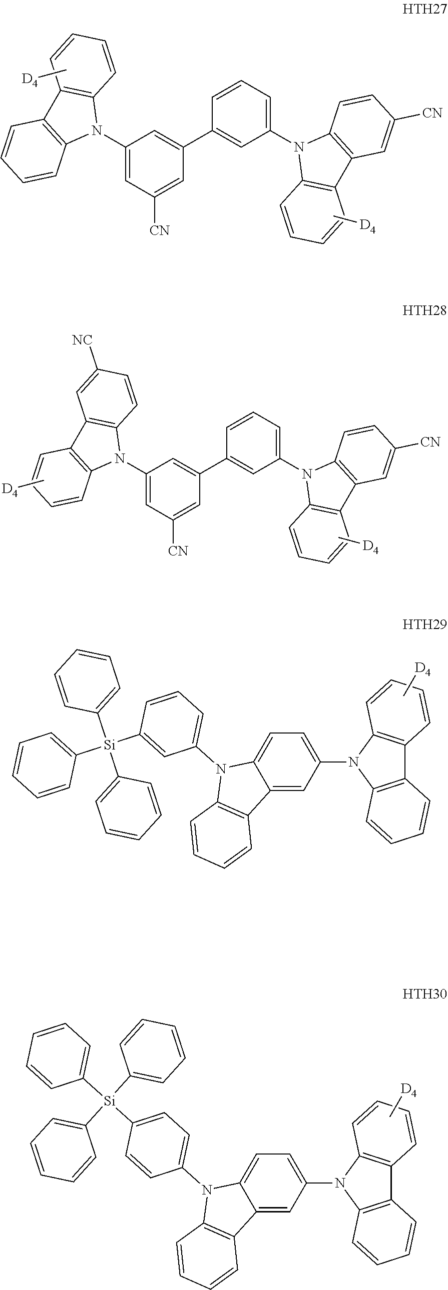

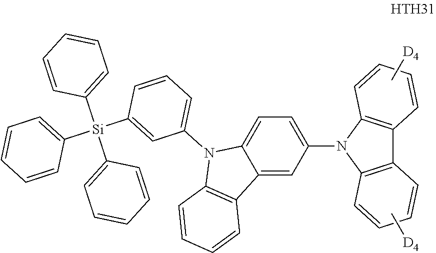

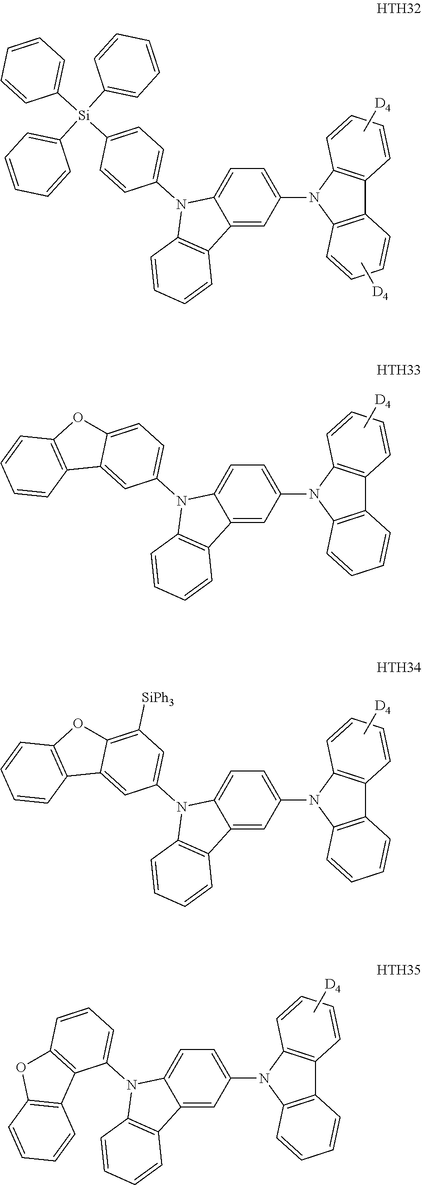

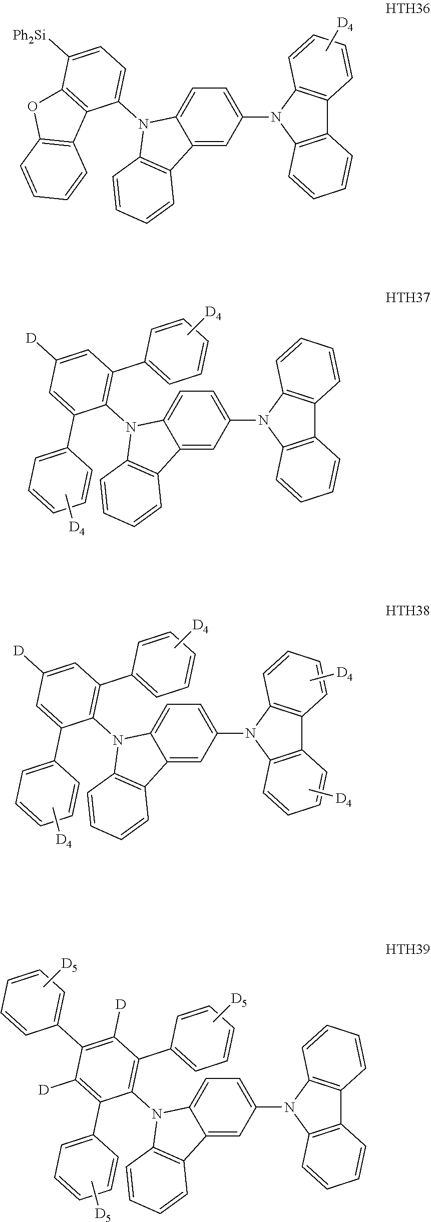

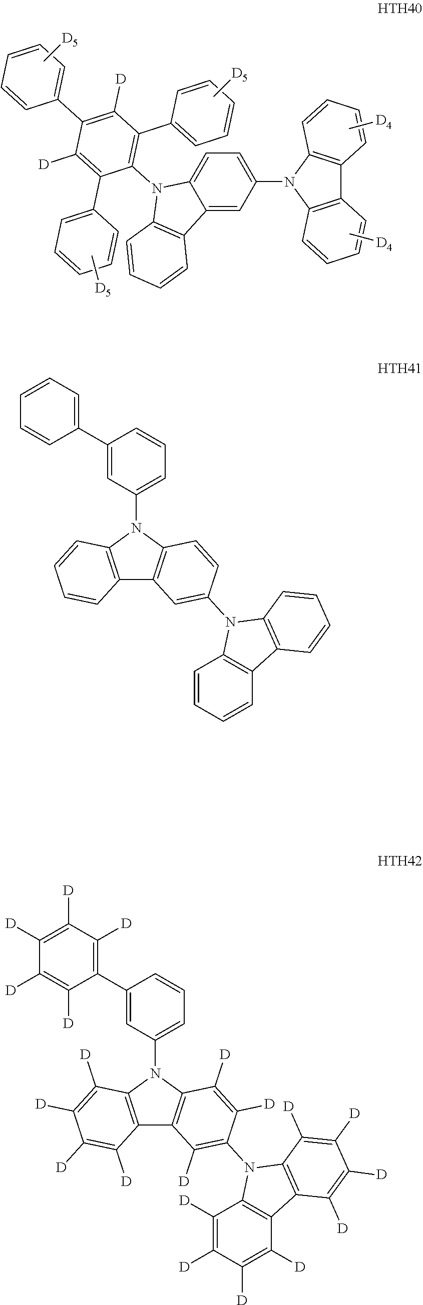

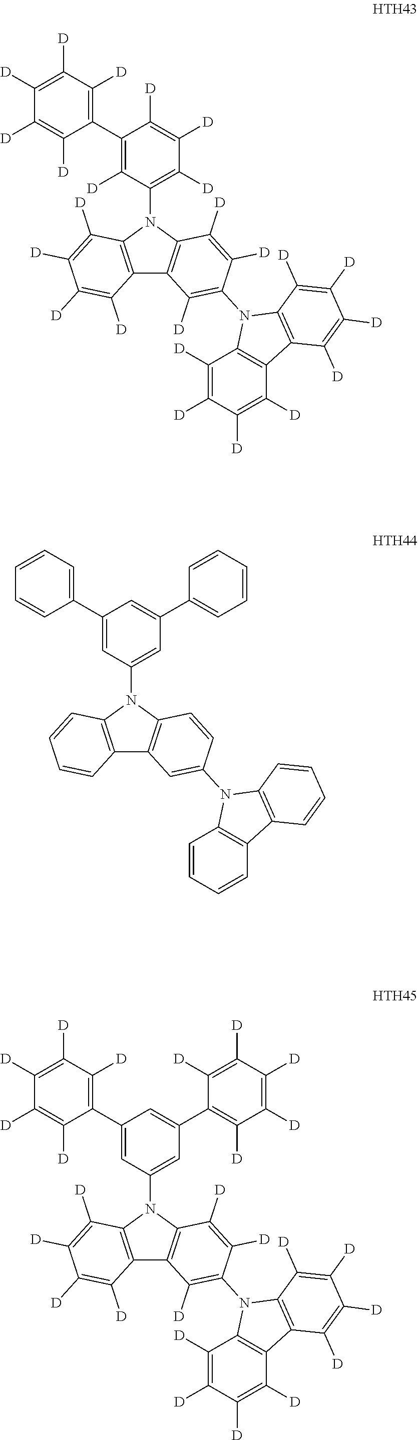 [SMILES: [2H]c1c([2H])c([2H])c(-c2c([2H])c([2H])c([2H])c(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2[2H])c([2H])c1[2H] ; c1ccc(-c2cc(-c3ccccc3)cc(-n3c4ccccc4c4cc(-n5c6ccccc6c6ccccc65)ccc43)c2)cc1 ; [2H]c1c([2H])c([2H])c(-c2cc(-c3c([2H])c([2H])c([2H])c([2H])c3[2H])cc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)c([2H])c1[2H]]

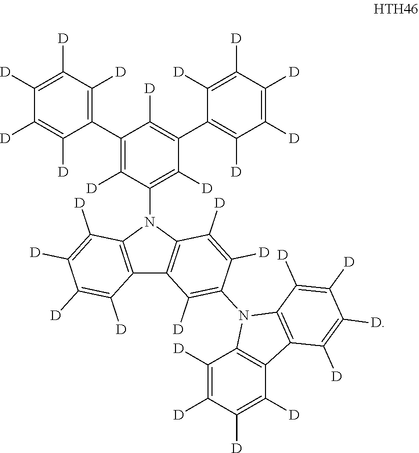

In one or more embodiments, the fourth compound may be at least one of Compounds DFD1 to DFD29 and DFD051:

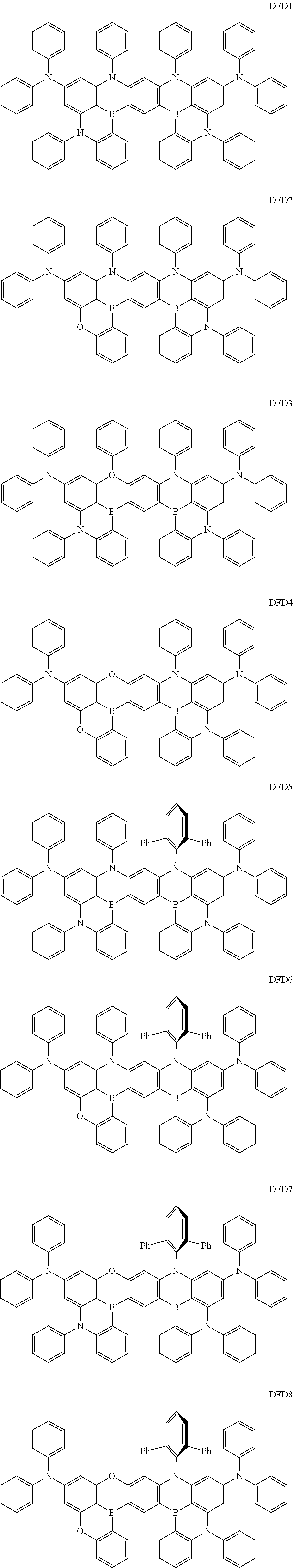

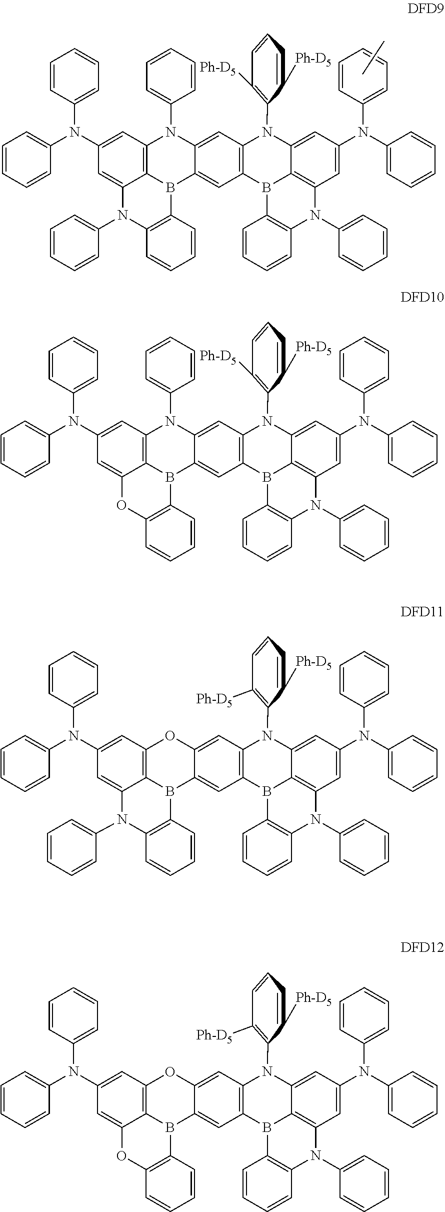

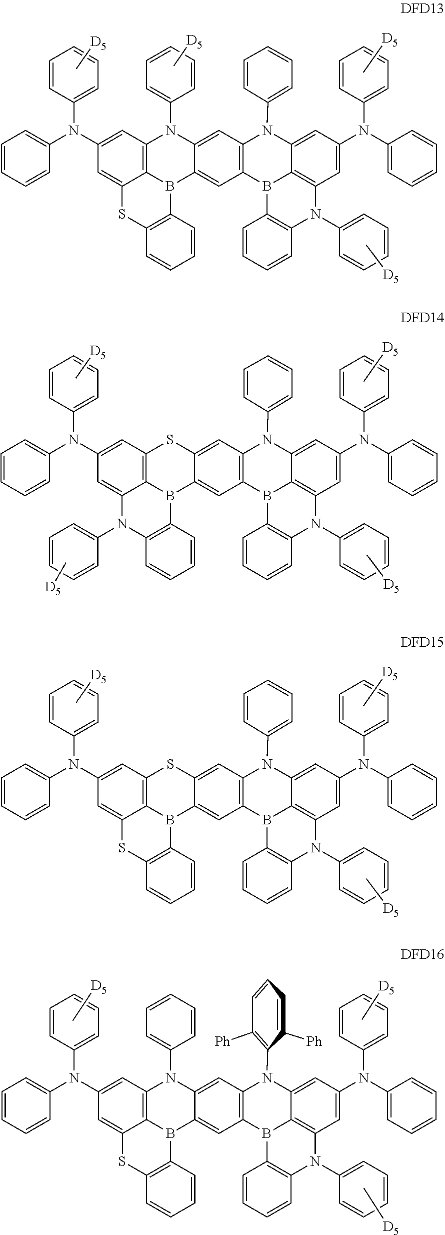

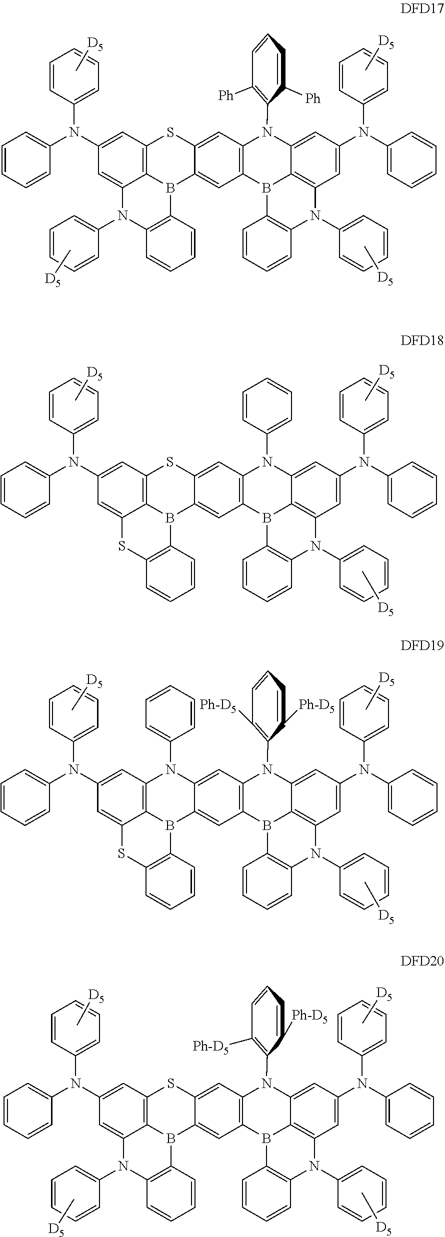

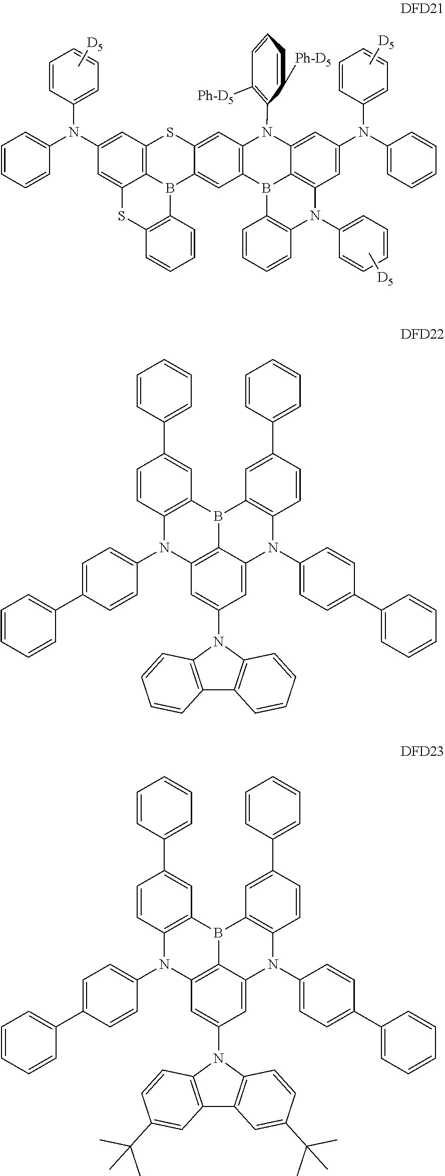

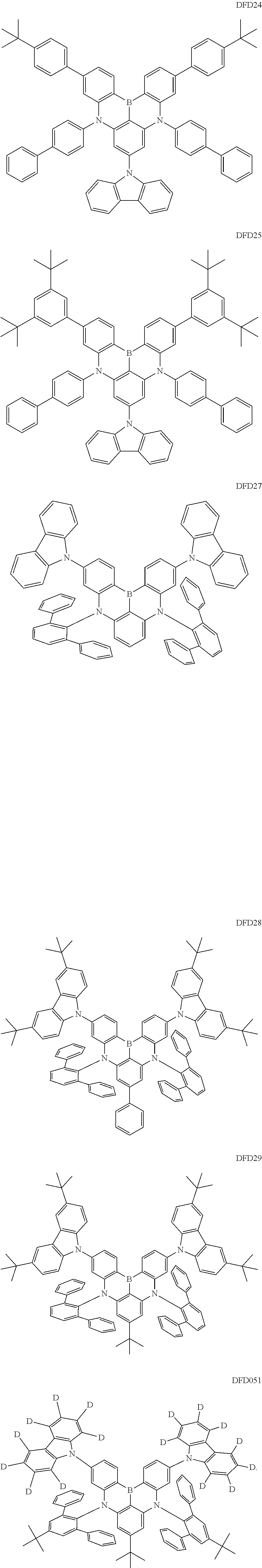

In the preceding compounds described herein, Ph represents a phenyl group, D₅ represents substitution with five deuteriums, and D₄ represents substitution with four deuteriums. For example, a group represented by

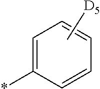

may be identical to a group represented by

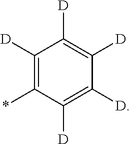

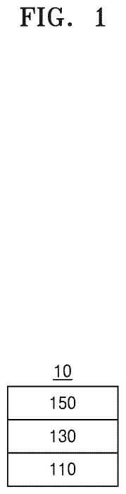

### Description of FIG. 1

FIG. 1 is a schematic cross-sectional view of a light-emitting device 10 according to one or more embodiments. The light-emitting device 10 includes a first electrode 110, an interlayer 130, and a second electrode 150.

Hereinafter, a structure of the light-emitting device 10 according to one or more embodiments and a method of manufacturing the light-emitting device 10 will be described with reference to FIG. 1.

### First Electrode 110

In FIG. 1, a substrate may be additionally arranged under the first electrode 110 or on the second electrode 150. As the substrate, a glass substrate or a plastic substrate may be utilized. In one or more embodiments, the substrate may be a flexible substrate and may include plastics with excellent or suitable heat resistance and durability, such as polyimide, polyethylene terephthalate (PET), polycarbonate, polyethylene napthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure including (e.g., consisting of) a single layer or a multilayer structure including a plurality of layers. In one or more embodiments, the first electrode 110 may have a three-layer structure of ITO/Ag/ITO.

### Interlayer 130

The interlayer 130 may be arranged on the first electrode 110. The interlayer 130 may include the emission layer.

The interlayer 130 may further include a hole transport region arranged between the first electrode 110 and the emission layer, and an electron transport region arranged between the emission layer and the second electrode 150.

The interlayer 130 may further include, in addition to one or more suitable organic materials, a metal-containing compound such as an organometallic compound, an inorganic material such as quantum dots, and/or the like.

In one or more embodiments, the interlayer 130 may include i) two or more emitting units sequentially stacked between the first electrode 110 and the second electrode 150, and ii) a charge generation layer located between two neighboring emitting units. When the interlayer 130 includes emitting units and a charge generation layer as described herein, the light-emitting device 10 may be a tandem light-emitting device.

### Hole Transport Region in Interlayer 130

The hole transport region may have: i) a single-layer structure including (e.g., consisting of) a single layer including (e.g., consisting of) a single material, ii) a single-layer structure including (e.g., consisting of) a single layer including (e.g., consisting of) a plurality of materials that are different from each other, or iii) a multilayer structure including a plurality of layers including a plurality of materials that are different from each other.

The hole transport region may include a hole injection layer, a hole transport layer, an emission auxiliary layer, an electron blocking layer, or any combination thereof.

In one or more embodiments, the hole transport region may have a multilayer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure are stacked sequentially from the first electrode 110.

The hole transport region may include a compound represented by Formula 201, a compound represented by Formula 202, and/or any combination thereof:

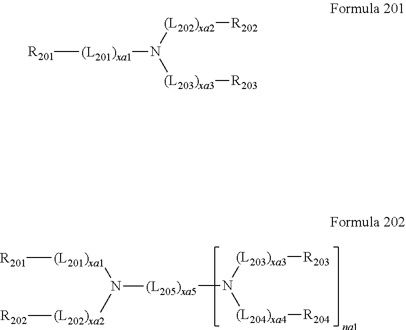

wherein, in Formulae 201 and 202,
L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀₅ may be *—O—*′, *—S—*′, *—N(Q₂₀₁)-*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R₂₀₁ and R₂₀₂ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group (e.g., a carbazole group and/or the like) unsubstituted or substituted with at least one R₁₀ₐ (e.g., see Compound HT16),
R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group that is unsubstituted or substituted with at least one R₁₀ₐ, and
na1 may be an integer from 1 to 4.

In one or more embodiments, each of Formulae 201 and 202 may include at least one of groups represented by Formulae CY201 to CY217:

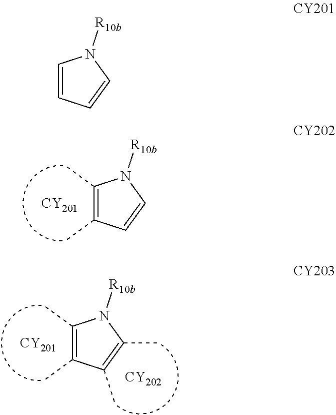

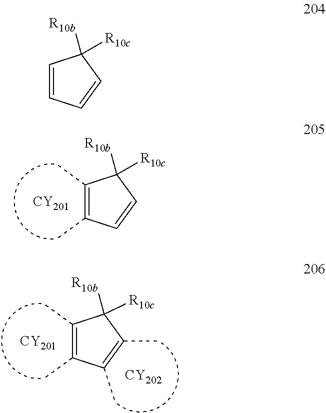

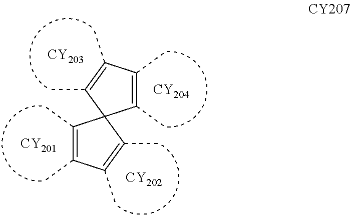

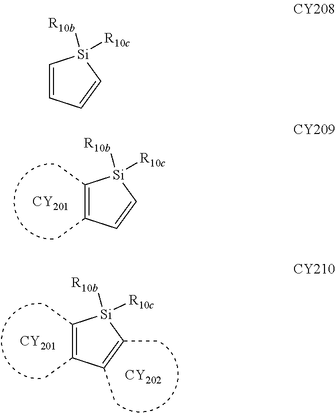

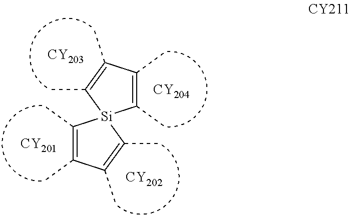

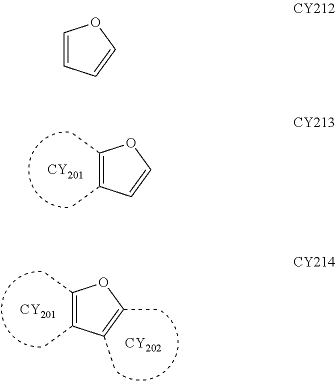

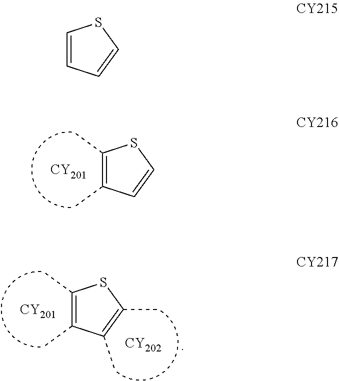

In Formulae CY201 to CY217, R_{10b}, and R_{10c} are each as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, ring CY₂₀₁ to ring CY₂₀₄ in Formulae CY201 to CY217 may each independently be a benzene group, a naphthalene group, a phenanthrene group, or an anthracene group.

In one or more embodiments, each of Formulae 201 and 202 may include at least one of groups represented by Formulae CY201 to CY203.

In one or more embodiments, Formula 201 may include at least one of groups represented by Formulae CY201 to CY203 and at least one of groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include (e.g., may exclude) groups represented by Formulae CY201 to CY203.

In one or more embodiments, each of Formulae 201 and 202 may not include (e.g., may exclude) groups represented by Formulae CY201 to CY203 and may include at least one of groups represented by Formulae CY₂₀₄ to CY₂₁₇.

In one or more embodiments, each of Formulae 201 and 202 may not include (e.g., may exclude) groups represented by Formulae CY201 to CY217.

In one or more embodiments, the hole transport region may include at least one selected from among Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), and/or any combination thereof:

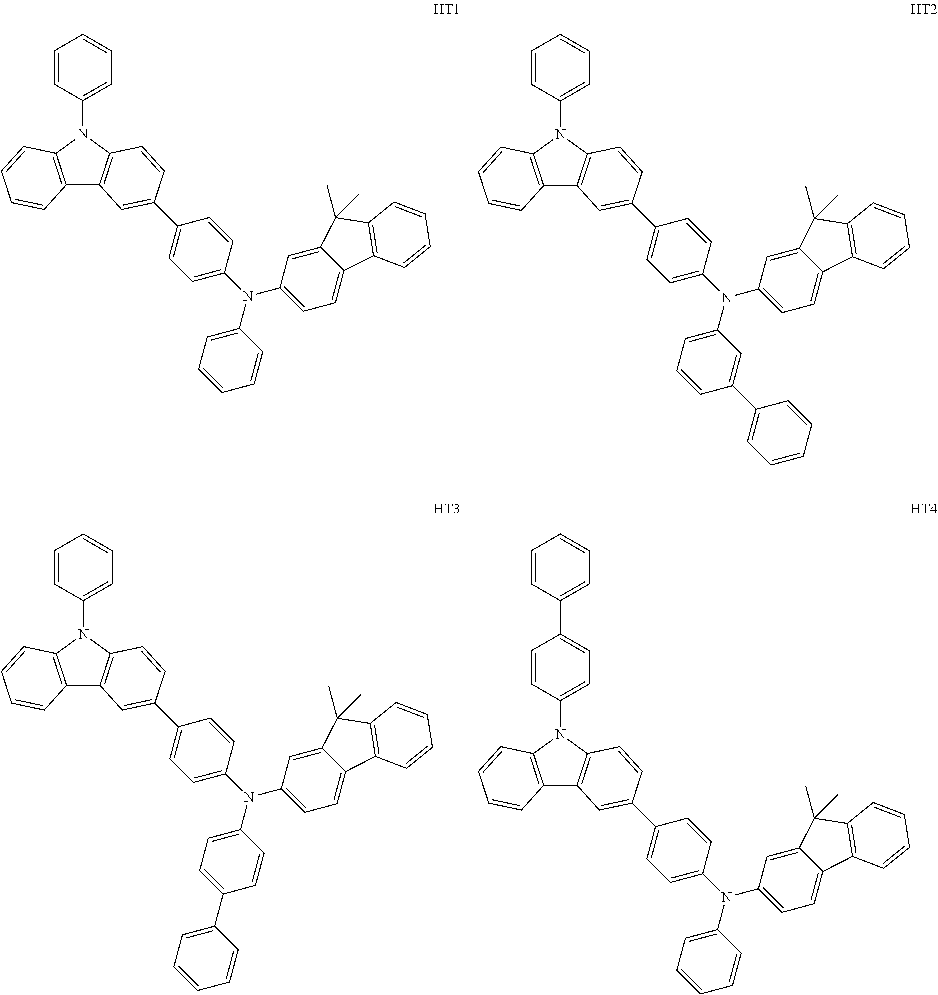 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

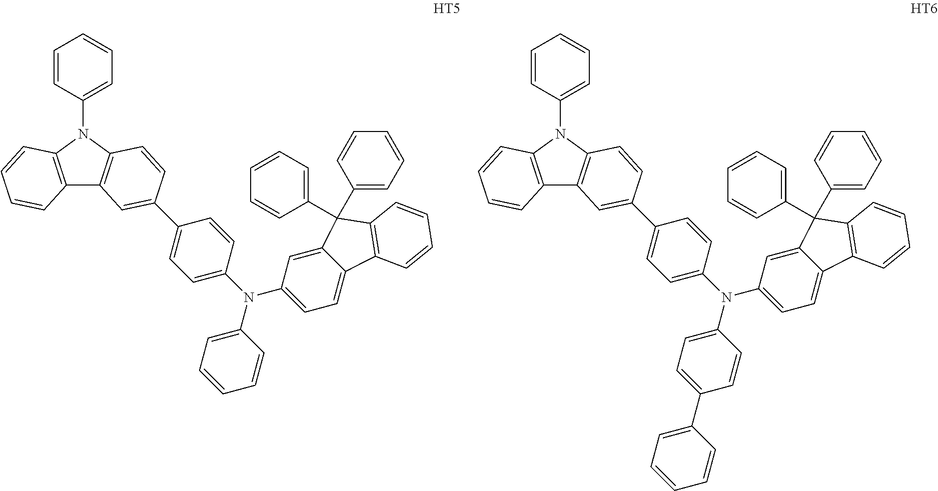 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

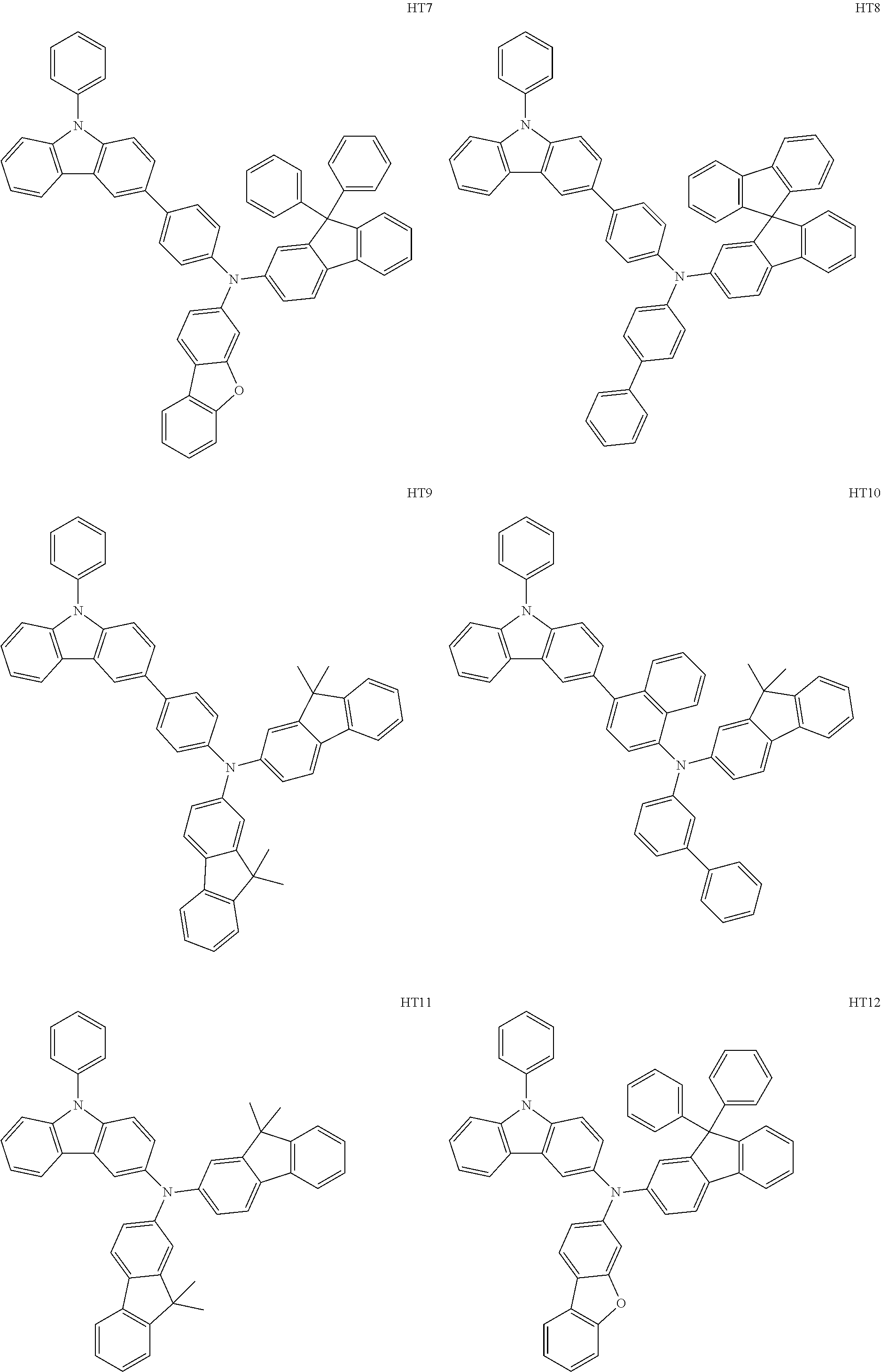

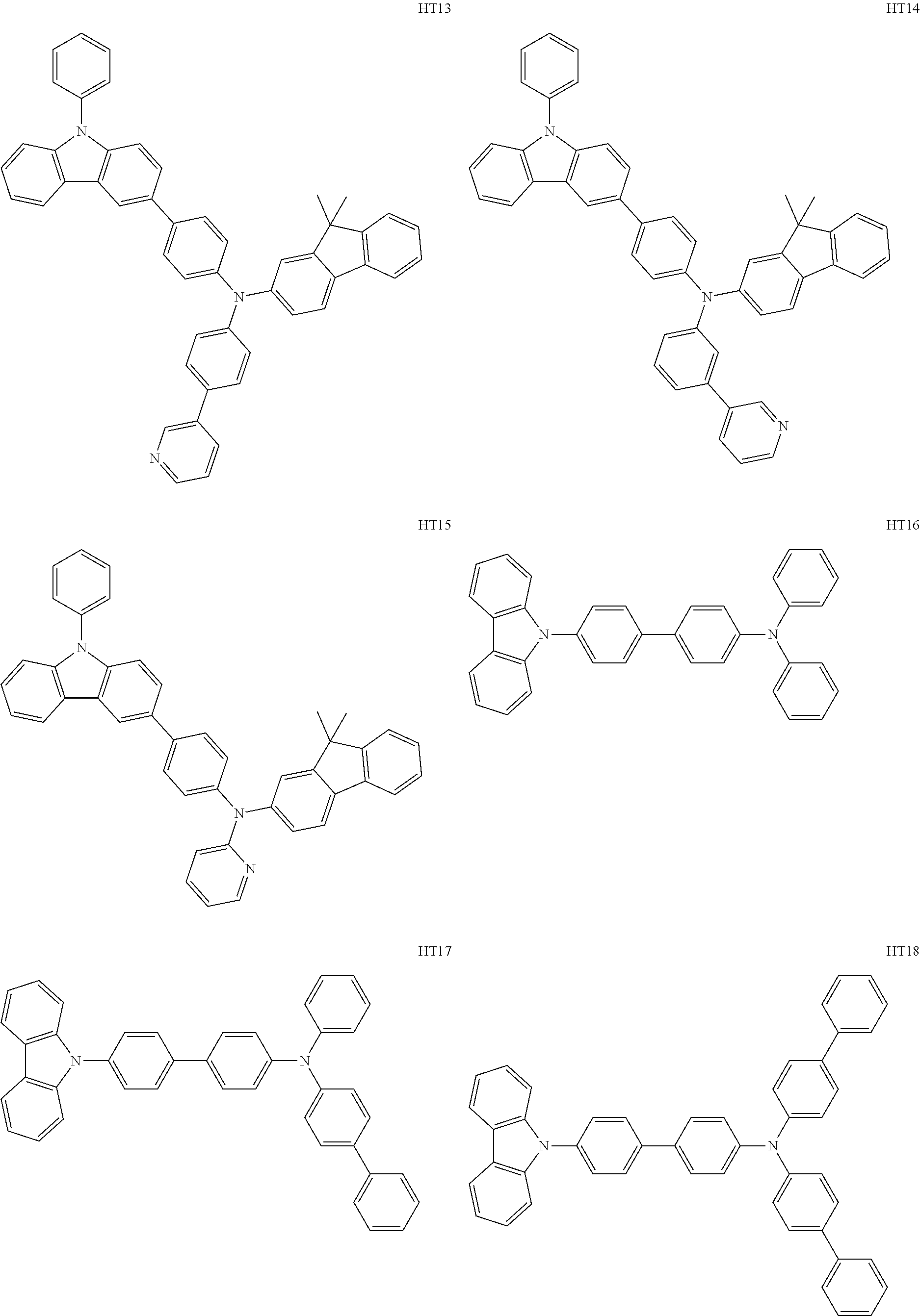 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

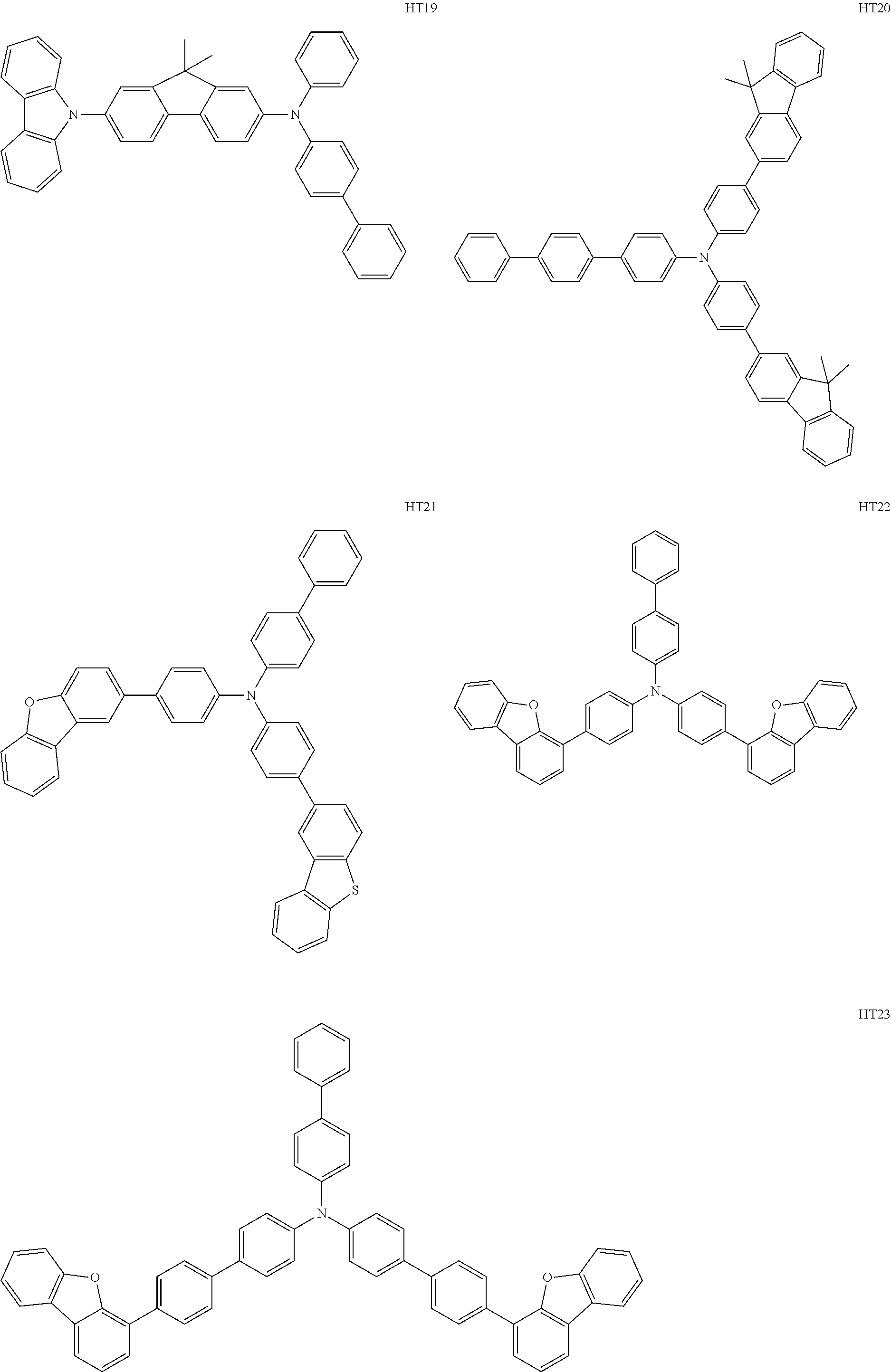 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

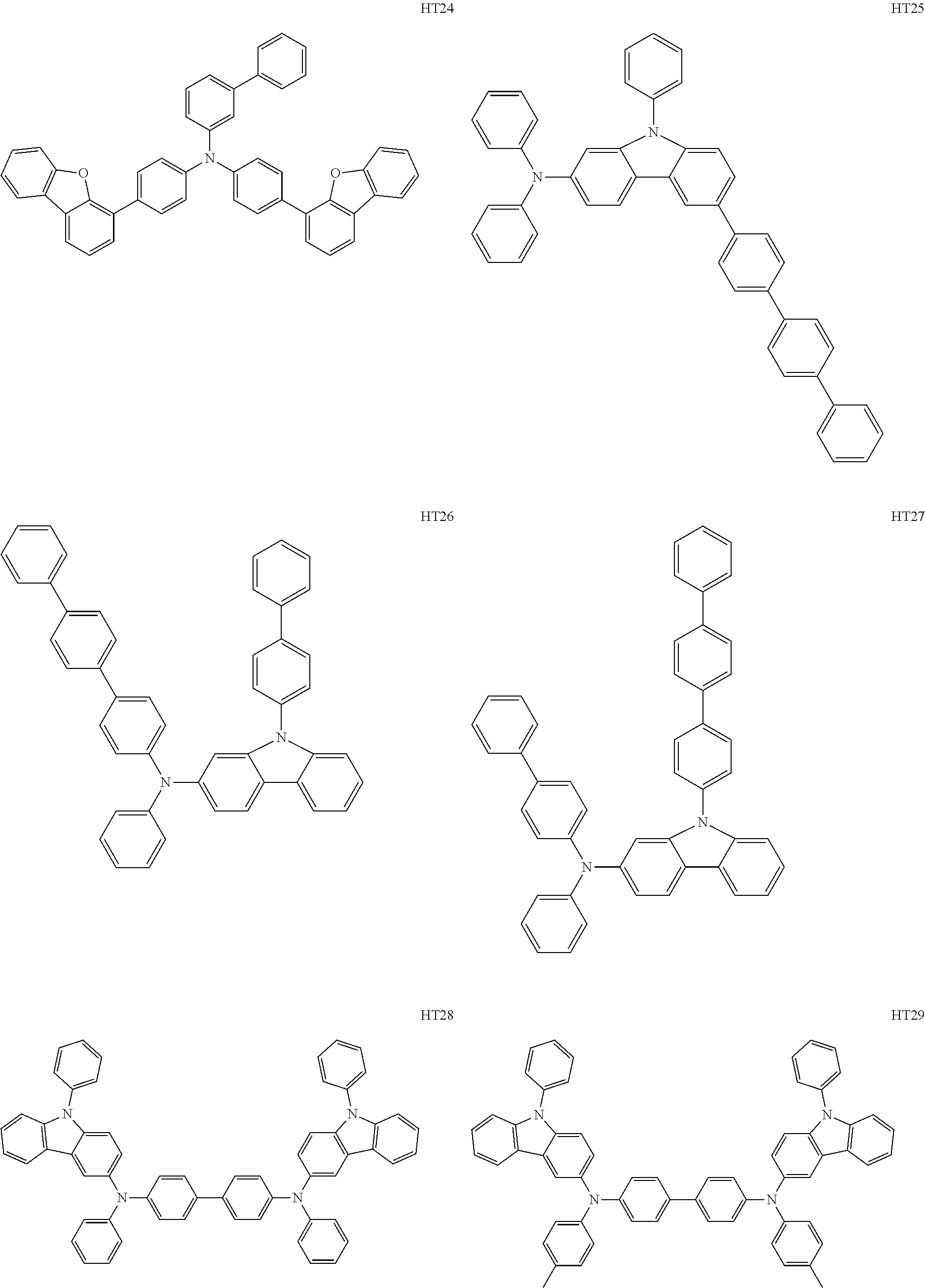

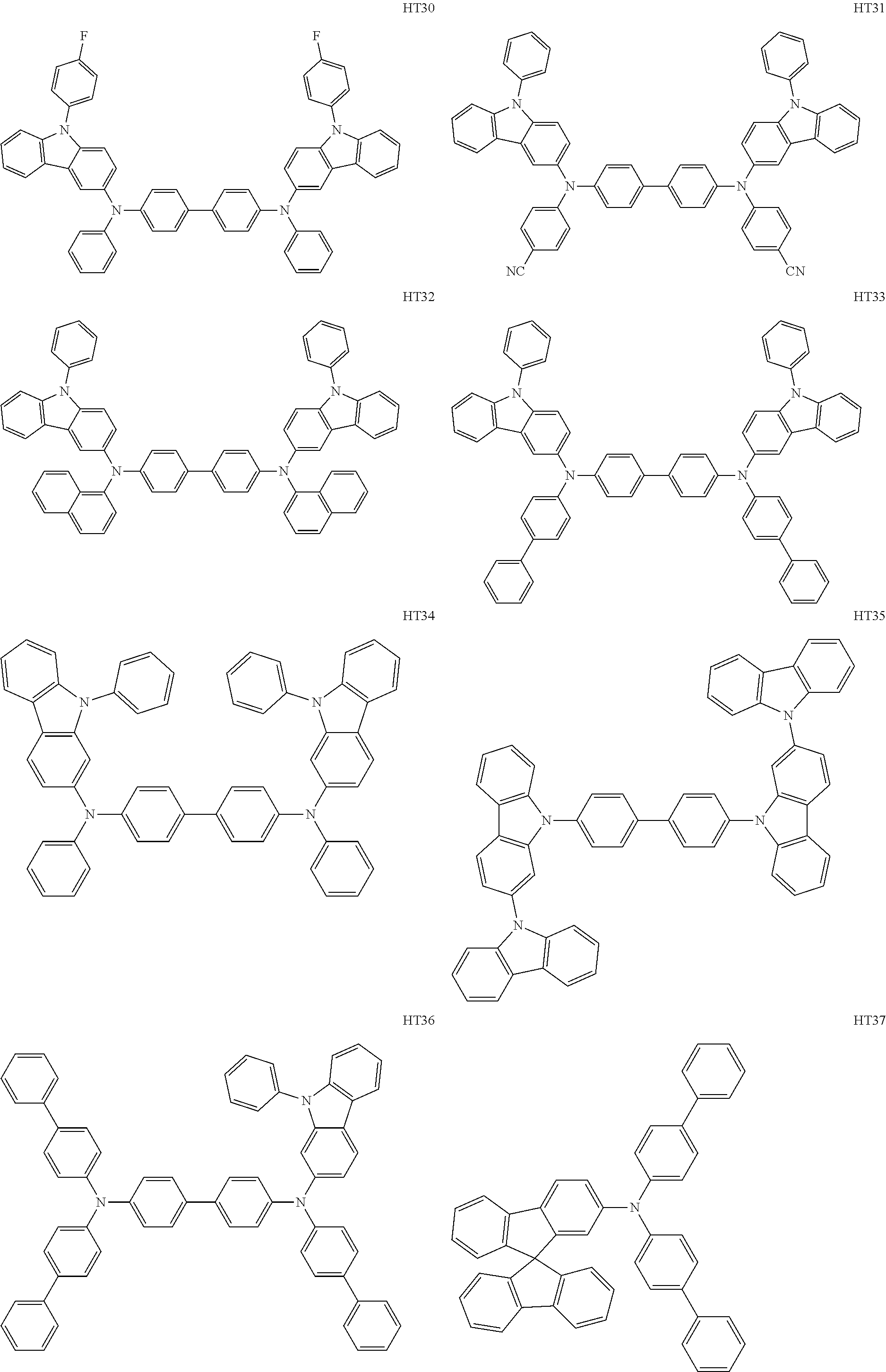

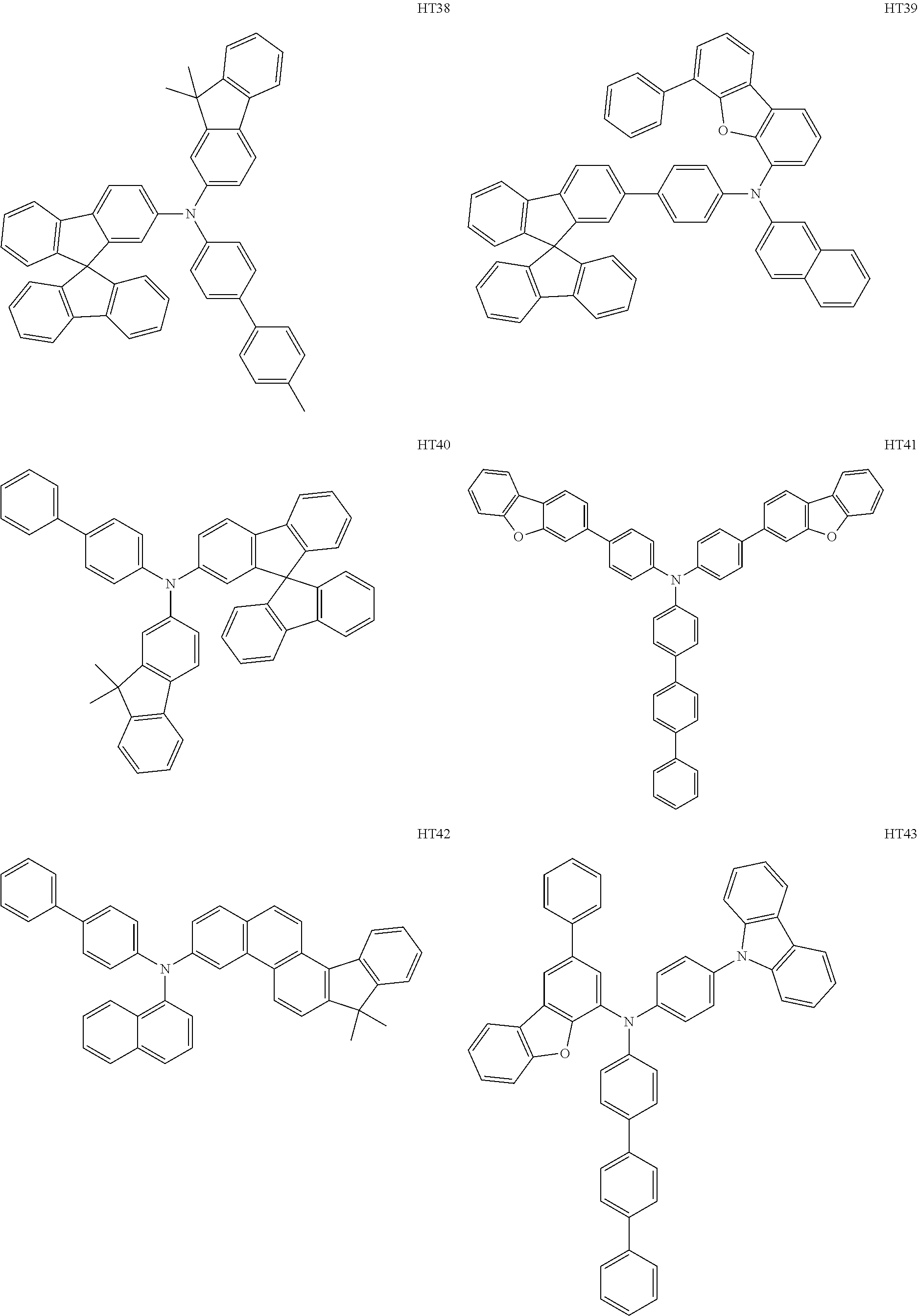

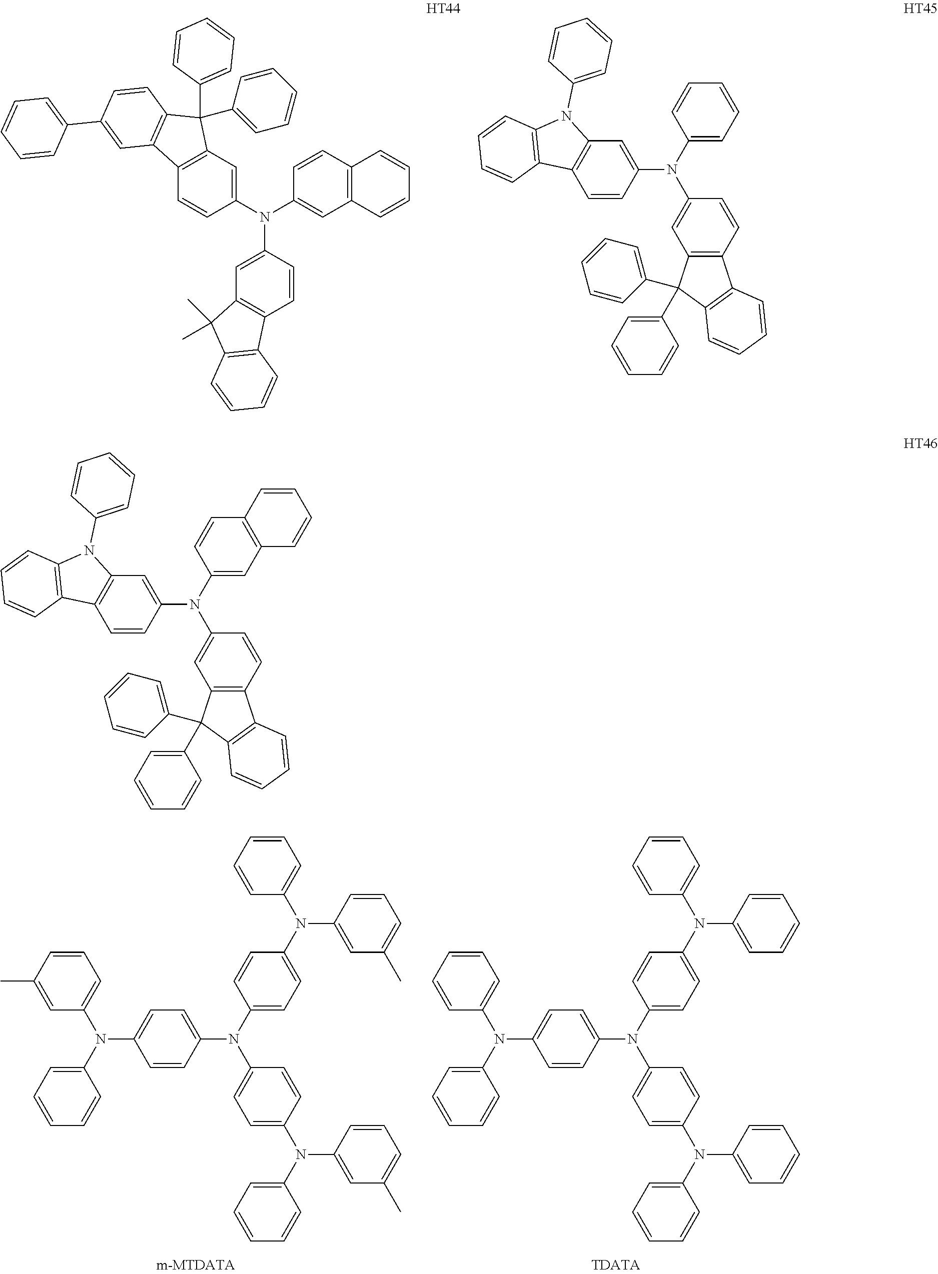

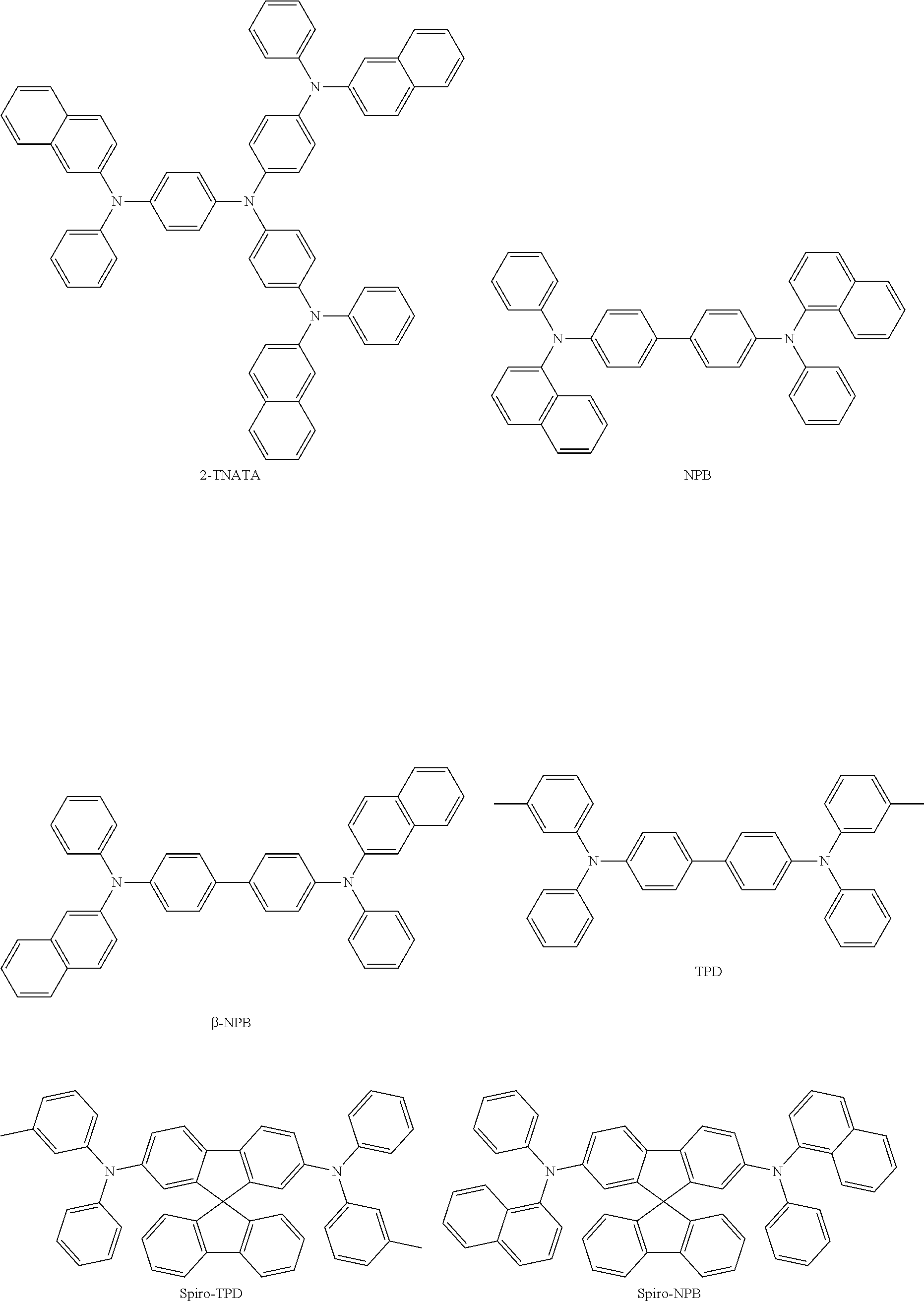

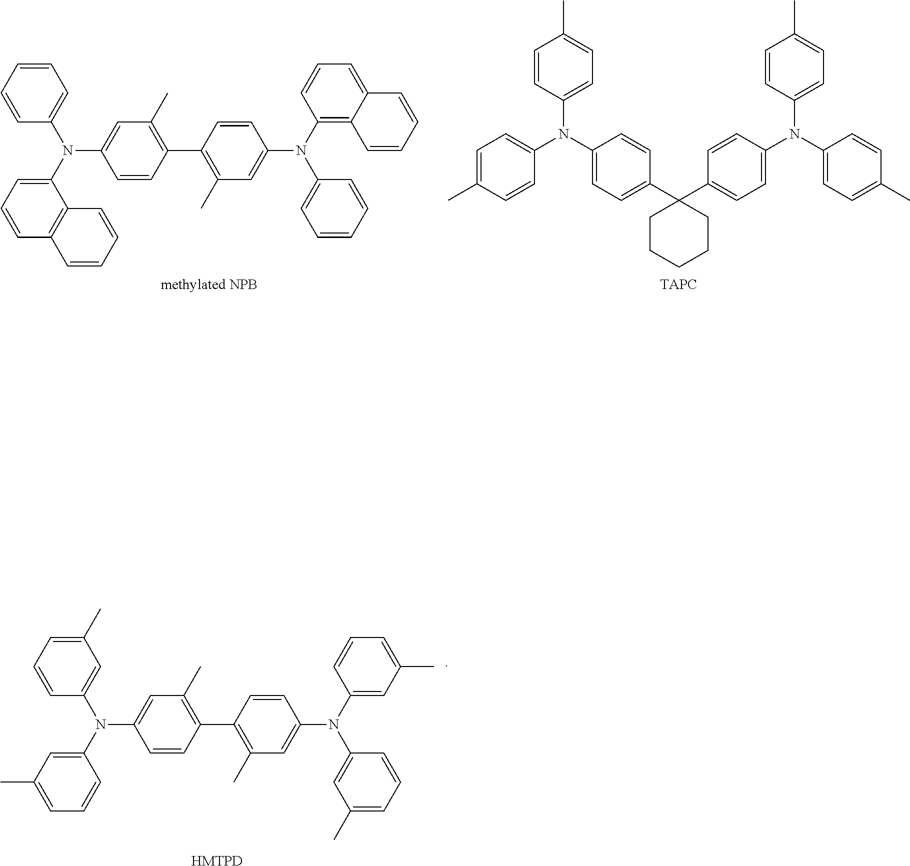

The thickness of the hole transport region may be about 50 Å to about 10,000 Å, for example, about 100 Å to about 4,000 Å. When the hole transport region includes a hole injection layer, a hole transport layer, or any combination thereof, a thickness of the hole injection layer may be about 100 Å to about 9,000 Å, for example, about 100 Å to about 1,000 Å, and a thickness of the hole transport layer may be about 50 Å to about 2,000 Å, for example, about 100 Å to about 1,500 Å. When the thicknesses of the hole transport region, the hole injection layer, and the hole transport layer are within the ranges described herein, satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block or reduce the leakage of electrons from the emission layer to the hole transport region. Materials that may be included in the hole transport region may be included in the emission auxiliary layer and the electron blocking layer.

p-Dopant

The hole transport region may further include, in addition to these materials, a charge-generation material for the improvement of conductive properties. The charge-generation material may be uniformly or non-uniformly dispersed in the hole transport region (for example, in the form of a single layer including (e.g., consisting of) a charge-generation material).

The charge-generation material may be, for example, a p-dopant.

For example, the LUMO energy level of the p-dopant may be less than or equal to −3.5 eV.

In one or more embodiments, the p-dopant may include a quinone derivative, a cyano group-containing compound, a compound including an element EL1 and an element EL2, or any combination thereof.

Examples of the quinone derivative may include TCNQ and/or F4-TCNQ.

Examples of the cyano group-containing compound may include HAT-CN and/or a compound represented by Formula 221.

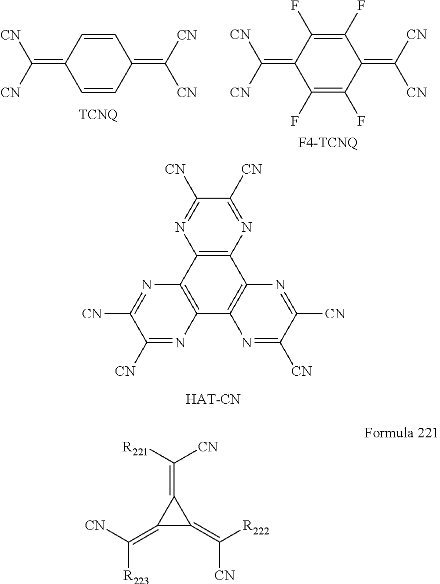

In Formula 221,
R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —C₁; —Br; —I; a C₁-C₂₀ alkyl group that is substituted with a cyano group, —F, —Cl, —Br, —I, or any combination thereof; or any combination thereof.

In the compound containing the element EL1 and the element EL2, the element EL1 may be metal, metalloid, or a combination thereof, and the element EL2 may be non-metal, metalloid, or a combination thereof.

Examples of the metal may include an alkali metal (for example, lithium (Li), sodium (Na), potassium (K), rubidium (Rb), cesium (Cs), and/or the like); an alkaline earth metal (for example, beryllium (Be), magnesium (Mg), calcium (Ca), strontium (Sr), barium (Ba), and/or the like); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (for example, zinc (Zn), indium (In), tin (Sn), and/or the like); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Examples of the metalloid may include silicon (Si), antimony (Sb), and/or tellurium (Te).

Examples of the non-metal may include oxygen (O) and/or halogen (for example, F, Cl, Br, I, and/or the like).

Examples of the compound including the element EL1 and the element EL2 may include a metal oxide, a metal halide (for example, a metal fluoride, a metal chloride, a metal bromide, a metal iodide, and/or the like), a metalloid halide (for example, a metalloid fluoride, a metalloid chloride, a metalloid bromide, a metalloid iodide, and/or the like), and a metal telluride, or one or more combinations thereof.

Examples of the metal oxide may include a tungsten oxide (for example, WO, W₂O₃, WO₂, WO₃, W₂O₅, and/or the like), a vanadium oxide (for example, VO, V₂O₃, VO₂, V₂O₅, and/or the like), a molybdenum oxide (MoO, Mo₂O₃, MoO₂, MoO₃, Mo₂O₅, and/or the like), and/or a rhenium oxide (for example, ReO₃, and/or the like).

Examples of the metal halide may include an alkali metal halide, an alkaline earth metal halide, a transition metal halide, a post-transition metal halide, and/or a lanthanide metal halide.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, Bel₂, Mg₁₂, CaI₂, SrI₂, and/or BaI₂.

Examples of the transition metal halide may include a titanium halide (for example, TiF₄, TiCl₄, TiBr₄, TiI₄, and/or the like), a zirconium halide (for example, ZrF₄, ZrCl₄, ZrBr₄, Zrl₄, and/or the like), a hafnium halide (for example, HfF₄, HfCl₄, HfBr₄, Hfl₄, and/or the like), a vanadium halide (for example, VF₃, VCl₃, VBr₃, VI₃, and/or the like), a niobium halide (for example, NbF₃, NbCl₃, NbBr₃, NbI₃, and/or the like), a tantalum halide (for example, TaF₃, TaCl₃, TaBr₃, TaI₃, and/or the like), a chromium halide (for example, CrF₃, CrCl₃, CrBr₃, CrI₃, and/or the like), a molybdenum halide (for example, MoF₃, MoCl₃, MoBr₃, MoI₃, and/or the like), a tungsten halide (for example, WF₃, WCl₃, WBr₃, WI₃, and/or the like), a manganese halide (for example, MnF₂, MnCl₂, MnBr₂, MnI₂, and/or the like), a technetium halide (for example, TcF₂, TcCl₂, TcBr₂, TcI₂, and/or the like), a rhenium halide (for example, ReF₂, ReCl₂, ReBr₂, ReI₂, and/or the like), an iron halide (for example, FeF₂, FeCl₂, FeBr₂, FeI₂, and/or the like), a ruthenium halide (for example, RuF₂, RuCl₂, RuBr₂, RuI₂, and/or the like), an osmium halide (for example, OsF₂, OsCl₂, OsBr₂, OsI₂, and/or the like), a cobalt halide (for example, CoF₂, CoCl₂, CoBr₂, CoI₂, and/or the like), a rhodium halide (for example, RhF₂, RhCl₂, RhBr₂, RhI₂, and/or the like), an iridium halide (for example, IrF₂, IrCl₂, IrBr₂, IrI₂, and/or the like), a nickel halide (for example, NiF₂, NiCl₂, NiBr₂, NiI₂, and/or the like), a palladium halide (for example, PdF₂, PdCl₂, PdBr₂, PdI₂, and/or the like), a platinum halide (for example, PtF₂, PtCl₂, PtBr₂, PtI₂, and/or the like), a copper halide (for example, CuF, CuCl, CuBr, CuI, and/or the like), a silver halide (for example, AgF, AgCl, AgBr, AgI, and/or the like), and/or a gold halide (for example, AuF, AuCl, AuBr, AuI, and/or the like).

Examples of the post-transition metal halide may include a zinc halide (for example, ZnF₂, ZnCl₂, ZnBr₂, ZnI₂, and/or the like), an indium halide (for example, InI₃, and/or the like), and/or a tin halide (for example, SnI₂, and/or the like).

Examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Examples of the metalloid halide may include an antimony halide (for example, SbCl₅, and/or the like).

Examples of the metal telluride may include an alkali metal telluride (for example, Li₂Te, Na₂Te, K₂Te, Rb₂Te, Cs₂Te, and/or the like), an alkaline earth metal telluride (for example, BeTe, MgTe, CaTe, SrTe, BaTe, and/or the like), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), a post-transition metal telluride (for example, ZnTe, and/or the like), and/or a lanthanide metal telluride (for example, LaTe, CeTe, PrTe, NdTe, PmTe, EuTe, GdTe, TbTe, DyTe, HoTe, ErTe, TmTe, YbTe, LuTe, and/or the like).

### Emission Layer in Interlayer 130

When the light-emitting device 10 is a full-color light-emitting device, the emission layer may be patterned into a red emission layer, a green emission layer, and/or a blue emission layer, according to a sub-pixel. In one or more embodiments, the emission layer may have a stacked structure of two or more layers of a red emission layer, a green emission layer, and a blue emission layer, in which the two or more layers contact each other or are separated from each other, to emit white light. In one or more embodiments, the emission layer may include two or more materials of a red light-emitting material, a green light-emitting material, and a blue light-emitting material, in which the two or more materials are mixed with each other in a single layer, to emit white light.

In one or more embodiments, the emission layer may include a host and a dopant (or emitter). In one or more embodiments, the emission layer may further include an auxiliary dopant that promotes energy transfer to a dopant (or emitter), in addition to the host and the dopant (or emitter). When the emission layer includes the dopant (or emitter) and the auxiliary dopant, the dopant (or emitter) and the auxiliary dopant are different from each other.

The organometallic compound represented by Formula 1 may act as the dopant (or emitter), or may act as the auxiliary dopant.

The amount (weight) of the dopant (or emitter) in the emission layer may be about 0.01 parts by weight to about 15 parts by weight based on 100 parts by weight of the host.

The emission layer may include the organometallic compound represented by Formula 1. The amount (weight) of the organometallic compound in the emission layer may be about 0.01 parts by weight to about 30 parts by weight, about 0.1 parts by weight to about 20 parts by weight, or about 0.1 parts by weight to about 15 parts by weight, based on 100 parts by weight of the emission layer.

The thickness of the emission layer may be about 100 Å to about 1,000 Å, for example, about 200 Å to about 600 Å. When the thickness of the emission layer is within the range, excellent or suitable light-emission characteristics may be obtained without a substantial increase in driving voltage.

### Host

The host in the emission layer may include the second compound or the third compound described herein, or any combination thereof.

In one or more embodiments, the host may include a compound represented by Formula 301.

[Ar₃₀₁]_{xb11}-[(L₃₀₁)_{xb1}-R₃₀₁]_{xb21} Formula 301

In Formula 301,
Ar₃₀₁ and L₃₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ are each as described in connection with Q₁.

In one or more embodiments, when xb11 in Formula 301 is 2 or more, two or more of Ar₃₀₁ may be linked to each other via a single bond.

In one or more embodiments, the host may include at least one compound represented by Formula 301-1, at least one compound represented by Formula 301-2, or any combination thereof:

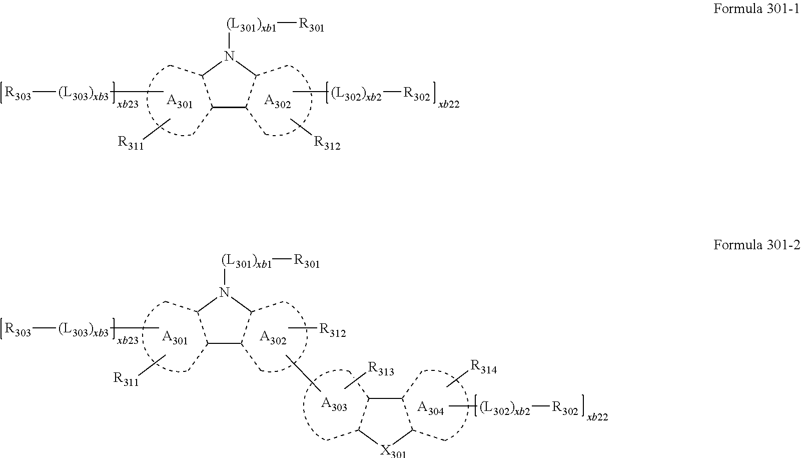

wherein, in Formulae 301-1 and 301-2,
ring A₃₀₁ to ring A₃₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ are each as described herein,
L₃₀₂ to L₃₀₄ may each independently be as described in connection with L₃₀₁, xb2 to xb4 may each independently be as described in connection with xb1, and

R₃₀₂ to R₃₀₅ and R₃₁₁ to R₃₁₄ are each as described in connection with R₃₀₁.

In one or more embodiments, the host may include an alkali earth metal complex, a post-transition metal complex, or any combination thereof. In one or more embodiments, the host may include a Be complex (for example, Compound H55), an Mg complex, a Zn complex, or any combination thereof.

In one or more embodiments, the host may include at least one selected from among Compounds H1 to H130, 9,10-di(2-naphthyl)anthracene (ADN), 2-methyl-9,10-bis(naphthalen-2-yl)anthracene (MADN), 9,10-di(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), and/or any combination thereof:

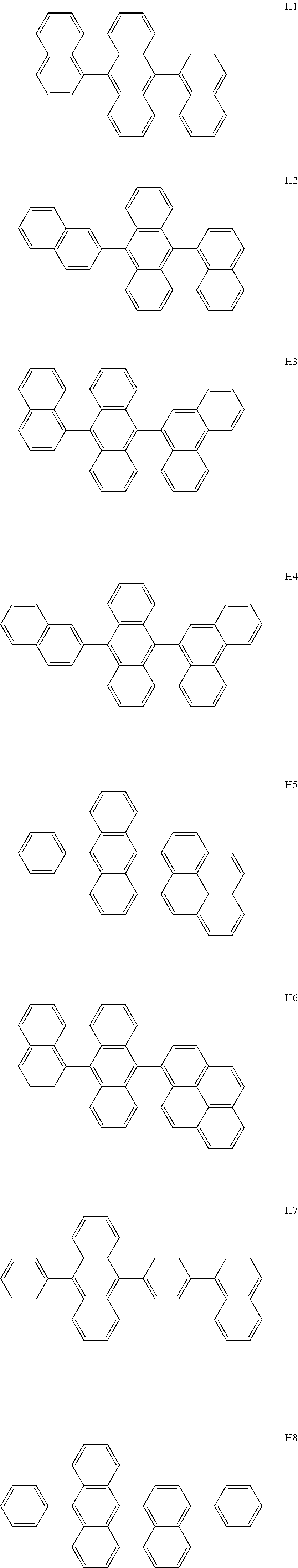

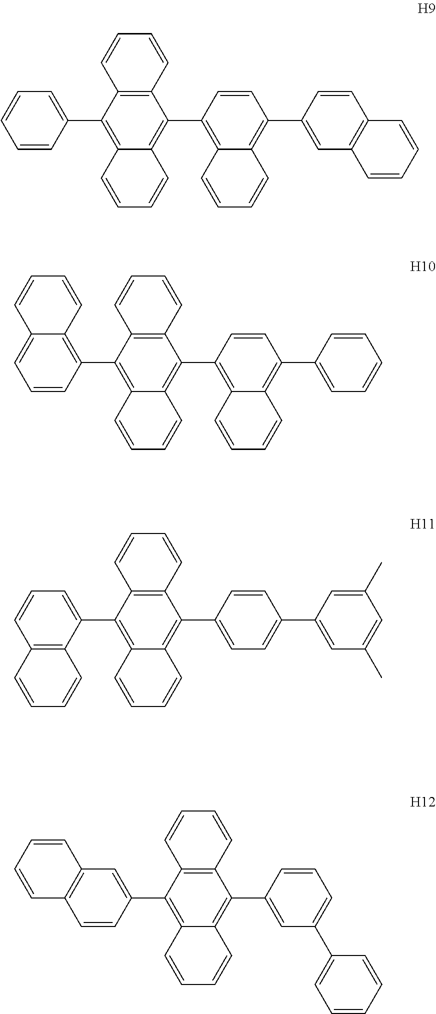

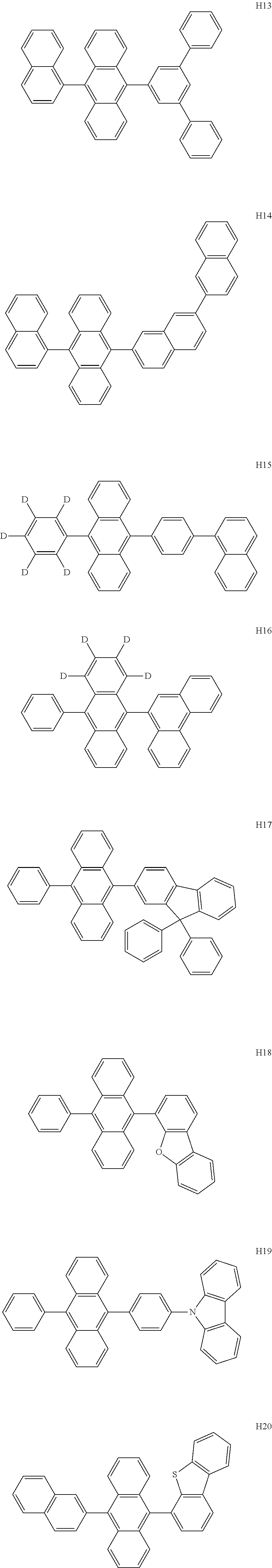

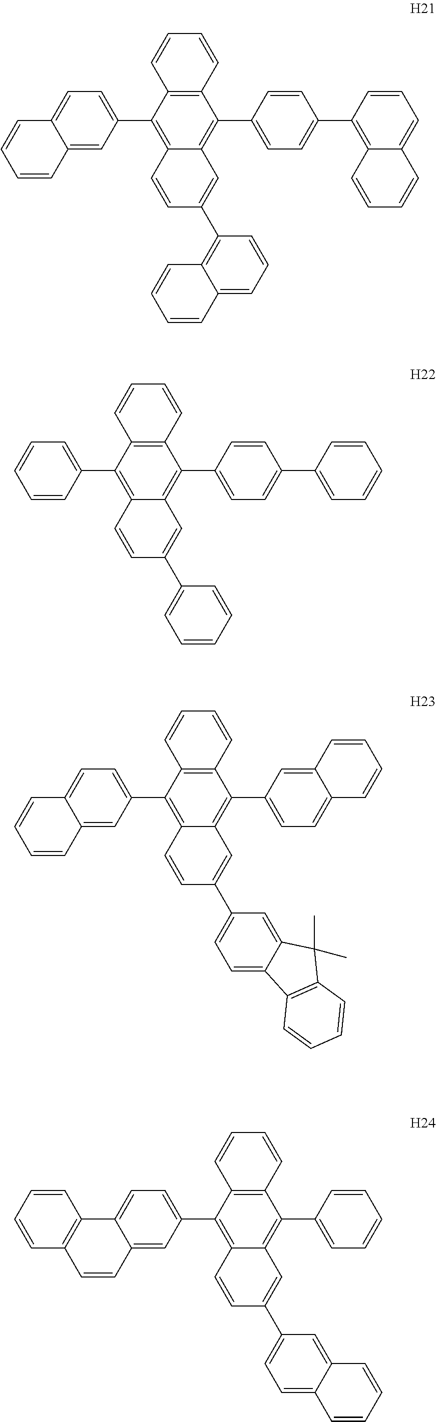

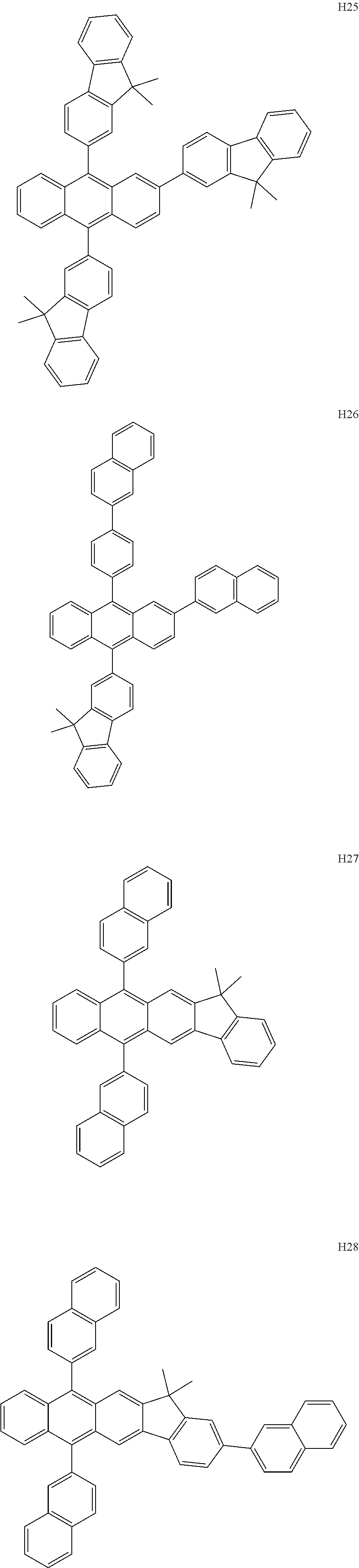

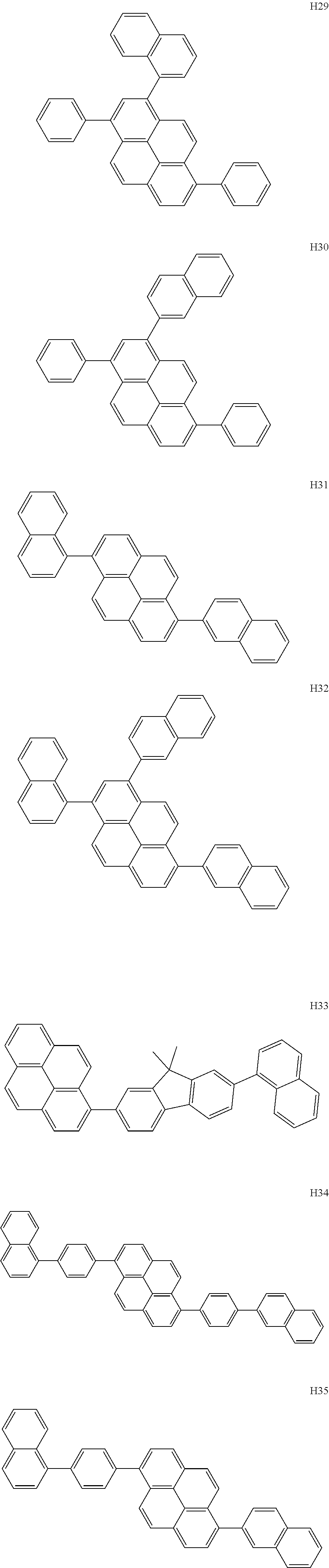

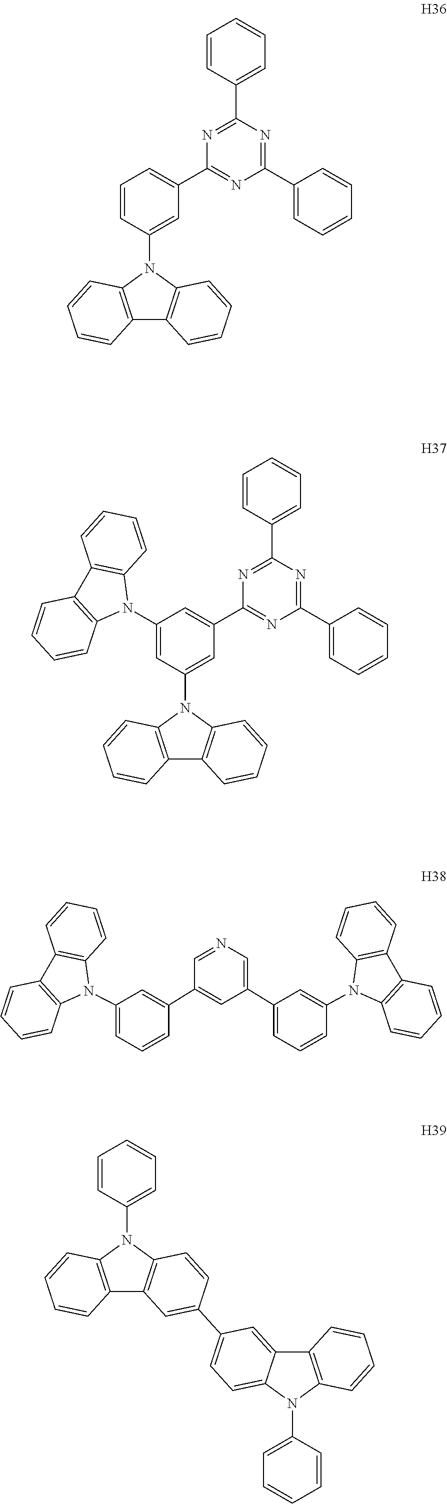 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

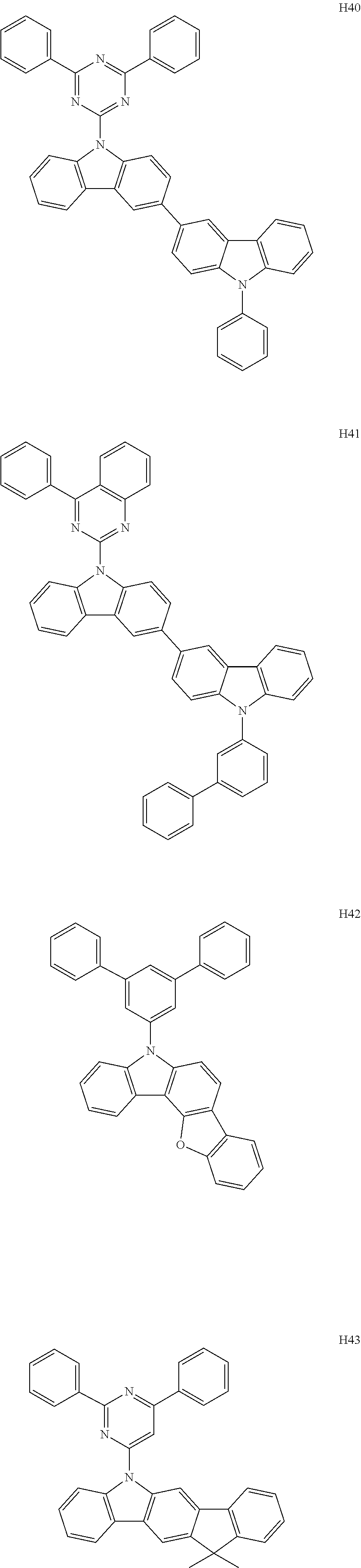 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1cc(-c2ccccc2)nc(-c2ccccc2)n1]

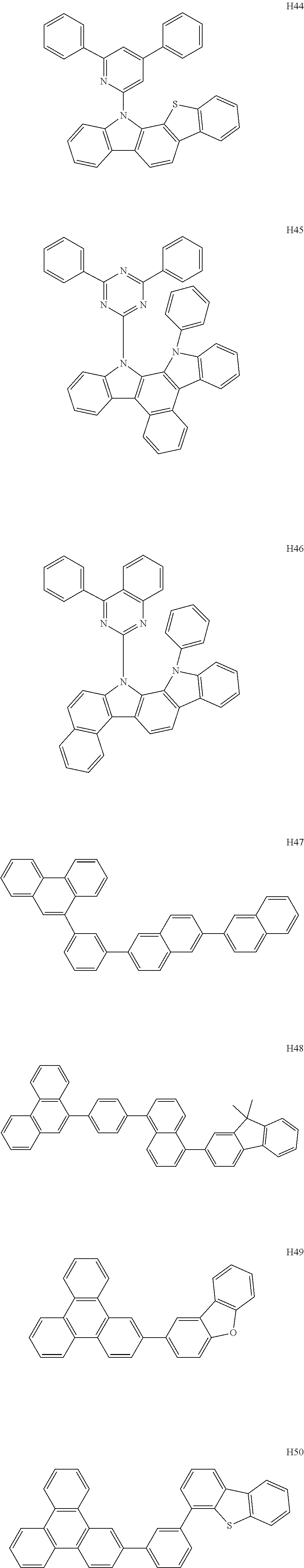

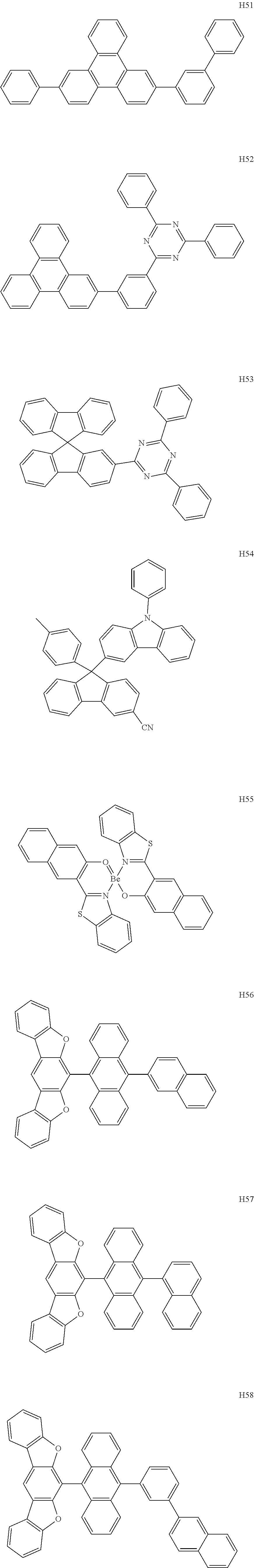

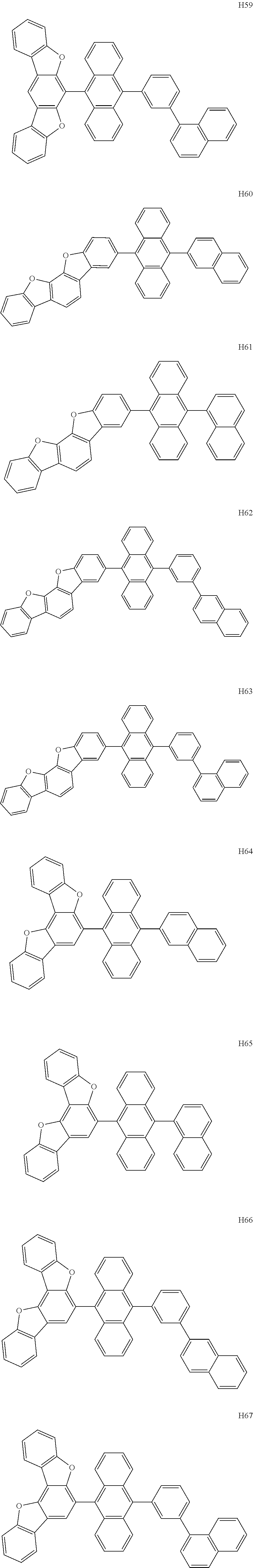

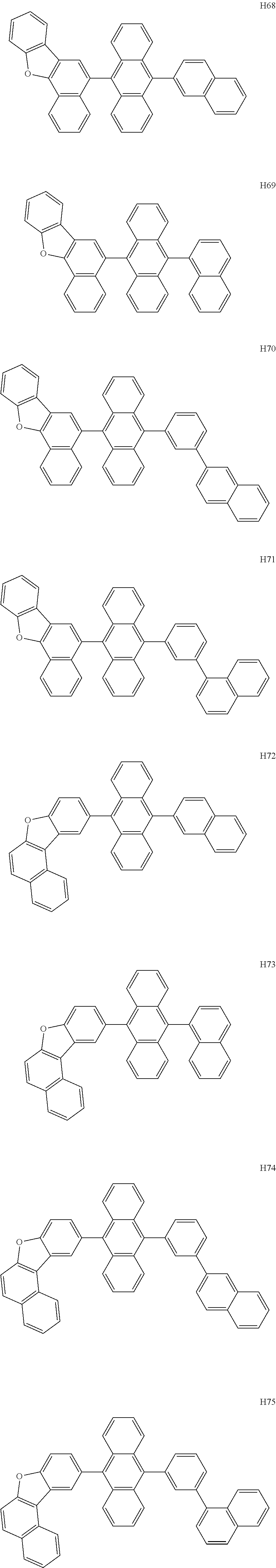

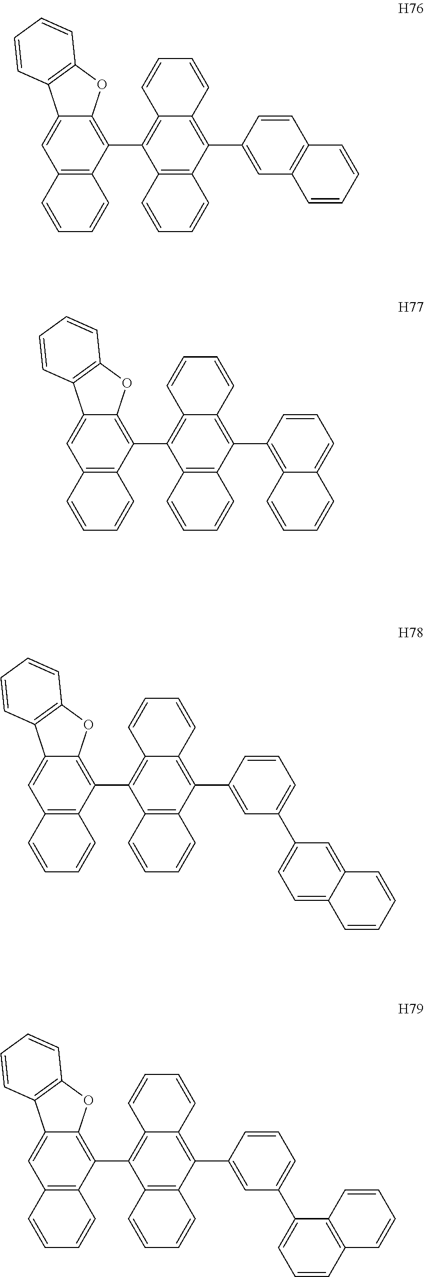 [SMILES: c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

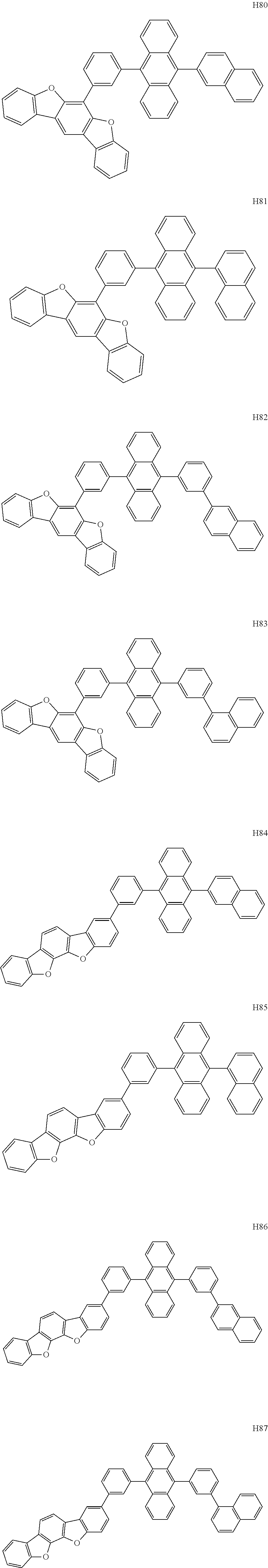

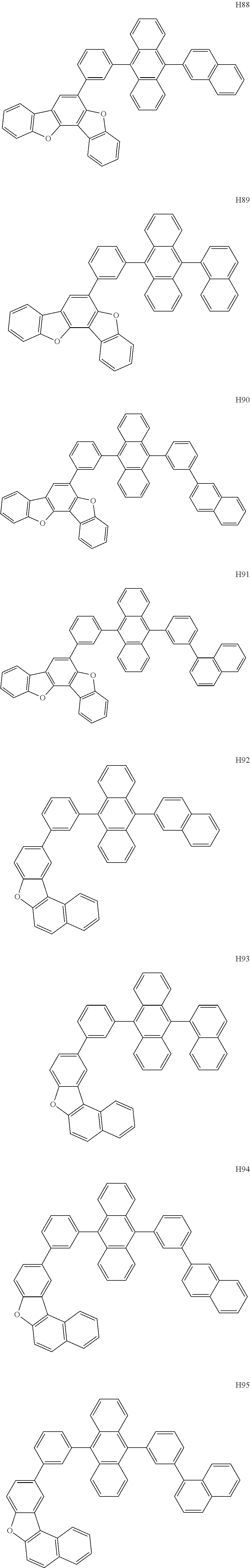

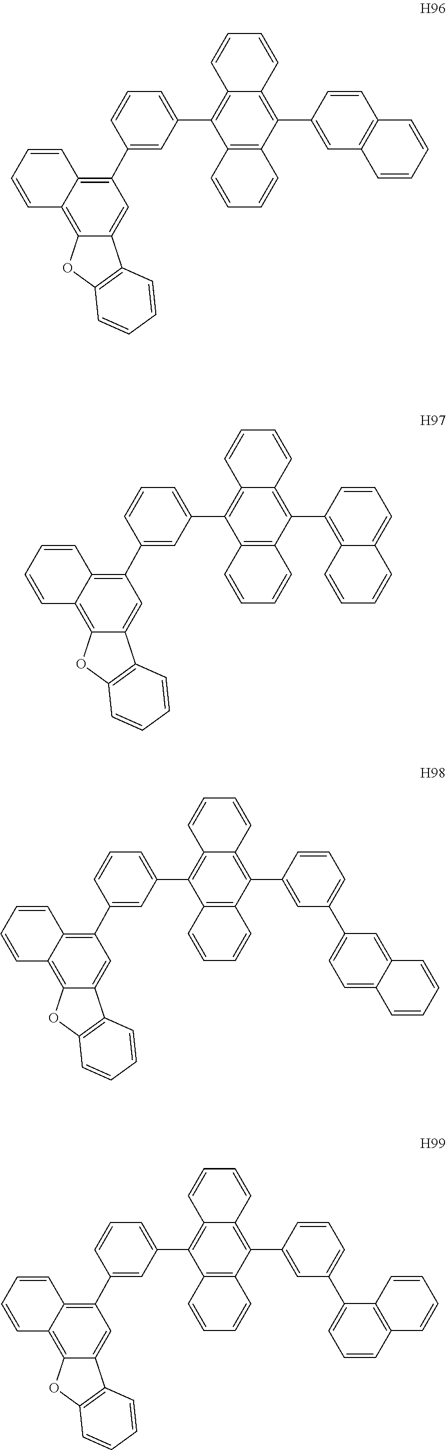

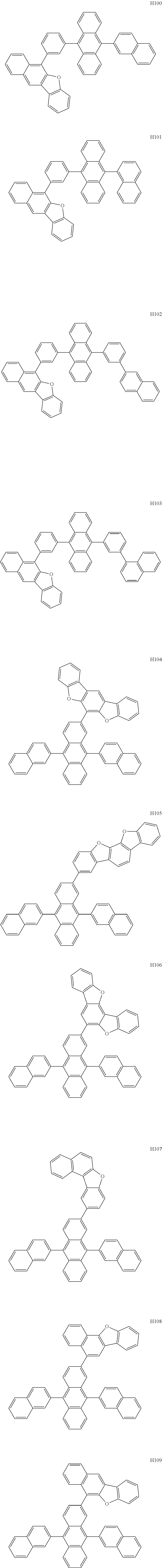

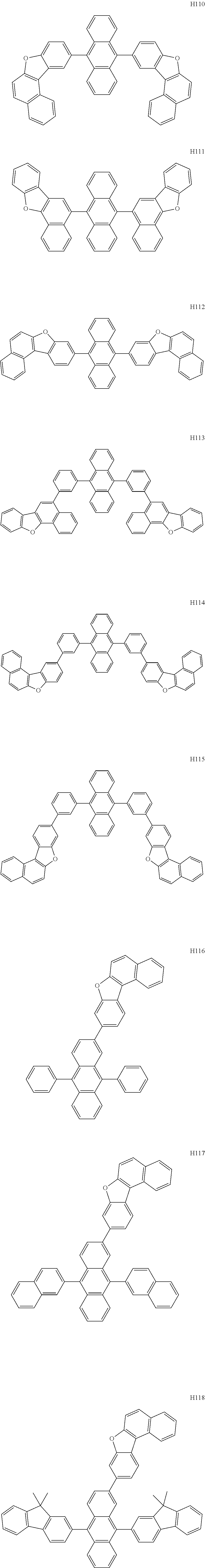

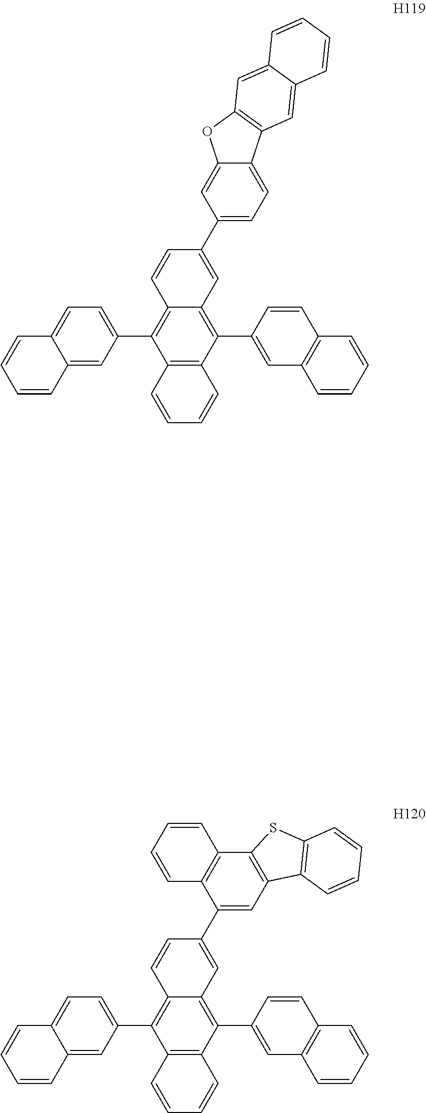 [SMILES: c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

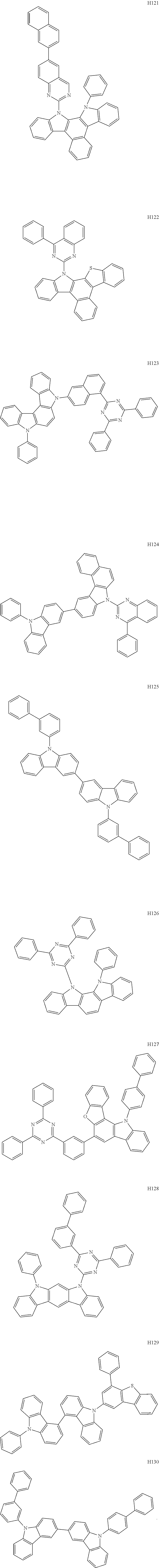

In one or more embodiments, the host may include a silicon-containing compound, a phosphine oxide-containing compound, or any combination thereof.

The host may have one or more suitable modifications. For example, the host may include only one kind of compound, or may include two or more kinds of different compounds.

### Phosphorescent Dopant

The emission layer may include, as a phosphorescent dopant, the organometallic compound represented by Formula 1 as described herein.

In one or more embodiments, when the emission layer includes the organometallic compound represented by Formula 1 as described herein, and the organometallic compound represented by Formula 1 as described herein acts as an auxiliary dopant, the emission layer may include a phosphorescent dopant.

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or a (e.g., any) combination thereof.

The phosphorescent dopant may be electrically neutral.

In one or more embodiments, the phosphorescent dopant may include at least one organometallic compound represented by Formula 401:

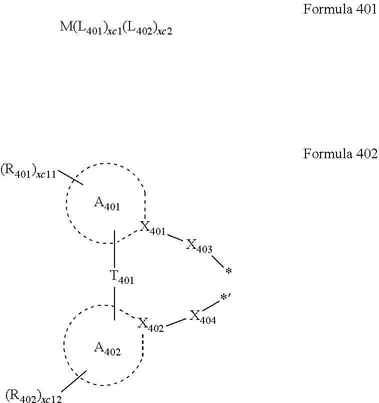

wherein, in Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, when xc1 is 2 or more, two or more of L₄₀₁ may be identical to or different from each other,
L₄₀₂ may be an organic ligand, and xc2 may be 0, 1, 2, 3, or 4, wherein, when xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C═*′, * and *′ each indicate a binding site to a neighboring atom,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃) (Q₄₁₄),
Q₄₁₁ to Q₄₁₄ are each as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group that is unsubstituted or substituted with at least one R₁₀ₐ, a C₁-C₂₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ are each as described in connection with Q₁,
xc11 and xc12 may each independently be an integer from 0 to 10, and
* and *′ in Formula 402 may each indicate a binding site to M in Formula 401.

In one or more embodiments, in Formula 402, i) X₄₀₁ may be nitrogen, and X₄₀₂ may be carbon, or ii) each of X₄₀₁ and X₄₀₂ may be nitrogen.

In one or more embodiments, when xc1 in Formula 401 is 2 or more, two ring A₄₀₁ in two or more selected from L₄₀₁ may be optionally linked to each other via T₄₀₂, which is a linking group, or two ring A₄₀₂ may optionally be linked to each other via T₄₀₃, which is a linking group (see Compounds PD1 to PD4 and PD7). T₄₀₂ and T₄₀₃ are each as described in connection with T₄₀₁.

L₄₀₂ in Formula 401 may be an organic ligand. In one or more embodiments, L₄₀₂ may include a halogen group, a diketone group (for example, an acetylacetonate group), a carboxylic acid group (for example, a picolinate group), —C(═O), an isonitrile group, a —CN, a phosphorus-containing group (for example, a phosphine group, a phosphite group, and/or the like), or any combination thereof.

The phosphorescent dopant may include, for example, at least one of Compounds PD1 to PD25, or a (e.g., any) combination thereof:

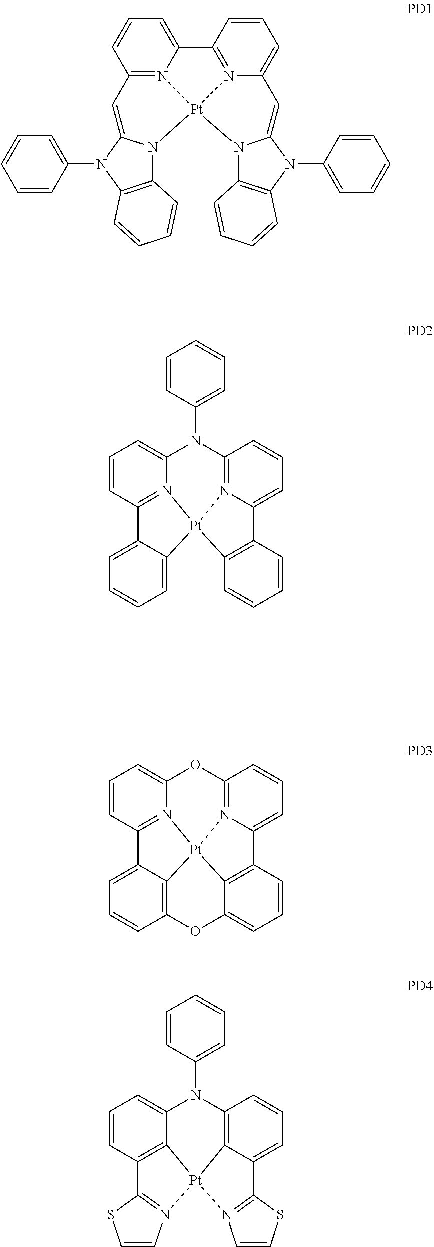

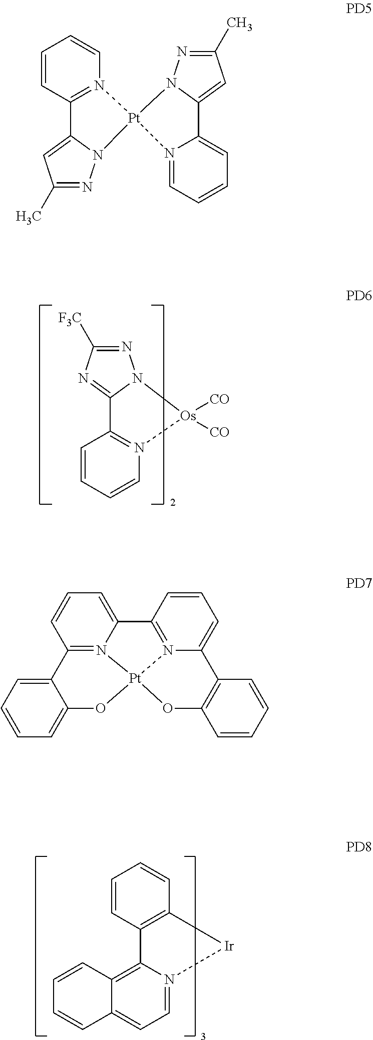

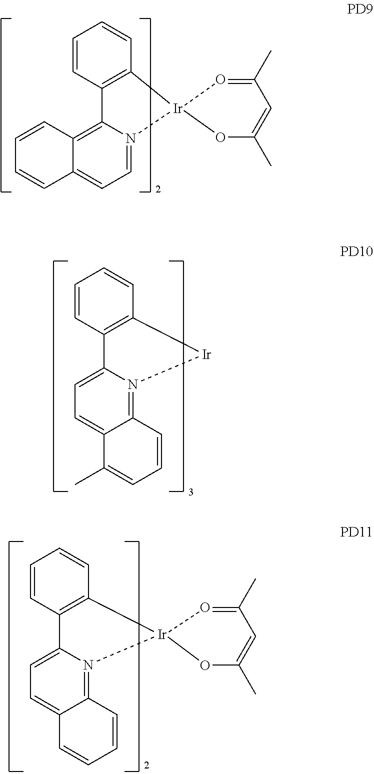

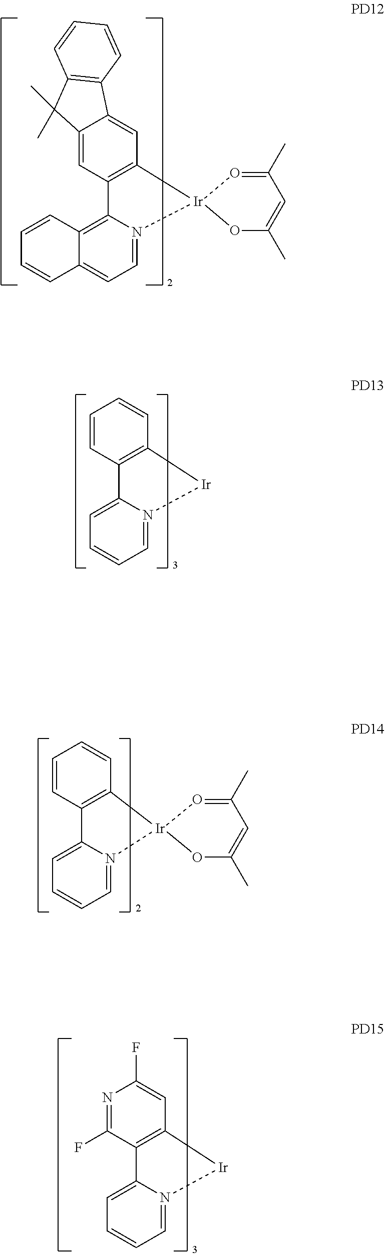

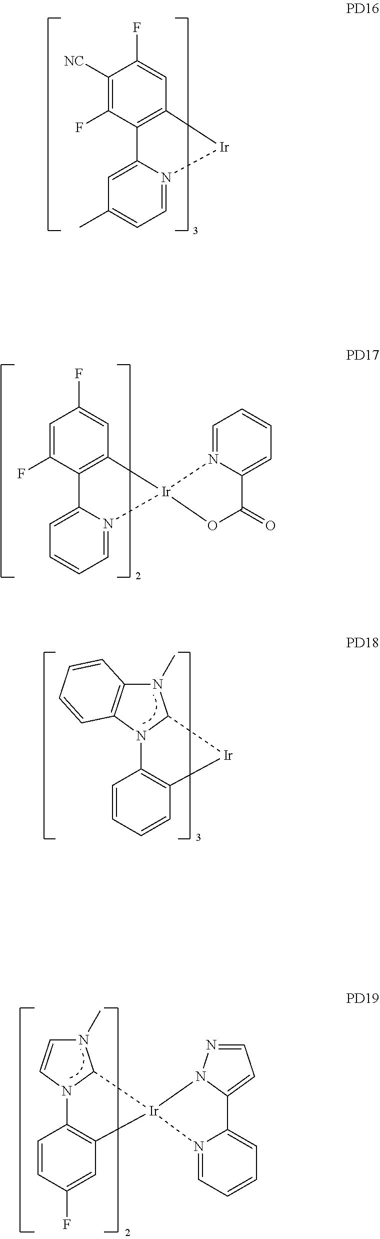

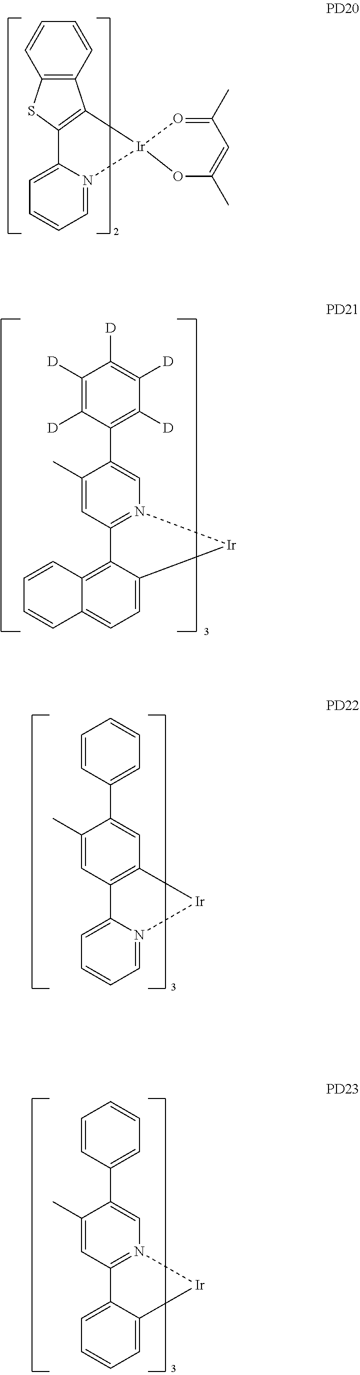

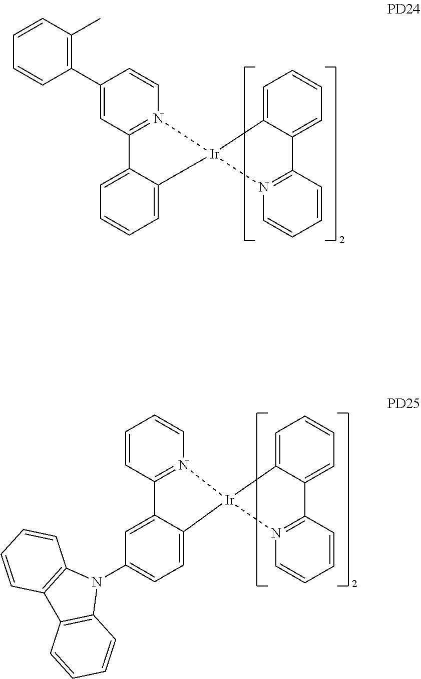

### Fluorescent Dopant

When the emission layer includes the organometallic compound represented by Formula 1 as described herein, and the organometallic compound represented by Formula 1 as described herein acts as an auxiliary dopant, the emission layer may further include a fluorescent dopant.

In one or more embodiments, when the emission layer includes the organometallic compound represented by Formula 1 as described herein, and the organometallic compound represented by Formula 1 as described herein acts as a phosphorescent dopant, the emission layer may further include an auxiliary dopant.

The fluorescent dopant and the auxiliary dopant may each independently include an arylamine compound, a styrylamine compound, a boron-containing compound, or any combination thereof.

In one or more embodiments, the fluorescent dopant and the auxiliary dopant may each independently include a compound represented by Formula 501:

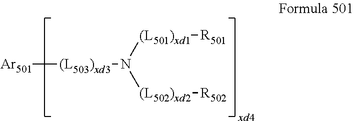

wherein, in Formula 501,
Ar₅₀₁, L₅₀₁ to L₅₀₃, R₅₀₁, and R₅₀₂ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (for example, an anthracene group, a chrysene group, a pyrene group, and/or the like) in which three or more monocyclic groups are condensed together.

In one or more embodiments, xd4 in Formula 501 may be 2.

In one or more embodiments, the fluorescent dopant and the auxiliary dopant may each include at least one of Compounds FD1 to FD36, DPVBi, DPAVBi, and/or any combination thereof:

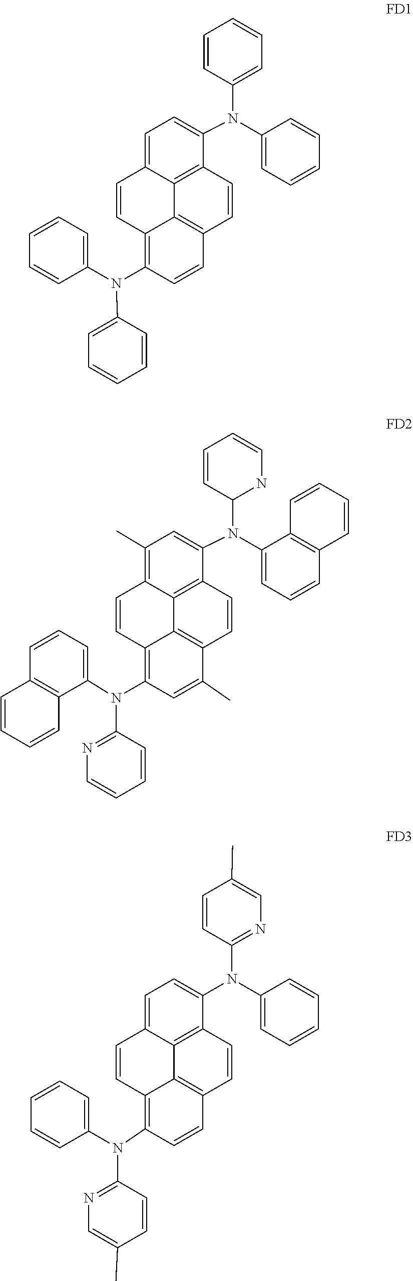 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4cccc5ccccc45)C4C=CC=CN4)c4ccc1c2c34 ; Cc1ccc(N(c2ccccc2)c2ccc3ccc4c(N(c5ccccc5)c5ccc(C)cn5)ccc5ccc2c3c54)nc1]

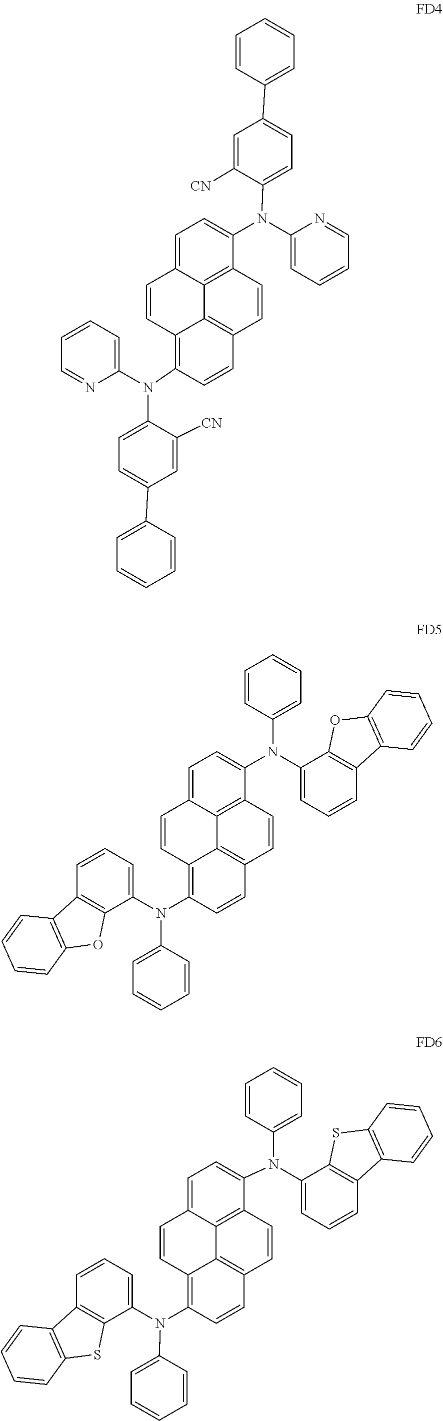

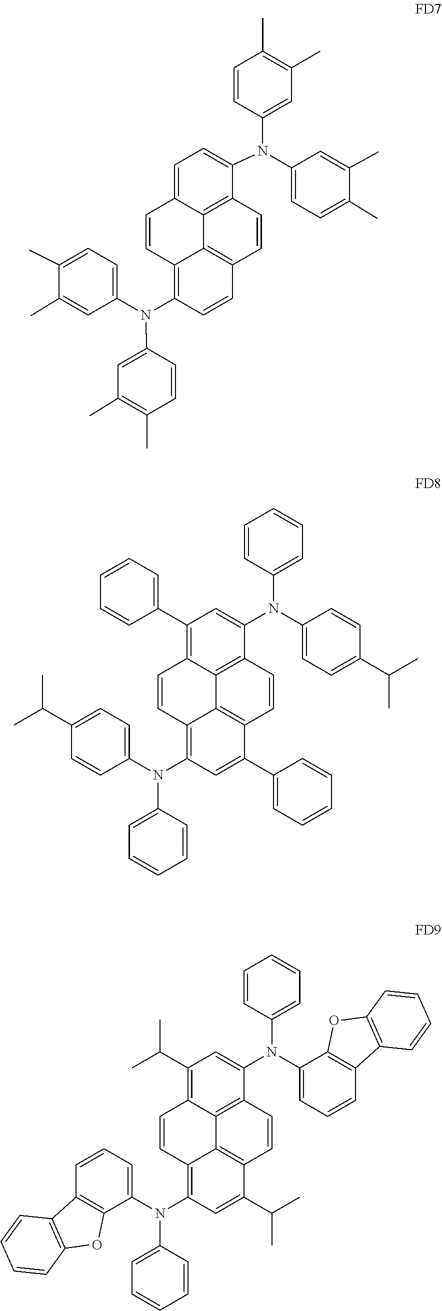

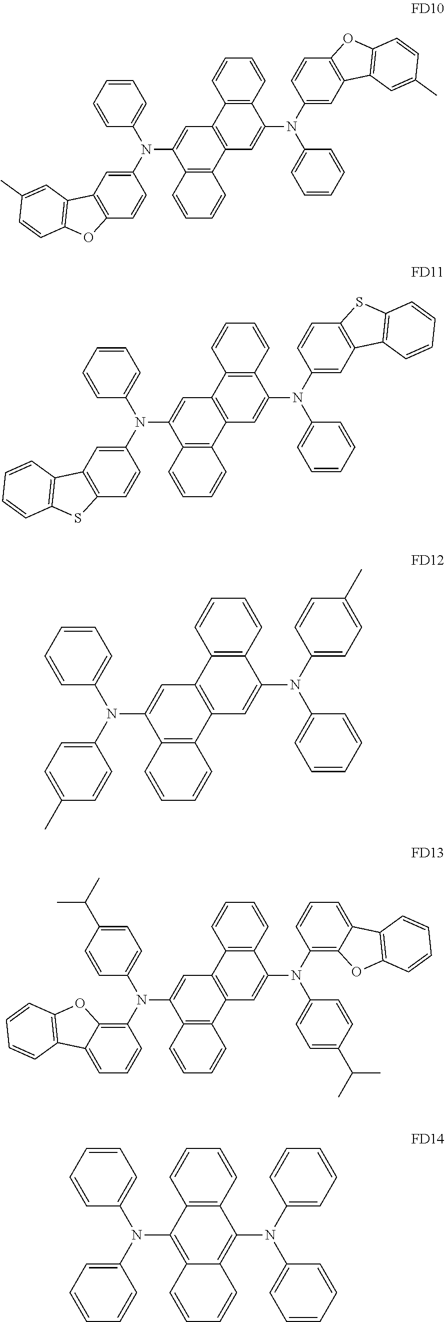

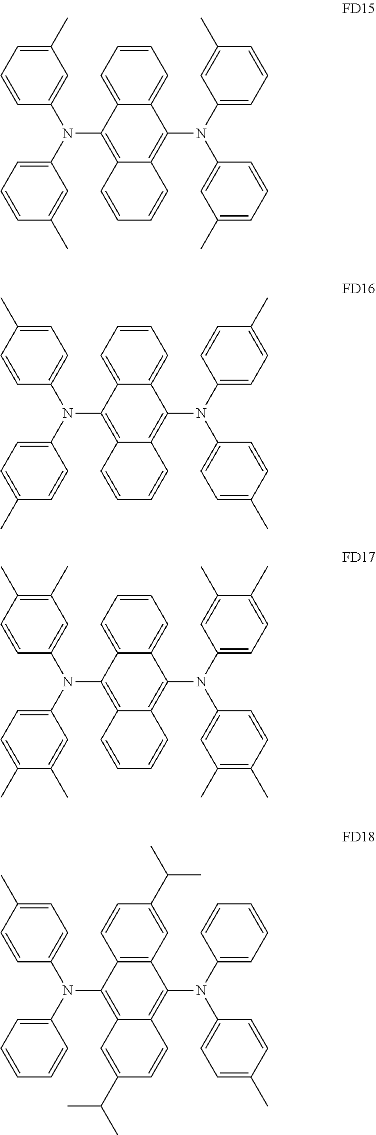

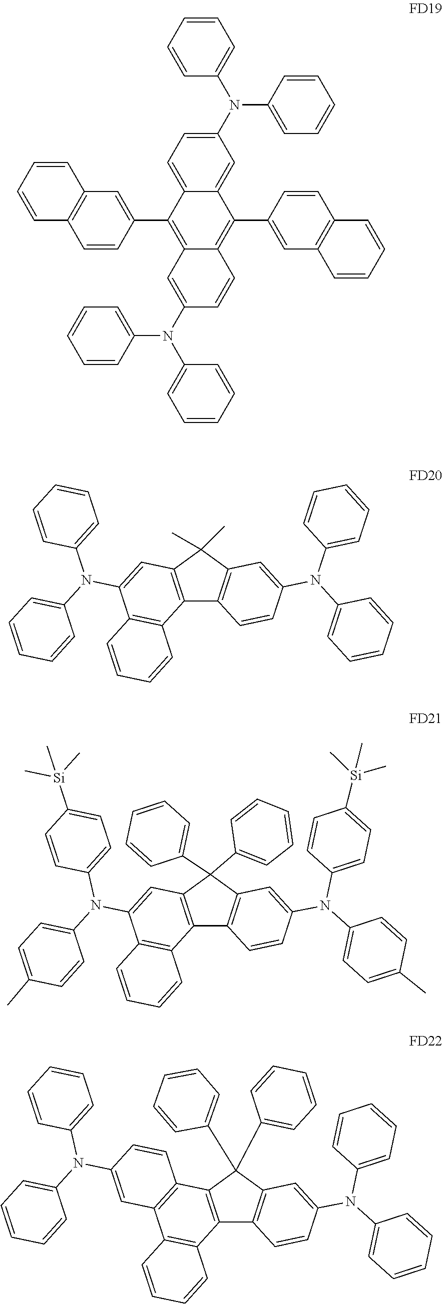

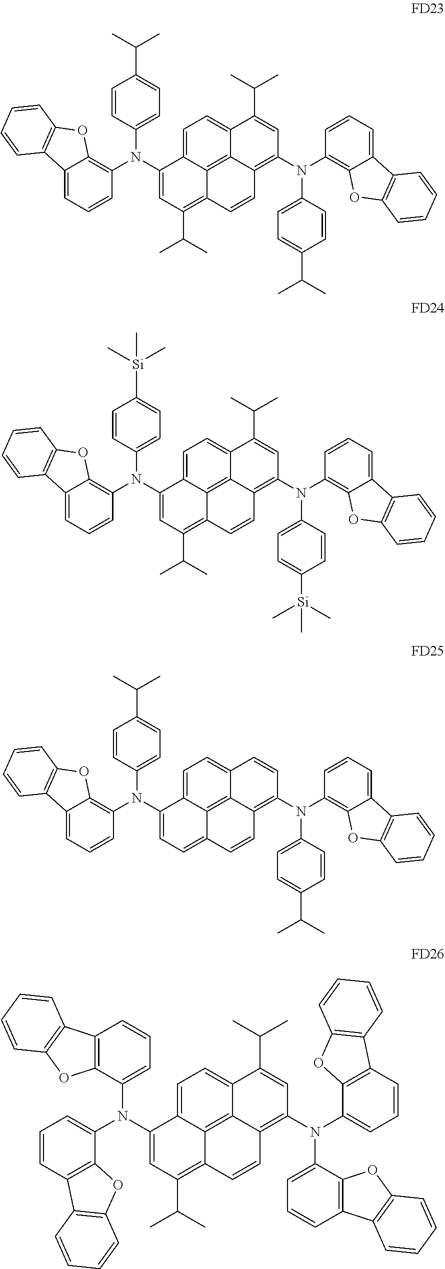 [SMILES: CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1 ; CC(C)c1cc(N(c2ccc([Si](C)(C)C)cc2)c2cccc3c2oc2ccccc23)c2ccc3c(C(C)C)cc(N(c4ccc([Si](C)(C)C)cc4)c4cccc5c4oc4ccccc45)c4ccc1c2c34 ; CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1 ; CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34]

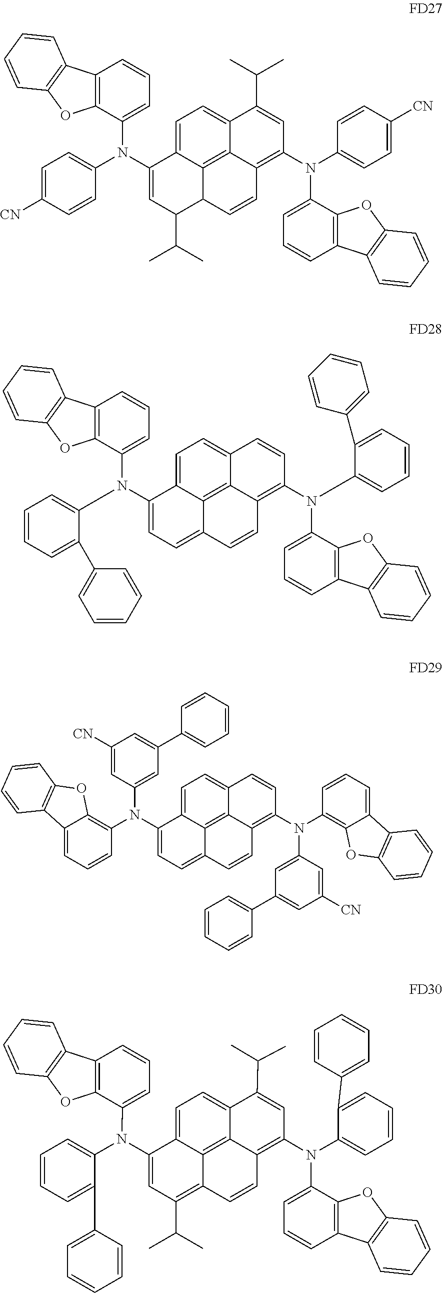

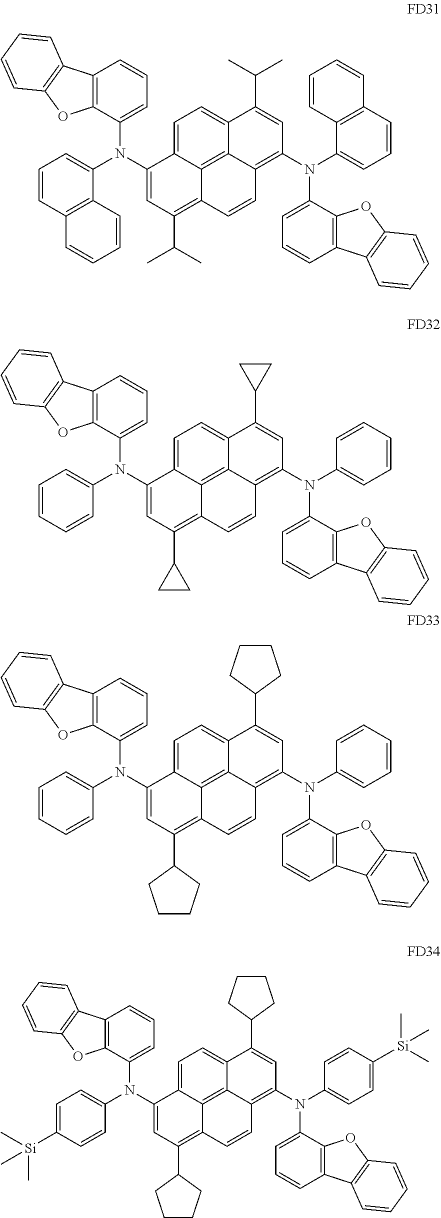

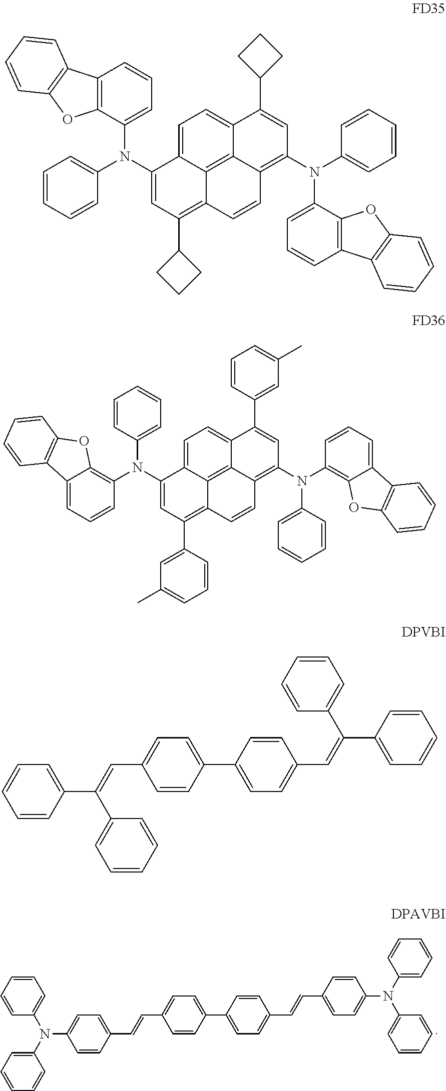

In one or more embodiments, the fluorescent dopant and the auxiliary dopant may each independently include a fourth compound represented by Formula 502 or 503 as described herein.

### Electron Transport Region in Interlayer 130

The electron transport region may have: i) a single-layered structure including (e.g., consisting of) a single layer including (e.g., consisting of) a single material, ii) a single-layered structure including (e.g., consisting of) a single layer including multiple different materials, or iii) a multilayer structure including multiple layers including multiple different materials.

The electron transport region may include a buffer layer, a hole blocking layer, an electron control layer, an electron transport layer, an electron injection layer, or any combination thereof.

In one or more embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers of each structure are stacked in the stated order from the emission layer.

The electron transport region (for example, the buffer layer, the hole blocking layer, the electron control layer, or the electron transport layer in the electron transport region) may include a metal-free compound including at least one π electron-deficient nitrogen-containing C₁-C₆₀ heterocyclic group.

In one or more embodiments, the electron transport region may include a compound represented by Formula 601.

[Ar₆₀₁]ₓₑ₁₁-[(L₆₀₁)ₓₑ₁-R₆₀₁]ₓₑ₂₁ Formula 601

In Formula 601,
Ar₆₀1 and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ are each as described in connection with Q₁,
xe21 may be 1, 2, 3, 4, or 5, and
at least one of Ar₆₀1, L₆₀₁, and R₆₀₁ may each independently be a π electron-deficient nitrogen-containing C₁-C₆₀ heterocyclic group that is unsubstituted or substituted with at least one R₁₀ₐ.

In one or more embodiments, when xe11 in Formula 601 is 2 or more, two or more of Ar₆₀1 may be linked together via a single bond.

In one or more embodiments, Ar₆₀1 in Formula 601 may be an anthracene group that is unsubstituted or substituted with at least one R₁₀ₐ.

In one or more embodiments, the electron transport region may include a compound represented by Formula 601-1:

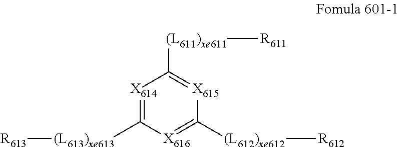

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ are each as described in connection with L₆₀₁,
xe611 to xe613 are each as described in connection with xe1,
R₆₁₁ to R₆₁₃ are each as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In one or more embodiments, xe1 and xe611 to xe613 in Formulae 601 and 601-1 may each independently be 0, 1, or 2.

The electron transport region may include at least one selected from among Compounds ET1 to ET46, 2,9-dimethyl-4,7-diphenyl-1,10-phenanthroline (BOP), 4,7-diphenyl-1,10-phenanthroline (Bphen), Alq₃, BAlq, TAZ, NTAZ, and/or any combination thereof:

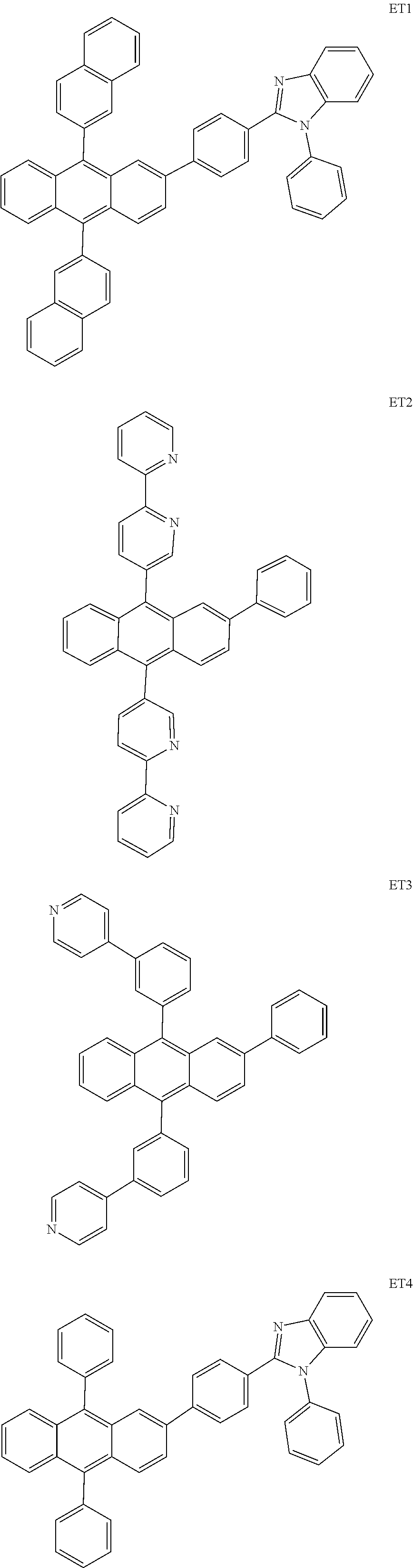 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1 ; c1ccc(-c2c3ccccc3c(-c3ccccc3)c3cc(-c4ccc(-c5nc6ccccc6n5-c5ccccc5)cc4)ccc23)cc1]

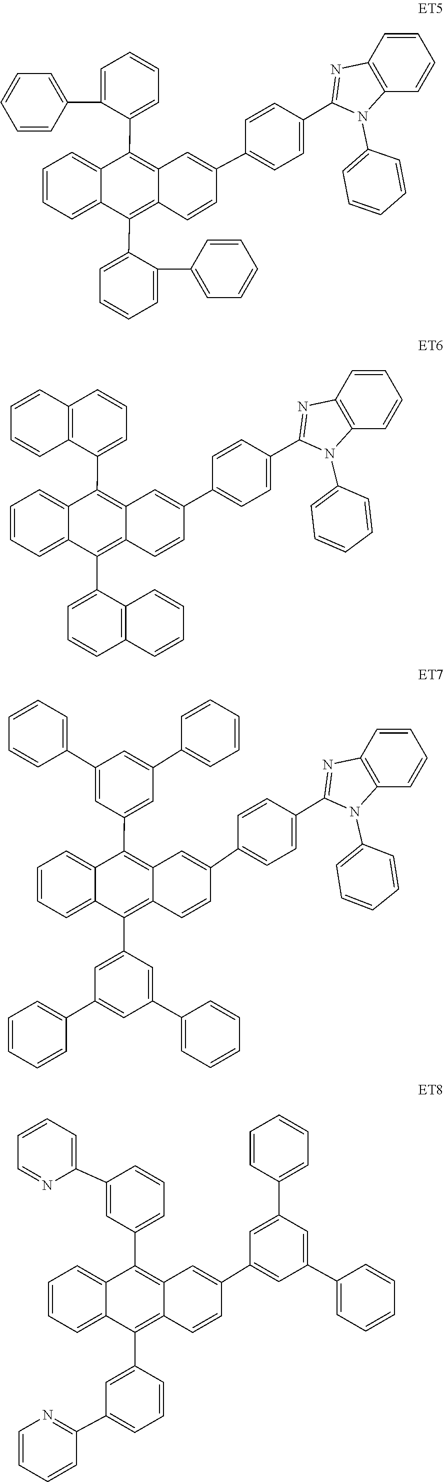 [SMILES: c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

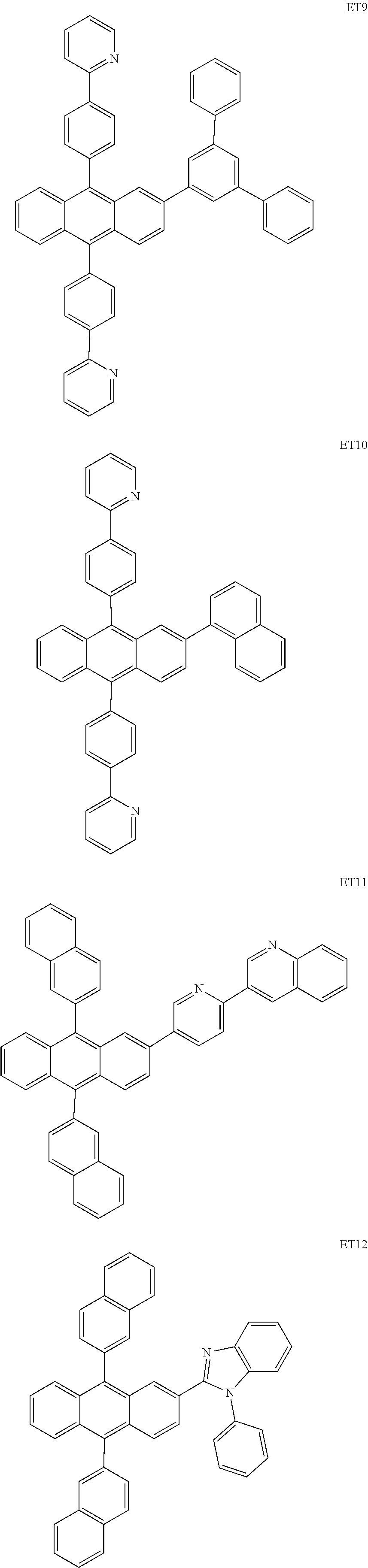 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

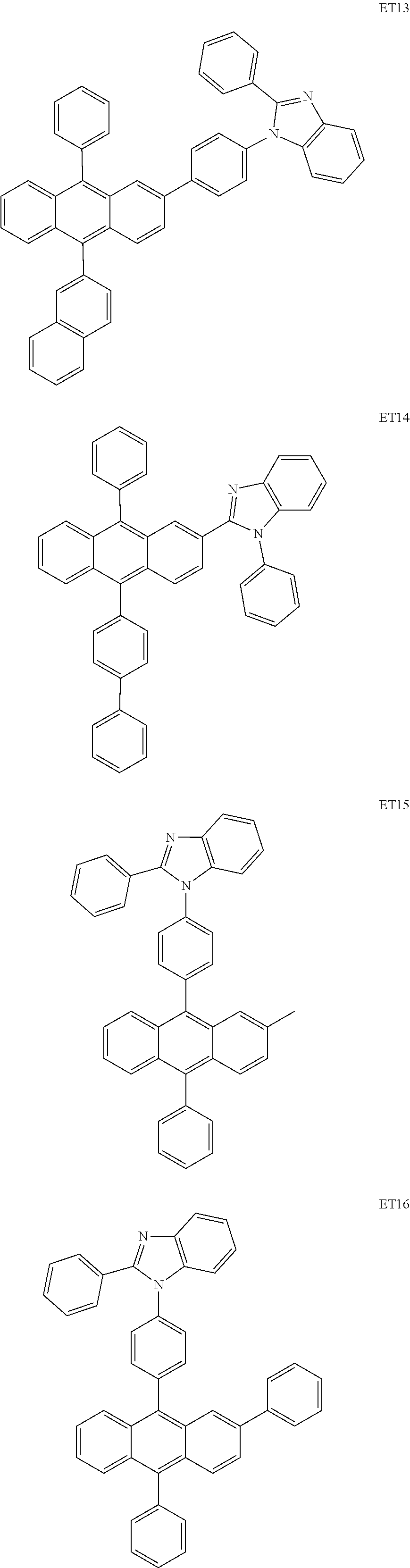 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

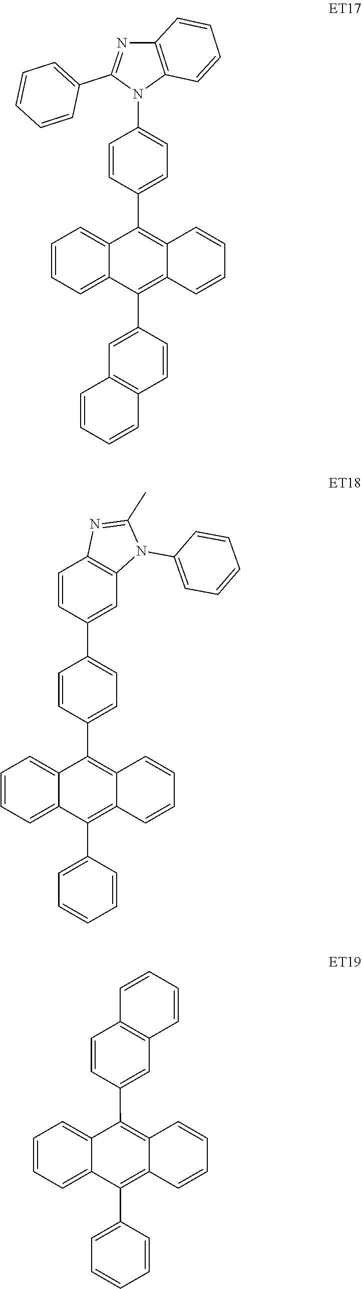

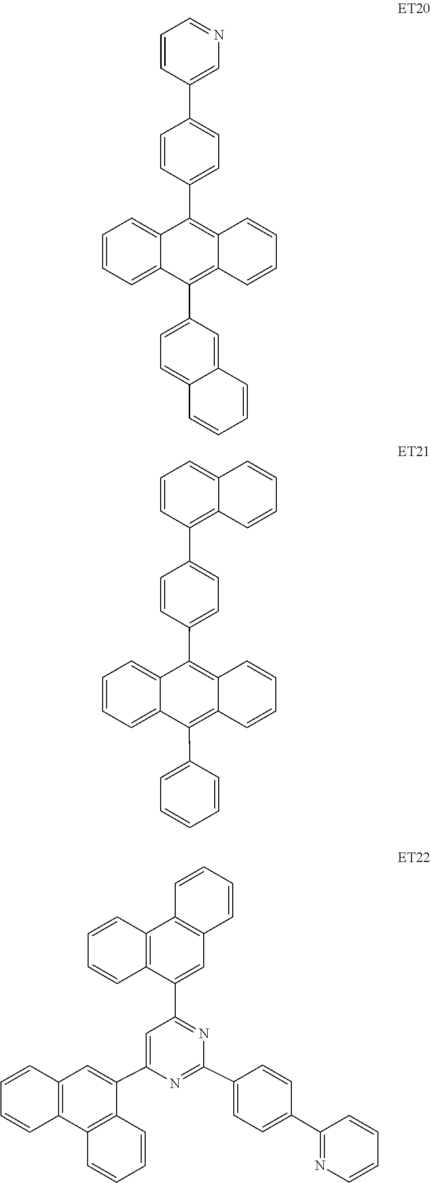

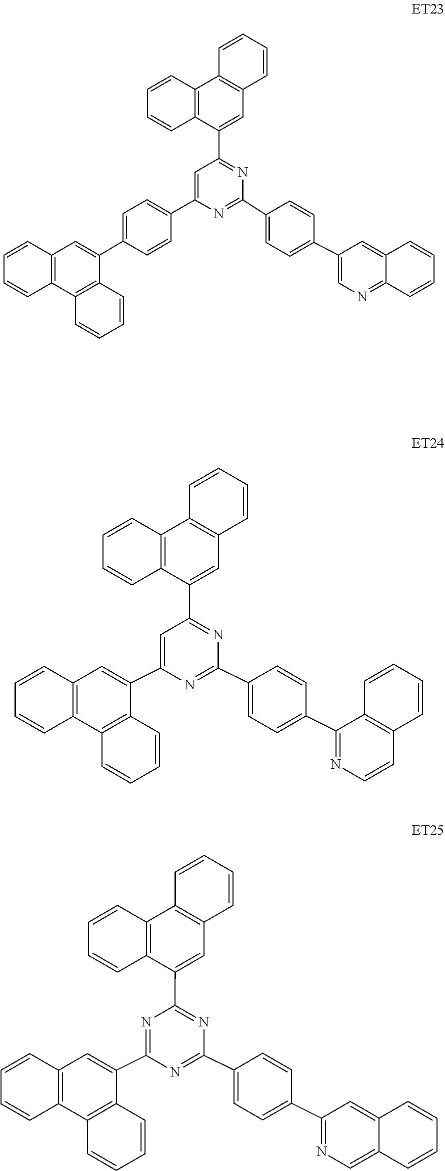 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)nc(-c5cc6ccccc6c6ccccc56)n4)cc3)ncc2c1]

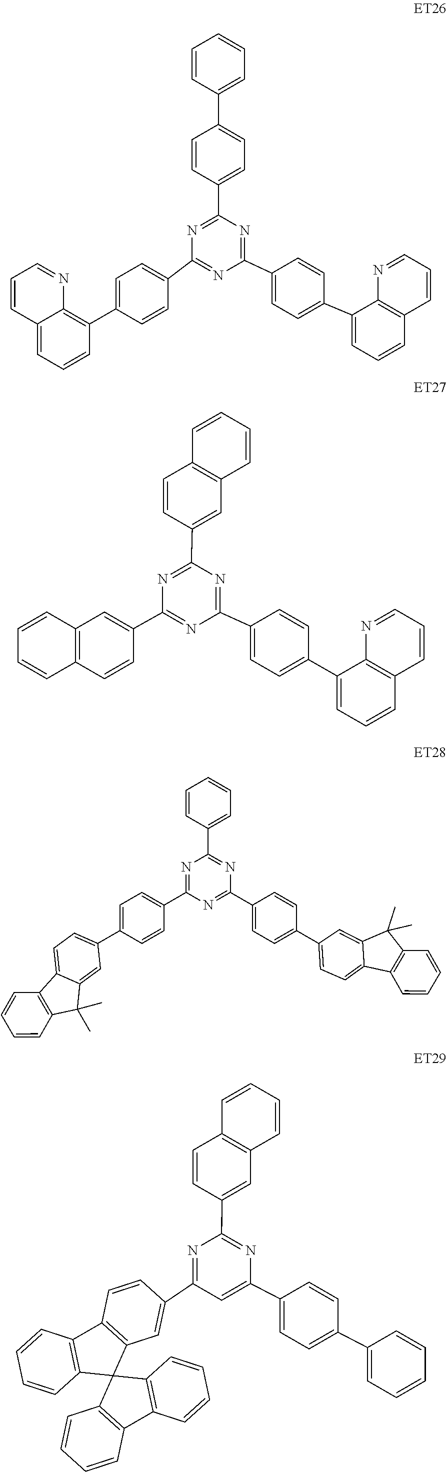 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

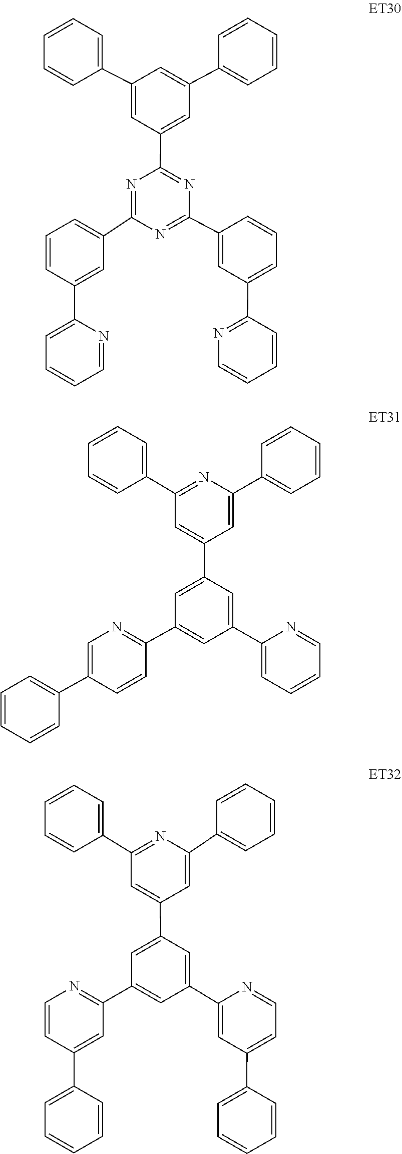 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

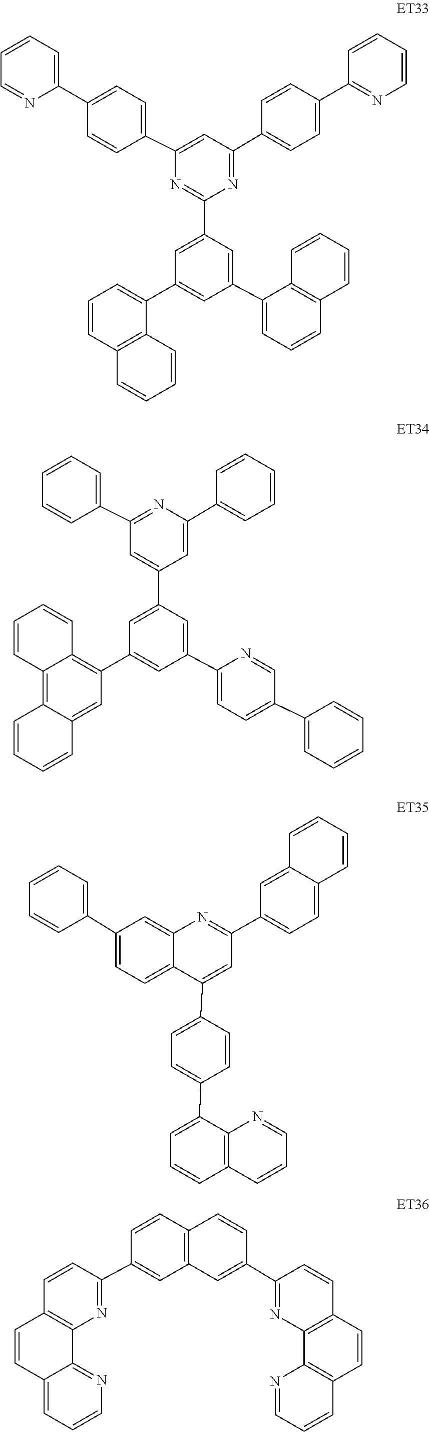

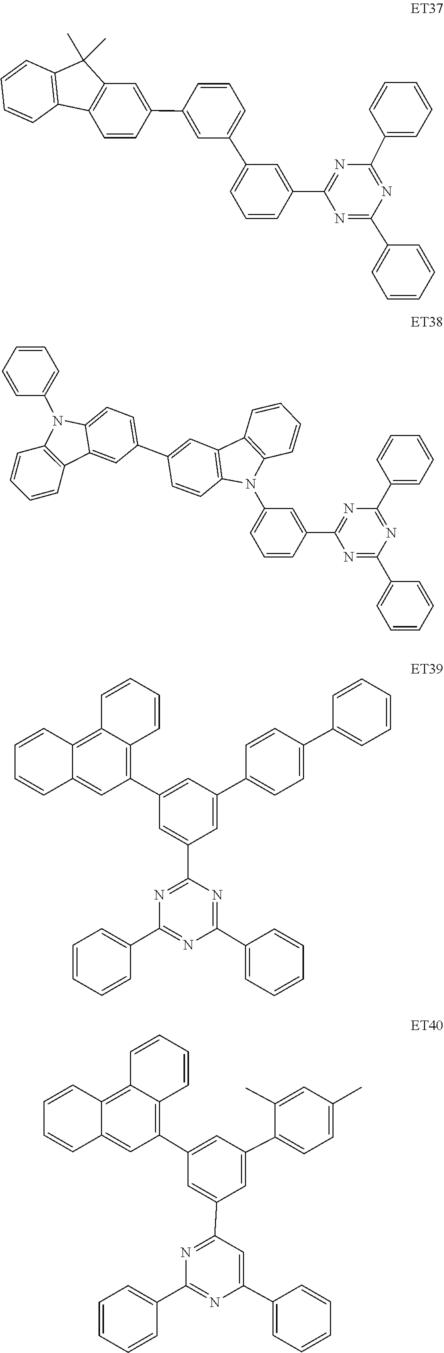 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

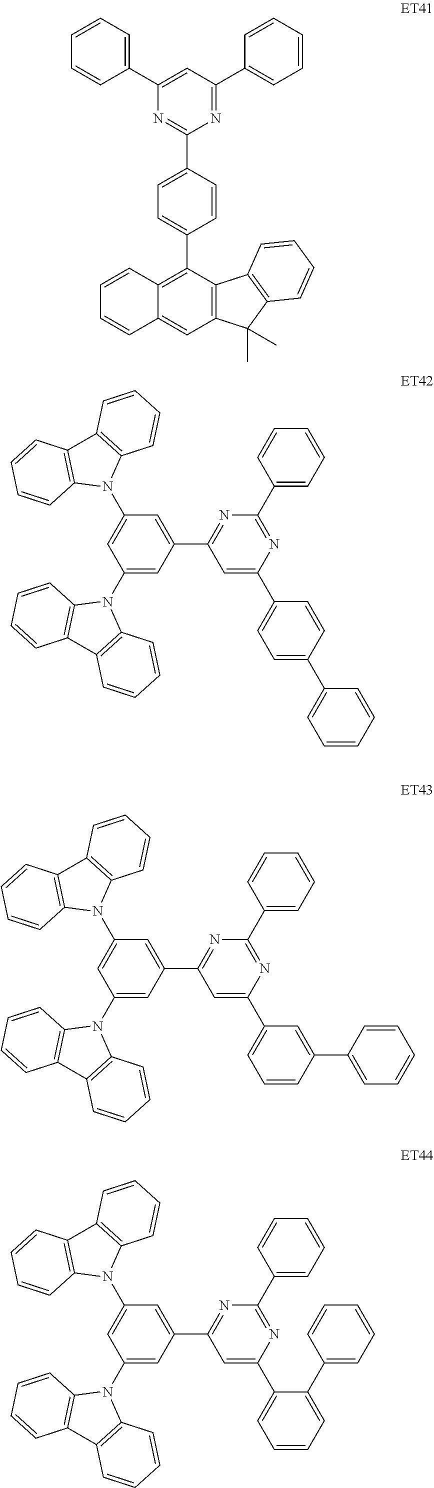 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1]

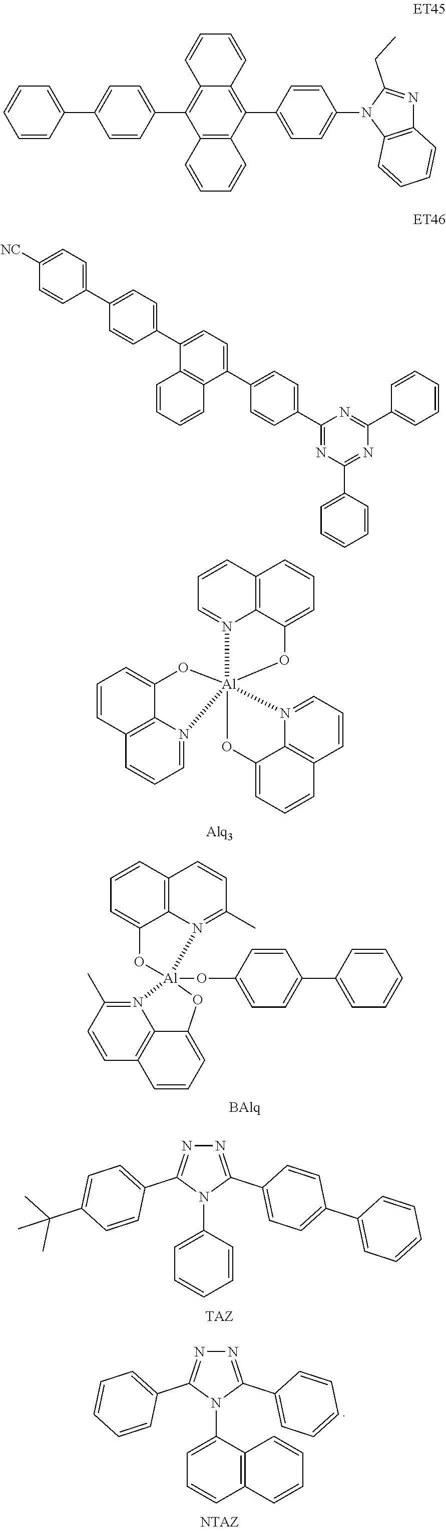

The thickness of the electron transport region may be about 100 Å to about 5,000 Å, for example, about 160 Å to about 4,000 Å. When the electron transport region includes a buffer layer, a hole blocking layer, an electron control layer, an electron transport layer, or any combination thereof, the thickness of the buffer layer, the hole blocking layer, or the electron control layer may each independently be from about 20 Å to about 1,000 Å, for example, about 30 Å to about 300 Å, and the thickness of the electron transport layer may be from about 100 Å to about 1,000 Å, for example, about 150 Å to about 500 Å. When the thicknesses of the buffer layer, the hole blocking layer, the electron control layer, the electron transport layer, and/or the electron transport layer are within these ranges, satisfactory electron-transporting characteristics may be obtained without a substantial increase in driving voltage.

The electron transport region (for example, the electron transport layer in the electron transport region) may further include, in addition to the materials described herein, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include at least one selected from among a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, and/or any combination thereof.

In one or more embodiments, the metal-containing material may include a Li complex. The Li complex may include, for example, Compound ET-D1 (LiQ) and/or ET-D2:

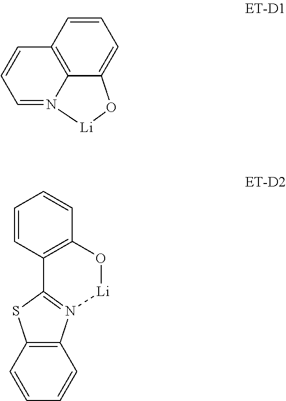

The electron transport region may include an electron injection layer that facilitates the injection of electrons from the second electrode 150. The electron injection layer may directly contact the second electrode 150.

The electron injection layer may have: i) a single-layered structure including (e.g., consisting of) a single layer including (e.g., consisting of) a single material, ii) a single-layered structure including (e.g., consisting of) a single layer including multiple different materials, or iii) a multilayer structure including multiple layers including multiple different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, and/or the like), or tellurides of the alkali metal, the alkaline earth metal, and the rare earth metal, and/or any combination thereof.

The alkali metal-containing compound may include: alkali metal oxides, such as Li₂O, Cs₂O, or K₂O; alkali metal halides, such as LiF, NaF, CsF, KF, LiI, NaI, CsI, KI, or RbI; or any combination thereof. The alkaline earth metal-containing compound may include an alkaline earth metal oxide, such as BaO, SrO, CaO, BaₓSr₁₋ₓO (x is a real number satisfying 0<x<1), or BaₓCa₁₋ₓO (x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth-metal complex, and the rare earth metal complex may include i) one selected from among metal ions of the alkali metal, the alkaline earth metal, and the rare earth metal and ii), a ligand bonded to the metal ion (e.g., the selected metal ion), for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, and/or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described herein. In one or more embodiments, the electron injection layer may further include an organic material (for example, a compound represented by Formula 601).

In one or more embodiments, the electron injection layer may include (e.g., consist of) i) an alkali metal-containing compound (for example, alkali metal halide), ii) a) an alkali metal-containing compound (for example, alkali metal halide); and b) an alkali metal, an alkaline earth metal, a rare earth metal, or any combination thereof. In one or more embodiments, the electron injection layer may be a KI:Yb co-deposited layer, an RbI:Yb co-deposited layer, a LiF:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly or non-uniformly dispersed in a matrix including the organic material.

The thickness of the electron injection layer may be about 1 Å to about 100 Å, and, for example, about 3 Å to about 90 Å. When the thickness of the electron injection layer is within the range as described herein, satisfactory electron injection characteristics may be obtained without a substantial increase in driving voltage.

### Second Electrode 150

The second electrode 150 is arranged on the interlayer 130. The second electrode 150 may be a cathode, which is an electron injection electrode, and as a material for forming the second electrode 150, a metal, an alloy, an electrically conductive compound, or any combination thereof, each having a low-work function, may be utilized.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layer structure or a multilayer structure including a plurality of layers.

### Capping Layer

The first capping layer may be arranged outside (and e.g., on) the first electrode 110, and/or the second capping layer may be arranged outside (and e.g., on) the second electrode 150. In detail, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in an emission layer of the interlayer 130 of the light-emitting device 10 may be extracted toward the outside through the first electrode 110, which is a semi-transmissive electrode or a transmissive electrode, and the first capping layer or light generated in an emission layer of the interlayer 130 of the light-emitting device 10 may be extracted toward the outside through the second electrode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 is increased, so that the luminescence efficiency of the light-emitting device 10 may be improved.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

At least one selected from among the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In one or more embodiments, at least one selected from among the first capping layer and the second capping layer may each independently include an amine group-containing compound.

In one or more embodiments, at least one selected from among the first capping layer and the second capping layer may each independently include a compound represented by Formula 201, a compound represented by Formula 202, or any combination thereof.

In one or more embodiments, at least one selected from among the first capping layer and the second capping layer may each independently include at least one selected from among Compounds HT28 to HT33, one of Compounds CP1 to CP6, β-NPB, and/or any combination thereof:

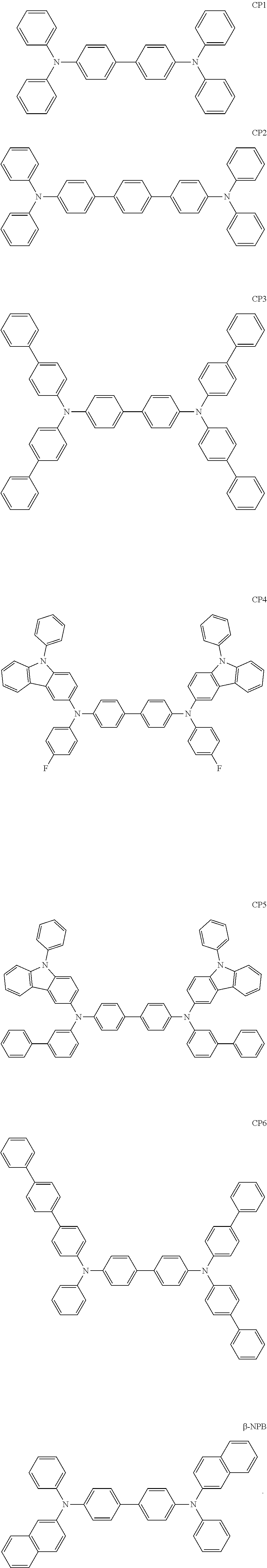

### Electronic Apparatus

The light-emitting device may be included in one or more suitable electronic apparatuses. In one or more embodiments, the electronic apparatus including the light-emitting device may be a light-emitting apparatus, an authentication apparatus, and/or the like.

The electronic apparatus (for example, light-emitting apparatus) may further include, in addition to the light-emitting device, i) a color filter, ii) a color conversion layer, or iii) a color filter and a color conversion layer. The color filter and/or the color conversion layer may be located in at least one traveling direction of light emitted from the light-emitting device. For example, the light emitted from the light-emitting device may be blue light, green light, or white light. The light-emitting device may be as described herein. In one or more embodiments, the color conversion layer may include quantum dots.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area emitting first color light, a second area emitting second color light, and/or a third area emitting third color light, wherein the first color light, the second color light, and/or the third color light may have different maximum emission wavelengths. In one or more embodiments, the first color light may be red light, the second color light may be green light, and the third color light may be blue light. In one or more embodiments, the plurality of color filter areas (or the plurality of color conversion areas) may include quantum dots. In detail, the first area may include red quantum dots, the second area may include green quantum dots, and the third area may not include (e.g., may exclude) quantum dots. A detailed description of the quantum dots is provided herein. The first area, the second area, and/or the third area may each further include a scatterer.

In one or more embodiments, the light-emitting device may be to emit a first light, the first area may be to absorb the first light to emit a first-1 color light, the second area may be to absorb the first light to emit a second-1 color light, and the third area may be to absorb the first light to emit a third-1 color light. In this case, the first-1 color light, the second-1 color light, and the third-1 color light may have different maximum emission wavelengths. In detail, the first light may be blue light, the first-1 color light may be red light, the second-1 color light may be green light, and the third-1 color light may be blue light.

The electronic apparatus may further include a thin-film transistor in addition to the light-emitting device as described herein. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion for sealing the light-emitting device. The sealing portion may be located between the color filter and/or the color-conversion layer and the light-emitting device. The sealing portion allows light from the light-emitting device to be extracted to the outside, while concurrently (e.g., simultaneously) preventing or reducing ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

Various functional layers may be additionally arranged on the sealing portion, in addition to the color filter and/or the color conversion layer, according to the utilize of the electronic apparatus. The functional layers may include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus that authenticates an individual by utilizing biometric information of a living body (for example, fingertips, pupils, and/or the like).

The authentication apparatus may further include, in addition to the light-emitting device, a biometric information collector.

The electronic apparatus may be applied to one or more suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

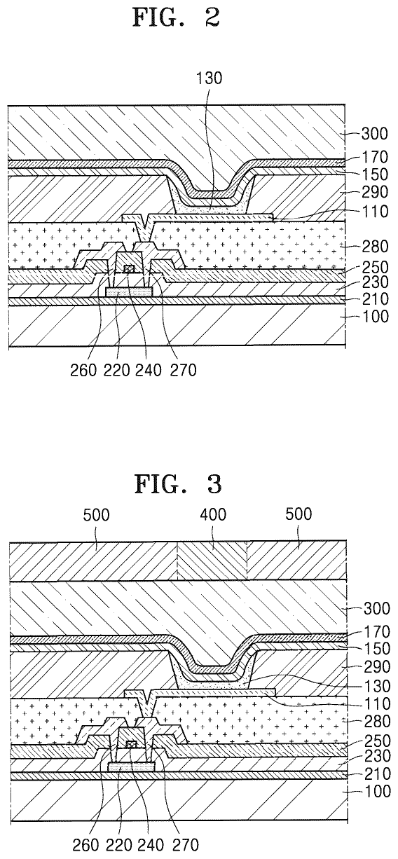

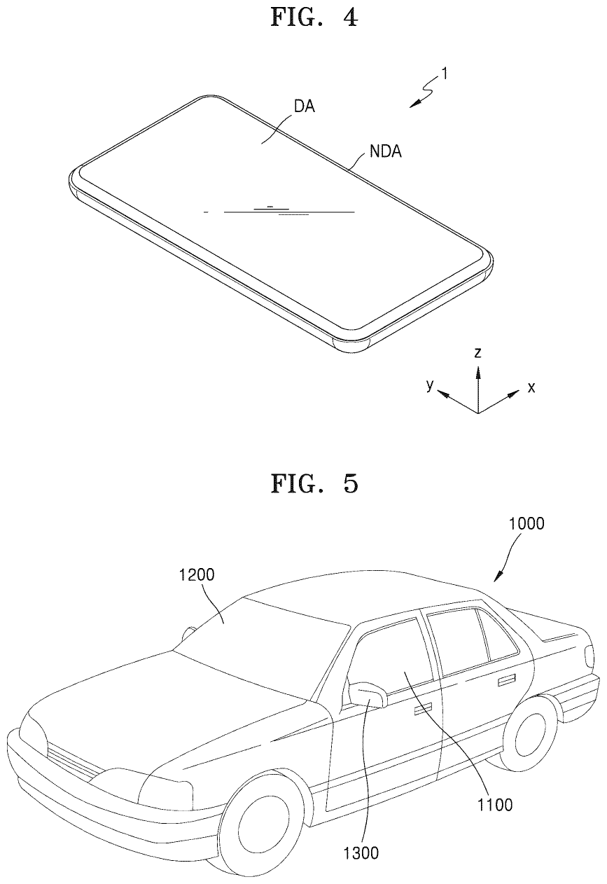

### Description of FIGS. 2 and 3

FIG. 2 is a cross-sectional view of a light-emitting apparatus which is one of electronic apparatuses, according to one or more embodiments.

The light-emitting apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent or reduce penetration of impurities through the substrate 100 and may provide a flat surface on the substrate 100.

A TFT may be arranged on the buffer layer 210. The TFT may include an activation layer 220, a gate electrode 240, a source electrode 260, and a drain electrode 270.

The activation layer 220 may include an inorganic semiconductor, such as silicon or polysilicon, an organic semiconductor, or an oxide semiconductor, and may include a source region, a drain region, and a channel region.

A gate insulating film 230 for insulating the activation layer 220 from the gate electrode 240 may be arranged on the activation layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 and between the gate electrode 240 and the drain electrode 270, to insulate from one another.

The source electrode 260 and the drain electrode 270 may be arranged on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220.

The TFT is electrically connected to a light-emitting device to drive the light-emitting device, and is covered by a passivation layer 280. The passivation layer 280 may include an inorganic insulating film, an organic insulating film, or a combination thereof. A light-emitting device is provided on the passivation layer 280. The light-emitting device may include a first electrode 110, an interlayer 130, and a second electrode 150.

The first electrode 110 may be arranged on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel-defining film 290 including an insulating material may be arranged on the first electrode 110. The pixel-defining film 290 may expose a certain region of the first electrode 110, and the interlayer 130 may be formed in the exposed region of the first electrode 110. The pixel-defining film 290 may be a polyimide-based organic film or a polyacrylic organic film. In one or more embodiments, at least some layers of the interlayer 130 may extend beyond the upper portion of the pixel-defining film 290 to be arranged in the form of a common layer.

A second electrode 150 may be located on the interlayer 130, and a second capping layer 170 may be additionally formed on the second electrode 150. The second capping layer 170 may be formed to cover the second electrode 150.

The encapsulation portion 300 may be located on the second capping layer 170. The encapsulation portion 300 may be located on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE), and/or the like), or any combination thereof; or a combination of the inorganic film and the organic film.

FIG. 3 is a cross-sectional view of a light-emitting apparatus which is one of electronic apparatuses, according to another embodiment.

The light-emitting apparatus of FIG. 3 is the same as the light-emitting apparatus of FIG. 2, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. In one or more embodiments, the light-emitting device included in the light-emitting apparatus of FIG. 3 may be a tandem light-emitting device.

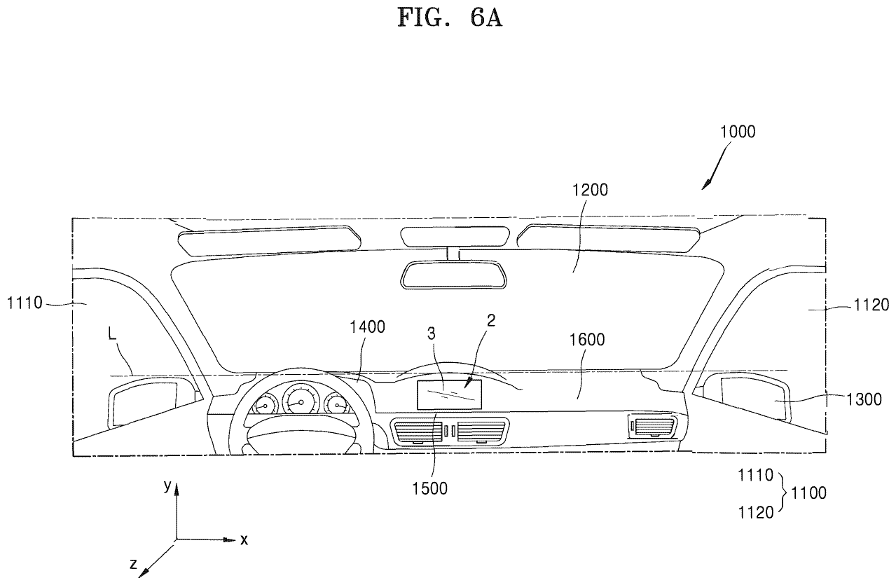

### Description of FIG. 4

FIG. 4 is a schematic perspective view of electronic equipment 1 including a light-emitting device, according to one or more embodiments. The electronic equipment 1 may be an apparatus for displaying a moving image or still image, and may be any product such as a television, a laptop, a monitor, a billboard, or internet of things (IOT), as well as portable electronic equipment such as a mobile phone, a smart phone, a tablet personal computer (PC), a mobile communication terminal, an electronic notebook, an electronic book, and a portable multimedia player (PMP) or navigation, an ultra mobile PC (UMPC), or a part thereof. In some embodiments, the electronic equipment 1 may be a wearable device, such as a smart watch, a watch phone, a glasses-type or kind display, or a head mounted display (HMD), or a part of the wearable device. However, embodiments are not limited thereto. In one or more embodiments, the electronic equipment 1 may be a dashboard of a vehicle, a center information display (CID) arranged on a center fascia or dashboard of a vehicle, a room mirror display instead of a side-view mirror of a vehicle, an entertainment for the back seat of a vehicle, or a display arranged on the back of the front seat of a vehicle, a head up display (HUD) installed on the front of a vehicle or projected on a front window glass, or a computer generated hologram augmented reality head up display (CGH AR HUD). FIG. 4 illustrates a case in which the electronic equipment 1 is a smartphone for convenience of explanation.

The electronic equipment 1 may include a display area DA and a non-display area NDA outside the display area DA. A display apparatus may implement an image through an array of a plurality of pixels that are two-dimensionally arranged in the display area DA.

The non-display area NDA is an area that does not display an image, and may entirely surround the display area DA. On the non-display area NDA, a driver for providing electrical signals or power to display devices arranged on the display area DA may be arranged. On the non-display area NDA, a pad, which is an area to which an electronic element or a printed circuit board, may be electrically connected may be arranged.

In the electronic equipment 1, the length in an x-axis direction and the length in a y-axis direction may be different from each other. In one or more embodiments, as shown in FIG. 4, the length in the x-axis direction may be less than the length in the y-axis direction. In one or more embodiments, the length in the x-axis direction may be the same as the length in the y-axis direction. In one or more embodiments, the length in the x-axis direction may be greater than the length in the y-axis direction.

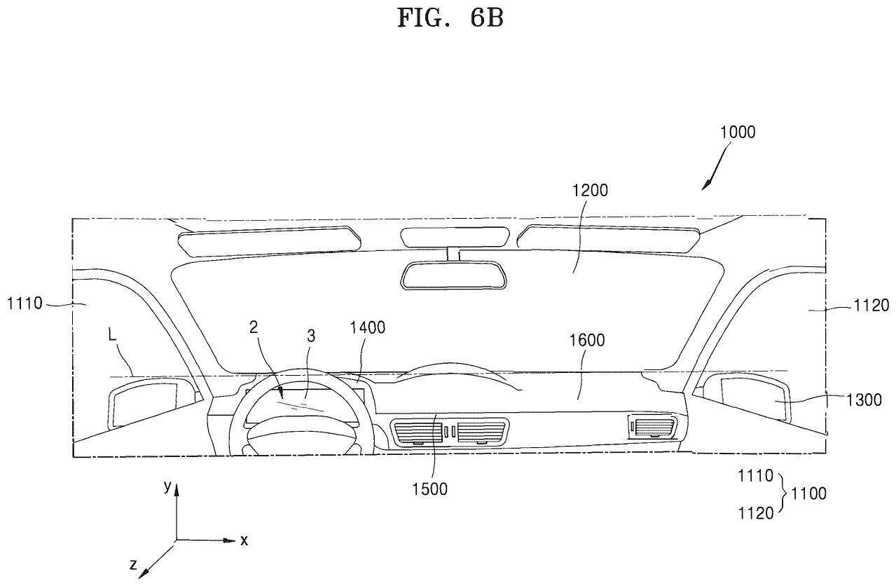

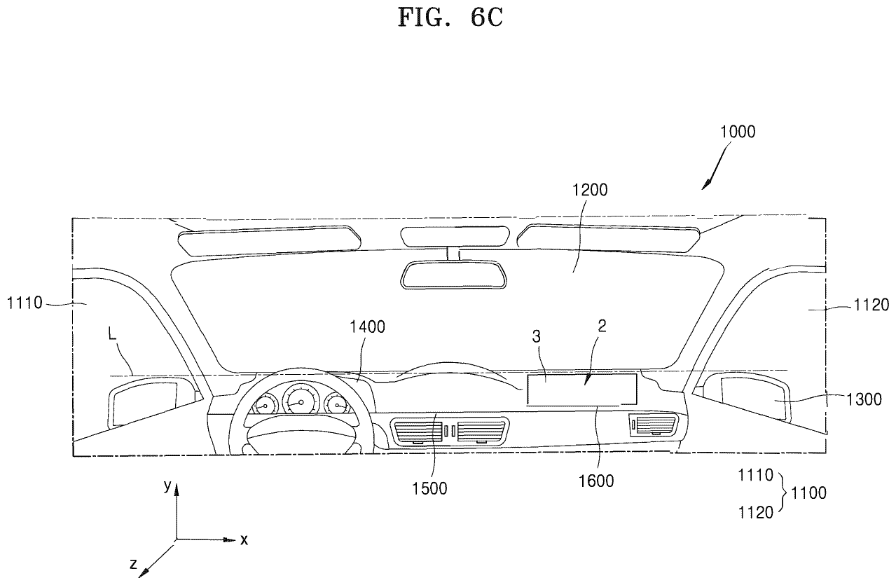

### Descriptions of FIGS. 5 and 6A to 6C

FIG. 5 is a schematic view of the exterior of a vehicle 1000 as electronic equipment including a light-emitting device, according to one or more embodiments. FIGS. 6A to 6C are each a schematic view of the interior of the vehicle 1000 according to one or more embodiments.

Referring to FIGS. 5, 6A, 6B, and 6C, the vehicle 1000 may refer to one or more suitable apparatuses for moving a subject to be transported, such as a human, an object, or an animal, from a departure point to a destination point. The vehicle 1000 may include a vehicle traveling on a road or track, a vessel moving over the sea or river, an airplane flying in the sky utilizing the action of air, and/or the like.

The vehicle 1000 may travel on a road or a track. The vehicle 1000 may move in a certain direction according to rotation of at least one wheel. In one or more embodiments, the vehicle 1000 may include a three-wheeled or four-wheeled vehicle, a construction machine, a two-wheeled vehicle, a prime mover device, a bicycle, and a train running on a track.

The vehicle 1000 may include a vehicle body having an interior and an exterior, and a chassis in which mechanical apparatuses necessary for driving are installed as other parts except for the vehicle body. The exterior of the vehicle body may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side-view mirror 1300, a cluster 1400, a center fascia 1500, a passenger seat dashboard 1600, and a display apparatus 2.

The side window glass 1100 and the front window glass 1200 may be partitioned by a filler arranged between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart from each other in an x direction or a −x direction. In one or more embodiments, the first side window glass 1110 and the second side window glass 1120 may be spaced and/or apart from each other in the x direction or the −x direction. In other words, an imaginary straight line L connecting the side window glasses 1100 may extend in the x direction or the −x direction. In one or more embodiments, an imaginary straight line L connecting the first side window glass 1110 and the second side window glass 1120 to each other may extend in the x direction or the −x direction.

The front window glass 1200 may be installed in front of the vehicle 1000. The front window glass 1200 may be arranged between the side window glasses 1100 facing each other.

The side-view mirror 1300 may provide a rear view of the vehicle 1000. The side-view mirror 1300 may be installed on the exterior of the vehicle body. In one or more embodiments, a plurality of side-view mirrors 1300 may be provided. Any one of the plurality of side-view mirrors 1300 may be arranged outside the first side window glass 1110. The other one of the plurality of side-view mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning lamp, a seat belt warning lamp, an odometer, an automatic shift selector indicator lamp, a door open warning lamp, an engine oil warning lamp, and/or a low fuel warning light.

The center fascia 1500 may include a control panel on which a plurality of buttons for adjusting an audio device, an air conditioning device, and a heater of a seat are provided. The center fascia 1500 may be arranged on one side of the cluster 1400.

The passenger seat dashboard 1600 may be spaced and/or apart from the cluster 1400 with the center fascia 1500 arranged therebetween. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may display an image. The display apparatus 2 may be arranged inside the vehicle 1000. In one or more embodiments, the display apparatus 2 may be arranged between the side window glasses 1100 facing each other. The display apparatus 2 may be arranged on at least one of the cluster 1400, the center fascia 1500, and the passenger seat dashboard 1600.

The display apparatus 2 may include an organic light-emitting display, an inorganic electroluminescent (EL) light-emitting display (inorganic light-emitting display), and a quantum dot display. Hereinafter, an organic light-emitting display including a light-emitting device according to one or more embodiments is described as an example of the display apparatus 2 according to one or more embodiments, but in embodiments, one or more suitable types (kinds) of display apparatuses as described herein may be utilized.

Referring to FIG. 6A, the display apparatus 2 may be arranged on the center fascia 1500. In one or more embodiments, the display apparatus 2 may display navigation information. In one or more embodiments, the display apparatus 2 may display audio, video, or information regarding vehicle settings.

Referring to FIG. 6B, the display apparatus 2 may be arranged on the cluster 1400. In this case, the cluster 1400 may display driving information and/or the like through the display apparatus 2. In other words, the cluster 1400 may be implemented digitally. The digital cluster 1400 may display vehicle information and driving information as images. In one or more embodiments, a needle and a gauge of a tachometer and one or more suitable warning light icons may be displayed by a digital signal.

Referring to FIG. 6C, the display apparatus 2 may be arranged on the passenger seat dashboard 1600. The display apparatus 2 may be embedded in the passenger seat dashboard 1600 or arranged on the passenger seat dashboard 1600. In one or more embodiments, the display apparatus 2 arranged on the passenger seat dashboard 1600 may display an image related to information displayed on the cluster 1400 and/or information displayed on the center fascia 1500. In one or more embodiments, the display apparatus 2 arranged on the passenger seat dashboard 1600 may display information different from information displayed on the cluster 1400 and/or information displayed on the center fascia 1500.

### Manufacturing Method

The layers constituting the hole transport region, the emission layer, and the layers constituting the electron transport region may be formed in a certain region by utilizing one or more suitable methods such as vacuum deposition, spin coating, casting, Langmuir-Blodgett (LB) deposition, ink-jet printing, laser-printing, laser-induced thermal imaging, and/or the like.

When layers constituting the hole transport region, an emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 angstrom per second (Å/sec) to about 100 Å/sec, depending on a material to be included in a layer to be formed and the structure of a layer to be formed.

### Definition of Terms

The term “C₃-C₆₀ carbocyclic group” as utilized herein refers to a cyclic group consisting of carbon only as a ring-forming atom and having three to sixty carbon atoms, and the term “C₁-C₆₀ heterocyclic group” as utilized herein refers to a cyclic group that has one to sixty carbon atoms and further includes, in addition to the carbon atoms, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In one or more embodiments, the number of ring-forming atoms of the C₁-C₆₀ heterocyclic group may be 3 to 61.

The “cyclic group” as utilized herein may include both (e.g., simultaneously) the C₃-C₆₀ carbocyclic group and the C₁-C₆₀ heterocyclic group.

The term “π electron-rich C₃-C₆₀ cyclic group” as utilized herein refers to a cyclic group that has three to sixty carbon atoms and does not include *—N═*′ as a ring-forming moiety, and the term “π electron-deficient nitrogen-containing C₁-C₆₀ heterocyclic group” as utilized herein refers to a heterocyclic group that has one to sixty carbon atoms and includes *—N═*′ as a ring-forming moiety.

In one or more embodiments, the C₃-C₆₀ carbocyclic group may be i) Group T1 or ii) a condensed cyclic group in which two or more of Group T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T₃ and at least one Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ cyclic group may be i) Group T4, ii) a condensed cyclic group in which two or more of Group T4 are condensed with each other, iii) a condensed cyclic group in which at least one Group T₄ and at least one Group T1 are condensed with each other, iv) a condensed cyclic group (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like) in which at least one Group T4 and at least one Group T3 are condensed with each other, or v) a condensed cyclic group in which at least one Group T₄, at least one Group T1, and at least one Group T3 are condensed with one another,
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ heterocyclic group” as utilized herein refers to a group condensed to any cyclic group or a polyvalent group (for example, a divalent group, a trivalent group, a tetravalent group, and/or the like), depending on the structure of a formula in connection with which the terms are utilized. In one or more embodiments, “a benzene group” may be a benzo group, a phenyl group, a phenylene group, and/or the like, which may be easily understood by those of ordinary skill in the art according to the structure of a formula including the “benzene group.”

Depending on context, a divalent group may refer or be a polyvalent group (e.g., trivalent, tetravalent, etc., and not just divalent) per, e.g., the structure of a formula in connection with which of the terms are utilized.

In one or more embodiments, examples of a monovalent C₃-C₆₀ carbocyclic group and a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as utilized herein refers to a linear or branched aliphatic hydrocarbon monovalent group that has one to sixty carbon atoms, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as utilized herein refers to a divalent group having the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as utilized herein refers to a divalent group having the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of the C₂-C₆₀ alkyl group, and examples thereof include an ethynyl group and a propynyl group. The term “C₂-C₆₀ alkynylene group” as utilized herein refers to a divalent group having the same structure as the C₂-C₆₀ alkynyl group.

The term “C₁-C₆₀ alkoxy group” as utilized herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group” as utilized herein refers to a monovalent saturated hydrocarbon cyclic group having three to ten carbon atoms, and examples thereof include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as utilized herein refers to a divalent group having the same structure as the C₃-C₁₀ cycloalkyl group.

The term “C₁-C₁₀ heterocycloalkyl group” as utilized herein refers to a monovalent cyclic group that has one to ten carbon atoms and further includes, in addition to the carbon atoms, at least one heteroatom as a ring-forming atom, and examples thereof include a 1,2,3,4-oxatriazolidinyl group, a tetrahydrofuranyl group, and a tetrahydrothiophenyl group. The term “C₁-C₁₀ heterocycloalkylene group” as utilized herein refers to a divalent group having the same structure as the C₁-C₁₀ heterocycloalkyl group.

The term “C₃-C₁₀ cycloalkenyl group” as utilized herein refers to a monovalent cyclic group that has three to ten carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group” as utilized herein refers to a divalent group having the same structure as the C₃-C₁₀ cycloalkenyl group.

The term “C₁-C₁₀ heterocycloalkenyl group” as utilized herein refers to a monovalent cyclic group that has one to ten carbon atoms, further includes, in addition to the carbon atoms, at least one heteroatom as a ring-forming atom, and has at least one double bond in the ring thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as utilized herein refers to a divalent group having the same structure as the C₁-C₁₀ heterocycloalkenyl group.

The term “C₆-C₆₀ aryl group” as utilized herein refers to a monovalent group having a carbocyclic aromatic system of six to sixty carbon atoms, and the term “C₆-C₆₀ arylene group” as utilized herein refers to a divalent group having a carbocyclic aromatic system of six to sixty carbon atoms. Examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the two or more rings may be condensed with each other.

The term “C₁-C₆₀ heteroaryl group” as utilized herein refers to a monovalent group having a heterocyclic aromatic system that has one to sixty carbon atoms and further includes, in addition to the carbon atoms, at least one heteroatom as a ring-forming atom. The term “C₁-C₆₀ heteroarylene group” as utilized herein refers to a divalent group having a heterocyclic aromatic system that has one to sixty carbon atoms and further includes, in addition to the carbon atoms, at least one heteroatom as a ring-forming atom. Examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the two or more rings may be condensed with each other.

The term “monovalent non-aromatic condensed polycyclic group” as utilized herein refers to a monovalent group having two or more rings condensed with each other, only carbon atoms (for example, eight to sixty carbon atoms) as ring-forming atoms, and no aromaticity in its molecular structure when considered as a whole. Examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as utilized herein refers to a divalent group having the same structure as the monovalent non-aromatic condensed polycyclic group.

The term “monovalent non-aromatic condensed heteropolycyclic group” as utilized herein refers to a monovalent group that has two or more rings condensed with each other, further includes, in addition to carbon atoms (for example, one to sixty carbon atoms), at least one heteroatom as a ring-forming atom, and has no aromaticity in its molecular structure when considered as a whole. Examples of the monovalent non-aromatic condensed heteropolycyclic group include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as utilized herein refers to a divalent group having the same structure as the monovalent non-aromatic condensed heteropolycyclic group.

The term “C₆-C₆₀ aryloxy group” as utilized herein indicates —OA₁₀₂ (wherein A₁₀₂ is the C₆-C₆₀ aryl group), and the term “C₆-C₆₀ arylthio group” as utilized herein indicates —SA₁₀₃ (wherein A₁₀₃ is the C₆-C₆₀ aryl group).

The term “C₇-C₆₀ arylalkyl group” as utilized herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as utilized herein refers to -A₁₀₆A₁₀₇ (wherein A₁₀₆ is a C₁-C₅₉ alkylene group, and A₁₀₇ is a C₁-C₅₉ heteroaryl group).

R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂—C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ as utilized herein may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as utilized herein refers to any atom other than a carbon atom. Examples of the heteroatom include O, S, N, P, Si, B, Ge, Se, or any combination thereof.

The term “transition metal” as utilized herein includes hafnium (Hf), tantalum (Ta), tungsten (W), rhenium (Re), osmium (Os), iridium (Ir), platinum (Pt), and gold (Au).

The term “Ph” as utilized herein refers to a phenyl group, the term “Me” as utilized herein refers to a methyl group, the term “Et” as utilized herein refers to an ethyl group, the term “ter-Bu” or “Bu^{t}” as utilized herein refers to a tert-butyl group, and the term “OMe” as utilized herein refers to a methoxy group.

The term “biphenyl group” as utilized herein refers to “a phenyl group that is substituted with a phenyl group.” In other words, the “biphenyl group” is a substituted phenyl group having a C₆-C₆₀ aryl group as a substituent.

The term “terphenyl group” as utilized herein refers to “a phenyl group that is substituted with a biphenyl group”. The “terphenyl group” is a substituted phenyl group having, as a substituent, a C₆-C₆₀ aryl group that is substituted with a C₆-C₆₀ aryl group.

*, *′, and *″ as utilized herein, unless defined otherwise, each refer to a binding site to a neighboring atom in a corresponding formula or moiety.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinafter, a compound and light-emitting device according to one or more embodiments will be described in more detail with reference to the following Synthesis example and Examples. The wording “B was utilized instead of A,” utilized in describing Synthesis Examples, indicates that an identical molar equivalent of B was utilized in place of A.

### EXAMPLES

### Synthesis Example 1: Synthesis of Compound 14

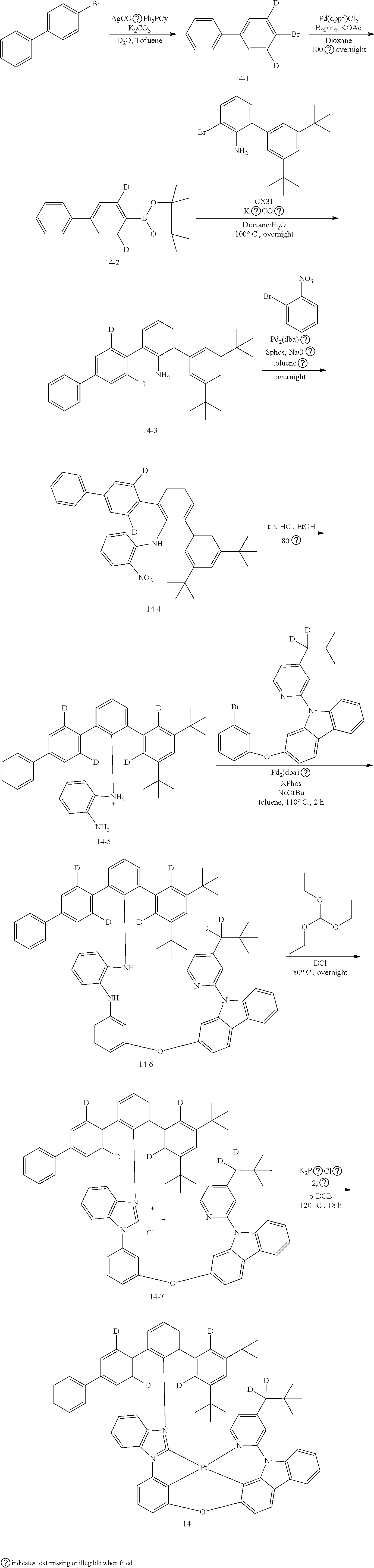

### Synthesis of Intermediate 14-1

4-bromo-1,1′-biphenyl (1.0 eq), silver carbonate (Ag₂CO₃, 0.2 eq), cyclohexyldiphenylphosphine (Ph₂PCy, 0.5 eq), K₂CO₃ (1 eq), and deuterium oxide (D₂O, 20 eq) were dissolved in toluene under a nitrogen atmosphere, stirred at 120° C. for 24 hours, cooled to room temperature, and then subjected to quenching by utilizing ammonium chloride (NH₃Cl). Next, a solvent was removed by distillation under reduced pressure at a pressure of 8 millibar (mbar), an organic layer obtained as a result of performing an extraction process three times utilizing methylene chloride (MC) and water was dried by utilizing magnesium sulfate, and then concentration and column chromatography (only n-hexane) was performed, to synthesize Intermediate 14-1 (yield: 94%).

### Synthesis of Intermediate 14-2

Intermediate 14-1 (1.0 eq), bis(diphenylphosphino)ferrocene dichloropalladium (0.05 eq), bis(pinacolato)diboron (1.5 eq), and potassium acetate (3 eq) were dissolved in 1,4-dioxane, stirred at 100° C. for 24 hours, and then cooled to room temperature. Next, a solvent was removed by distillation under reduced pressure at a pressure of 8 mbar, an organic layer obtained as a result of performing an extraction process three times utilizing MC and water was dried by utilizing magnesium sulfate, and then concentration and column chromatography (MC:hexane) was performed, to synthesize Intermediate 14-2 (yield: 87%).

### Synthesis of Intermediate 14-3

Intermediate 14-2 (1.0 eq), CX31 Umicore (0.05 eq), 3-bromo-3′,5′-di-tert-butyl-[1,1′-biphenyl]-2-amine (1.5 eq), and potassium acetate (3 eq) were dissolved in a mixture of 1,4-dioxane and H₂O (a volume ratio of 3:1), stirred at 100° C. for 24 hours, and then cooled to room temperature. Next, a solvent was removed by distillation under reduced pressure at a pressure of 8 mbar, an organic layer obtained as a result of performing an extraction process three times utilizing MC and water was dried by utilizing magnesium sulfate, and then concentration and column chromatography (MC:hexane) was performed, to synthesize Intermediate 14-3 (yield: 76%).

### Synthesis of Intermediate 14-4

Intermediate 14-3 (1.0 eq), 1-bromo-2-nitrobenzene (2 eq), 2-dicyclohexylphosphino-2′,6′-dimethoxybiphenyl (Sphos, 0.10 eq), tris(dibenzylideneacetone)dipalladium (0) (Pd₂(dba)₃, 0.05 eq), and sodium tert-butoxide (NaOtBu, 3 eq) were dissolved in toluene, stirred at 110° C. for 24 hours, and then cooled to room temperature. Next, a solvent was removed by distillation under reduced pressure at a pressure of 8 mbar, an organic layer obtained as a result of performing an extraction process three times utilizing MC and water was dried by utilizing magnesium sulfate, and then concentration and column chromatography (MC:hexane) was performed, to synthesize Intermediate 14-4 (yield: 78%).

### Synthesis of Intermediate 14-5

Intermediate 14-4 (1.0 eq) and tin (5 eq) were dissolved in ethanol (EtOH) and then stirred. Hydrogen chloride (12 M) was injected to a mixture obtained therefrom, stirred at 80° C. for 6 hours, and then cooled to room temperature. Next, a solvent was removed by distillation under reduced pressure at a pressure of 8 mbar, an organic layer obtained as a result of performing an extraction process three times utilizing MC and water was dried by utilizing magnesium sulfate, and then concentration and column chromatography (MC:hexane) was performed, to synthesize Intermediate 14-5 (yield: 81%).

### Synthesis of Intermediate 14-6

Intermediate 14-5 (1.0 eq), 2-(3-bromophenoxy)-9-(4-(2,2-dimethylpropyl-1,1-d2)pyridin-2-yl)-9H-carbazole (1.0 eq), tris(dibenzylideneacetone)dipalladium(0) (Pd₂(dba)₃) (0.05 eq), 2-dicyclohexylphosphino-2′,4′,6′-triisopropylbiphenyl (Xphos) (0.10 eq), and sodium tert-butoxide (2.0 eq) were dissolved in toluene (0.1 M), stirred at 110° C. for 2 hours, and then cooled to room temperature. Next, a solvent was removed by distillation under reduced pressure at a pressure of 8 mbar, an organic layer obtained as a result of performing an extraction process three times utilizing MC and water was dried by utilizing magnesium sulfate, and then concentration and column chromatography (MC:hexane) was performed, to synthesize Intermediate 14-6 (yield: 77%).

### Synthesis of Intermediate 14-7

Intermediate 14-6 (1.0 eq) was dissolved in triethyl orthoformate (30 eq), and 37% DCI (1.5 eq) was added thereto, stirred at 80° C. for 24 hours, and then cooled to room temperature, to concentrate and remove triethyl orthoformate. Next, an organic layer obtained as a result of performing an extraction process three times utilizing MC and water was dried by utilizing magnesium sulfate, and concentration and column chromatography MC:methanol) was performed, to synthesize Intermediate 14-7 (yield: 85%).

### Synthesis of Compound 14

Intermediate 14-7 (1.0 eq), potassium platinum (II) chloride (1.1 eq), and 2,6-lutidine (4.0 eq) were dissolved in 1,2-dichlorobenzene (0.05 M), stirred at 120° C. for 18 hours under a nitrogen condition, and then cooled to room temperature, to concentrate and remove 1,2-dichlorobenzene. Next, an organic layer obtained as a result of performing an extraction process three times utilizing dichloromethane and water was dried by utilizing magnesium sulfate, and concentration and column chromatography MC:hexane) was performed, to synthesize Compound 14 (yield: 51

ESI-LCMS for Compound 14: [M]+: C₆₇H₅₄D₆N₄OPt, 1138.4

### Synthesis Example 2: Synthesis of Compound 54

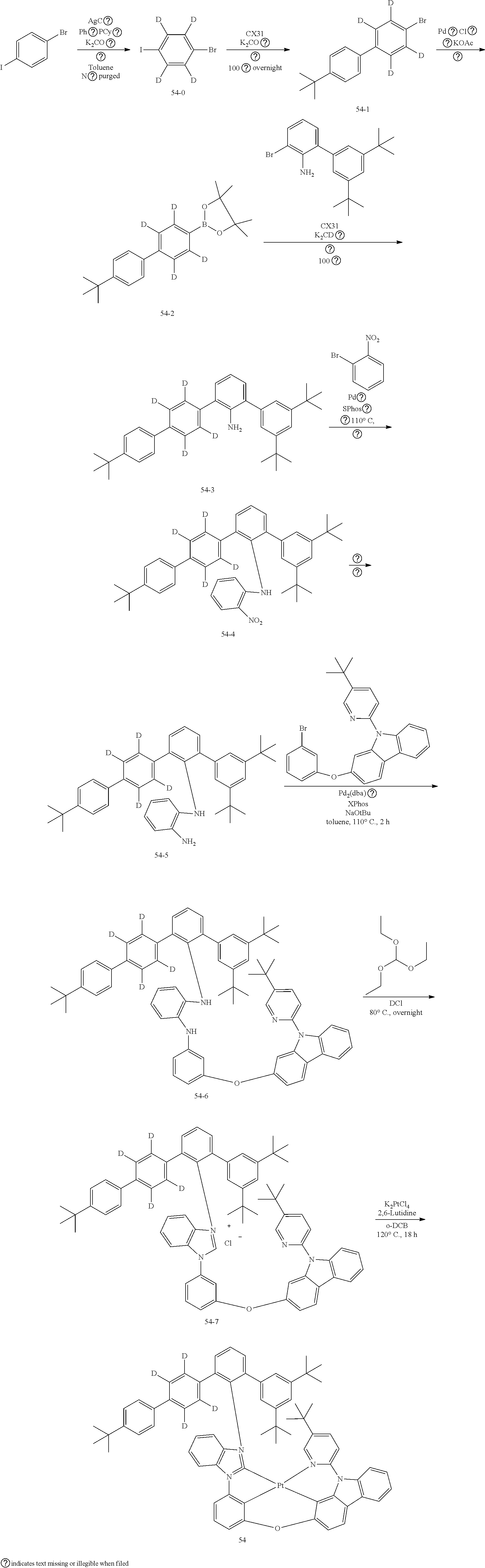

### Synthesis of Intermediate 54-0

Intermediate 54-0 was synthesized in substantially the same manner as utilized to synthesize Intermediate 14-1 of Synthesis Example 1, except that 1-bromo-4-iodobenzene was utilized instead of 4-bromo-1,1′-biphenyl.

### Synthesis of Intermediate 54-1

Intermediate 54-1 was synthesized in substantially the same manner as utilized to synthesize Intermediate 14-3 of Synthesis Example 1, except that Intermediate 54-0 and 1-bromo-4-(tert-butyl)benzene were respectively utilized instead of Intermediate 14-2 and 3-bromo-3′,5′-di-tert-butyl-[1,1′-biphenyl]-2-amine.

### Synthesis of Intermediates 54-2, 54-3, 54-4, and 54-5

Intermediates 54-2, 54-3, 54-4, and 54-5 were sequentially synthesized in substantially the same manner as utilized to sequentially synthesize Intermediates 14-2, 14-3, 14-4, and 14-5 of Synthesis Example 1, except that Intermediates 54-1, 54-2, 54-3, and 54-4 were respectively utilized instead of Intermediates 14-1, 14-2, 14-3, and 14-4.

### Synthesis of Intermediate 54-6

Intermediate 54-6 was synthesized in substantially the same manner as utilized to synthesize Intermediate 14-6 of Synthesis Example 1, except that Intermediate 54-5 and 2-(3-bromophenoxy)-9-(5-(tert-butyl)pyridin-2-yl)-9H-carbazole were respectively utilized instead of Intermediate 14-5 and 2-(3-bromophenoxy)-9-(4-(2,2-dimethylpropyl-1,1-d2)pyridin-2-yl)-9H-carbazole.

### Synthesis of Intermediate 54-7

Intermediate 54-7 was synthesized in substantially the same manner as utilized to synthesize Intermediate 14-7 of Synthesis Example 1, except that Intermediate 54-6 was utilized instead of Intermediate 14-6.

### Synthesis of Compound 54

Compound 54 (yield: 54%) was synthesized in substantially the same manner as utilized to synthesize Compound 14 of Synthesis Example 1, except that Intermediate 54-7 was utilized instead of Intermediate 14-7.

ESI-LCMS for Compound 54: [M]+: C₇₀H₆₂D₄N₄OPt, 1178.5

### Synthesis Example 3: Synthesis of Compound 197

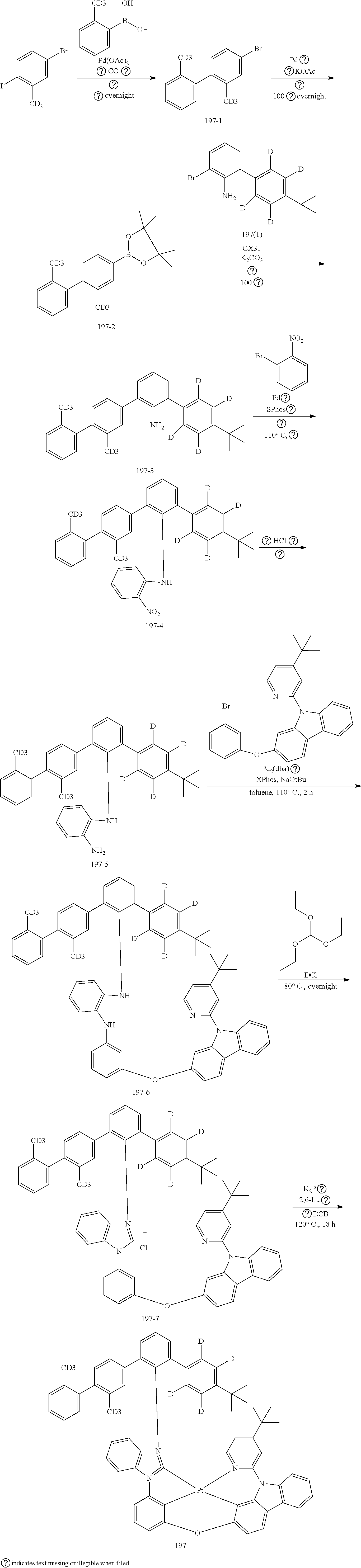

### Synthesis of Intermediate 197-1

4-bromo-1-iodo-2-(methyl-d3)benzene (1.0 eq), (2-(methyl-d3)phenyl)boronic acid (1.2 eq), Pd(OAC)₂ (5 mol %), PPh₃ (10 mol %), and Na₂CO₃ (2.0 eq) were dissolved in a mixture of acetone and H₂O (a volume ratio of 1:3, 0.1 M), and then stirred at 60° C. for 24 hours, and then cooled to room temperature. Next, a solvent was removed by distillation under reduced pressure at a pressure of 8 mbar, an organic layer obtained as a result of performing an extraction process three times utilizing MC and water was dried by utilizing magnesium sulfate, and then concentration and column chromatography (only n-hexane) was performed, to synthesize Intermediate 197-1 (yield: 73%).

### Synthesis of Intermediate 197-2

Intermediate 197-2 was synthesized in substantially the same manner as utilized to synthesize Intermediate 14-2 of Synthesis Example 1, except that Intermediate 197-1 was utilized instead of Intermediate 14-1.

### Synthesis of Intermediate 197-3

Intermediate 197-3 was synthesized in substantially the same manner as utilized to synthesize Intermediate 14-3 of Synthesis Example 1, except that Intermediate 197-2 and Compound 197(1) were utilized instead of Intermediate 14-2 and 3-bromo-3′,5′-di-tert-butyl-[1,1′-biphenyl]-2-amine.

### Synthesis of Intermediates 197-4 and 197-5

Intermediates 197-4 and 197-5 were sequentially synthesized in substantially the same manner as utilized to sequentially synthesize Intermediates 14-4 and 14-5 of Synthesis Example 1, except that Intermediates 197-3 and 197-4 were respectively utilized instead of Intermediates 14-3 and 14-4.

### Synthesis of Intermediate 197-6

Intermediate 197-6 was synthesized in substantially the same manner as utilized to synthesize Intermediate 14-6 of Synthesis Example 1, except that Intermediate 197-5 and 2-(3-bromophenoxy)-9-(4-(tert-butyl)pyridin-2-yl)-9H-carbazole were respectively utilized instead of Intermediate 14-5 and 2-(3-bromophenoxy)-9-(4-(2,2-dimethylpropyl-1,1-d2)pyridin-2-yl)-9H-carbazole.

### Synthesis of Intermediate 197-7

Intermediate 197-7 was synthesized in substantially the same manner as utilized to synthesize Intermediate 14-7 of Synthesis Example 1, except that Intermediate 197-6 was utilized instead of Intermediate 14-6.

### Synthesis of Compound 197

Compound 197 (yield: 50%) was synthesized in substantially the same manner as utilized to synthesize Compound 14 of Synthesis Example 1, except that Intermediate 197-7 was utilized instead of Intermediate 14-7.

ESI-LCMS for Compound 197: [M]+: C₆₄H₄₄D₁₀N₄OPt, 1100.4

### Synthesis Example 4: Synthesis of Compound 219

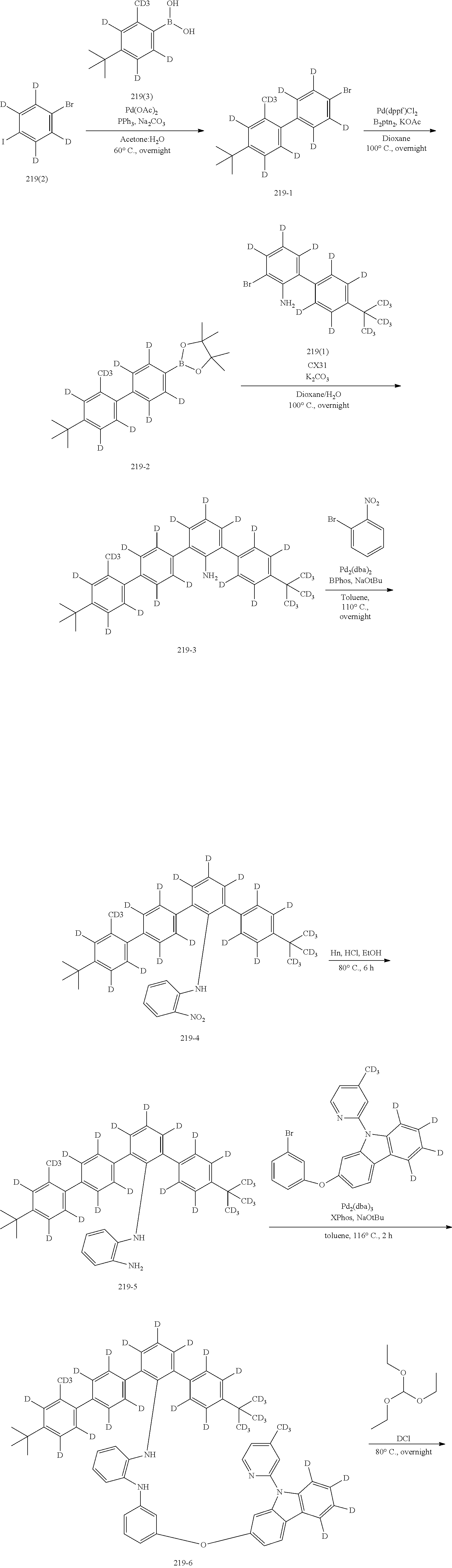

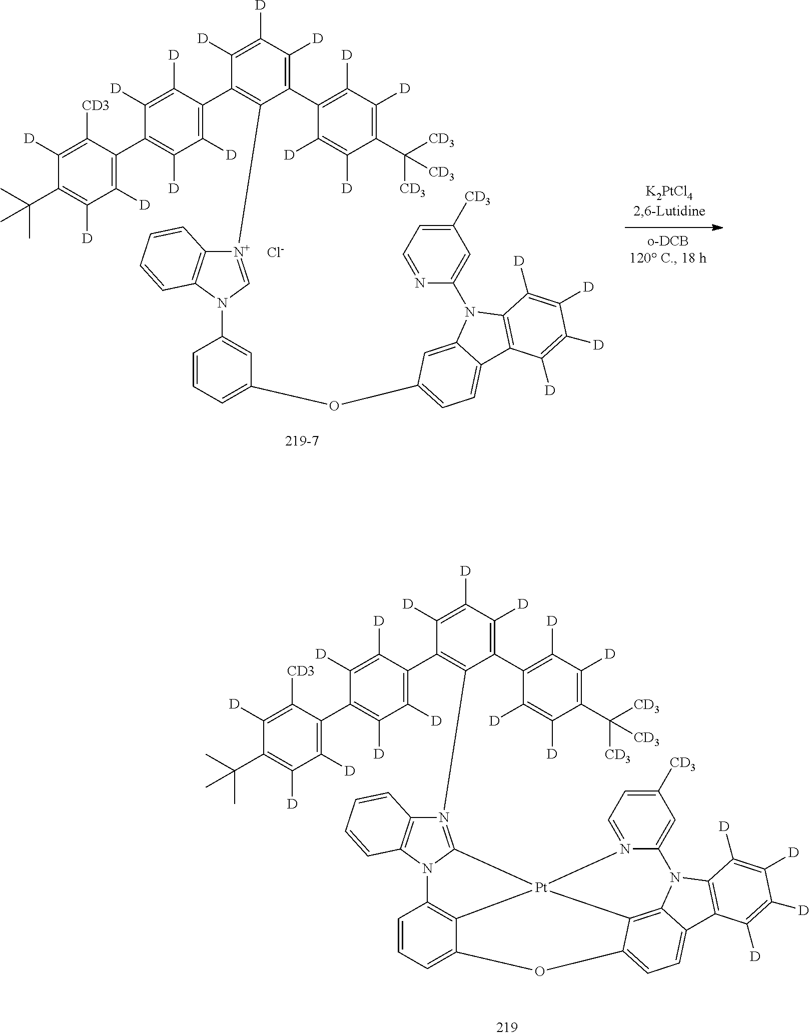

### Synthesis of Intermediate 219-1

Intermediate 219-1 was synthesized in substantially the same manner as utilized to synthesize Intermediate 197-1 of Synthesis Example 3, except that Compound 219(2) and Compound 219(3) were respectively utilized instead of 4-bromo-1-iodo-2-(methyl-d₃)benzene and (2-(methyl-d3)phenyl)boronic acid.

### Synthesis of Intermediate 219-2

Intermediate 219-2 was synthesized in substantially the same manner as utilized to synthesize Intermediate 14-2 of Synthesis Example 1, except that Intermediate 219-1 was utilized instead of Intermediate 14-1.

### Synthesis of Intermediate 219-3

Intermediate 219-3 was synthesized in substantially the same manner as utilized to synthesize Intermediate 14-3 of Synthesis Example 1, except that Intermediate 219-2 and Compound 219(1) were utilized instead of Intermediate 14-2 and 3-bromo-3′,5′-di-tert-butyl-[1,1′-biphenyl]-2-amine.

### Synthesis of Intermediates 219-4 and 219-5

Intermediates 219-4 and 219-5 were sequentially synthesized in substantially the same manner as utilized to sequentially synthesize Intermediates 14-4 and 14-5 of Synthesis Example 1, except that Intermediates 219-3 and 219-4 were respectively utilized instead of Intermediates 14-3 and 14-4.

### Synthesis of Intermediate 219-6

Intermediate 219-6 was synthesized in substantially the same manner as utilized to synthesize Intermediate 14-6 of Synthesis Example 1, except that Intermediate 219-5 and 2-(3-bromophenoxy)-9-(4-(methyl-d3)pyridin-2-yl)-9H-carbazole-5,6,7,8-d4 were respectively utilized instead of Intermediate 14-5 and 2-(3-bromophenoxy)-9-(4-(2,2-dimethylpropyl-1,1-d2)pyridin-2-yl)-9H-carbazole.

### Synthesis of Intermediate 219-7

Intermediate 219-7 was synthesized in substantially the same manner as utilized to synthesize Intermediate 14-7 of Synthesis Example 1, except that Intermediate 219-6 was utilized instead of Intermediate 14-6. Synthesis of Compound 219

Compound 219 (yield: 53%) was synthesized in substantially the same manner as utilized to synthesize Compound 14 of Synthesis Example 1, except that Intermediate 219-7 was utilized instead of Intermediate 14-7.

ESI-LCMS for Compound 219: [M]+: C₆₄H₂₁D₃₃N₄OPt, 1123.5

### Synthesis Example 5: Synthesis of Compound 281

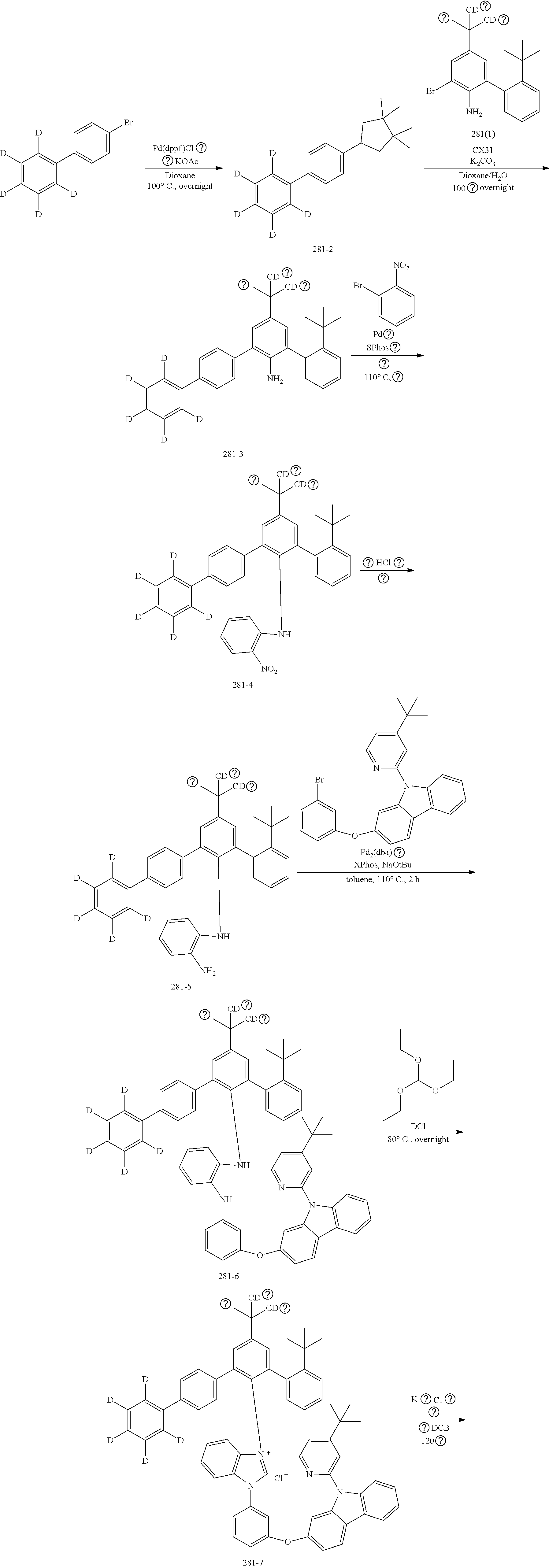

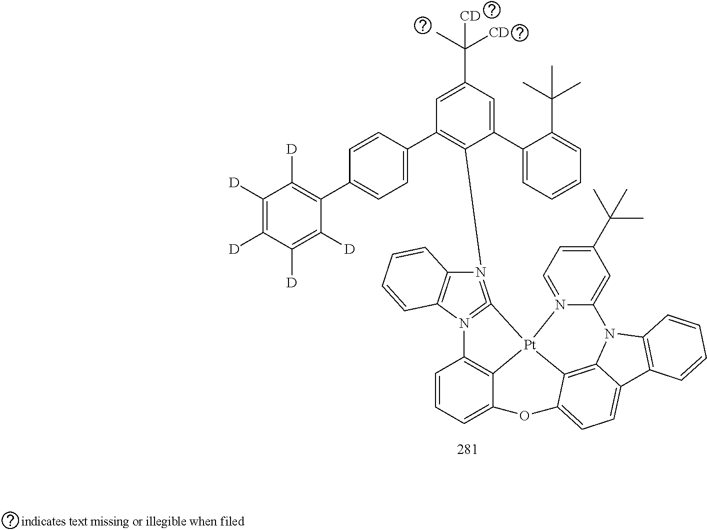

### Synthesis of Intermediate 281-2

Intermediate 281-2 was synthesized in substantially the same manner as utilized to synthesize Intermediate 14-2 of Synthesis Example 1, except that Compound 4-bromo-1,1′-biphenyl-2′,3′,4′,5′,6′-d5 was utilized instead of Intermediate 14-1.

### Synthesis of Intermediate 281-3

Intermediate 281-3 was synthesized in substantially the same manner as utilized to synthesize Intermediate 14-3 of Synthesis Example 1, except that Intermediate 281-2 and Compound 281(1) were utilized instead of Intermediate 14-2 and 3-bromo-3′,5′-di-tert-butyl-[1,1′-biphenyl]-2-amine.

### Synthesis of Intermediates 281-4 and 281-5

Intermediates 281-4 and 281-5 were sequentially synthesized in substantially the same manner as utilized to sequentially synthesize Intermediates 14-4 and 14-5 of Synthesis Example 1, except that Intermediates 281-3 and 281-4 were respectively utilized instead of Intermediates 14-3 and 14-4.

### Synthesis of Intermediate 281-6

Intermediate 281-6 was synthesized in substantially the same manner as utilized to synthesize Intermediate 14-6 of Synthesis Example 1, except that Intermediate 281-5 and 2-(3-bromophenoxy)-9-(4-(tert-butyl)pyridin-2-yl)-9H-carbazole were respectively utilized instead of Intermediate 14-5 and 2-(3-bromophenoxy)-9-(4-(2,2-dimethylpropyl-1,1-d2)pyridin-2-yl)-9H-carbazole.

### Synthesis of Intermediate 281-7

Intermediate 281-7 was synthesized in substantially the same manner as utilized to synthesize Intermediate 14-7 of Synthesis Example 1, except that Intermediate 281-6 was utilized instead of Intermediate 14-6.

### Synthesis of Compound 281

Compound 281 (yield: 56%) was synthesized in substantially the same manner as utilized to synthesize Compound 14 of Synthesis Example 1, except that Intermediate 281-7 was utilized instead of Intermediate 14-7.

ESI-LCMS for Compound 281: [M]+: C₆₆H₄₄D₁₄N₄OPt, 1132.5

### Synthesis Example 6: Synthesis of Compound 299

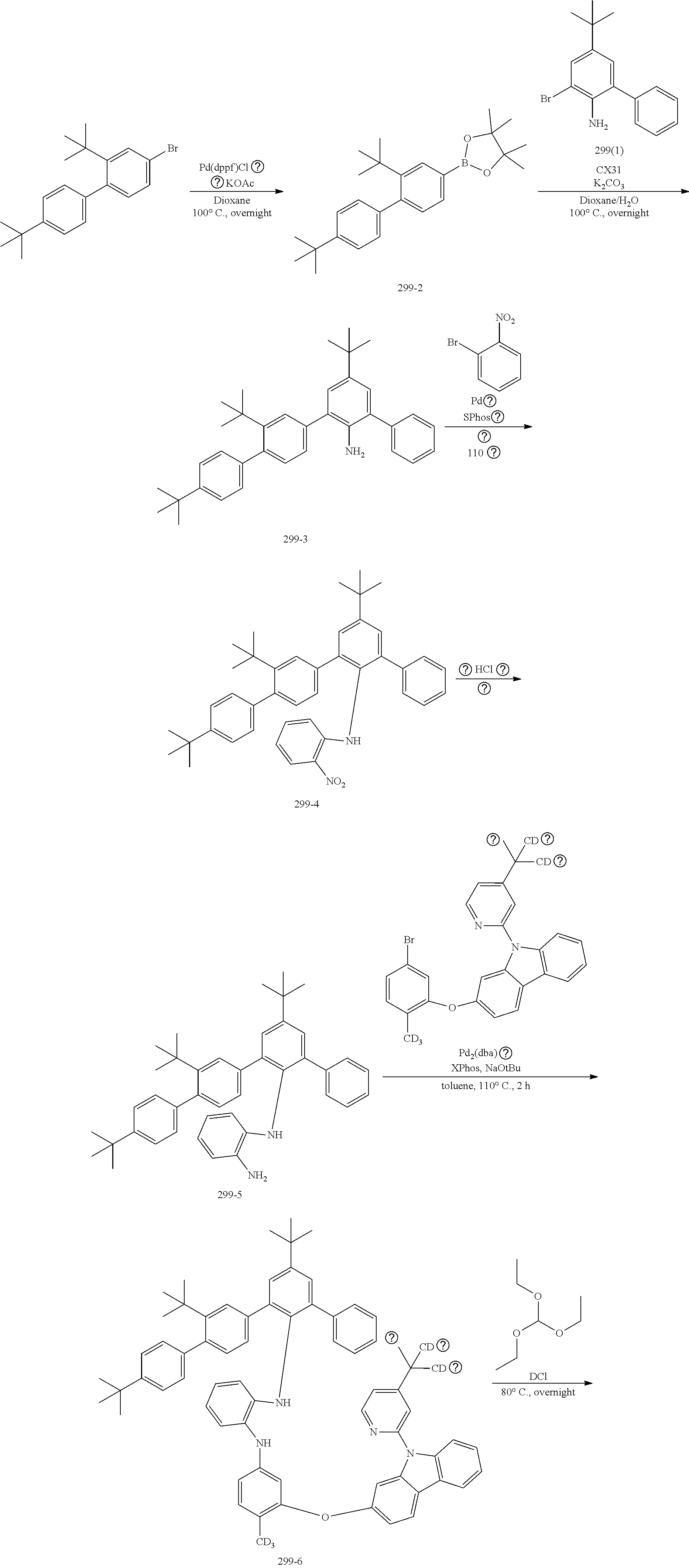

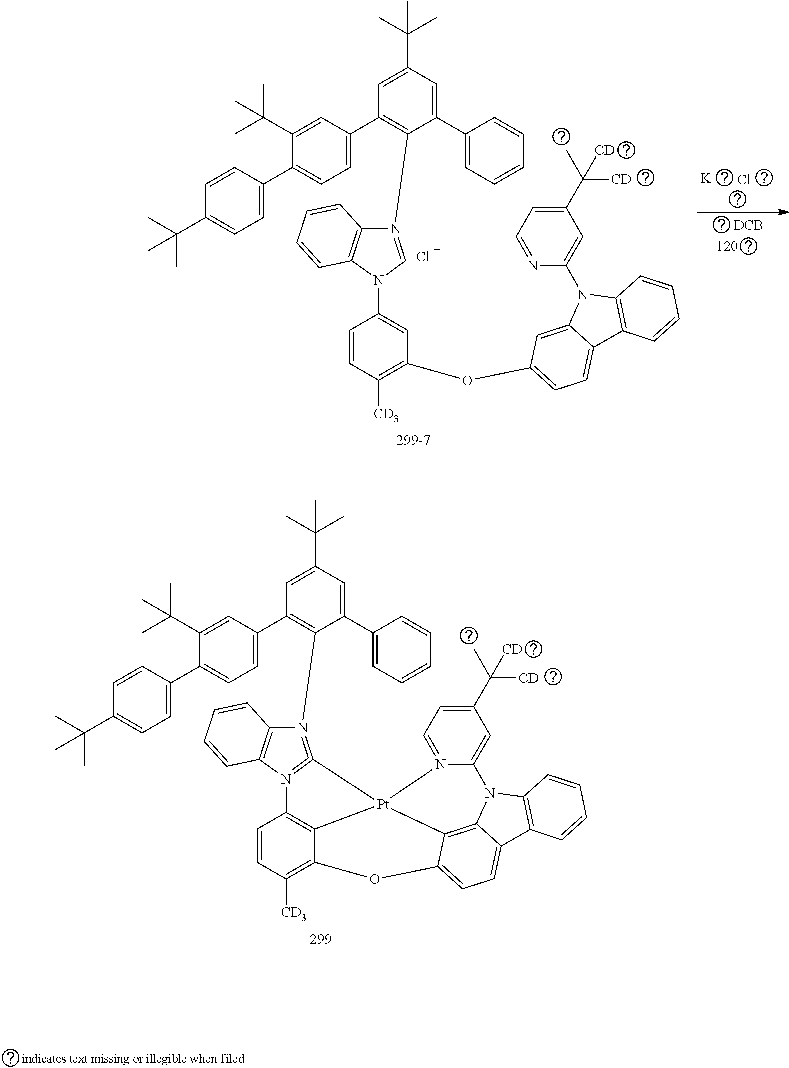

### Synthesis of Intermediate 299-2

Intermediate 299-2 was synthesized in substantially the same manner as utilized to synthesize Intermediate 14-2 of Synthesis Example 1, except that Compound 4-bromo-2,4′-di-tert-butyl-1,1′-biphenyl was utilized instead of Intermediate 14-1.

### Synthesis of Intermediate 299-3

Intermediate 299-3 was synthesized in substantially the same manner as utilized to synthesize Intermediate 14-3 of Synthesis Example 1, except that Intermediate 281-2 and Compound 299(1) were utilized instead of Intermediate 14-2 and 3-bromo-3′,5′-di-tert-butyl-[1,1′-biphenyl]-2-amine.

### Synthesis of Intermediates 299-4 and 299-5

Intermediates 299-4 and 299-5 were sequentially synthesized in substantially the same manner as utilized to sequentially synthesize Intermediates 14-4 and 14-5 of Synthesis Example 1, except that Intermediates 299-3 and 299-4 were respectively utilized instead of Intermediates 14-3 and 14-4.

### Synthesis of Intermediate 299-6

Intermediate 299-6 was synthesized in substantially the same manner as utilized to synthesize Intermediate 14-6 of Synthesis Example 1, except that Intermediate 299-5 and 2-(5-bromo-2-(methyl-d3)phenoxy)-9-(4-(2-(methyl-d3)propan-2-yl-1,1,1,3,3,3-d₆)pyridin-2-yl)-9H-carbazole were respectively utilized instead of Intermediate 14-5 and 2-(3-bromophenoxy)-9-(4-(2,2-dimethylpropyl-1,1-d2)pyridin-2-yl)-9H-carbazole.

### Synthesis of Intermediate 299-7

Intermediate 299-7 was synthesized in substantially the same manner as utilized to synthesize Intermediate 14-7 of Synthesis Example 1, except that Intermediate 299-6 was utilized instead of Intermediate 14-6.

### Synthesis of Compound 299

Compound 299 (yield: 48%) was synthesized in substantially the same manner as utilized to synthesize Compound 14 of Synthesis Example 1, except that Intermediate 299-7 was utilized instead of Intermediate 14-7.

ESI-LCMS for Compound 299: [M]+: C₇₁H₅₆D₁₂N₄OPt, 1200.6

### Synthesis Example 7: Synthesis of Compound 1

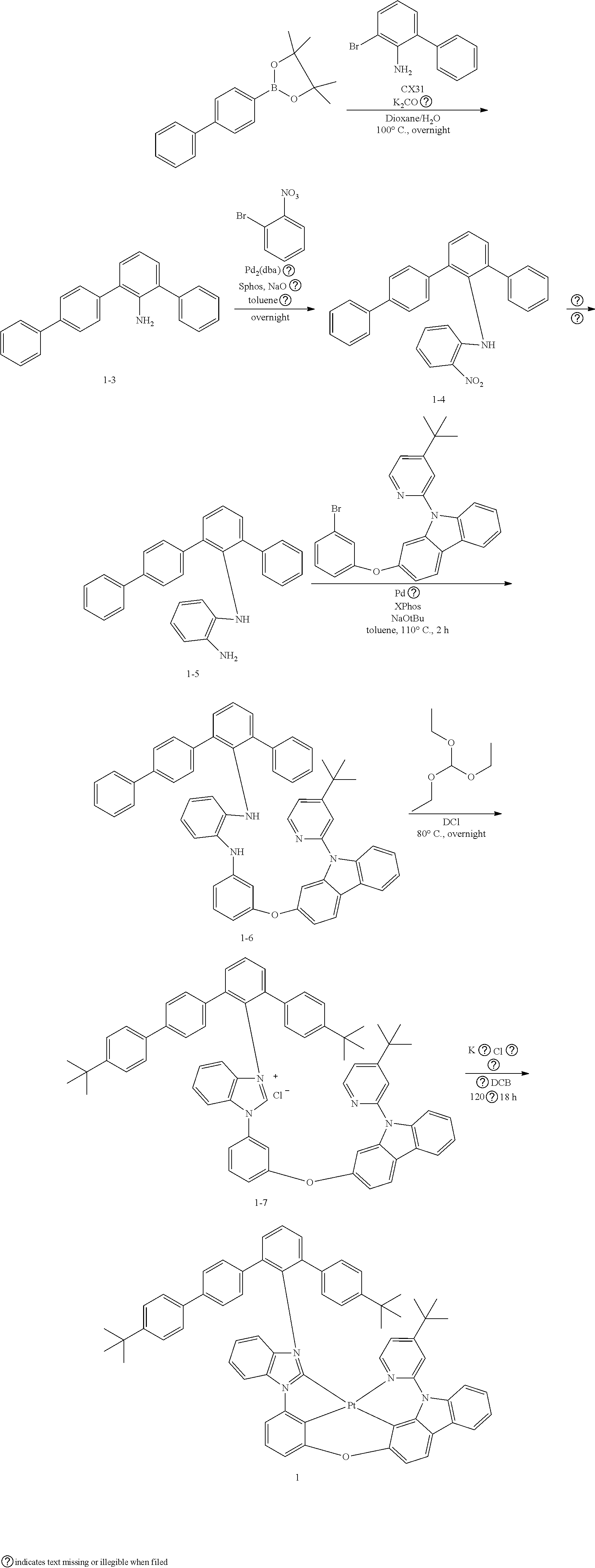

### Synthesis of Intermediate 1-3

Intermediate 1-3 was synthesized in substantially the same manner as utilized to synthesize Intermediate 14-3 of Synthesis Example 1, except that 2-([1,1′-biphenyl]-4-yl)-4,4,5,5-tetramethyl-1,3,2-dioxaborolane and 3-bromo-[1,1′-biphenyl]-2-amine were utilized instead of Intermediate 14-2 and 3-bromo-3′,5′-di-tert-butyl-[1,1′-biphenyl]-2-amine.

### Synthesis of Intermediates 1-4 and 1-5

Intermediates 1-4 and 1-5 were sequentially synthesized in substantially the same manner as utilized to sequentially synthesize Intermediates 14-4 and 14-5 of Synthesis Example 1, except that Intermediates 1-3 and 1-4 were respectively utilized instead of Intermediates 14-3 and 14-4.

### Synthesis of Intermediate 1-6

Intermediate 1-6 was synthesized in substantially the same manner as utilized to synthesize Intermediate 14-6 of Synthesis Example 1, except that Intermediate 1-5 and 2-(3-bromophenoxy)-9-(4-(tert-butyl)pyridin-2-yl)-9H-carbazole were respectively utilized instead of Intermediate 14-5 and 2-(3-bromophenoxy)-9-(4-(2,2-dimethylpropyl-1,1-d2)pyridin-2-yl)-9H-carbazole.

### Synthesis of Intermediate 1-7

Intermediate 1-7 was synthesized in substantially the same manner as utilized to synthesize Intermediate 14-7 of Synthesis Example 1, except that Intermediate 1-6 was utilized instead of Intermediate 14-6.

### Synthesis of Compound 1

Compound 1 (yield: 59%) was synthesized in substantially the same manner as utilized to synthesize Compound 14 of Synthesis Example 1, except that Intermediate 1-7 was utilized instead of Intermediate 14-7.

ESI-LCMS for Compound 1: [M]+: C₅₈H₄₂N₄OPt, 1006.1

### Synthesis Example 8: Synthesis of Compound 337

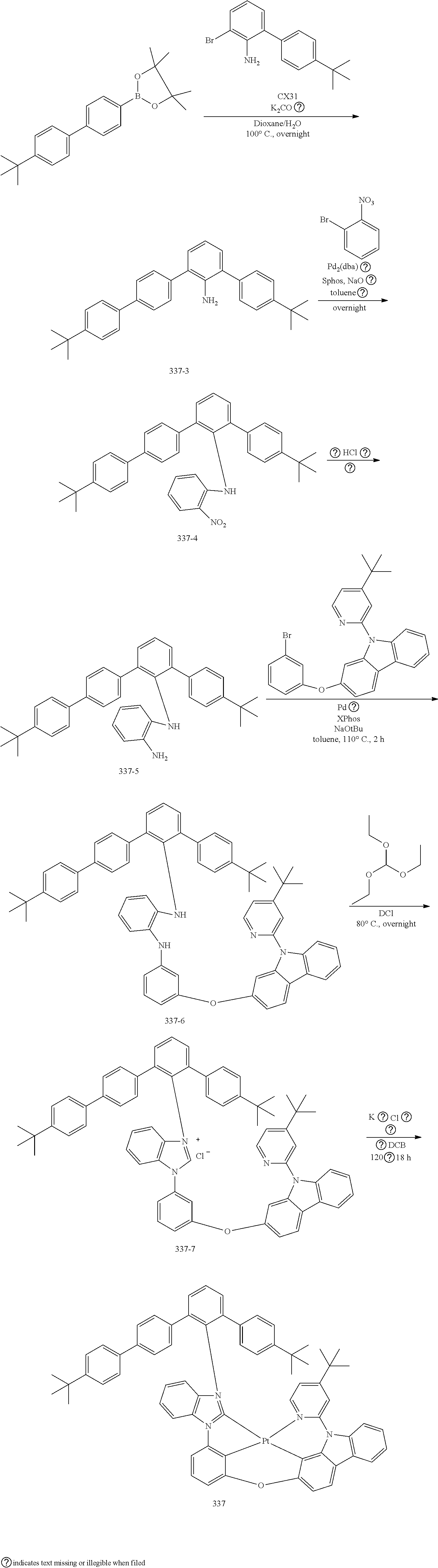

### Synthesis of Intermediate 337-3

Intermediate 337-3 was synthesized in substantially the same manner as utilized to synthesize Intermediate 14-3 of Synthesis Example 1, except that 2-(4′-(tert-butyl)-[1,1′-biphenyl]-4-yl)-4,4,5,5-tetramethyl-1,3,2-dioxaborolane and 3-bromo-4′-(tert-butyl)-[1,1′-biphenyl]-2-amine were utilized instead of Intermediate 14-2 and 3-bromo-3′,5′-di-tert-butyl-[1,1′-biphenyl]-2-amine.

### Synthesis of Intermediates 337-4 and 337-5

Intermediates 337-4 and 337-5 were sequentially synthesized in substantially the same manner as utilized to sequentially synthesize Intermediates 14-4 and 14-5 of Synthesis Example 1, except that Intermediates 337-3 and 337-4 were respectively utilized instead of Intermediates 14-3 and 14-4.

### Synthesis of Intermediate 337-6

Intermediate 337-6 was synthesized in substantially the same manner as utilized to synthesize Intermediate 14-6 of Synthesis Example 1, except that Intermediate 337-5 and 2-(3-bromophenoxy)-9-(4-(tert-butyl)pyridin-2-yl)-9H-carbazole were respectively utilized instead of Intermediate 14-5 and 2-(3-bromophenoxy)-9-(4-(2,2-dimethylpropyl-1,1-d2)pyridin-2-yl)-9H-carbazole.

### Synthesis of Intermediate 337-7

Intermediate 337-7 was synthesized in substantially the same manner as utilized to synthesize Intermediate 14-7 of Synthesis Example 1, except that Intermediate 337-6 was utilized instead of Intermediate 14-6.

### Synthesis of Compound 337

Compound 337 (yield: 48%) was synthesized in substantially the same manner as utilized to synthesize Compound 14 of Synthesis Example 1, except that Intermediate 337-7 was utilized instead of Intermediate 14-7.

ESI-LCMS for Compound 337: [M]+: C₆₆H₅₈N₄OPt, 1118.4

For the compounds synthesized in Synthesis Examples 1 to 8, high-resolution mass (HR-MS) was measured, and results thereof are shown in Table 1. Synthesis methods of other compounds in addition to the compounds synthesized in Synthesis Examples 1 to 8 may be easily recognized by those of ordinary skill in the art by referring to the synthesis paths and source materials.

TABLE 1

| | HR-MS (m/z) | |
|---|---|---|
| | [M⁺] | |
| Compound | found | calc. |
| 14 | 1138.4 | 1138.38 |
| 54 | 1178.5 | 1178.43 |
| 197 | 1100.4 | 1100.31 |
| 219 | 1123.5 | 1123.45 |
| 281 | 1132.5 | 1132.39 |
| 299 | 1200.6 | 1200.51 |
| 1 | 1006.1 | 1006.09 |
| 337 | 1118.4 | 1118.30 |

### Evaluation Example 1

According to the methods of Table 2, the HOMO and LUMO energy levels of each of Compounds 14, 54, 197, 219, 281, 299, 1, 337, A, B, and C were evaluated, and results thereof are shown in Table 3.

TABLE 2

| | |
|---|---|
| HOMO energy | By utilizing cyclic voltammetry (CV) |
| level evaluation | (electrolyte: 0.1M Bu₄NPF₆/solvent: |
| method | dimethylformamide (DMF)/electrode: |
| | 3-electrode system (working electrode: |
| | GC, reference electrode: Ag/AgCl, |
| | and auxiliary electrode: Pt)), the |
| | potential (V)-current (A) graph of |
| | each compound was obtained, and |
| | then, from the oxidation onset |
| | of the graph, the HOMO energy level |
| | of each compound was calculated. |
| LUMO energy | By utilizing cyclic voltammetry (CV) |
| level evaluation | (electrolyte: 0.1M Bu₄NPF₆/solvent: |
| method | dimethylformamide (DMF)/electrode: |
| | 3-electrode system (working electrode: |
| | GC, reference electrode: Ag/AgCl, |
| | and auxiliary electrode: Pt)), the |
| | potential (V)-current (A) graph of |
| | each compound was obtained, and then, |
| | from the reduction onset of the graph, |
| | the LUMO energy level of each compound |
| | was calculated. |

TABLE 3

| Compound No. | HOMO (eV) | LUMO (eV) |
|---|---|---|
| 14 | −5.30 | −2.05 |
| 54 | −5.29 | −2.09 |
| 197 | −5.32 | −2.12 |
| 219 | −5.30 | −2.08 |
| 281 | −5.26 | −2.06 |
| 299 | −5.28 | −2.08 |
| 1 | −5.28 | −2.08 |
| 337 | −5.26 | −2.06 |
| A | −5.30 | −2.18 |
| B | −5.32 | −2.23 |
| C | −5.26 | −1.89 |

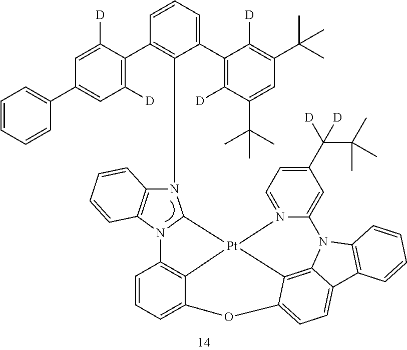

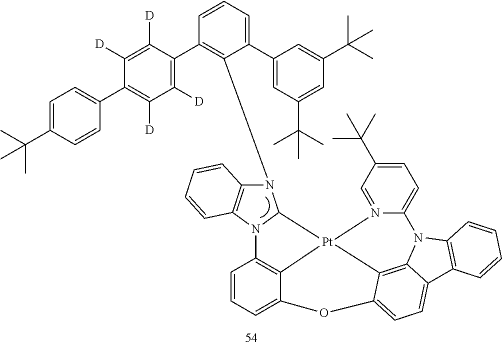

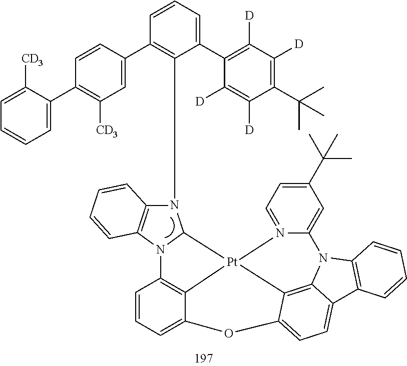

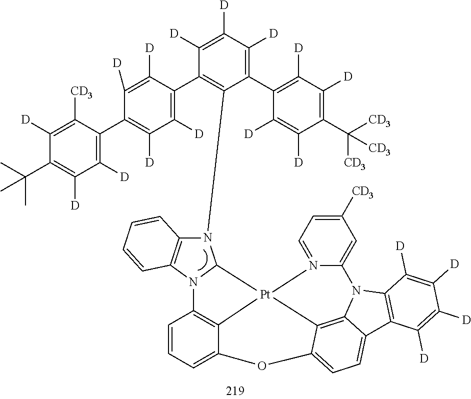

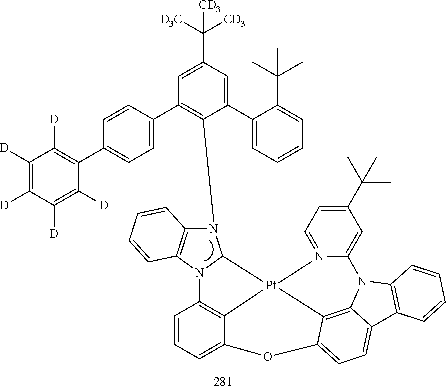

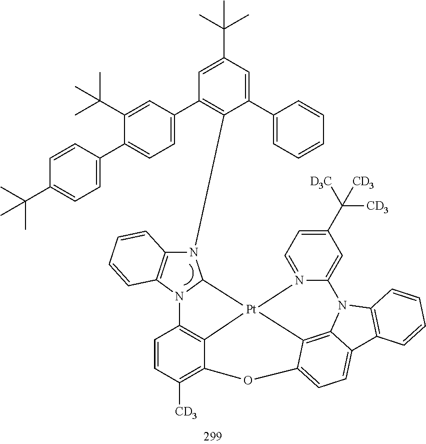

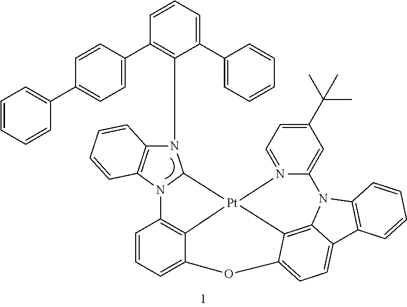

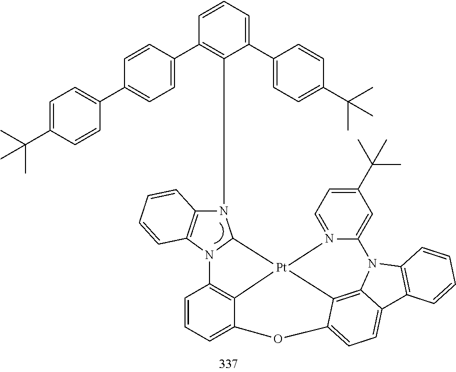

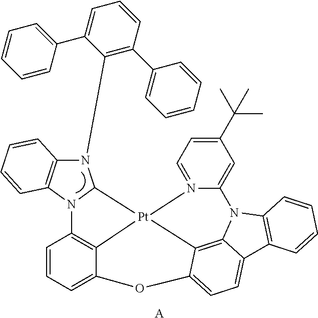

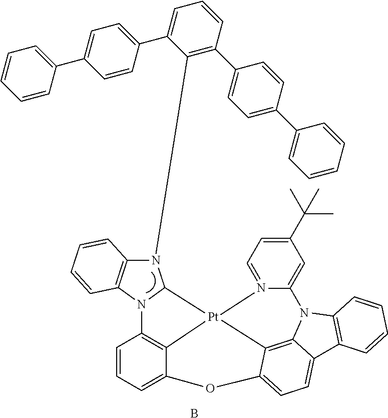

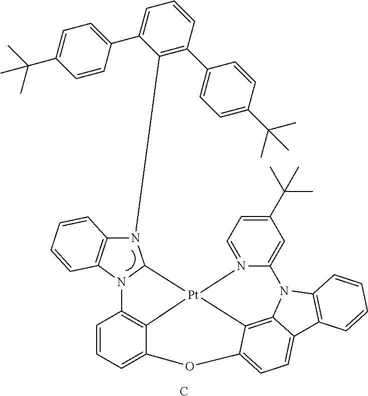

### Evaluation Example 2

After Compound 14 (2 mg), Compound ETH2 (10 mg), Compound HTH2 (10 mg), and PMMA in CH₂Cl₂ (the weight of PMMA is 50 mg) were mixed, a result obtained therefrom was coated on a quartz substrate by utilizing a spin coater, heat treated in an oven at 80° C., and then cooled to room temperature, to prepare Film 14 having a thickness of 40 nanometer (nm). Next, Films 54, 197, 219, 281, 299, 1, 337, A, B, and C were prepared in substantially the same manner as utilized to prepare Film 14, except that Compounds 54, 197, 219, 281, 299, 1, 337, A, B, and C were each utilized instead of Compound 14.

The photoluminescence (PL) spectrum of each of Films 14, 54, 197, 219, 281, 299, 1, 337, A, B, and C was measured by a Quantaurus-QY Absolute PL quantum yield spectrometer (equipped with a xenon light source, a monochromator, a photonic multichannel analyzer, and an integrating sphere, and utilizing a photoluminescence quantum yield (PLQY) measurement software (Hamamatsu Photonics, Ltd., Shizuoka, Japan)) of Hamamatsu Company. During the measurement, the excitation wavelength was scanned from 320 nm to 380 nm at intervals of 10 nm, and the spectrum measured at the excitation wavelength of 340 nm was taken to obtain the maximum emission wavelength (emission peak wavelength) and full width at half maximum (FWHM) of the organometallic compound included in each Film, which are shown in Table 4.

Next, the PLOY of each of Films 14, 54, 197, 219, 281, 299, 1, 337, A, B, and C was measured by scanning the excitation wavelength from 300 nm to 380 nm at intervals of 10 nm by utilizing a Quantaurus-QY Absolute PL quantum yield spectrometer of Hamamatsu Company, and then, the PLOY measured at the excitation wavelength of 330 nm was taken to obtain the PLOY of the organometallic compound included in each Film. Results thereof are shown in Table 4.

TABLE 4

| | Organometallic | Maximum | Emission | |
|---|---|---|---|---|
| Film | compound No. | emission | FWHM | PLQY |
| No. | included in Film | wavelength (nm) | (nm) | (%) |
| 14 | 14 | 457 | 37 | 60 |
| 54 | 54 | 457 | 38 | 57 |
| 197 | 197 | 456 | 35 | 63 |
| 219 | 219 | 457 | 38 | 58 |
| 281 | 281 | 455 | 37 | 65 |
| 299 | 299 | 455 | 36 | 61 |
| 1 | 1 | 457 | 37 | 56 |
| 337 | 337 | 455 | 35 | 59 |
| A | A | 456 | 40 | 53 |
| B | B | 458 | 41 | 47 |
| C | C | 455 | 39 | 55 |

From Table 4, it may be confirmed that each of Compounds 14, 54, 197, 219, 281, 299, 1, and 337 had improved PLOY and emitted blue light having a relatively small FWHM, as compared to Compounds A to C.

### Evaluation Example 3

Subsequently, the PL spectrum of each of Films 14, 54, 197, 219, 281, 299, 1, 337, A, B, and C was evaluated at room temperature by utilizing FluoTime 300, which is a time-resolved photoluminescence (TRPL) measurement system of PicoQuant Inc., and PLS340 (excitation wavelength=340 nm, spectral width=20 nm), which is a pumping source of PicoQuant Inc., and then, the wavelength of the main peak of the spectrum was determined. The PLS340 repeated the measure of the number of photons emitted from each Film at the wavelength of the main peak by photon pulse (pulse width=500 picoseconds) applied to each Film, based on time-correlated single photon counting (TCSPC) according to time, to obtain a TRPL curve sufficient for fitting. A result thus obtained therefrom was fitted with one or more exponential decay functions to obtain T_{decay} (Ex), that is, a decay time, of each of Films 14, 54, 197, 219, 281, 299, 1, 337, A, B, and C. Results thereof are shown in Table 5. A function for fitting is as shown in Equation 1, and from among T_{decay} obtained from each exponential decay function utilized for fitting, the largest value was obtained as T_{decay}(Ex). In this regard, the same measurement was performed during the same measurement time as that for obtaining TRPL curve in the dark state (in which pumping signals entering the set or predetermined film are blocked) to obtain a baseline or a background signal curve for utilization as a baseline for fitting.

$$f ( t ) = {\sum }_{\dot{t} = 1}^{n} {A}_{i} exp ( - t / {T}_{decay , i} ) \qquad Equation l$$

TABLE 5

| Film | Organometallic compound No. | T |
|---|---|---|
| No. | included in Film | (μs) |
| 14 | 14 | 2.05 |
| 54 | 54 | 2.01 |
| 197 | 197 | 1.98 |
| 219 | 219 | 1.99 |
| 281 | 281 | 2.08 |
| 299 | 299 | 2.10 |
| 1 | 1 | 2.15 |
| 337 | 337 | 2.09 |
| A | A | 2.25 |
| B | B | 2.67 |
| C | C | 2.45 |

From Table 5, it may be confirmed that each of Compounds 14, 54, 197, 219, 281, 299, 1, and 337 had a relatively small emission decay time, as compared to Compounds A to C.

### Example 1

As an anode, a glass substrate (product of Corning Inc.) with a 15 ohm per centimeter (Ω/cm²) (1,200 angstrom (A)) ITO formed thereon was cut to a size of 50 mm×50 mm×0.7 mm, sonicated by utilizing isopropyl alcohol and pure water each for 5 minutes, washed by irradiation of ultraviolet rays and exposure of ozone thereto for 30 minutes, and then mounted on a vacuum deposition apparatus.

2-TNATA was vacuum-deposited on the anode to form a hole injection layer having a thickness of 600 Å, and 4,4′-bis[N-(1-naphthyl)-N-phenylamino]biphenyl (hereinafter, referred as “NPB”) was vacuum-deposited on the hole injection layer to form a hole transport layer having a thickness of 300 Å.

A first compound (Compound 14), a second compound (Compound ETH2), a third compound (Compound HTH29), and a fourth compound (Compound DFD051) were vacuum-deposited on the hole transport layer to form an emission layer having a thickness of 350 Å. In this regard, the amount of the first compound was 13 wt % based on the total amount (100 wt %) of the emission layer, the amount of the fourth compound was 1.3 wt % based on the total amount (100 wt %) of the emission layer, and the weight ratio of the second compound to the third compound was adjusted to 4:6.

Compound ETH34 was vacuum-deposited on the emission layer to form a hole blocking layer having a thickness of 50 Å, and ET46 and LiQ were vacuum-deposited on the hole blocking layer at a weight ratio of 4:6 to form an electron transport layer having a thickness of 310 Å. Next, Yb was vacuum-deposited on the electron transport layer to form an electron injection layer having a thickness of 15 Å, and then Mg was vacuum-deposited thereon to form a cathode having a thickness of 800 Å, thereby completing manufacture of an organic light-emitting device.

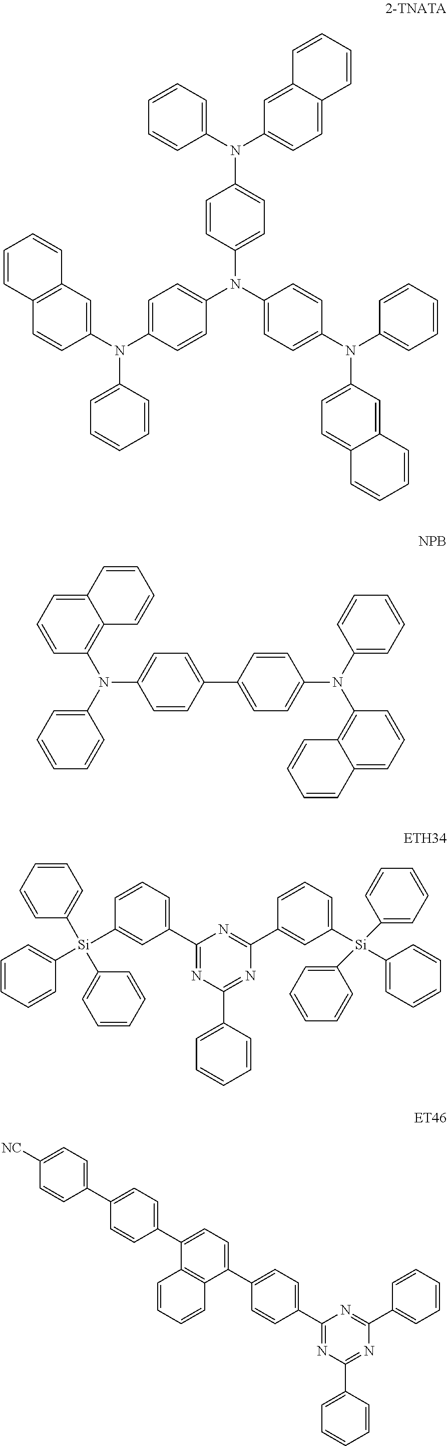 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; N#Cc1ccc(-c2ccc(-c3ccc(-c4ccc(-c5nc(-c6ccccc6)nc(-c6ccccc6)n5)cc4)c4ccccc34)cc2)cc1]

### Examples 2 to 8 and Comparative Examples A to C

Organic light-emitting devices were manufactured in substantially the same manner as in Example 1, except that, in forming the emission layer, compounds shown in Table 6 were each utilized instead of Compound 14 as the first compound. The weight in parentheses in Table 6 indicates the weight of the corresponding compound based on 100 wt % of the emission layer.

### Evaluation Example 4

Each of the driving voltage (V) at 1,000 (candela per square meter (cd/m²)), color coordinate value (CIE(y)), y color conversion efficiency (candela per ampere per “y” (cd/A/y)), maximum emission wavelength (nanometer (nm)), and lifespan (T₉₅) of the organic light-emitting devices manufactured in Examples 1 to 8 and Comparative Examples A to C were measured utilizing the Keithley MU 236 and the luminance meter PR650, and results thereof are shown in Table 7. In Table 7, the lifespan (T₉₅) is a measure of the time (hour (h)) taken until the luminance reaches 95% of the initial luminance, and is expressed as a relative value (%).

TABLE 6

| | | | | | Weight ratio of |
|---|---|---|---|---|---|
| | | | | | second |
| | First | Second | Third | Fourth | compound to |
| No. | compound | compound | compound | compound | third compound |
| Example 1 | 14 | ETH2 | HTH29 | DFD051 | 4:6 |
| | (13 wt %) | | | (1.3 wt %) | |
| Example 2 | 54 | ETH2 | HTH29 | DFD051 | 4:6 |
| | (13 wt %) | | | (1.3 wt %) | |
| Example 3 | 197 | ETH2 | HTH29 | DFD051 | 4:6 |
| | (13 wt %) | | | (1.3 wt %) | |
| Example 4 | 219 | ETH2 | HTH29 | DFD051 | 4:6 |
| | (13 wt %) | | | (1.3 wt %) | |
| Example 5 | 281 | ETH2 | HTH29 | DFD051 | 4:6 |
| | (13 wt %) | | | (1.3 wt %) | |
| Example 6 | 299 | ETH2 | HTH29 | DFD051 | 4:6 |
| | (13 wt %) | | | (1.3 wt %) | |
| Example 7 | 1 | ETH2 | HTH29 | DFD051 | 4:6 |
| | (13 wt %) | | | (1.3 wt %) | |
| Example 8 | 337 | ETH2 | HTH29 | DFD051 | 4:6 |
| | (13 wt %) | | | (1.3 wt %) | |
| Comparative | A | ETH2 | HTH29 | DFD051 | 4:6 |
| Example A | (13 wt %) | | | (1.3 wt %) | |
| Comparative | B | ETH2 | HTH29 | DFD051 | 4:6 |
| Example B | (13 wt %) | | | (1.3 wt %) | |
| Comparative | C | ETH2 | HTH29 | DFD051 | 4:6 |
| Example C | (13 wt %) | | | (1.3 wt %) | |

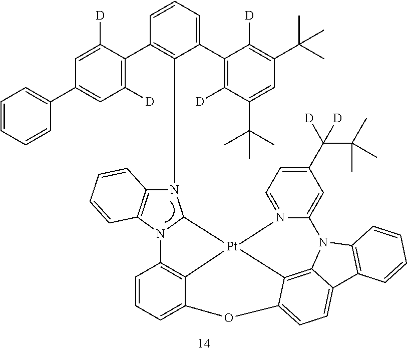

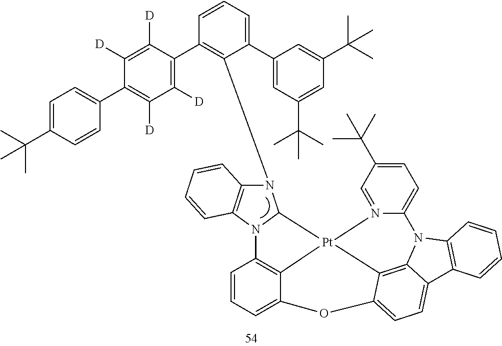

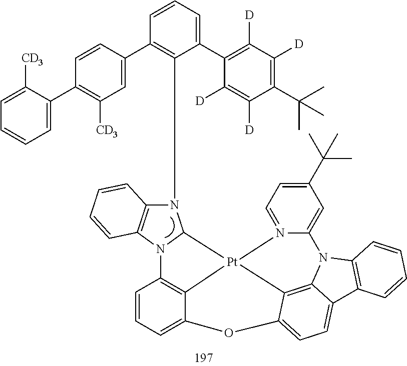

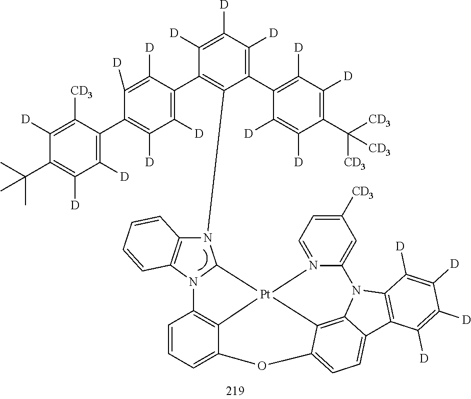

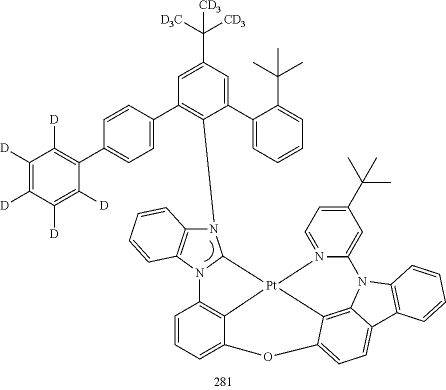

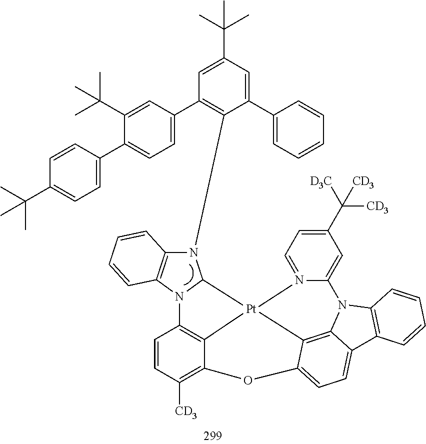

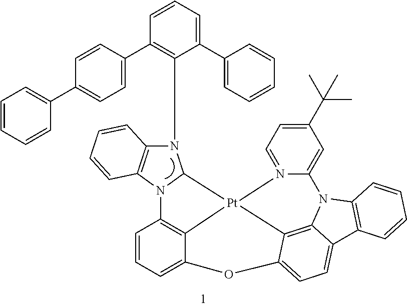

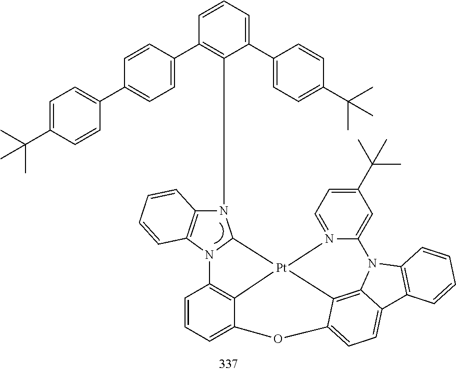

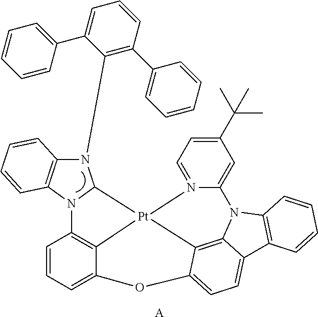

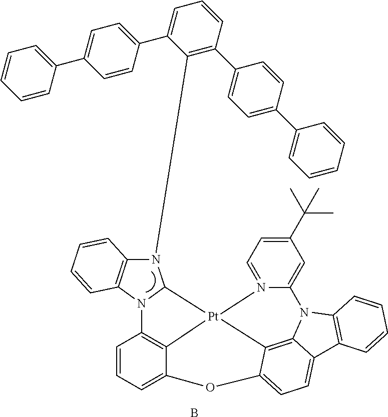

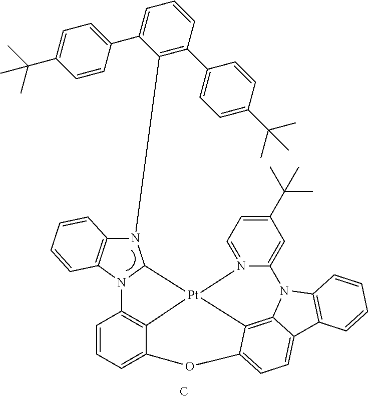

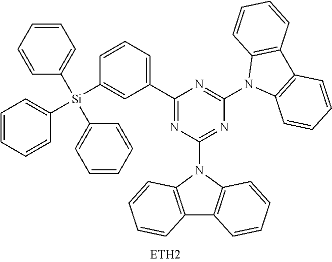 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

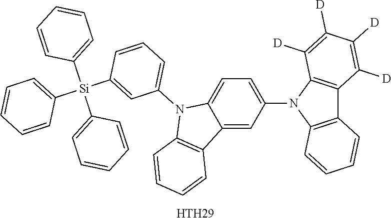

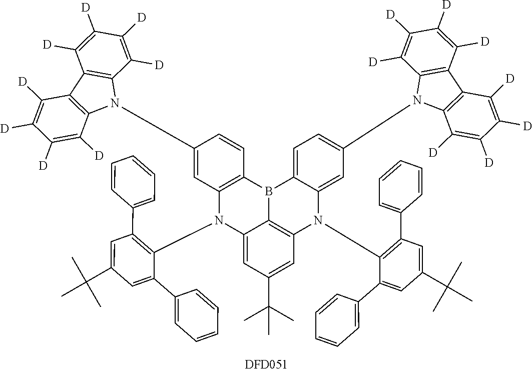

TABLE 7

| | | | | | Color | Maximum | Lifespan |
|---|---|---|---|---|---|---|---|
| | | | Driving | | conversion | emission | (T₉₅) |
| | First | Fourth | Voltage | | Efficiency | wavelength | (Relative |
| No. | compound | compound | (V) | CIE(y) | (cd/A/y) | (nm) | value, %) |
| Example 1 | 14 | DFD051 | 4.14 | 0.109 | 152.4 | 462 | 168 |
| Example 2 | 54 | DFD051 | 4.11 | 0.104 | 145.6 | 461 | 160 |
| Example 3 | 197 | DFD051 | 4.19 | 0.106 | 155.7 | 461 | 179 |
| Example 4 | 219 | DFD051 | 4.21 | 0.105 | 148.9 | 461 | 184 |
| Example 5 | 281 | DFD051 | 4.25 | 0.112 | 159.3 | 462 | 158 |
| Example 6 | 299 | DFD051 | 4.23 | 0.114 | 155.4 | 462 | 151 |
| Example 7 | 1 | DFD051 | 4.26 | 0.120 | 137.2 | 463 | 145 |
| Example 8 | 337 | DFD051 | 4.24 | 0.118 | 142.5 | 462 | 149 |
| Comparative | A | DFD051 | 4.32 | 0.117 | 129.8 | 462 | 125 |
| Example | | | | | | | |
| A | | | | | | | |
| Comparative | B | DFD051 | 4.46 | 0.126 | 117.3 | 465 | 100 |
| Example | | | | | | | |
| B | | | | | | | |
| Comparative | C | DFD051 | 4.37 | 0.121 | 132.4 | 463 | 117 |
| Example | | | | | | | |
| C | | | | | | | |

From Table 7, it may be confirmed that the organic light-emitting devices of Examples 1 to 6 each emitted deep blue light and had excellent or suitable driving voltage, excellent or suitable color purity, excellent or suitable luminescence efficiency, excellent or suitable color conversion efficiency, and excellent or suitable lifespan characteristics. It may also be confirmed that the organic light-emitting devices of Examples 7 and 8 each emitted deep blue light and had improved characteristics in terms of driving voltage, color purity, color conversion efficiency, and lifespan, as compared to Comparative Examples A to C.

### Examples 11 to 18 and Comparative Examples 1A to 1C

Organic light-emitting devices were manufactured in substantially the same manner as in Example 1, except that, in forming the emission layer, compounds shown in Table 8 were each utilized as the first compound and the fourth compound, and the amounts of the first compound and the fourth compound and the weight ratio of the second compound to the third compound were each adjusted to those as shown in Table 8. The weight in parentheses in Table 8 indicates the weight of the corresponding compound based on 100 wt % of the emission layer.

### Evaluation Example 5

Each of the driving voltage (V) at 1,000 cd/m², y color coordinate value (CIE(y)), color conversion efficiency (cd/A/y), maximum emission wavelength (nm), and lifespan (T₉₅) of the organic light-emitting devices manufactured in Examples 11 to 18 and Comparative Examples 1A to 1C was measured in substantially the same manner as utilized in Evaluation Example 4, and results thereof are shown in Table 9. In Table 9, the lifespan (T₉₅) is a measure of the time (h) taken until the luminance reaches 95% of the initial luminance, and is expressed as a relative value (%).

TABLE 8

| | | | | | Weight ratio of |
|---|---|---|---|---|---|
| | | | | | second |
| | First | Second | Third | Fourth | compound to |
| No. | compound | compound | compound | compound | third compound |
| Example | 14 | ETH2 | HTH29 | DFD7 | 3:7 |
| 11 | (14 wt %) | | | (1.0 wt %) | |
| Example | 54 | ETH2 | HTH29 | DFD7 | 3:7 |
| 12 | (14 wt %) | | | (1.0 wt %) | |
| Example | 197 | ETH2 | HTH29 | DFD7 | 3:7 |
| 13 | (14 wt %) | | | (1.0 wt %) | |
| Example | 219 | ETH2 | HTH29 | DFD7 | 3:7 |
| 14 | (14 wt %) | | | (1.0 wt %) | |
| Example | 281 | ETH2 | HTH29 | DFD7 | 3:7 |
| 15 | (14 wt %) | | | (1.0 wt %) | |
| Example | 299 | ETH2 | HTH29 | DFD7 | 3:7 |
| 16 | (14 wt %) | | | (1.0 wt %) | |
| Example | 1 | ETH2 | HTH29 | DFD7 | 3:7 |
| 17 | (14 wt %) | | | (1.0 wt %) | |
| Example | 337 | ETH2 | HTH29 | DFD7 | 3:7 |
| 18 | (14 wt %) | | | (1.0 wt %) | |
| Comparative | A | ETH2 | HTH29 | DFD7 | 3:7 |
| Example | (14 wt %) | | | (1.0 wt %) | |
| 1A | | | | | |
| Comparative | B | ETH2 | HTH29 | DFD7 | 3:7 |
| Example | (14 wt %) | | | (1.0 wt %) | |
| 1B | | | | | |
| Comparative | C | ETH2 | HTH29 | DFD7 | 3:7 |
| Example | (14 wt %) | | | (1.0 wt %) | |
| 1C | | | | | |

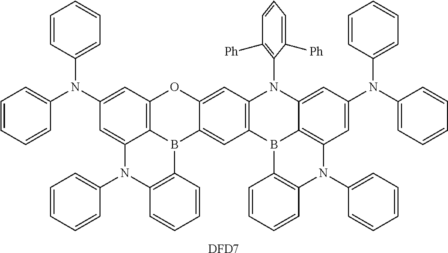

TABLE 9

| | | | | | Color | Maximum | Lifespan |
|---|---|---|---|---|---|---|---|
| | | | Driving | | conversion | emission | (T₉₅) |
| | First | Fourth | Voltage | | Efficiency | wavelength | (Relative |
| No. | compound | compound | (V) | CIE(y) | (cd/A/y) | (nm) | value, %) |
| Example | 14 | DFD07 | 4.36 | 0.133 | 129.8 | 463 | 179 |
| 11 | | | | | | | |
| Example | 54 | DFD07 | 4.42 | 0.128 | 123.4 | 462 | 182 |
| 12 | | | | | | | |
| Example | 197 | DFD07 | 4.51 | 0.124 | 122.3 | 462 | 167 |
| 13 | | | | | | | |
| Example | 219 | DFD07 | 4.53 | 0.136 | 121.7 | 463 | 202 |
| 14 | | | | | | | |
| Example | 281 | DFD07 | 4.47 | 0.139 | 136.6 | 464 | 173 |
| 15 | | | | | | | |
| Example | 299 | DFD07 | 4.43 | 0.121 | 130.2 | 464 | 171 |
| 16 | | | | | | | |
| Example | 1 | DFD07 | 4.49 | 0.138 | 117.8 | 464 | 149 |
| 17 | | | | | | | |
| Example | 337 | DFD07 | 4.45 | 0.132 | 119.5 | 463 | 158 |
| 18 | | | | | | | |
| Comparative | A | DFD07 | 4.61 | 0.137 | 115.7 | 465 | 137 |
| Example | | | | | | | |
| 1A | | | | | | | |
| Comparative | B | DFD07 | 4.72 | 0.154 | 103.4 | 466 | 100 |
| Example | | | | | | | |
| 1B | | | | | | | |
| Comparative | C | DFD07 | 4.68 | 0.145 | 118.3 | 465 | 122 |
| Example | | | | | | | |
| 1C | | | | | | | |

From Table 9, it may be confirmed that the organic light-emitting devices of Examples 11 to 16 each emitted deep blue light and had excellent or suitable driving voltage, excellent or suitable color purity, excellent or suitable luminescence efficiency, excellent or suitable color conversion efficiency, and excellent or suitable lifespan characteristics. It may also be confirmed that the organic light-emitting devices of Examples 17 and 18 each emitted deep blue light and had improved characteristics in terms of driving voltage, color purity, color conversion efficiency, and lifespan, as compared to Comparative Examples 1A to 1C.

The organometallic compound has excellent or suitable processability and excellent or suitable electrical characteristics, and thus a light-emitting device including the organometallic compound may have improved color purity, improved luminescence efficiency, and improved lifespan.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A composition comprising:
an organometallic compound represented by Formula 1; and
a second compound comprising at least one π electron-deficient nitrogen-containing C₁-C₆₀ heterocyclic group, a third compound comprising a group represented by Formula 3, a fourth compound capable of emitting delayed fluorescence, or a combination thereof,
wherein the organometallic compound, the second compound, the third compound, and the fourth compound are different from each other: 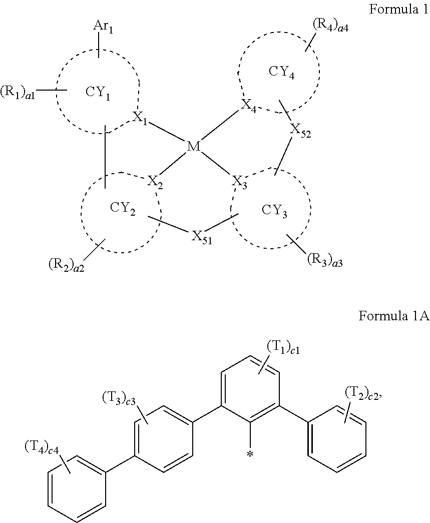
wherein Ar₁ in Formula 1 is a group represented by Formula 1A,
* in Formula 1A indicates a binding site to ring CY₁ in Formula 1,
in Formula 1 and Formula 1A,
M is platinum (Pt), palladium (Pd), gold (Au), nickel (Ni), silver (Ag), or copper (Cu),
X₁ to X₄ are each independently C or N,
i) a bond between X₁ and M is a coordinate bond,
ii) one selected from among a bond between X₂ and M, a bond between X₃ and M, and a bond between X₄ and M is a coordinate bond and two selected from among the bond between X₂ and M, the bond between X₃ and M, and the bond between X₄ and M is each a covalent bond,
ring CY₁ to ring CY₄ are each independently a C₃-C₆₀ carbocyclic group or a C₁-C₆₀ heterocyclic group,
X₅₁ is a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′ *—O—*, *—C(═O)—*′, *—S(═O)—*′, *—S(═O)₂—*′, *—C(Z₅₁ₐ)=*′, *=C(Z₅₁ₐ)—*′, *—C(Z₅₁ₐ)═C(Z_{51b})—*′, *—C(═S)—*′, or *—C≡C—*′,
X₅₂ is a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′ *—O—*, *—C(═O)—*, *—S(═O)—*, *—S(=O)₂—*′, *—C(Z₅₂ₐ)=*′, *=C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, Z_{52b}, and T₁ to T₄ are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a1 to a4 are each independently an integer from 0 to 10,
c1 is an integer from 1 to 3,
c2 and c4 are each independently an integer from 1 to 5,
c3 is an integer from 1 to 4,
in Formula 1A, a group represented by 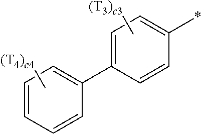
and a group represented by 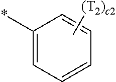
are different from each other,
two or more selected from among R₁, R₂, R₃, R₄, Z₅₁ₐ, Z_{51b}, Z₅₂ₐ, Z_{52b}, T₁, T₂, T₃, and T₄ are optionally bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof: 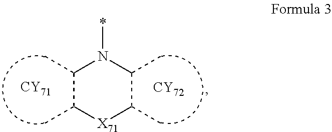
and
wherein, in Formula 3,
ring CY₇₁ and ring CY₇₂ are each independently a π electron-rich C₃-C₆₀ cyclic group or a pyridine group,
X₇₁ is a single bond, or a linking group comprising O, S, N, B, C, Si, or a combination thereof, and
* in Formula 3 indicates a binding site to an atom in the third compound that is not included in Formula 3.

2. A light-emitting device comprising:
a first electrode;
a second electrode facing the first electrode;
an interlayer between the first electrode and the second electrode and comprising an emission layer; and
an organometallic compound represented by Formula 1: 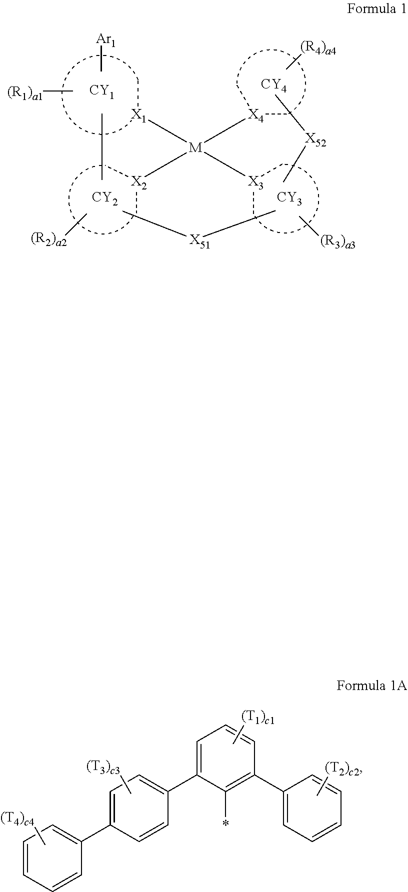
wherein Ar₁ in Formula 1 is a group represented by Formula 1A,
* in Formula 1A indicates a binding site to ring CY₁ in Formula 1,
in Formulae 1 and 1 Å,
M is platinum (Pt), palladium (Pd), gold (Au), nickel (Ni), silver (Ag), or copper (Cu),
X₁ to X₄ are each independently C or N,
i) a bond between X₁ and M is a coordinate bond,
ii) one selected from among a bond between X₂ and M, a bond between X₃ and M, and a bond between X₄ and M is a coordinate bond and two selected from among the bond between X₂ and M, the bond between X₃ and M, and the bond between X₄ and M is each a covalent bond,
ring CY₁ to ring CY₄ are each independently a C₃-C₆₀ carbocyclic group or a C₁-C₆₀ heterocyclic group,
X₅₁ is a single bond, *—N(Z₅₁ₐ)—*, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*, *—S—*, *—Se—*′, *—O—*, *—C(═O)—*′, *—S(═O)—*′, *—S(=O)₂—*′, *—C(Z₅₁ₐ)=*′, *=C(Z₅₁ₐ)—*′, *—C(Z₅₁ₐ)═C(Z_{51b})—*′, *—C(═S)—*′, or *—C≡C—*′,
X₅₂ is a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′ *—O—*, *—C(═O)—*, *—S(═O)—*, *—S(=O)₂—*′, *—C(Z₅₂ₐ)=*′, *=C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, Z_{52b}, and T₁ to T₄ are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a1 to a4 are each independently an integer from 0 to 10,
c1 is an integer from 1 to 3,
c2 and c4 are each independently an integer from 1 to 5,
c3 is an integer from 1 to 4,
in Formula 1A, a group represented by 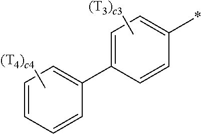
and a group represented by 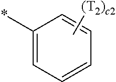
are different from each other,
two or more selected from among R₁, R₂, R₃, R₄, Z₅₁ₐ, Z_{51b}, Z₅₂ₐ, Z_{52b}, T₁, T₂, T₃, and T₄ are optionally bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently hydrogen; deuterium; —F; —C₁; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

3. The light-emitting device of claim 2, further comprising a second compound comprising at least one π electron-deficient nitrogen-containing C₁-C₆₀ heterocyclic group, a third compound comprising a group represented by Formula 3, a fourth compound capable of emitting delayed fluorescence, or any combination thereof,
wherein the organometallic compound, the second compound, the third compound, and the fourth compound are different from each other: 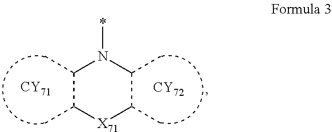
and
wherein, in Formula 3,
ring CY₇₁ and ring CY₇₂ are each independently a π electron-rich C₃-C₆₀ cyclic group or a pyridine group,
X₇₁ is a single bond, or a linking group comprising O, S, N, B, C, Si, or a combination thereof, and
* in Formula 3 indicates a binding site to an atom in the third compound that is not included in Formula 3.

4. The light-emitting device of claim 3, wherein the second compound comprises a pyridine group, a pyrimidine group, a pyrazine group, a pyridazine group, a triazine group, or a combination thereof, and
the fourth compound is a compound comprising at least one cyclic group comprising each of boron (B) and nitrogen (N) as a ring-forming atom.

5. The light-emitting device of claim 3, wherein the emission layer comprises:
i) the organometallic compound represented by Formula 1; and
ii) the second compound, the third compound, the fourth compound, or a combination thereof, and
the emission layer is configured to emit blue light.

6. The light-emitting device of claim 3, comprising the second compound and the third compound, wherein at least one of the second compound or the third compound comprises at least one deuterium, at least one silicon, or a combination thereof.

7. An electronic apparatus, the electronic apparatus comprising the light-emitting device of claim 2.

8. The electronic apparatus of claim 7, further comprising a color filter, a color conversion layer, a touch screen layer, a polarizing layer, or a combination thereof.

9. An electronic equipment, the electronic equipment comprising the light-emitting device of claim 2.

10. The electronic equipment of claim 9, wherein the electronic equipment is at least one selected from among a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, and a signboard, or a combination thereof.

11. An organometallic compound represented by Formula 1: 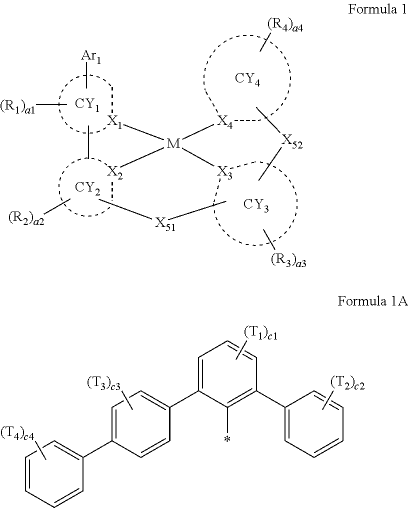
wherein Ar₁ in Formula 1 is a group represented by Formula 1A,
* in Formula 1A indicates a binding site to ring CY₁ in Formula 1,
in Formula 1 and Formula 1A,
M is platinum (Pt), palladium (Pd), gold (Au), nickel (Ni), silver (Ag), or copper (Cu),
X₁ to X₄ are each independently C or N,
i) a bond between X₁ and M is a coordinate bond,
ii) one selected from among a bond between X₂ and M, a bond between X₃ and M, and a bond between X₄ and M is a coordinate bond, and two selected from among a bond between X₂ and M, a bond between X₃ and M, and a bond between X₄ and M is each a covalent bond,
ring CY₁ to ring CY₄ are each independently a C₃-C₆₀ carbocyclic group or a C₁-C₆₀ heterocyclic group,
X₅₁ is a single bond, *—N(Z₅₁ₐ)—*′, *—B(Z₅₁ₐ)—*′, *—P(Z₅₁ₐ)—*′, *—C(Z₅₁ₐ)(Z_{51b})—*′, *—Si(Z₅₁ₐ)(Z_{51b})—*′, *—Ge(Z₅₁ₐ)(Z_{51b})—*′, *—S—*′, *—Se—*′ *—O—*, *—C(═O)—*′, *—S(═O)—*′, *—S(=O)₂—*′, *—C(Z₅₁ₐ)=*′, *=C(Z₅₁ₐ)—*′, *—C(Z₅₁ₐ)═C(Z_{51b})—*′, *—C(═S)—*′, or *—C≡C—*′,
X₅₂ is a single bond, *—N(Z₅₂ₐ)—*′, *—B(Z₅₂ₐ)—*′, *—P(Z₅₂ₐ)—*′, *—C(Z₅₂ₐ)(Z_{52b})—*′, *—Si(Z₅₂ₐ)(Z_{52b})—*′, *—Ge(Z₅₂ₐ)(Z_{52b})—*′, *—S—*′, *—Se—*′ *—O—*, *—C(═O)—*, *—S(═O)—*, *—S(=O)₂—*′, *—C(Z₅₂ₐ)=*′, *=C(Z₅₂ₐ)—*′, *—C(Z₅₂ₐ)═C(Z_{52b})—*′, *—C(═S)—*′, or *—C≡C—*′,
R₁ to R₄, Z₅₁ₐ, Z_{51b}, Z₅₂ₐ, Z_{52b}, and T₁ to T₄ are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a1 to a4 are each independently an integer from 0 to 10,
c1 is an integer from 1 to 3,
c2 and c4 are each independently an integer from 1 to 5,
c3 is an integer from 1 to 4,
in Formula 1A, a group represented by 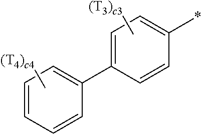
and a group represented by 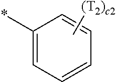
are different from each other,
two or more selected from among R₁, R₂, R₃, R₄, Z₅₁ₐ, Z_{51b}, Z₅₂ₐ, Z_{52b}, T₁, T₂, T₃, and T₄ are optionally bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

12. The organometallic compound of claim 11, wherein X₁ is C, and
ring CY₁ is an imidazole group, a triazole group, a benzimidazole group, a naphthoimidazol group, or an imidazopyridine group.

13. The organometallic compound of claim 1, wherein R₁ to R₄, Z₅₁ₐ, Z_{51b}, Z₅₂ₐ, Z_{52b}, and T₁ to T₄ are each independently:
hydrogen, deuterium, —F, or a cyano group;
a C₁-C₂₀ alkyl group that is unsubstituted or substituted with deuterium, —F, a cyano group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof; or
a C₃-C₁₀ cycloalkyl group, a phenyl group, a naphthyl group, a dibenzofuranyl group, or a dibenzothiophenyl group, each unsubstituted or substituted with deuterium, —F, cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, or a combination thereof.

14. The organometallic compound of claim 11, wherein T₁ to T₄ are each independently:
hydrogen, deuterium, —F, or a cyano group; or
a C₁-C₂₀ alkyl group that is unsubstituted or substituted with deuterium, —F, a cyano group, or a combination thereof.

15. The organometallic compound of claim 11, comprising at least one deuterium.

16. The organometallic compound of claim 11, wherein Formula 1A satisfies one selected from among Condition C1 to Condition C3:
Condition C1
T₁ is hydrogen or deuterium;
Condition C2
one of T₁ is:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₁ are hydrogen or deuterium; and
Condition C3
two of T₁ are each independently:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₁ is hydrogen or deuterium.

17. The organometallic compound of claim 11, wherein Formula 1A satisfies one selected from among Condition D1 to Condition D4:
Condition D1
T₂ is hydrogen or deuterium;
Condition D2
one of T₂ is:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₂ are hydrogen or deuterium;
Condition D3
two of T₂ are each independently:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₂ are hydrogen or deuterium; and
Condition D4
three of T₂ are each independently:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₂ are hydrogen or deuterium.

18. The organometallic compound of claim 11, wherein Formula 1A satisfies one selected from among Condition E1 to Condition E3:
Condition E1
T₃ is hydrogen or deuterium;
Condition E2
one of T₃ is:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₃ are hydrogen or deuterium; and
Condition E3
two of T₃ are each independently:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₃ are hydrogen or deuterium.

19. The organometallic compound of claim 11, wherein Formula 1A satisfies one selected from among Condition F1 to Condition F4:
Condition F1
T₄ is hydrogen or deuterium;
Condition F2
one of T₄ is:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₄ are hydrogen or deuterium;
Condition F3
two of T₄ are each independently:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₄ are hydrogen or deuterium; and
Condition F4
three of T₄ are each independently:
a C₁-C₂₀ alkyl group that is unsubstituted or substituted with at least one deuterium; or
a C₆-C₂₀ aryl group that is unsubstituted or substituted with deuterium, a C₁-C₂₀ alkyl group, a deuterated C₁-C₂₀ alkyl group, or any combination thereof, and any remaining T₄ are hydrogen or deuterium.

20. The organometallic compound of claim 11, wherein the organometallic compound is represented by Formula 1-1 or Formula 1-2: 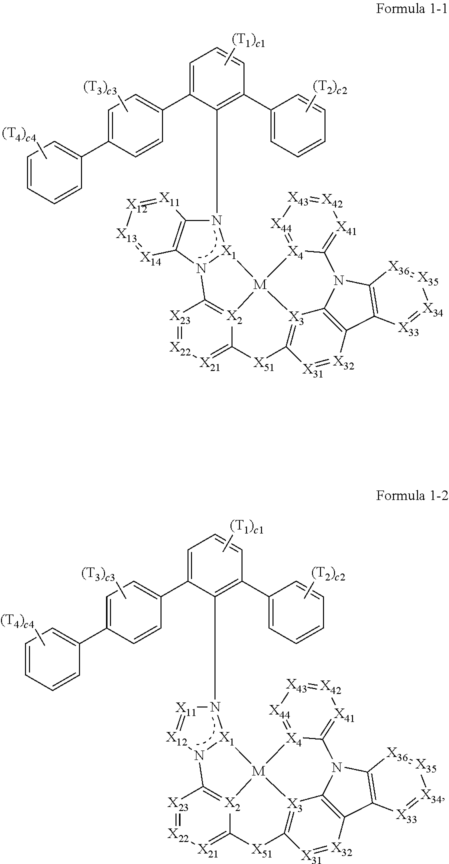
and
wherein, in Formula 1-1 and Formula 1-2,
M, X₁ to X₄, X₅₁, T₁ to T₄, and c1 to c4 are each as described for Formula 1 and Formula 1A,
X₁₁ is C(R₁₁) or N, X₁₂ is C(R₁₂) or N, X₁₃ is C(R₁₃) or N, and X₁₄ is C(R₁₄) or N,
R₁ to R₁₄ are each as described in connection with R₁ for Formula 1, wherein two or more selected from among R₁₁ to R₁₄ are optionally bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₂₁ is C(R₂₁) or N, X₂₂ is C(R₂₂) or N, and X₂₃ is C(R₂₃) or N,
R₂₁ to R₂₃ are each as described in connection with R₂ for Formula 1, wherein two or more selected from among R₂₁ to R₂₃ are optionally bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₃₁ is C(R₃₁) or N, X₃₂ is C(R₃₂) or N, X₃₃ is C(R₃₃) or N, X₃₄ is C(R₃₄) or N, X₃₅ is C(R₃₅) or N, and X₃₆ is C(R₃₆) or N,
R₃₁ to R₃₆ are each as described in connection with R₃ for Formula 1, wherein two or more selected from among R₃₁ to R₃₆ are optionally bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₄₁ is C(R₄₁) or N, X₄₂ is C(R₄₂) or N, X₄₃ is C(R₄₃) or N, and X₄₄ is C(R₄₄) or N,
R₄₁ to R₄₄ are each as described in connection with R₄ for Formula 1, wherein two or more selected from among R₄₁ to R₄₄ are optionally bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
a group represented by 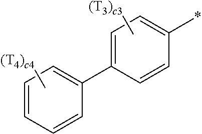
and a group represented by 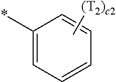
are different from each other, and
* indicates a binding site to a neighboring atom,
R₁₀ₐ is the same as defined in claim 11.
